(19) United States
(12) Patent Application Publication
(10) Pub. No.: US 2026/0090193 A1
(43) Pub. Date: Mar. 26, 2026

(54) LIGHT-EMITTING ELEMENT, FUSED POLYCYCLIC COMPOUND FOR LIGHT-EMITTING ELEMENT, AND ELECTRONIC APPARATUS INCLUDING THE LIGHT-EMITTING ELEMENT

(71) Applicant: Samsung Display Co., Ltd., Yongin-si (KR)

(72) Inventors: Hyungjong KIM, Yongin-si (KR); TAEIL KIM, Yongin-si (KR); Hirokazu MIYASHITA, Yongin-si (KR); JUNHA PARK, Yongin-si (KR); MUN-KI SIM, Yongin-si (KR); MINJUNG JUNG, Yongin-si (KR); Seonhyoung HUR, Yongin-si (KR)

(73) Assignee: Samsung Display Co., Ltd., Yongin-si (KR)

(21) Appl. No.: 19/330,963

(22) Filed: Sep. 17, 2025

(30) Foreign Application Priority Data
Sep. 23, 2024 (KR) 10-2024-0127986

(51) Int. Cl. H10K 50/12; H10K 59/38; H10K 85/30; H10K 85/40; H10K 85/60

(52) U.S. Cl. CPC H10K 50/12; H10K 59/38; H10K 85/342; H10K 85/346; H10K 85/40; H10K 85/623; H10K 85/626; H10K 85/633; H10K 85/636; H10K 85/654; H10K 85/6572; H10K 85/6574; H10K 85/6576; H10K 85/658

(57) ABSTRACT

Embodiments provide a fused polycyclic compound, a light-emitting element that includes the fused polycyclic compound, and an electronic apparatus that includes the light-emitting element. The light-emitting element includes a first electrode, a second electrode disposed on the first electrode, and an emission layer disposed between the first electrode and the second electrode; and the emission layer includes the fused polycyclic compound. The fused polycyclic compound is represented by Formula 1, which is explained in the specification.

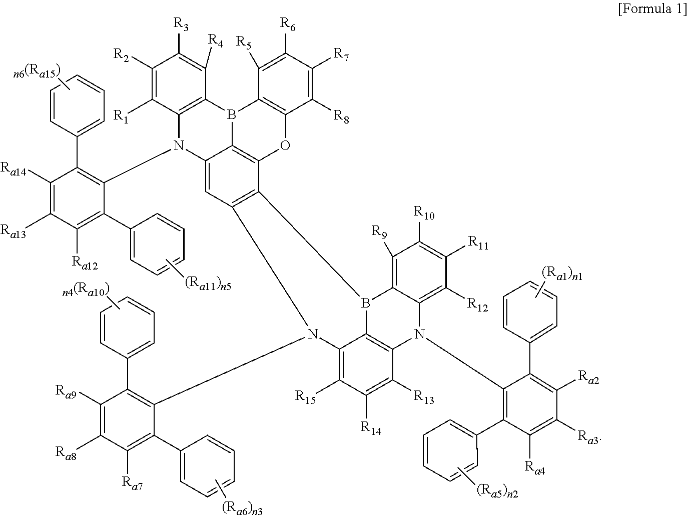

### CROSS-REFERENCE TO RELATED APPLICATION(S)

This application claims priority to and benefits of Korean Patent Application No. 10-2024-0127986 under 35 U.S.C. § 119, filed on Sep. 23, 2024, in the Korean Intellectual Property Office, the entire contents of which are incorporated herein by reference.

### BACKGROUND

### 1. Technical Field

The disclosure relates to a light-emitting element, a fused polycyclic compound used for the light-emitting element, and a display device including the light-emitting element.

### 2. Description of the Related Art

Ongoing development continues for organic electroluminescence display devices and the like as image display devices. The organic electroluminescence display devices and the like are display devices that include so-called self-emissive light-emitting elements in which holes and electrons respectively injected from a first electrode and a second electrode recombine in an emission layer, so that in the emission layer, an emission material emits light to achieve display.

In the application of a light-emitting element to a display device, there is a persistent demand for improvements in lifespan and the like. Thus, continuous development is required for materials for light-emitting elements that are capable of stably achieving such characteristics.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a light-emitting element having improved color purity and lifespan, and a display device including the same.

The disclosure also provides a fused polycyclic compound, which improves color purity and lifespan, as a material for the light-emitting element.

According to an embodiment, a light-emitting element may include a first electrode, a second electrode disposed on the first electrode, and an emission layer disposed between the first electrode and the second electrode, wherein the emission layer may include a first compound represented by Formula 1.

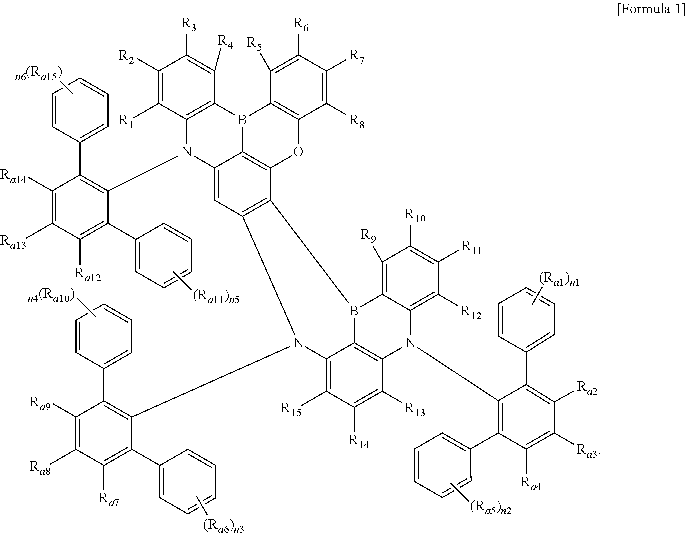

In Formula 1, n1 to n6 may each independently be an integer from 0 to 5; R₁ to R₁₅ and R₁ to Rₐ₁₅ may each independently be a hydrogen atom, a deuterium atom, a halogen atom, a cyano group, a nitro group, a substituted or unsubstituted silyl group, a substituted or unsubstituted amine group, a substituted or unsubstituted oxy group, a substituted or unsubstituted thio group, a substituted or unsubstituted selenium group, a substituted or unsubstituted alkyl group having 1 to 60 carbons, a substituted or unsubstituted cycloalkyl group having 3 to 60 carbons, a substituted or unsubstituted alkenyl group having 2 to 60 carbons, a substituted or unsubstituted hydrocarbon ring group having 6 to 60 ring-forming carbons, or a substituted or unsubstituted heterocyclic group having 2 to 60 ring-forming carbons, or bonded to an adjacent group to form a ring.

In an embodiment, the emission layer may further include at least one of a second compound represented by Formula HT-1, a third compound represented by Formula ET-1, and a fourth compound represented by Formula D-1.

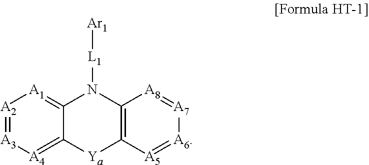

In Formula HT-1, A₁ to A₈ may each independently be N or C(R₅₁); L₁ may be a direct linkage, a substituted or unsubstituted arylene group having 6 to 30 ring-forming carbons, or a substituted or unsubstituted heteroarylene group having 2 to 30 ring-forming carbons; Yₐ may be a direct linkage, C(R₅₂)(R₅₃), or Si(R₅₄)(R₅₅); Ar₁ may be a substituted or unsubstituted aryl group having 6 to 30 ring-forming carbons or a substituted or unsubstituted heteroaryl group having 2 to 30 ring-forming carbons; and R₅₁ to R₅₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbons, a substituted or unsubstituted alkenyl group having 2 to 20 carbons, a substituted or unsubstituted aryl group having 6 to 60 ring-forming carbons, or a substituted or unsubstituted heteroaryl group having 2 to 60 ring-forming carbons, or bonded to an adjacent group to form a ring.

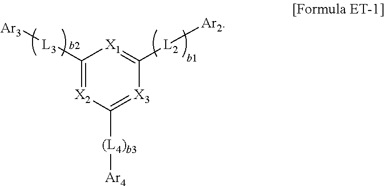

In Formula ET-1, at least one of X₁ to X₃ may be N; the remainder of X₁ to X₃ may each independently be C(R₅₆); R₅₆ may be a hydrogen atom, a deuterium atom, a substituted or unsubstituted alkyl group having 1 to 20 carbons, a substituted or unsubstituted aryl group having 6 to 60 ring-forming carbons, or a substituted or unsubstituted heteroaryl group having 2 to 60 ring-forming carbons; b1 to b3 may each independently be an integer from 0 to 10; Ar₂ to Ar₄ may each independently be a hydrogen atom, a deuterium atom, a substituted or unsubstituted alkyl group having 1 to 20 carbons, a substituted or unsubstituted aryl group having 6 to 30 ring-forming carbons, or a substituted or unsubstituted heteroaryl group having 2 to 30 ring-forming carbons; and L₂ to L₄ may each independently be a direct linkage, a substituted or unsubstituted arylene group having 6 to 30 ring-forming carbons, or a substituted or unsubstituted heteroarylene group having 2 to 30 ring-forming carbons.

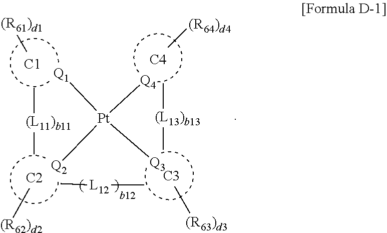

In Formula D-1, Q₁ to Q₄ may each independently be C or N; C1 to C4 may each independently be a substituted or unsubstituted hydrocarbon ring having 5 to 30 ring-forming carbons, a substituted or unsubstituted aryl group having 6 to 30 ring-forming carbons, or a substituted or unsubstituted heterocycle having 2 to 30 ring-forming carbons; L₁₁ to L₁₃ may each independently be a direct linkage,

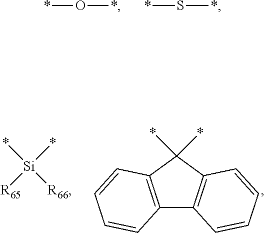

a substituted or unsubstituted alkylene group having 1 to 20 carbons, a substituted or unsubstituted arylene group having 6 to 30 ring-forming carbons, or a substituted or unsubstituted heteroarylene group having 2 to 30 ring-forming carbons; b11 to b13 may each independently be 0 or 1; R₆₁ to R₆₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbons, a substituted or unsubstituted alkenyl group having 2 to 20 carbons, a substituted or unsubstituted aryl group having 6 to 60 ring-forming carbons, or a substituted or unsubstituted heteroaryl group having 2 to 60 ring-forming carbons; and d1 to d4 may each independently be an integer from 0 to 4.

In an embodiment, the first compound may be represented by one of Formula 1-A1 to Formula 1-A3.

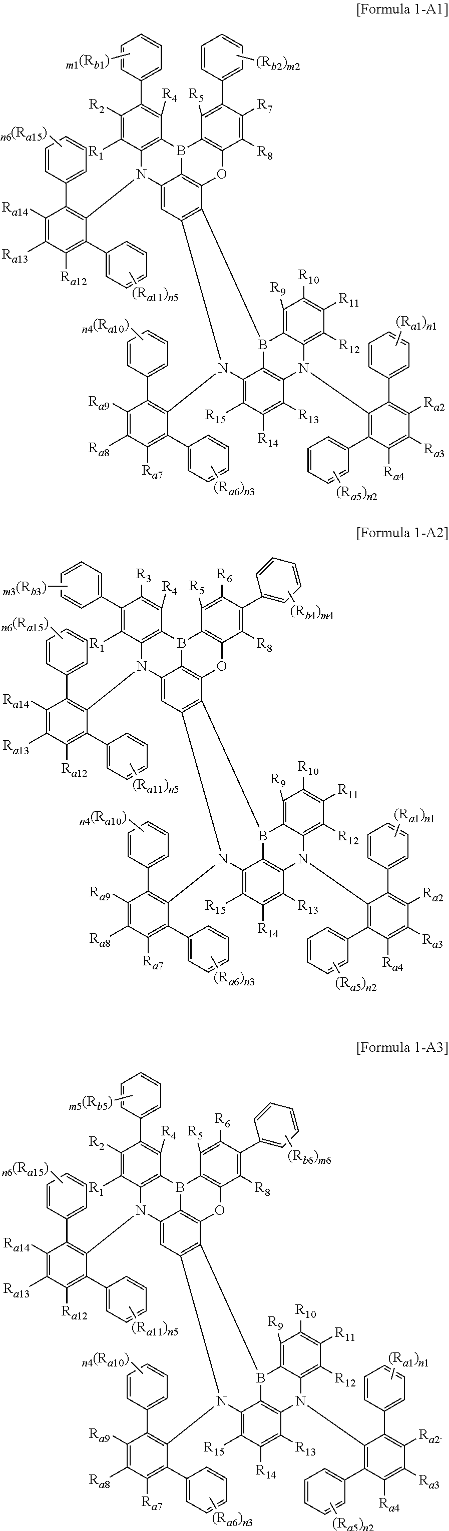

In Formula 1-A1 to Formula 1-A3, m1 to m6 may each independently be an integer from 0 to 5; and R_{b1} to R_{b6} may each independently be a hydrogen atom, a deuterium atom, a substituted or unsubstituted oxy group, a substituted or unsubstituted thio group, a substituted or unsubstituted alkyl group having 1 to 30 carbons, or a substituted or unsubstituted aryl group having 6 to 30 ring-forming carbons, or bonded to an adjacent group to form a ring. In Formula 1-A1 to Formula 1-A3, n1 to n6, R₁ to R₁₅, and Rₐ₁ to Rₐ₁₅ may be the same as defined in Formula 1.

In an embodiment, the first compound may be represented by one of Formula 1-A4 to Formula 1-A6.

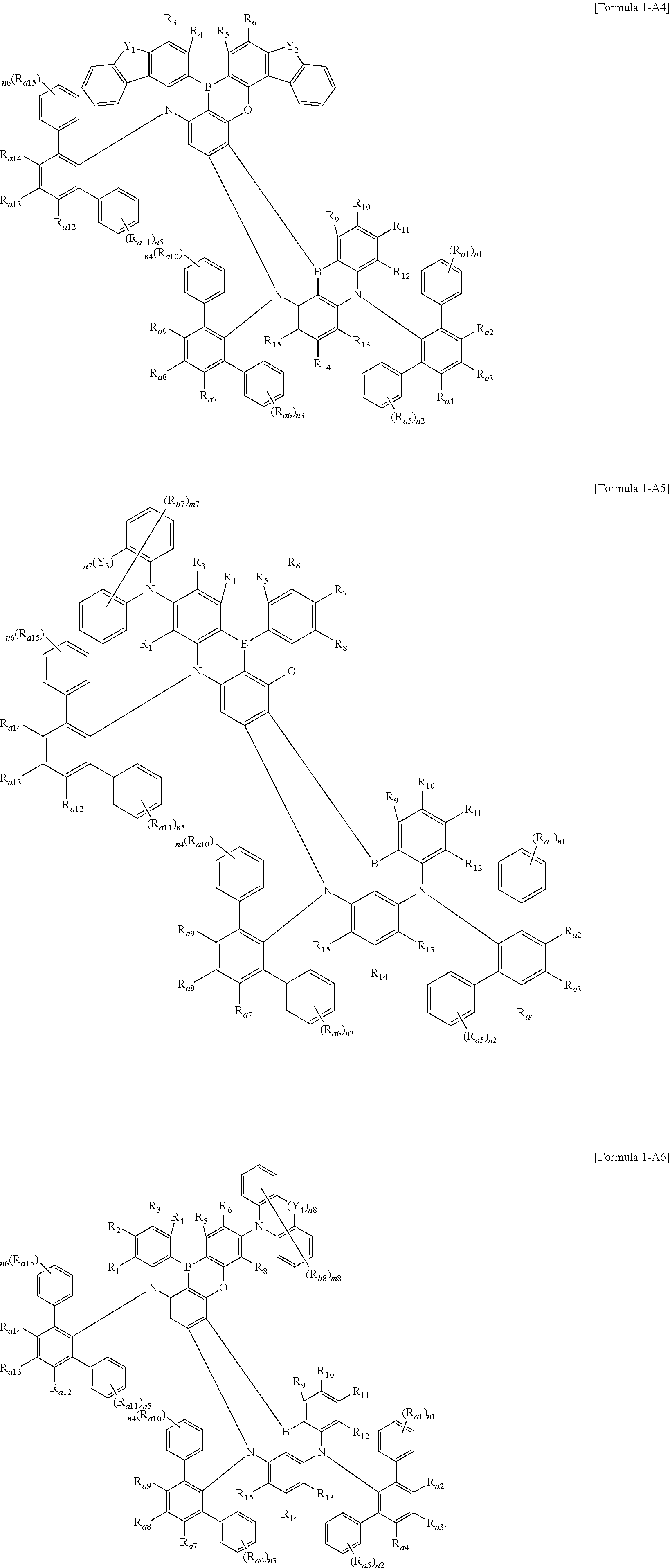

In Formula 1-A4, Y₁ and Y₂ may each independently be N(R₁₆), O, or S; and R₁₆ may be a substituted or unsubstituted aryl group having 6 to 30 ring-forming carbons. In Formula 1-A5, n7 may be 0 or 1; Y₃ may be a direct linkage; m7 may be an integer from 0 to 10; and R_{b7}, may be a hydrogen atom or a deuterium atom. In Formula 1-A6, n8 may be 0 or 1; Y₄ may be a direct linkage; m8 may be an integer from 0 to 10; and R_{b8} may be a hydrogen atom or a deuterium atom. In Formula 1-A4 to Formula 1-A6, n1 to n6, R₁ to R₁₅, and Rₐ₁ to Rₐ₁₅ may be the same as defined in Formula 1.

In an embodiment, the first compound may be represented by Formula 1-B1.

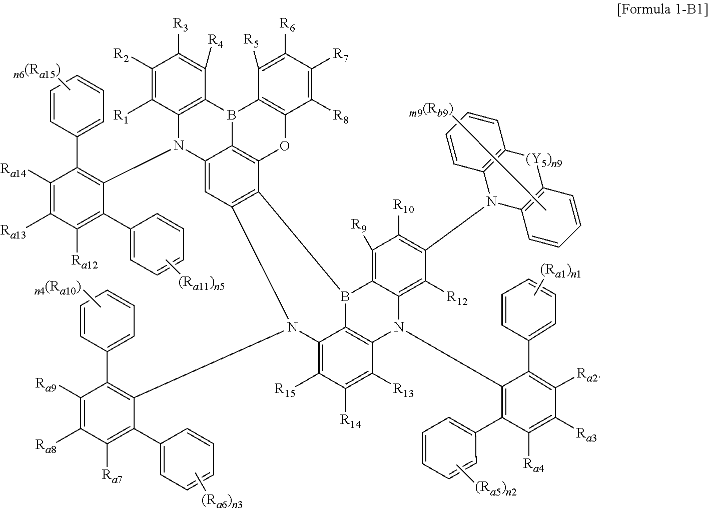

In Formula 1-B1, n9 may be 0 or 1; Y₅ may be a direct linkage; m9 may be an integer from 0 to 10; and R_{b9} may be a hydrogen atom, a deuterium atom, a substituted or unsubstituted oxy group, a substituted or unsubstituted thio group, a substituted or unsubstituted selenium group, a substituted or unsubstituted alkyl group having 1 to 30 carbons, a substituted or unsubstituted alkenyl group having 2 to 30 carbons, a substituted or unsubstituted aryl group having 6 to 30 ring-forming carbons, or a substituted or unsubstituted heteroaryl group having 2 to 30 ring-forming carbons, or bonded to an adjacent group to form a ring. In Formula 1-B1, n1 to n6, R₁ to R₁₀, R₁₂ to R₁₅, and Rₐ₁ to Rₐ₁₅ may be the same as defined in Formula 1.

In an embodiment, in Formula 1, R₁₀ and R₁₁ may each independently be a hydrogen atom, a deuterium atom, or a group represented by one of Formulas R-1 to R-33.

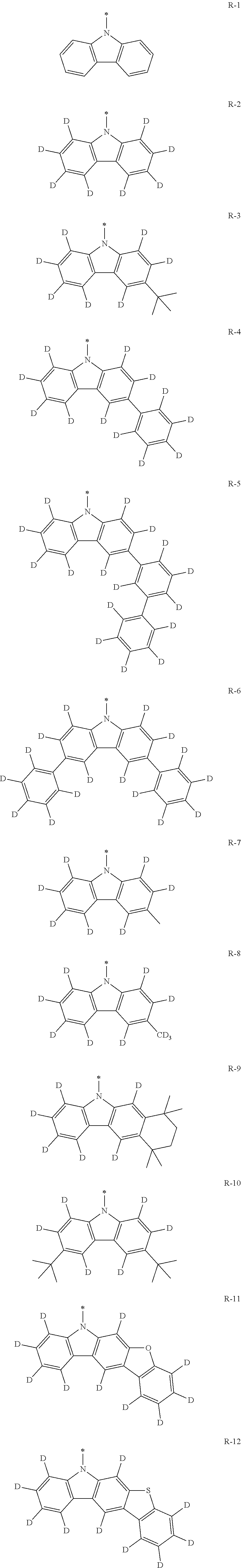

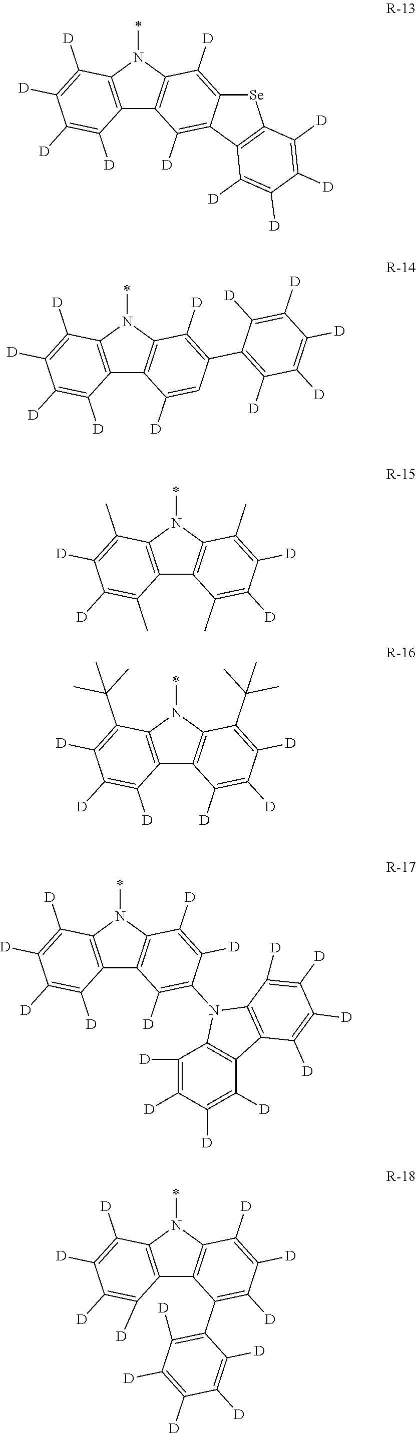

In Formulas R-2 to R-19, R-24 to R-26, and R-33, D is a deuterium atom.

In an embodiment, in Formula 1, a first terphenyl moiety that includes Rₐ₁ to Rₐ₅, a second terphenyl moiety that includes Rₐ₆ to Rₐ₁₀, and a third terphenyl moiety that includes Rₐ₁₁ to Rₐ₁₅ may each independently be a moiety represented by one of Formulas RA-1 to RA-8.

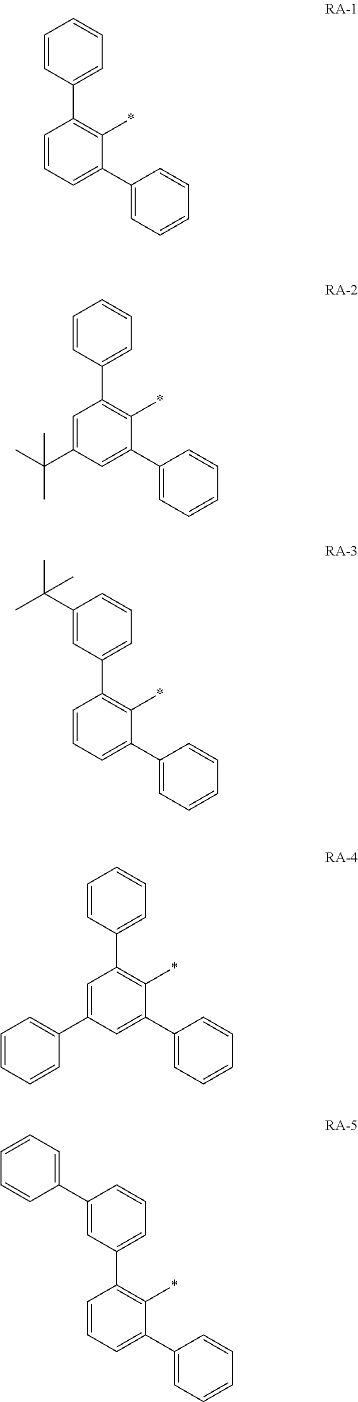 [SMILES: *c1c(-c2ccccc2)cccc1-c1ccccc1 ; *c1c(-c2ccccc2)cc(C(C)(C)C)cc1-c1ccccc1 ; *c1c(-c2ccccc2)cccc1-c1cccc(C(C)(C)C)c1 ; *c1c(-c2ccccc2)cc(-c2ccccc2)cc1-c1ccccc1 ; *c1c(-c2ccccc2)cccc1-c1cccc(-c2ccccc2)c1]

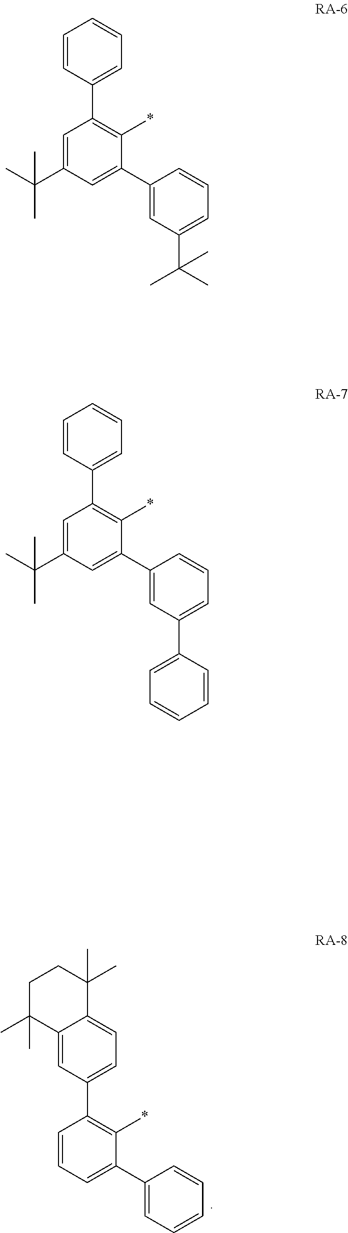

In an embodiment, in Formula 1, R₁₃ to R₁₅ may each independently be a hydrogen atom, a deuterium atom, a substituted or unsubstituted diphenylamine group, a substituted or unsubstituted methyl group, a substituted or unsubstituted t-butyl group, a substituted or unsubstituted phenyl group, or a substituted or unsubstituted carbazole group.

In an embodiment, the first compound may include at least one compound selected from Compound Group 1, which is explained below.

According to an embodiment, a fused polycyclic compound may be represented by Formula 1.

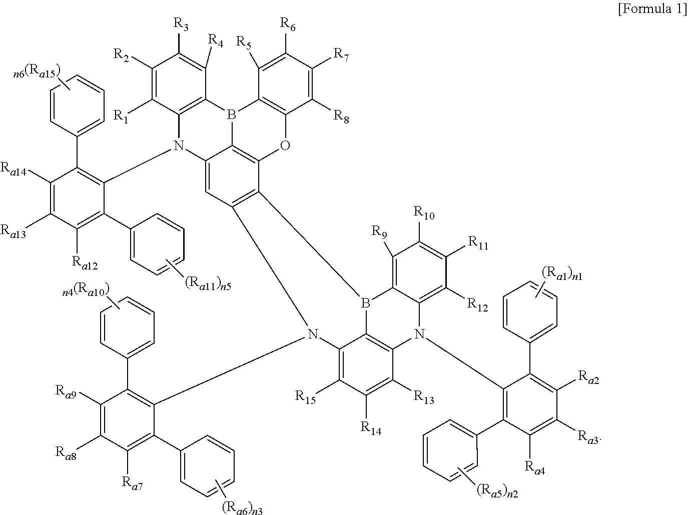

In Formula 1, n1 to n6 may each independently be an integer from 0 to 5; and R₁ to R₁₅ and Rₐ₁ to Rₐ₁₅ may each independently be a hydrogen atom, a deuterium atom, a halogen atom, a cyano group, a nitro group, a substituted or unsubstituted silyl group, a substituted or unsubstituted amine group, a substituted or unsubstituted oxy group, a substituted or unsubstituted thio group, a substituted or unsubstituted selenium group, a substituted or unsubstituted alkyl group having 1 to 60 carbons, a substituted or unsubstituted cycloalkyl group having 3 to 60 carbons, a substituted or unsubstituted alkenyl group having 2 to 60 carbons, a substituted or unsubstituted hydrocarbon ring group having 6 to 60 ring-forming carbons, or a substituted or unsubstituted heterocyclic group having 2 to 60 ring-forming carbons, or bonded to an adjacent group to form a ring.

In an embodiment, the fused polycyclic compound may be represented by one of Formula 1-A1 to Formula 1-A3, which are explained herein.

In an embodiment, the fused polycyclic compound may be represented by one of Formula 1-A4 to Formula 1-A6, which are explained herein.

In an embodiment, the fused polycyclic compound may be represented by Formula 1-B1, which is explained herein.

In an embodiment, in Formula 1, R₁₀ and R₁₁ may each independently be a hydrogen atom, a deuterium atom, or a group represented by one of Formulas R-1 to R-33, which are explained below.

In an embodiment, a first terphenyl moiety that includes Rₐ₁ to Rₐ₅, a second terphenyl moiety that includes Rₐ₆ to Rₐ₁₀, and a third terphenyl moiety that includes Rₐ₁₁ to Rₐ₁₅ may each independently be a moiety represented by one of Formulas RA-1 to RA-8, which are explained herein.

In an embodiment, in Formula 1, R₁₃ to R₁₅ may each independently be a hydrogen atom, a deuterium atom, a substituted or unsubstituted diphenylamine group, a substituted or unsubstituted methyl group, a substituted or unsubstituted t-butyl group, a substituted or unsubstituted phenyl group, or a substituted or unsubstituted carbazole group.

In an embodiment, the fused polycyclic compound may be selected from Compound Group 1, which is explained below.

According to an embodiment, an electronic apparatus may include a circuit layer disposed on a base layer, and a display element layer disposed on the circuit layer and including a light-emitting element, wherein the light-emitting element includes a first electrode, a second electrode disposed on the first electrode, and an emission layer disposed between the first electrode and the second electrode and including a fused polycyclic compound represented by Formula 1, which is explained herein.

In an embodiment, the electronic apparatus may further include at least one of a light control layer and a color filter layer, wherein the light control layer may include a quantum dot, and the color filter layer may include a pigment or dye.

In an embodiment, the light-emitting element may emit first color light; and the light control layer may include a first light control part including a first quantum dot that converts the first color light into second color light that is different from the first color light, a second light control part including a second quantum dot that converts the first color light into third color light that is different from the first color light and the second color light, and a third light control part that transmits the first color light.

It is to be understood that the embodiments above are described in a generic and explanatory sense only and not for the purposes of limitation, and the disclosure is not limited to the embodiments described above.

### BRIEF DESCRIPTION OF THE DRAWINGS

The accompanying drawings are included to provide a further understanding of the embodiments, and are incorporated in and constitute a part of this specification. The drawings illustrate embodiments of the disclosure and principles thereof. The above and other aspects and features of the disclosure will become more apparent by describing in detail embodiments thereof with reference to the accompanying drawings, in which:

FIG. 1 is a schematic plan view of a display device according to an embodiment;

FIG. 2 is a schematic cross-sectional view of a display device, showing a portion taken along virtual line I-I′ in FIG. 1;

FIG. 3 is a schematic cross-sectional view of a light-emitting element according to an embodiment;

FIG. 4 is a schematic cross-sectional view of a light-emitting element according to an embodiment;

FIG. 5 is a schematic cross-sectional view of a light-emitting element according to an embodiment;

FIG. 6 is a schematic cross-sectional view of a light-emitting element according to an embodiment;

FIG. 7 is a schematic cross-sectional view of a display device according to an embodiment;

FIG. 8 is a schematic cross-sectional view of a display device according to an embodiment;

FIG. 9 is a schematic cross-sectional view of a display device according to an embodiment;

FIG. 10 is a schematic cross-sectional view of a display device according to an embodiment;

FIG. 11 is a schematic diagram of an interior of a vehicle in which a display device according to an embodiment is disposed;

FIG. 12 is a schematic perspective view of an electronic apparatus according to an embodiment;

FIG. 13 is an exploded schematic perspective view of an electronic apparatus according to an embodiment;

FIG. 14 is a block diagram of an electronic apparatus according to an embodiment; and

FIG. 15 is a schematic diagram of an electronic apparatus according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like reference numbers and reference characters refer to like elements throughout.

In the specification, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the specification, when an element is “directly on,” “directly connected to,” or “directly coupled to” another element, there are no intervening elements present. For example, “directly on” may mean that two layers or two elements are disposed without an additional element such as an adhesion element therebetween.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group consisting of” for the purpose of its meaning and interpretation. For example, “at least one of A, B, and C” may be understood to mean A only, B only, C only, or any combination of two or more of A, B, and C, such as ABC, ACC, BC, or CC. When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, ±10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

In the specification, the term “substituted or unsubstituted” may describe a group that is unsubstituted or substituted with at least one substituent selected from the group consisting of a deuterium atom, a halogen atom, a cyano group, a nitro group, an amine group, an amino group, a silyl group, an oxy group, a thio group, a sulfinyl group, a sulfonyl group, a carbonyl group, a boron group, a selenium group, a phosphine oxide group, a phosphine sulfide group, an alkyl group, an alkenyl group, an alkynyl group, a hydrocarbon ring group, an aryl group, and a heterocyclic group. Each of the substituents listed above may itself be substituted or unsubstituted. For example, a biphenyl group may be interpreted as an aryl group, or it may be interpreted as a phenyl group substituted with a phenyl group.

In the specification, the term “bonded to an adjacent group to form a ring” may refer to a group that is bonded to an adjacent group to form a substituted or unsubstituted hydrocarbon ring or a substituted or unsubstituted heterocycle. A hydrocarbon ring may be aliphatic or aromatic. A heterocycle may be aliphatic or aromatic. A hydrocarbon ring and a heterocycle may each independently be monocyclic or polycyclic. A ring that is formed by adjacent groups being bonded to each other may itself be connected to another ring to form a spiro structure.

In the specification, the term “adjacent group” may be interpreted as a substituent that is substituted for an atom which is directly linked to an atom substituted with a corresponding substituent, as another substituent that is substituted for an atom which is substituted with a corresponding substituent, or as a substituent that is sterically positioned at the nearest position to a corresponding substituent. For example, two methyl groups in 1,2-dimethylbenzene may be interpreted as “adjacent groups” to each other, and two ethyl groups in 1,1-diethylcyclopentane may be interpreted as “adjacent groups” to each other. For example, two methyl groups in 4,5-dimethylphenanthrene may be interpreted as “adjacent groups” to each other.

In the specification, examples of a halogen atom may include a fluorine atom, a chlorine atom, a bromine atom, and an iodine atom.

In the specification, an alkyl group may be linear or branched. The number of carbons in an alkyl group may be 1 to 60, 1 to 50, 1 to 30, 1 to 20, 1 to 10, or 1 to 6. Examples of an alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but embodiments are not limited thereto.

In the specification, a cycloalkyl group may be a cyclic alkyl group. The number of carbons in a cycloalkyl group may be 3 to 60, 3 to 50, 3 to 30, 3 to 20, or 3 to 10. Examples of a cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, an adamantyl group, a 1-adamantyl group, a 2-adamantyl group, an isobornyl group, a bicycloheptyl group, etc., but embodiments are not limited thereto.

In the specification, an alkenyl group be a hydrocarbon group that includes at least one carbon-carbon double bond in the middle or at a terminus of an alkyl group having 2 or more carbon atoms. An alkenyl group may be linear or branched. The number of carbon atoms in an alkenyl group is not particularly limited, and may be 2 to 60, 2 to 30, 2 to 20, or 2 to 10. Examples of an alkenyl group may include a vinyl group, a 1-butenyl group, a 1-pentenyl group, a 1,3-butadienyl aryl group, a styrenyl group, a styryl vinyl group, etc., but embodiments are not limited thereto.

In the specification, an alkynyl group may be a hydrocarbon group including at least one carbon-carbon triple bond in the middle or at a terminus of an alkyl group having 2 or more carbon atoms. An alkynyl group may be linear or branched. The number of carbon atoms is not particularly limited, and may be 2 to 30, 2 to 20, or 2 to 10. Examples of an alkynyl group may include an ethynyl group, a propynyl group, etc., but embodiments are not limited thereto.

In the specification, a hydrocarbon ring group may be any functional group or substituent derived from an aliphatic hydrocarbon ring or an aromatic hydrocarbon ring. The number of ring-forming carbon atoms in a hydrocarbon ring group may be 5 to 60, 5 to 30, 5 to 20, or 5 to 10.

In the specification, an aryl group may be any functional group or substituent derived from an aromatic hydrocarbon ring. An aryl group may be monocyclic or polycyclic. The number of ring-forming carbon atoms in an aryl group may be 6 to 60, 6 to 30, 6 to 20, or 6 to 15. Examples of an aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but embodiments are not limited thereto.

In the specification, a fluorenyl group may be substituted, and two substituents may be bonded to each other to form a spiro structure. Examples of a substituted fluorenyl group may include the groups shown below. However, embodiments are not limited thereto.

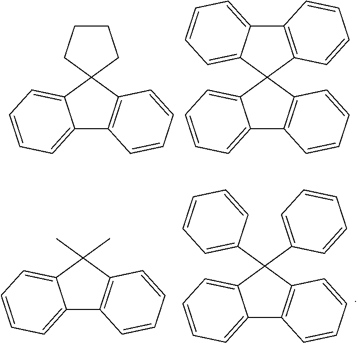

In the specification, a heterocyclic group may be any functional group or substituent derived from a ring that includes at least one of B, O, N, P, Si, S, and Se as a heteroatom. A heterocyclic group may be aliphatic or aromatic. An aromatic heterocyclic group may be a heteroaryl group. An aliphatic heterocycle and an aromatic heterocycle may each independently be monocyclic or polycyclic.

If a heterocyclic group includes two or more heteroatoms, the two or more heteroatoms may be the same as or different from each other. The number of ring-forming carbon atoms in a heterocyclic group may be 2 to 60, 2 to 30, 2 to 20, or 2 to 10.

Examples of an aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., but embodiments are not limited thereto.

Examples of a heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzoimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but embodiments are not limited thereto.

In the specification, the above description of an aryl group may be applied to an arylene group, except that an arylene group is a divalent group. In the specification, the above description of a heteroaryl group may be applied to a heteroarylene group, except that a heteroarylene group is a divalent group.

In the specification, a silyl group may be an alkylsilyl group or an arylsilyl group. Examples of a silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., but embodiments are not limited thereto.

In the specification, a number of carbon atoms in a carbonyl group is not particularly limited, and may be 1 to 40, 1 to 30, or 1 to 20. For example, a carbonyl group may have one of the following structures, but embodiments are not limited thereto.

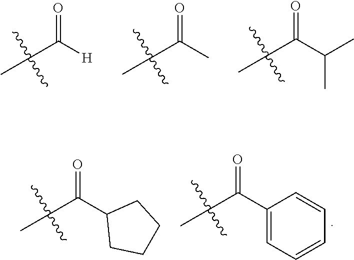

In the specification, the number of carbon atoms in a sulfinyl group or a sulfonyl group is not particularly limited, and may be 1 to 30. A sulfinyl group may be an alkyl sulfinyl group or an aryl sulfinyl group. A sulfonyl group may be an alkyl sulfonyl group or an aryl sulfonyl group.

In the specification, a thio group may be an alkylthio group or an arylthio group. A thio group may be a sulfur atom that is bonded to an alkyl group or to an aryl group as defined above. Examples of a thio group may include a methylthio group, an ethylthio group, a propylthio group, a pentylthio group, a hexylthio group, an octylthio group, a dodecylthio group, a cyclopentylthio group, a cyclohexylthio group, a phenylthio group, and a naphthylthio group, but embodiments are not limited thereto.

In the specification, an oxy group may be an oxygen atom that is bonded to an alkyl group or to an aryl group as defined above. An oxy group may be an alkoxy group or an aryl oxy group. An alkoxy group may be linear, branched, or cyclic. The number of carbon atoms in an alkoxy group is not particularly limited, and may be, for example, 1 to 20 or 1 to 10. Examples of an oxy group may include a methoxy group, an ethoxy group, an n-propoxy group, an isopropoxy group, a butoxy group, a pentyloxy group, a hexyloxy group, an octyloxy group, a nonyloxy group, a decyloxy group, a benzyloxy group, etc., but embodiments are not limited thereto.

In the specification, a boron group may be a boron atom that is bonded to an alkyl group or to an aryl group as defined above. A boron group may be an alkyl boron group or an aryl boron group. Examples of a boron group may include a dimethylboron group, a diethylboron group, a t-butylmethylboron group, a diphenylboron group, a phenylboron group, etc., but embodiments are not limited thereto.

In the specification, the number of carbon atoms in an amine group is not particularly limited, and may be 1 to 50, 1 to 30, or 1 to 20. An amine group may be an alkyl amine group or an aryl amine group. Examples of an amine group may include a methylamine group, a dimethylamine group, a phenylamine group, a diphenylamine group, a naphthylamine group, a 9-methyl-anthracenylamine group, etc., but embodiments are not limited thereto.

In the specification, a selenium (Se) group may be an alkyl selenium group or an aryl selenium group. A selenium group may be a selenium atom that is bonded to an alkyl group or to an aryl group as defined above. Examples of a selenium group may include a methyl selenium group, an ethyl selenium group, a propyl selenium group, a pentyl selenium group, a hexyl selenium group, an octyl selenium group, a dodecyl selenium group, a cyclopentyl selenium group, a cyclohexyl selenium group, a phenyl selenium group, a naphthyl selenium group, etc. However, embodiments are not limited thereto.

In the specification, an alkyl group within an alkylthio group, an alkylsulfoxy group, an alkylaryl group, an alkylamino group, an alkyl boron group, an alkyl silyl group, an alkyl amine group, or an alkyl selenium group may be the same as an example of an alkyl group as described above.

In the specification, an aryl group within an aryloxy group, an arylthio group, an arylsulfoxy group, an arylamino group, an arylboron group, an arylsilyl group, an arylamine group, or an aryl selenium group may be the same as an example of an aryl group as described above.

In the specification, a direct linkage may be a single bond. In the specification, the symbols

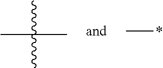

each represent a bond to a neighboring atom in a corresponding formula or moiety.

Hereinafter, embodiments will be described with reference to the accompanying drawings.

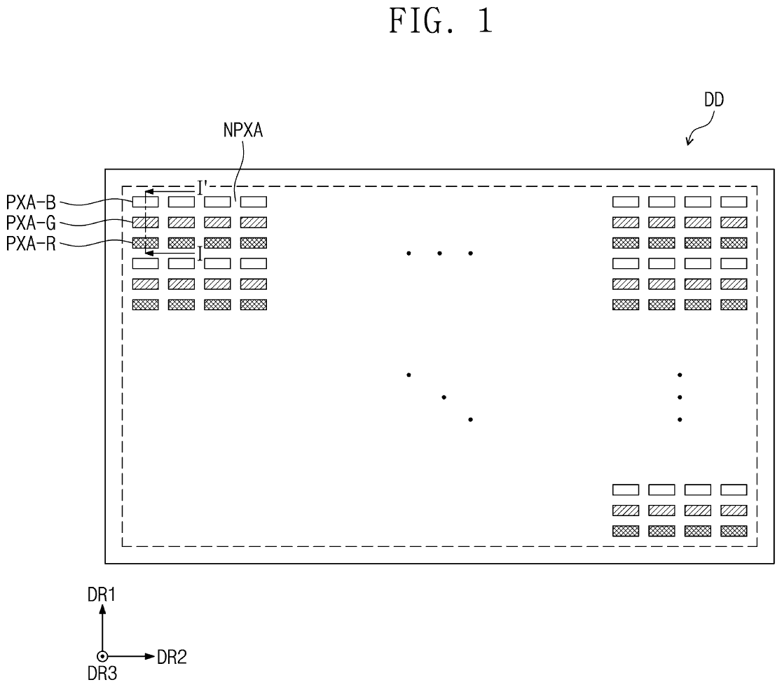

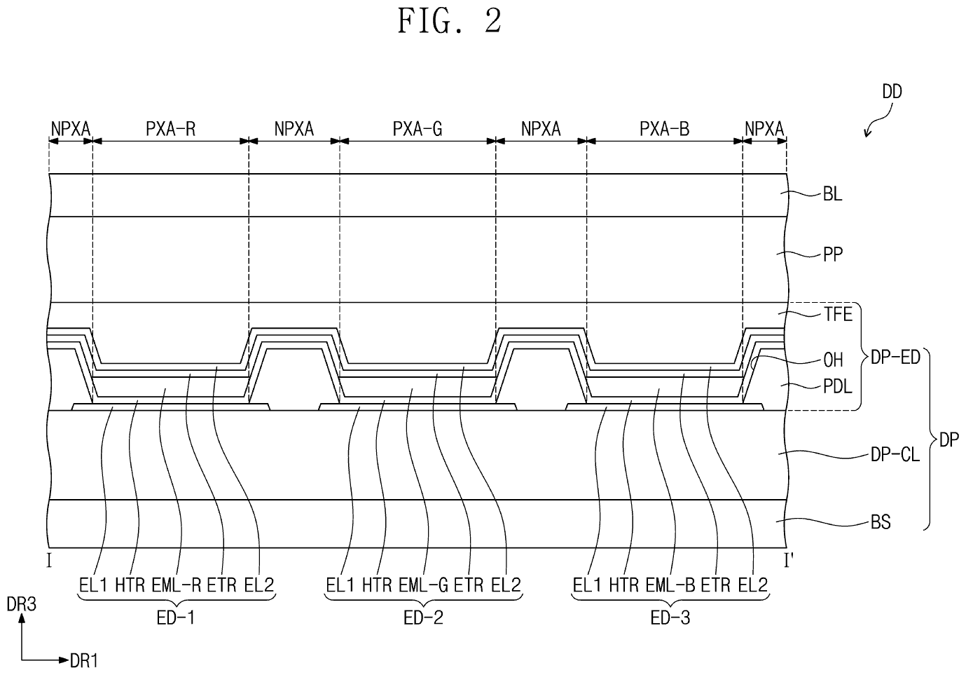

FIG. 1 is a schematic plan view of a display device DD according to an embodiment. FIG. 2 is a schematic cross-sectional view of the display device DD according to an embodiment. FIG. 2 is a schematic cross-sectional view of a portion taken along virtual line I-I′ in FIG. 1.

The display device DD may include a display panel DP and an optical layer PP disposed on the display panel DP. The display panel DP includes light-emitting elements ED-1, ED-2, and ED-3. The display device DD may include multiples of each of the light-emitting elements ED-1, ED-2, and ED-3. The optical layer PP may be disposed on the display panel DP to control light that is reflected at the display panel DP from an external light. The optical layer PP may include, for example, a polarization layer or a color filter layer. Although not shown in the drawings, in an embodiment, the optical layer PP may be omitted from the display device DD.

A base substrate BL may be disposed on the optical layer PP. The base substrate BL may provide a base surface on which the optical layer PP is disposed. The base substrate BL may be a glass substrate, a metal substrate, a plastic substrate, etc. However, the embodiments are not limited thereto, and the base substrate BL may include an inorganic layer, an organic layer, or a composite material layer. Although not shown in the drawings, in an embodiment, the base substrate BL may be omitted.

The display device DD according to an embodiment may further include a filling layer (not shown). The filling layer (not shown) may be disposed between a display element layer DP-ED and the base substrate BL. The filling layer (not shown) may be an organic material layer. The filling layer (not shown) may include at least one of an acrylic-based resin, a silicone-based resin, and an epoxy-based resin.

The display panel DP may include a base layer BS, a circuit layer DP-CL provided on the base layer BS, and the display element layer DP-ED. The display element layer DP-ED may include a pixel defining film PDL, light-emitting elements ED-1, ED-2, and ED-3 disposed between portions of the pixel defining film PDL, and an encapsulation layer TFE disposed on the light-emitting elements ED-1, ED-2, and ED-3.

The base layer BS may provide a base surface on which the display element layer DP-ED is disposed. The base layer BS may be a glass substrate, a metal substrate, a plastic substrate, etc. However, the embodiments are not limited thereto, and the base layer BS may include an inorganic layer, an organic layer, or a composite material layer.

In an embodiment, the circuit layer DP-CL is disposed on the base layer BS, and the circuit layer DP-CL may include transistors (not shown). The transistors (not shown) may each include a control electrode, an input electrode, and an output electrode. For example, the circuit layer DP-CL may include a switching transistor and a driving transistor for driving the light-emitting elements ED-1, ED-2, and ED-3 of the display element layer DP-ED.

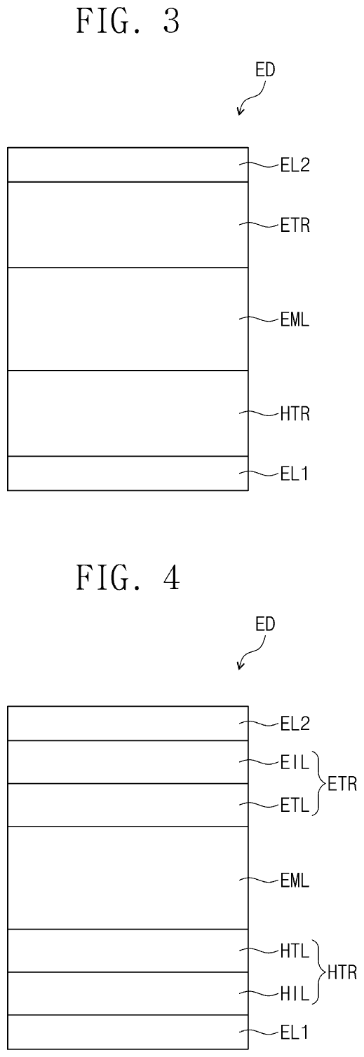

The light-emitting elements ED-1, ED-2, and ED-3 may each have a structure of a light-emitting element ED according to any of FIGS. 3 to 6, which will be described later. The light-emitting elements ED-1, ED-2, and ED-3 may each include a first electrode EL1, a hole transport region HTR, emission layers EML-R, EML-G, and EML-B, an electron transport region ETR, and a second electrode EL2.

FIG. 2 illustrates an embodiment in which the emission layers EML-R, EML-G, and EML-B of the light-emitting elements ED-1, ED-2, and ED-3 are disposed in openings OH defined in the pixel defining film PDL, and the hole transport region HTR, the electron transport region ETR, and the second electrode EL2 are each provided as a common layer throughout the light-emitting elements ED-1, ED-2, and ED-3. However, embodiments are not limited thereto. Although not shown in FIG. 2, in an embodiment, the hole transport region HTR and the electron transport region ETR may each be provided by being patterned in the openings OH defined in the pixel defining film PDL. For example, in an embodiment, the hole transport region HTR, the emission layers EML-R, EML-G, and EML-B, and the electron transport region ETR of the light-emitting elements ED-1, ED-2, and ED-3 may be provided by being patterned through an inkjet printing method.

The encapsulation layer TFE may cover the light-emitting elements ED-1, ED-2, and ED-3. The encapsulation layer TFE may seal elements (such as light-emitting elements ED-1, ED-2, and ED-3) of the display element layer DP-ED. The encapsulation layer TFE may be a thin film encapsulation layer. The encapsulation layer TFE may be formed of a single layer or of multiple layers. The encapsulation layer TFE may include at least one insulation layer. The encapsulation layer TFE according to an embodiment may include at least one inorganic film (hereinafter, an encapsulation-inorganic film). The encapsulation layer TFE according to an embodiment may include at least one organic film (hereinafter, an encapsulation-organic film) and at least one encapsulation-inorganic film.

The encapsulation-inorganic film protects the display element layer DP-ED from moisture and/or oxygen, and the encapsulation-organic film protects the display element layer DP-ED from foreign substances such as dust particles. The encapsulation-inorganic film may include silicon nitride, silicon oxynitride, silicon oxide, titanium oxide, aluminum oxide, or the like, but embodiments are not limited thereto. The encapsulation-organic film may include an acrylic-based compound, an epoxy-based compound, or the like. The encapsulation-organic film may include a photopolymerizable organic material, but embodiments are not limited thereto.

The encapsulation layer TFE may be disposed on the second electrode EL2 and may be disposed to fill the openings OH.

Referring to FIGS. 1 and 2, the display device DD may include non-light emitting regions NPXA and light emitting regions PXA-R, PXA-G, and PXA-B. The light emitting regions PXA-R, PXA-G, and PXA-B may each be a region that emits light respectively generated by the light-emitting elements ED-1, ED-2, and ED-3. The light emitting regions PXA-R, PXA-G, and PXA-B may be spaced apart from each other in a plan view.

The light emitting regions PXA-R, PXA-G, and PXA-B may be regions that are separated from each other by the pixel defining film PDL. The non-light emitting regions NPXA may be areas between adjacent light emitting regions PXA-R, PXA-G, and PXA-B, and which may correspond to the pixel defining film PDL. In an embodiment, the light emitting regions PXA-R, PXA-G, and PXA-B may each correspond to a pixel. The pixel defining film PDL may separate the light-emitting elements ED-1, ED-2, and ED-3. The emission layers EML-R, EML-G, and EML-B of the light-emitting elements ED-1, ED-2, and ED-3 may be disposed in openings OH defined in the pixel defining film PDL and separated from each other.

The light emitting regions PXA-R, PXA-G, and PXA-B may be arranged into groups according to the color of light generated from the light-emitting elements ED-1, ED-2, and ED-3. In the display device DD according to an embodiment illustrated in FIGS. 1 and 2, three light emitting regions PXA-R, PXA-G, and PXA-B, which respectively emit red light, green light, and blue light, are illustrated as an example. For example, the display device DD may include a red light emitting region PXA-R, a green light emitting region PXA-G, and a blue light emitting region PXA-B, which are distinct from each other.

In the display device DD according to an embodiment, the light-emitting elements ED-1, ED-2, and ED-3 may emit light having wavelengths that are different from each other. For example, in an embodiment, the display device DD may include a first light-emitting element ED-1 that emits red light, a second light-emitting element ED-2 that emits green light, and a third light-emitting element ED-3 that emits blue light. For example, the red light emitting region PXA-R, the green light emitting region PXA-G, and the blue light emitting region PXA-B of the display device DD may respectively correspond to the first light-emitting element ED-1, the second light-emitting element ED-2, and the third light-emitting element ED-3.

However, embodiments are not limited thereto, and the first to third light-emitting elements ED-1, ED-2, and ED-3 may emit light in a same wavelength range, or at least one light-emitting element may emit a light in a wavelength range that is different from the remainder. For example, the first to third light-emitting elements ED-1, ED-2, and ED-3 may each emit blue light.

The light emitting regions PXA-R, PXA-G, and PXA-B in the display device DD according to an embodiment may be arranged in a stripe configuration. Referring to FIG. 1, the red light emitting regions PXA-R, the green light emitting regions PXA-G, and the blue light emitting regions PXA-B may be respectively arranged along a second directional axis DR2. In another embodiment, the red light emitting region PXA-R, the green light emitting region PXA-G, and the blue light emitting region PXA-B may be arranged in this repeating order along a first directional axis DR1.

FIGS. 1 and 2 illustrate that the light emitting regions PXA-R, PXA-G, and PXA-B all have a similar area, but embodiments are not limited thereto. In an embodiment, the light emitting regions PXA-R, PXA-G, and PXA-B may be different in size or shape from each other according to a wavelength range of emitted light. The areas of the light emitting regions PXA-R, PXA-G, and PXA-B may be areas in a plan view that are defined by the first directional axis DR1 and the second directional axis DR2.

An arrangement of the light emitting regions PXA-R, PXA-G, and PXA-B is not limited to the configuration illustrated in FIG. 1, and the order in which the red light emitting region PXA-R, the green light emitting region PXA-G, and the blue light emitting region PXA-B are arranged may be provided in various combinations according to the display quality characteristics that are required for the display device DD. For example, the light emitting regions PXA-R, PXA-G, and PXA-B may be arranged in a pentile configuration (such as PenTile®) or in a diamond configuration (such as Diamond Pixel®).

The areas of the light emitting regions PXA-R, PXA-G, and PXA-B may be different in size from each other. For example, in an embodiment, an area of a green light emitting region PXA-G may be smaller than an area of a blue light emitting region PXA-B, but embodiments are not limited thereto.

Hereinafter, FIG. 3 to FIG. 6 are each a schematic cross-sectional view of a light-emitting element ED according to embodiments. For example, as shown in FIG. 3, a light-emitting element ED according to an embodiment may include a first electrode EL1, a hole transport region HTR, an emission layer EML, an electron transport region ETR, and a second electrode EL2, which are stacked in that order.

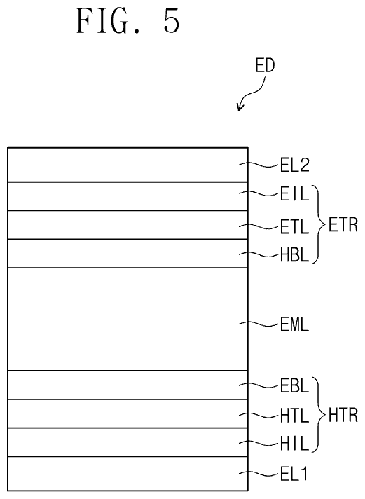

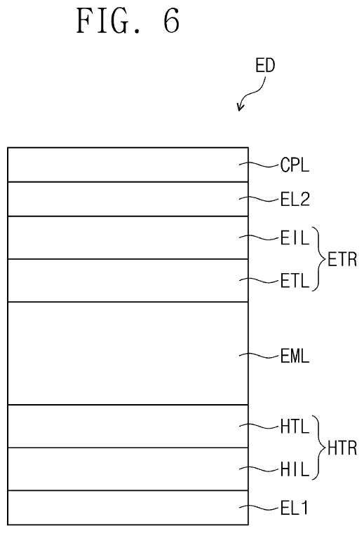

In comparison to FIG. 3, FIG. 4 is a schematic cross-sectional view of a light-emitting element ED, in which a hole transport region HTR includes a hole injection layer HIL and a hole transport layer HTL, and an electron transport region ETR includes an electron injection layer EIL and an electron transport layer ETL. In comparison to FIG. 3, FIG. 5 is a schematic cross-sectional view of a light-emitting element ED, in which a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. Although not shown in FIG. 5, in an embodiment, the hole injection layer HIL may be omitted from the hole transport region HTR. In comparison to FIG. 4, FIG. 6 is a schematic cross-sectional view of a light-emitting element ED that further includes a capping layer CPL disposed on the second electrode EL2.

The first electrode EL1 has conductivity. The first electrode EL1 may include a metal material, a metal alloy, or a conductive compound. The first electrode EL1 may be an anode or a cathode. However, embodiments are not limited thereto. In an embodiment, the first electrode EL1 may be a pixel electrode. The first electrode EL1 may be a transmissive electrode, a transflective electrode, or a reflective electrode. The first electrode EL1 may include at least one of Ag, Mg, Cu, Al, Pt, Pd, Au, Ni, Nd, Ir, Cr, Li, Ca, LiF, Mo, Ti, W, In, Sn, Zn, an oxide thereof, a compound thereof, and a mixture thereof.

If the first electrode EL1 is a transmissive electrode, the first electrode EL1 may include a transparent metal oxide such as indium tin oxide (ITO), indium zinc oxide (IZO), zinc oxide (ZnO), or indium tin zinc oxide (ITZO). If the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, a compound thereof, or a mixture thereof (e.g., a mixture of Ag and Mg). In another embodiment, the first electrode EL1 may have a multilayered structure that includes a reflective film or a transflective film formed of the above-described materials, and a transparent conductive film formed of ITO, IZO, ZnO, ITZO, etc. For example, the first electrode EL1 may have a three-layered structure of ITO/Ag/ITO, but embodiments are not limited thereto. In an embodiment, the first electrode EL1 may include the above-described metal materials, combinations of at least two of the above-described metal materials, oxides of the above-described metal materials, or the like. A thickness of the first electrode EL1 may be in a range of about 700 Å to about 10,000 Å. For example, the thickness of the first electrode EL1 may be in a range of about 1,000 Å to about 3,000 Å.

The hole transport region HTR may be provided on the first electrode EL1. The hole transport region HTR may include at least one of a hole injection layer HIL, a hole transport layer HTL, a buffer layer (not shown), an emission-auxiliary layer (not shown), and an electron blocking layer EBL. A thickness of the hole transport region HTR may be, for example, in a range of about 50 Å to about 15,000 Å.

The hole transport region HTR may have a structure consisting of a layer consisting of a single material, a structure consisting of a layer including different materials, or a structure including multiple layers including different materials.

For example, the hole transport region HTR may have a single-layered structure of a hole injection layer HIL or a hole transport layer HTL, or may have a single-layered structure that includes a hole injection material and a hole transport material. In an embodiment, the hole transport region HTR may have a hole injection layer HIL/hole transport layer HTL structure, a hole injection layer HIL/hole transport layer HTL/buffer layer (not shown) structure, a hole injection layer HIL/buffer layer (not shown) structure, a hole transport layer HTL/buffer layer (not shown) structure, or a hole injection layer HIL/hole transport layer HTL/electron blocking layer EBL structure, in which the layers of each structure may be stacked in its respective stated order from the first electrode EL1, but embodiments are not limited thereto.

The hole transport region HTR may be formed using various methods such as a vacuum deposition method, a spin coating method, a cast method, a Langmuir-Blodgett (LB) method, an inkjet printing method, a laser printing method, and a laser induced thermal imaging (LITI) method.

In the light-emitting element ED according to an embodiment, the hole transport region HTR may include a compound represented by Formula H-1:

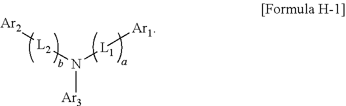

In Formula H-1, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. In Formula H-1, a and b may each independently be an integer from 0 to 10. When a or b is 2 or greater, multiple L₁ or multiple L₂ may each independently be a substituted or unsubstituted arylene group having 6 to 30 ring-forming carbon atoms or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms. In Formula H-1, Ar₃ may be a substituted or unsubstituted aryl group having 6 to 30 ring-forming carbon atoms or a substituted or unsubstituted heteroaryl group having 2 to 30 ring-forming carbon atoms.

In an embodiment, the compound represented by Formula H-1 may be a monoamine compound. In another embodiment, the compound represented by Formula H-1 may be a diamine compound in which at least one of Ar₁ to Ar₃ includes an amine group as a substituent. In an embodiment, the compound represented by Formula H-1 may be a carbazole-based compound in which at least one of Ar₁ and Ar₂ includes a substituted or unsubstituted carbazole group, or may be a fluorene-based compound in which at least one of Ar₁ and Ar₂ includes a substituted or unsubstituted fluorene group.

The compound represented by Formula H-1 may be any compound selected from Compound Group H. However, the compounds listed in Compound Group H are only examples, and a compound represented by Formula H-1 is not limited to Compound Group H:

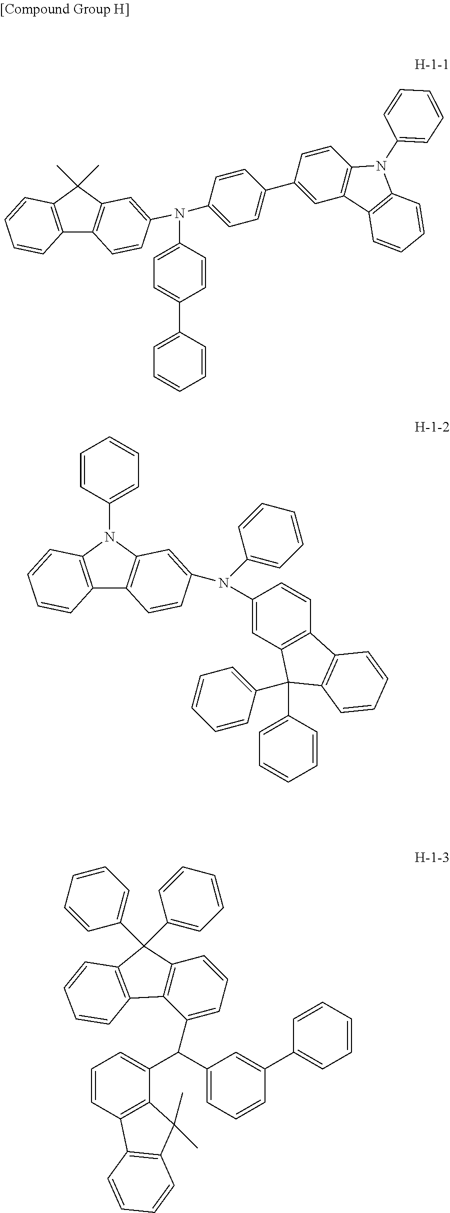

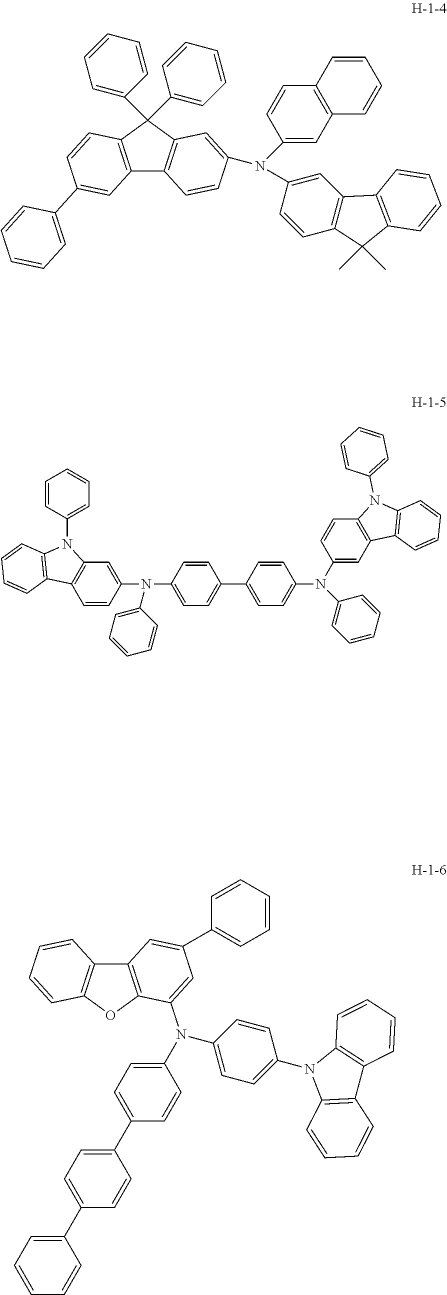 [SMILES: CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21 ; c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1]

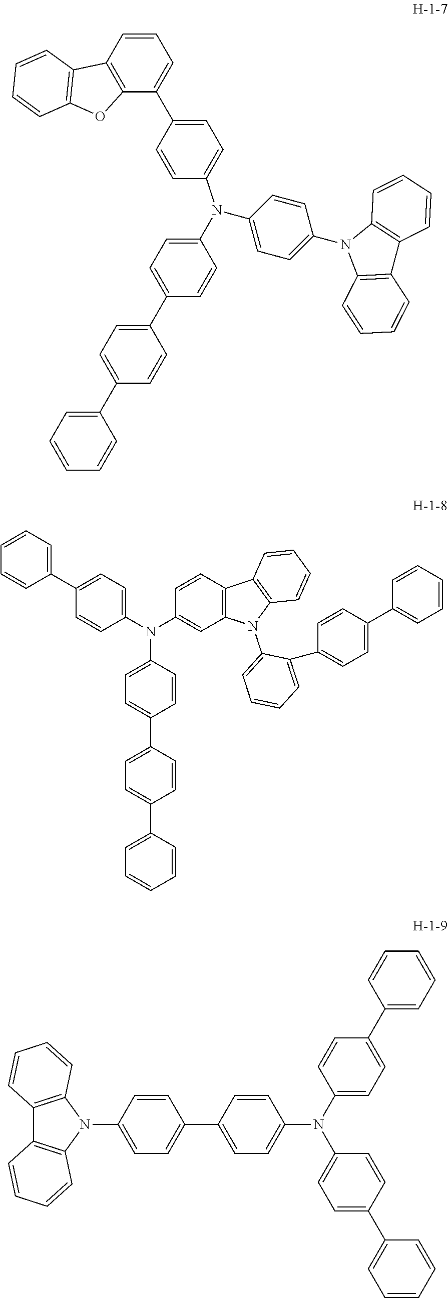 [SMILES: c1ccc(-c2ccc(-c3ccc(N(c4ccc(-c5cccc6c5oc5ccccc56)cc4)c4ccc(-n5c6ccccc6c6ccccc65)cc4)cc3)cc2)cc1 ; c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

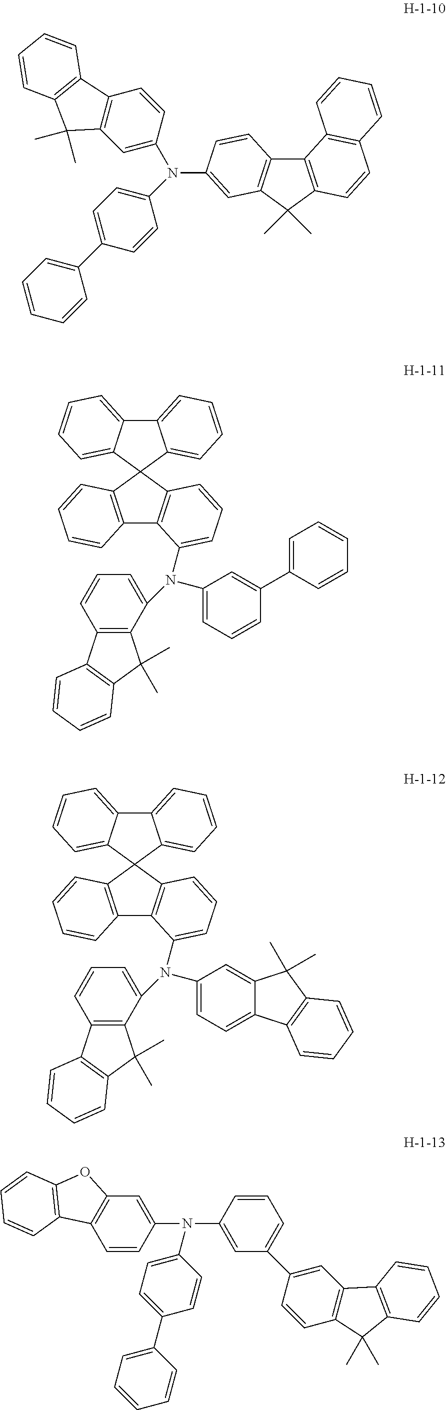 [SMILES: CC1(C)c2ccccc2-c2ccc(N(c3ccc(-c4ccccc4)cc3)c3ccc4c(c3)C(C)(C)c3ccc5ccccc5c3-4)cc21 ; CC1(C)c2ccccc2-c2cccc(N(c3cccc(-c4ccccc4)c3)c3cccc4c3-c3ccccc3C43c4ccccc4-c4ccccc43)c21 ; CC1(C)c2ccccc2-c2ccc(N(c3cccc4c3-c3ccccc3C43c4ccccc4-c4ccccc43)c3cccc4c3C(C)(C)c3ccccc3-4)cc21 ; CC1(C)c2ccccc2-c2cc(-c3cccc(N(c4ccc(-c5ccccc5)cc4)c4ccc5c(c4)oc4ccccc45)c3)ccc21]

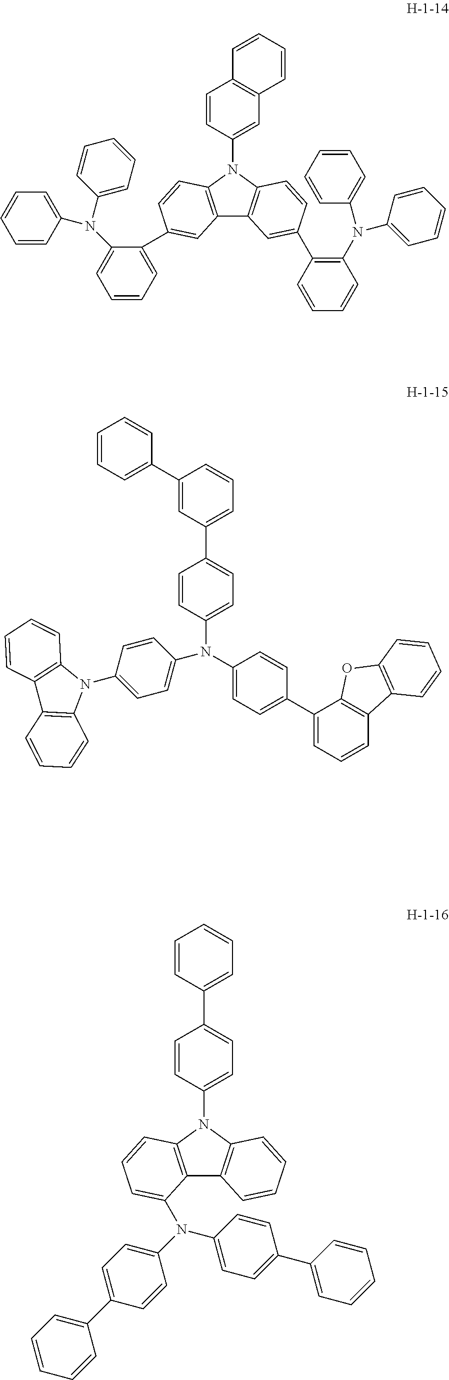 [SMILES: c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1 ; c1ccc(-c2ccc(N(c3ccc(-c4ccccc4)cc3)c3cccc4c3c3ccccc3n4-c3ccc(-c4ccccc4)cc3)cc2)cc1]

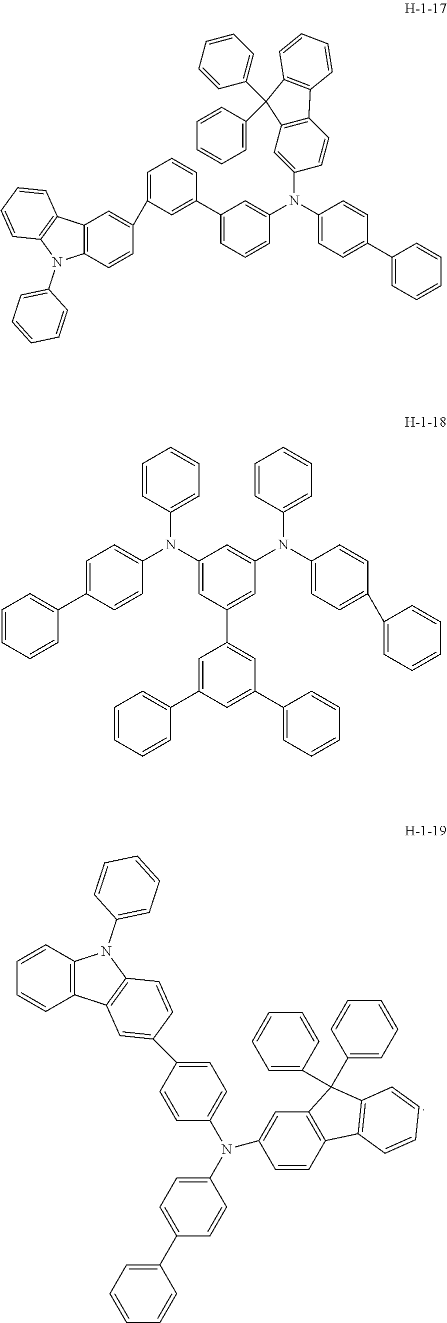 [SMILES: c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may include a phthalocyanine compound such as copper phthalocyanine, N¹,N^{1′}-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalen-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HATCN), etc.

The hole transport region HTR may include a carbazole-based derivative such as N-phenyl carbazole or polyvinyl carbazole, a fluorene-based derivative, a triphenylamine-based derivative such as N,N′-bis(3-methylphenyl)-N,N′-diphenyl-[1,1-biphenyl]-4,4′-diamine (TPD) or 4,4′,4″-tris(N-carbazolyl)triphenylamine (TCTA), N,N′-di(naphthalen-1-yl)-N,N′-diphenyl-benzidine (NPB), 4,4′-cyclohexylidene bis[N,N-bis(4-methylphenyl)benzenamine](TAPC), 4,4′-bis[N,N′-(3-tolyl)amino]-3,3′-dimethylbiphenyl (HMTPD), 1,3-bis(N-carbazolyl)benzene (mCP), etc.

In an embodiment, the hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport region HTR may include the above-described compounds of the hole transport region in at least one of a hole injection layer HIL, a hole transport layer HTL, and an electron blocking layer EBL.

A thickness of the hole transport region HTR may be in a range of about 100 Å to about 10,000 Å. For example, the thickness of the hole transport region HTR may be in a range of about 100 Å to about 5,000 Å. When the hole transport region HTR includes a hole injection layer HIL, a hole injection layer HIL may have, for example, a thickness in a range of about 30 Å to about 1,000 Å. When the hole transport region HTR includes the hole transport layer HTL, a hole transport layer HTL may have a thickness in a range of about 30 Å to about 1,000 Å. When the hole transport region HTR includes an electron blocking layer EBL, the electron blocking layer EBL may have a thickness in a range of about 10 Å to about 1,000 Å. If the thicknesses of the hole transport region HTR, the hole injection layer HIL, the hole transport layer HTL and the electron blocking layer EBL satisfy the above-described ranges, satisfactory hole transport properties may be achieved without a substantial increase in driving voltage.

The hole transport region HTR may further include a charge generating material to increase conductivity, in addition to the above-described materials. The charge generating material may be dispersed uniformly or non-uniformly in the hole transport region HTR. The charge generating material may be, for example, a p-dopant. The p-dopant may include at least one of a metal halide, a quinone derivative, a metal oxide, and a cyano group-containing compound, but embodiments are not limited thereto. For example, the p-dopant may include a metal halide such as CuI or RbI, a quinone derivative such as tetracyanoquinodimethane (TCNQ) or 2,3,5,6-tetrafluoro-7,7′,8,8-tetracyanoquinodimethane (F4-TCNQ), a metal oxide such as tungsten oxide or molybdenum oxide, a cyano group-containing compound such as dipyrazino[2,3-f: 2′,3′-h]quinoxaline-2,3,6,7,10,11-hexacarbonitrile (HATCN) or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., but embodiments are not limited thereto.

As described above, the hole transport region HTR may further include at least one of a buffer layer (not shown) or an electron blocking layer EBL, in addition to a hole injection layer HIL and a hole transport layer HTL. The buffer layer (not shown) may compensate for a resonance distance according to a wavelength of light emitted from the emission layer EML and may thus increase light emission efficiency. A material that may be included in the hole transport region HTR may be included in the buffer layer (not shown). The electron blocking layer EBL may prevent the injection of electrons from an electron transport region ETR to the hole transport region HTR.

In an embodiment, the emission layer EML may include a fused polycyclic compound according to an embodiment. The emission layer EML according to an embodiment may further include at least one of a second compound, a third compound, and a fourth compound. The second compound may include a tricyclic fused ring that includes a nitrogen atom as a ring-forming atom. The third compound may include a six-membered heterocyclic group that includes at least one nitrogen atom as a ring-forming atom. The fourth compound may include an organometallic complex. The second, third, and fourth compounds will be described later in more detail.

In the specification, the fused polycyclic compound according to an embodiment may be referred to as a first compound. The fused polycyclic compound according to an embodiment may include a core structure and a terphenyl moiety bonded to the core structure. The fused polycyclic compound according to an embodiment may include a core structure having nine rings, and three nitrogen atoms, two boron atoms, and an oxygen atom as ring-forming atoms. In an embodiment, the fused polycyclic compound according to an embodiment may include three terphenyl moieties, each bonded to the three ring-forming nitrogen atoms of the core structure. Therefore, the fused polycyclic compound according to an embodiment may exhibit excellent material stability and contribute to improving color purity, efficiency, and lifespan.

In an embodiment, the light-emitting element ED may include the fused polycyclic compound. The fused polycyclic compound according to an embodiment may be represented by Formula 1.

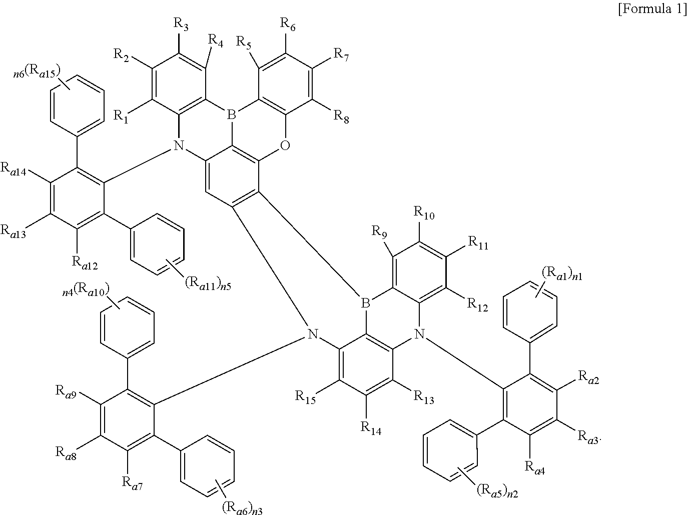

In Formula 1, R₁ to R₁₅ and Rₐ₁ to Rₐ₁₅ may each independently be a hydrogen atom, a deuterium atom, a halogen atom, a cyano group, a nitro group, a substituted or unsubstituted silyl group, a substituted or unsubstituted amine group, a substituted or unsubstituted oxy group, a substituted or unsubstituted thio group, a substituted or unsubstituted selenium group, a substituted or unsubstituted alkyl group having 1 to 60 carbons, a substituted or unsubstituted cycloalkyl group having 3 to 60 carbons, a substituted or unsubstituted alkenyl group having 2 to 60 carbons, a substituted or unsubstituted hydrocarbon ring having 6 to 60 ring-forming carbons, or a substituted or unsubstituted heterocyclic group having 2 to 60 ring-forming carbons, or bonded to an adjacent group to form a ring. For example, at least one of R₁ to R₈ may be a substituent that is not a hydrogen atom. However, this is only an example, and embodiments are not limited thereto.

For example, R₁ to R₁₅ may each independently be a hydrogen atom, a deuterium atom, a substituted or unsubstituted silyl group, a substituted or unsubstituted amine group, a substituted or unsubstituted oxy group, a substituted or unsubstituted thio group, a substituted or unsubstituted selenium group, a substituted or unsubstituted alkyl group having 1 to 10 carbons, a substituted or unsubstituted cycloalkyl group having 3 to 10 carbons, a substituted or unsubstituted alkenyl group having 2 to 10 carbons, a substituted or unsubstituted hydrocarbon ring having 6 to 30 ring-forming carbons, or a substituted or unsubstituted heterocyclic group having 2 to 30 ring-forming carbons, or bonded to an adjacent group to form a ring. For example, Rₐ₁ to Rₐ₁₅ may each independently be a hydrogen atom, a deuterium atom, a substituted or unsubstituted alkyl group having 1 to 10 carbons, a substituted or unsubstituted aryl group having 6 to 30 ring-forming carbons, or bonded to an adjacent group to form a ring.

In an embodiment, R₁ to R₈ may each independently be a hydrogen atom, a deuterium atom, or a group represented by one of Formulas R1-1 to R1-9. In Formulas R1-1 to R1-9, D is a deuterium atom.

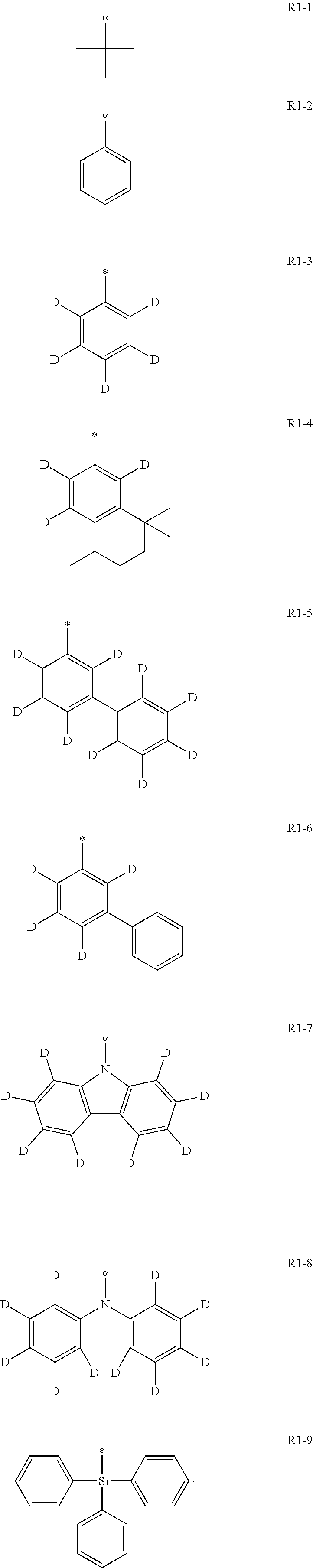

In an embodiment, R₂ may be the same as R₇, and R₂ and R₇ may each be a group represented by one of Formulas R1-1 to R1-9. In an embodiment, R₃ may be the same as R₆, and R₃ and R₆ may each be a group represented by one of Formulas R1-1 to R1-9. In another embodiment, R₃ may be the same as R₇, and R₃ and R₇ may each be a group represented by one of Formulas R1-1 to R1-9. However, this is only an example, and embodiments are not limited thereto.

In an embodiment, in Formula 1, R₁₀ and R₁₁ may each independently be a hydrogen atom, a deuterium atom, or a group represented by one of Formulas R-1 to R-33. In Formulas R-2 to R-19, R-24 to R-26, and R-33, D is a deuterium atom.

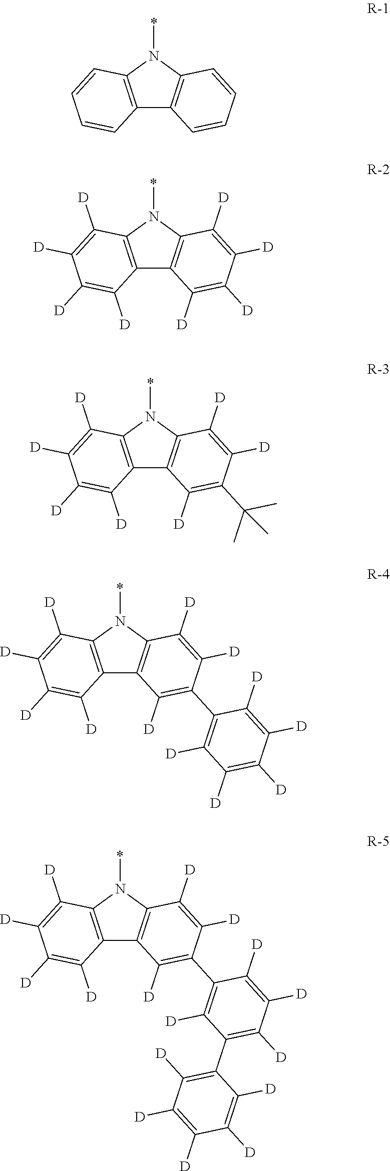 [SMILES: *n1c2ccccc2c2ccccc21 ; *n1c2c([2H])c([2H])c([2H])c([2H])c2c2c([2H])c([2H])c([2H])c([2H])c21 ; *n1c2c([2H])c([2H])c([2H])c([2H])c2c2c([2H])c(C(C)(C)C)c([2H])c([2H])c21 ; *n1c2c([2H])c([2H])c([2H])c([2H])c2c2c([2H])c(-c3c([2H])c([2H])c([2H])c([2H])c3[2H])c([2H])c([2H])c21 ; *n1c2c([2H])c([2H])c([2H])c([2H])c2c2c([2H])c(-c3c([2H])c([2H])c([2H])c(-c4c([2H])c([2H])c([2H])c([2H])c4[2H])c3[2H])c([2H])c([2H])c21]

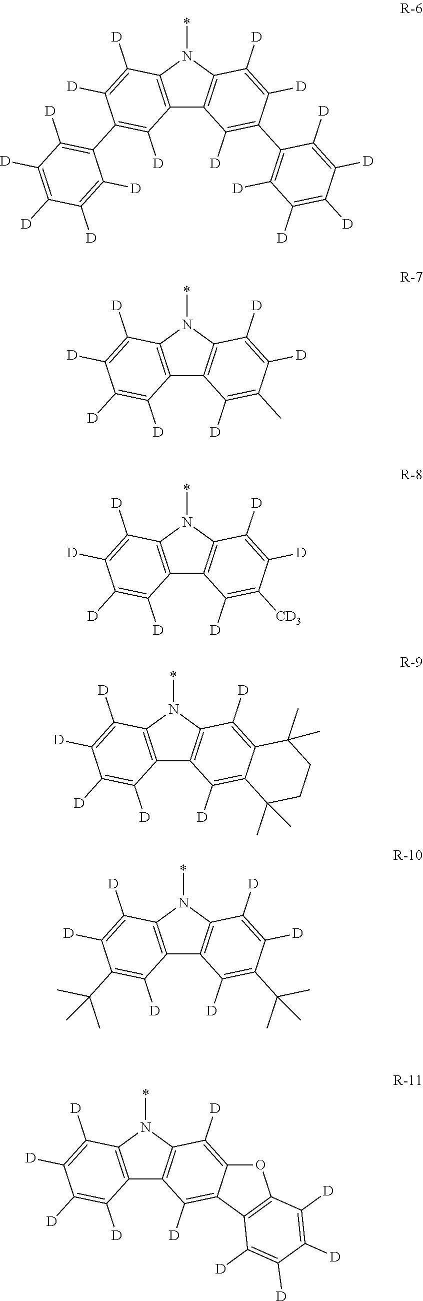

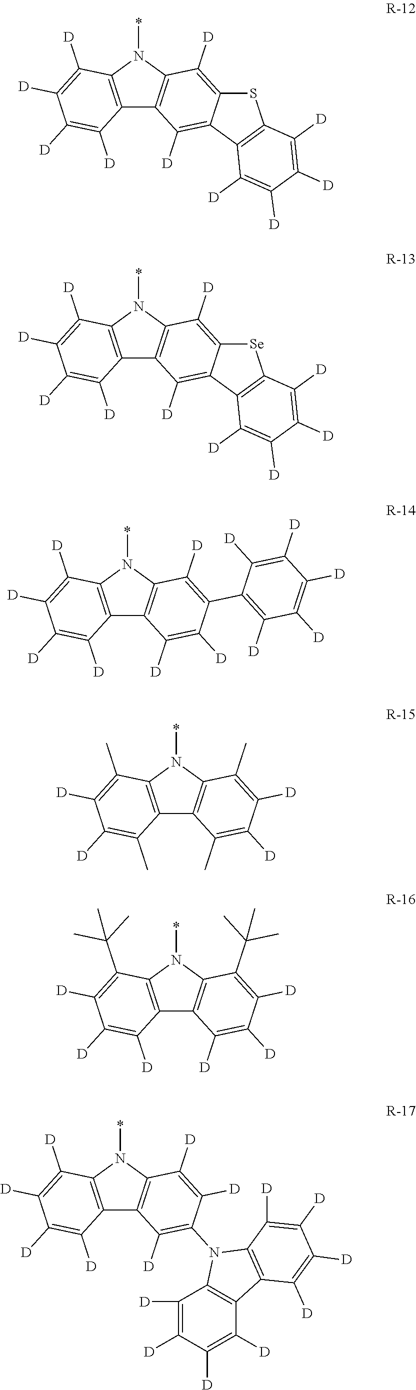

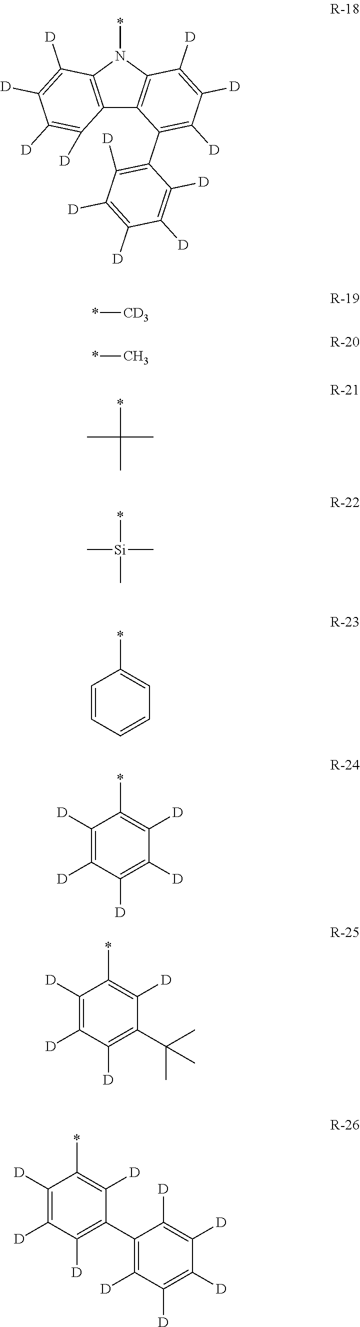

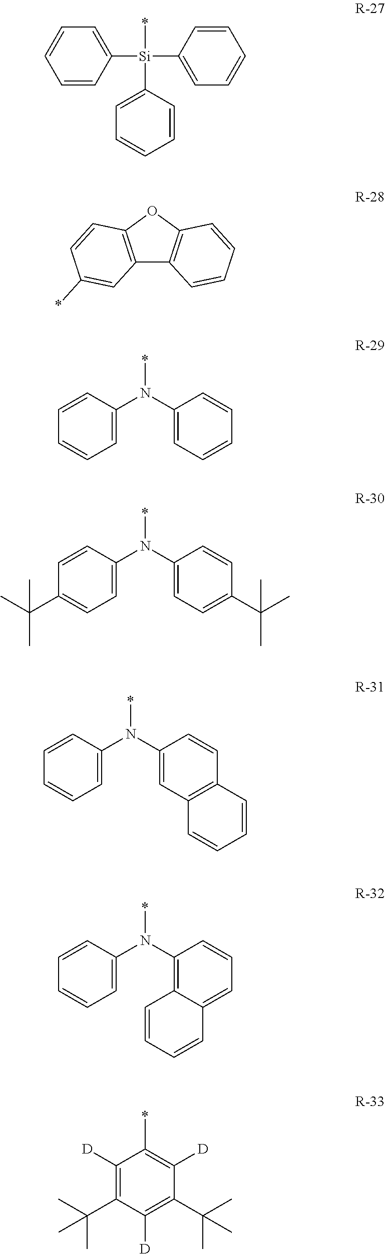

In Formula 1, n1 to n6 may each independently be an integer from 0 to 5. If n1 is 2 or greater, multiple Rₐ₁ may all be the same or at least one thereof may be different. A case where n1 is 5 and five Rₐ₁ are all hydrogen atoms may be the same as a case where n1 is 0. If n2 is 2 or greater, multiple Rₐ₅ may all be the same or at least one thereof may be different. A case where n2 is 5 and five Rₐ₅ are all hydrogen atoms may be the same as a case where n2 is 0. If n3 is 2 or greater, multiple Rₐ₆ may all be the same or at least one thereof may be different. A case where n3 is 5 and five Rₐ₆ are all hydrogen atoms may be the same as a case where n3 is 0.

If n4 is 2 or greater, multiple Rₐ₁₀ may all be the same or at least one thereof may be different. A case where n4 is 5 and five Rₐ₁₀ are all hydrogen atoms may be the same as a case where n4 is 0. If n5 is 2 or greater, multiple Rₐ₁₁ may all be the same or at least one thereof may be different. A case where n5 is 5 and five Rₐ₁₁ are all hydrogen atoms may be the same as a case where n5 is 0. If n6 is 2 or greater, multiple Rₐ₁₅ may all be the same or at least one thereof may be different. A case where n6 is 5 and five Rₐ₁₅ are all hydrogen atoms may be the same as a case where n6 is 0.

In an embodiment, in Formula 1, a first terphenyl moiety that includes Rₐ₁ to Rₐ₅, a second terphenyl moiety that includes Rₐ₆ to Rₐ₁₀, and a third terphenyl moiety that includes Rₐ₁₁ to Rₐ₁₅ may each independently be a moiety represented by one of Formulas RA-1 to RA-8. For example, the first to third terphenyl moieties may each independently be a moiety represented by Formula RA-1 or Formula RA-2.

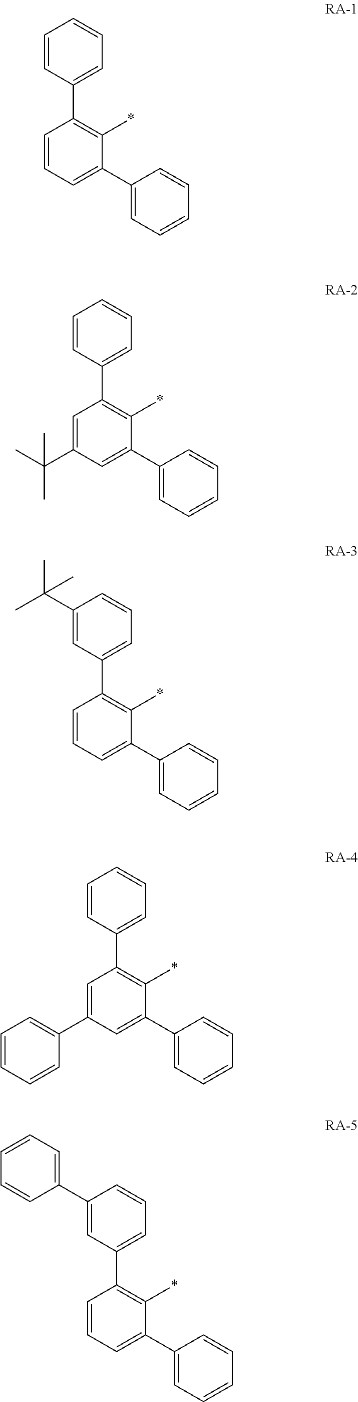 [SMILES: *c1c(-c2ccccc2)cccc1-c1ccccc1 ; *c1c(-c2ccccc2)cc(C(C)(C)C)cc1-c1ccccc1 ; *c1c(-c2ccccc2)cccc1-c1cccc(C(C)(C)C)c1 ; *c1c(-c2ccccc2)cc(-c2ccccc2)cc1-c1ccccc1 ; *c1c(-c2ccccc2)cccc1-c1cccc(-c2ccccc2)c1]

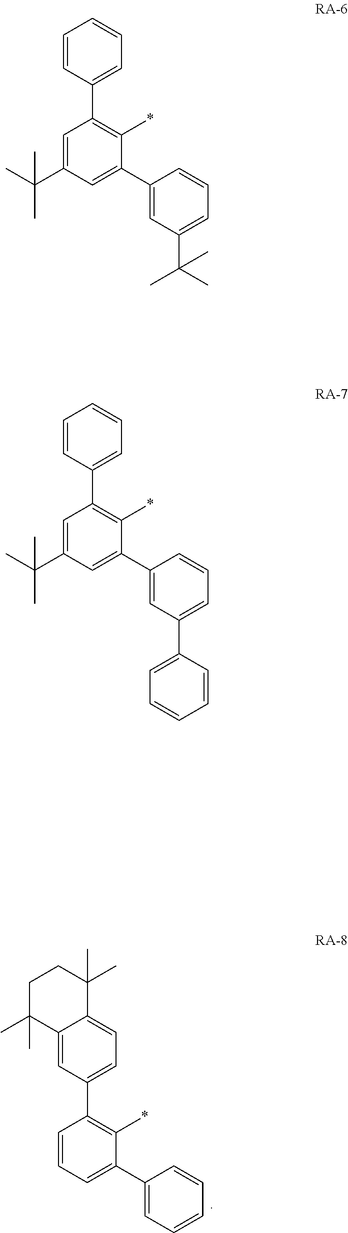

In an embodiment, in Formula 1, R₁₃ to R₁₅ may each independently be a hydrogen atom, a deuterium atom, a substituted or unsubstituted diphenylamine group, a substituted or unsubstituted methyl group, a substituted or unsubstituted t-butyl group, a substituted or unsubstituted phenyl group, or a substituted or unsubstituted carbazole group. For example, R₁₃ and R₁₅ may each independently be a hydrogen atom, or a deuterium atom. For example, R₁₄ may be a hydrogen atom, a deuterium atom, a substituted or unsubstituted diphenylamine group, a substituted or unsubstituted methyl group, a substituted or unsubstituted t-butyl group, a substituted or unsubstituted phenyl group, or a substituted or unsubstituted carbazole group. However, this is only an example, and embodiments are not limited thereto.

In an embodiment, the fused polycyclic compound represented by Formula 1 may include a deuterium atom. In an embodiment, in Formula 1, at least one of R₁ to R₁₅ may be a deuterium atom, or may include a substituent that is substituted with a deuterium atom.

In an embodiment, the fused polycyclic compound represented by Formula 1 may be represented by one of Formula 1-A1 to Formula 1-A3. Formula 1-A1 may represent a case where R₃ and R₆ are each independently a substituted or unsubstituted phenyl group in Formula 1. Formula 1-A2 may represent a case where R₂ and R7 are each independently a substituted or unsubstituted phenyl group in Formula 1. Formula 1-A3 may represent a case where R₃ and R₇ are each independently a substituted or unsubstituted phenyl group in Formula 1.

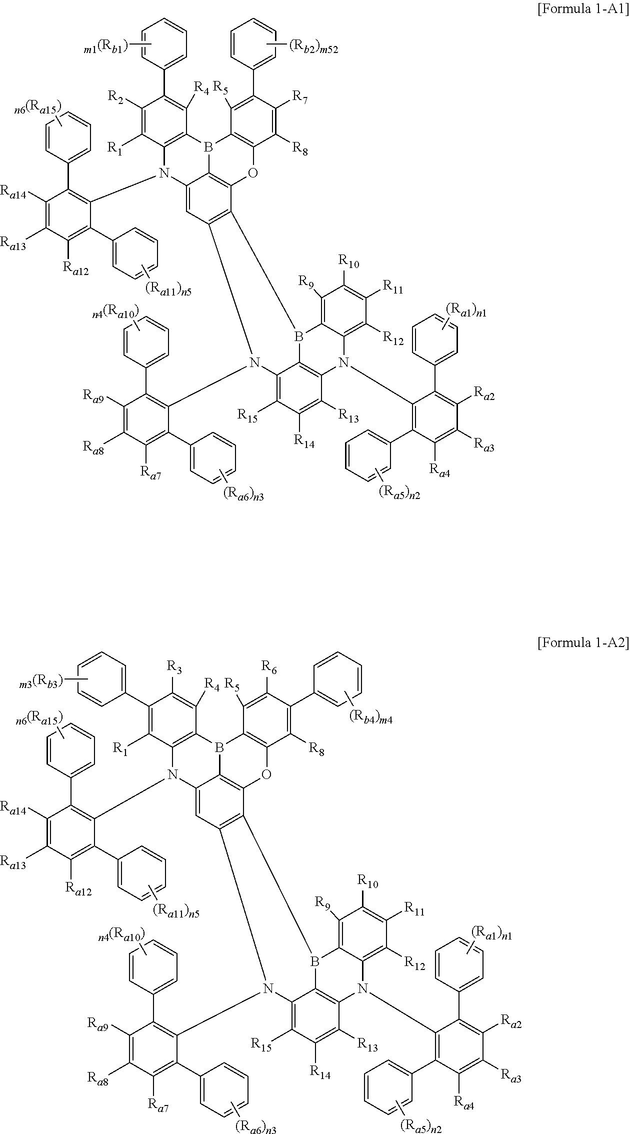

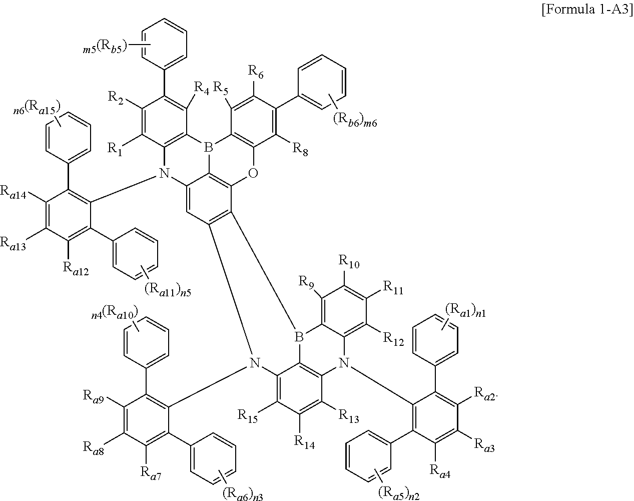

In Formula 1-A1 to Formula 1-A3, n1 to n6, R₁ to R₁₅, and Rₐ₁ to Rₐ₁₅ are the same as defined in Formula 1.

In Formula 1-A1 to Formula 1-A3, R_{b1} to R_{b6} may each independently be a hydrogen atom, a deuterium atom, a substituted or unsubstituted oxy group, a substituted or unsubstituted thio group, a substituted or unsubstituted alkyl group having 1 to 30 carbons, or a substituted or unsubstituted aryl group having 6 to 30 ring-forming carbons, or bonded to an adjacent group to form a ring. For example, R_{b3} to R_{b6} may each independently be a hydrogen atom, a deuterium atom, or a substituted or unsubstituted phenyl group.

For example, R_{b1} may be a hydrogen atom, a deuterium atom, a substituted or unsubstituted oxy group, or a substituted or unsubstituted thio group, or bonded to the benzene ring substituted with R_{b1} to form a ring. A ring that is formed with R_{b1} may include O or S as a ring-forming atom. For example, R_{b2} may be a hydrogen atom, a deuterium atom, a substituted or unsubstituted oxy group, or a substituted or unsubstituted thio group, or bonded to an adjacent group to form a ring. A ring that is formed with R_{b2} may include O or S as a ring-forming atom.

In Formula 1-A1 to Formula 1-A3, m1 to m6 may each independently be an integer from 0 to 5. If m1 is 2 or greater, multiple R_{b1} may all be the same, or at least one thereof may be different. A case where m1 is 5 and five R_{b1} are all hydrogen atoms are the same as a case where m1 is 0. If m2 is 2 or greater, multiple R_{b2} may all be the same, or at least one thereof may be different. A case where m2 is 5 and five R_{b2} are all hydrogen atoms are the same as a case where m2 is 0. If m3 is 2 or greater, multiple R_{b3} may all be the same, or at least one thereof may be different. A case where m3 is 5 and five R_{b3} are all hydrogen atoms are the same as a case where m3 is 0.

If m4 is 2 or greater, multiple R_{b4} may all be the same, or at least one thereof may be different. A case where m4 is 5 and five R_{b4} are all hydrogen atoms may be the same as a case where m4 is 0. If m5 is 2 or greater, multiple R_{b5} may all be the same, or at least one thereof may be different. A case where m5 is 5 and five R_{b5} are all hydrogen atoms may be the same as a case where m5 is 0. If m6 is 2 or greater, multiple R_{b6} may all be the same, or at least one thereof may be different. A case where m6 is 5 and five R_{b6} are all hydrogen atoms may be the same as a case where m6 is 0.

In an embodiment, the fused polycyclic compound represented by Formula 1 may be represented by one of Formula 1-A4 to Formula 1-A6. Formula 1-A4 may represent a case where R₁ binds to R₂ to form a ring, and R7 binds to R₈ to form a ring in Formula 1. Formula 1-A5 may represent a case where R₂ in Formula 1 is an amine group or a carbazole group. Formula 1-A6 may represent a case where R₇ in Formula 1 is an amine group or a carbazole group.

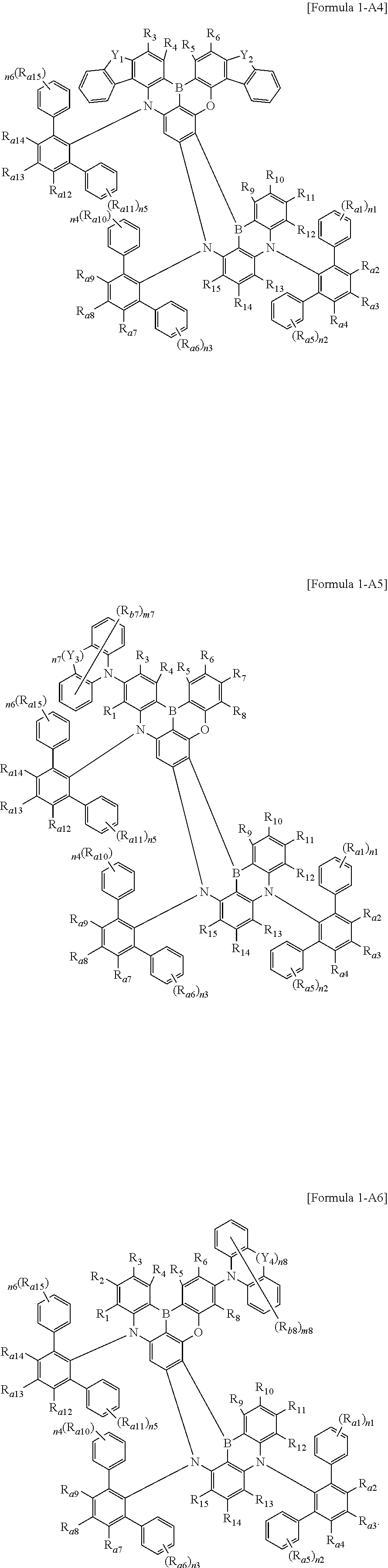

In Formula 1-A4 to Formula 1-A6, n1 to n6, R₁ to R₁₅, and Rₐ₁ to Rₐ₁₅ are the same as defined in Formula 1.

In Formula 1-A4, Y₁ and Y₂ may each independently be N(R₁₆), O, or S; and R₁₆ may be a substituted or unsubstituted aryl group having 6 to 30 ring-forming carbons. For example, Y₁ and Y₂ may each independently N(Ph), O, or S, wherein Ph represents an unsubstituted phenyl group.

In Formula 1-A5, n7 may be 0 or 1; and Y₃ may be a direct linkage. If n7 is 0, Y₃ is not present, and a moiety that includes R_{b7} may be a substituted or unsubstituted diphenylamine group. If n7 is 1, Y₃ is present. If n7 is 1, Y₃ may be a direct linkage, and a moiety that includes R_{b7} may be a substituted or unsubstituted carbazole group.

In Formula 1-A5, m7 may be an integer from 0 to 10; and R_{b7} may be a hydrogen atom or a deuterium atom. If m7 is 2 or greater, multiple R_{b7} may all be the same or at least one may be different.

In Formula 1-A5, if n7 is 0, Y₃ is not present, and thus up to ten R_{b7} may be present. A case where n7 is 0, m7 is 10, and ten R_{b7} are all hydrogen atoms may be the same as a case where n7 is 0 and m7 is 0.

In Formula 1-A5, if n7 is 1, Y₃ is present, and thus up to eight R_{b7} may be present. A case where n7 is 1, m7 is 8, and eight R_{b7} are all hydrogen atoms may be the same as a case where n7 is 1 and m7 is 0.

In Formula 1-A6, n8 may be 0 or 1; and Y₄ may be a direct linkage. If n8 is 0, Y₄ is not present, and a moiety that includes R_{b8} may be a substituted or unsubstituted diphenylamine group. If n8 is 1, Y₄ is present. If n8 is 1, Y₃ may be a direct linkage, and a moiety that includes R_{b8} may be a substituted or unsubstituted carbazole group.

In Formula 1-A6, m8 may be an integer from 0 to 10; and R_{b8} may be a hydrogen atom or a deuterium atom. If m8 is 2 or greater, multiple R_{b8} may all be the same or at least one thereof may be different.

In Formula 1-A6, if n8 is 0, Y₄ is not present, and thus up to ten R_{b8} may be present. A case where n8 is 0, m8 is 10, and ten R_{b8} are all hydrogen atoms may be the same as a case where n8 is 0 and m8 is 0.

In Formula 1-A6, if n8 is 1, Y₄ is present, and thus up to eight R_{b8} may be present. A case where n8 is 1, m8 is 8, and eight R_{b8} are all hydrogen atoms may be the same as a case where n8 is 1 and m8 is 0.

In an embodiment, the fused polycyclic compound represented by Formula 1 may be represented by Formula 1-B. Formula 1-B1 may represent a case where R₁₁ is an amine group or a carbazole group in Formula 1.

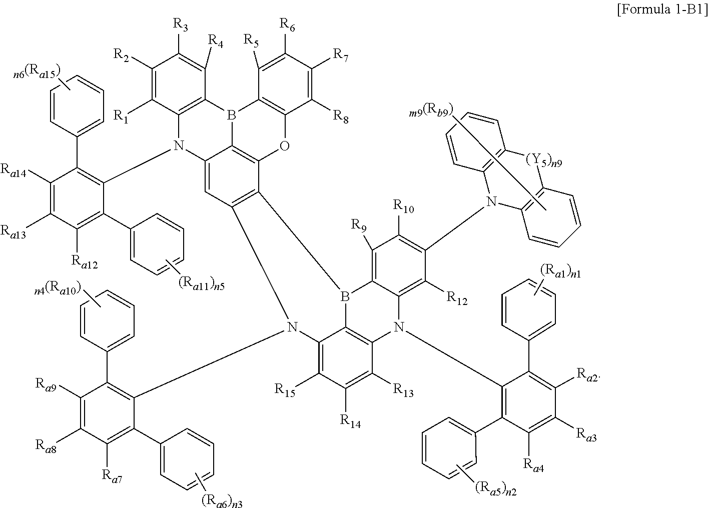

In Formula 1-B1, n1 to n6, R₁ to R₁₀, R₁₂ to R₁₅, and Rₐ₁ to Rₐ₁₅ are the same as defined in Formula 1.

In Formula 1-B1, n9 may be 0 or 1; and Y₅ may be a direct linkage. If n9 is 0, Y₅ is not present, and a moiety that includes R_{b9} may be a substituted or unsubstituted diphenylamine group. If n9 is 1, Y₅ is present. If n9 is 1, Y₅ may be a direct linkage, and a moiety that includes R_{b9} may be a substituted or unsubstituted carbazole group.

In Formula 1-B1, m9 may be an integer from 0 to 10; and R may be a hydrogen atom, a deuterium atom, a substituted or unsubstituted oxy group, a substituted or unsubstituted thio group, a substituted or unsubstituted selenium group, a substituted or unsubstituted alkyl group having 1 to 30 carbons, a substituted or unsubstituted alkenyl group having 2 to 30 carbons, a substituted or unsubstituted aryl group having 6 to 30 ring-forming carbons, or a substituted or unsubstituted heteroaryl group having 2 to 30 ring-forming carbons, or bonded to an adjacent group to form a ring. For example, in an embodiment, the moiety that includes R_{b9} may be a moiety represented by one of Formulas R-1 to R-18 and R-29 to R-32, as described above.

In Formula 1-B1, if m9 is 2 or greater, multiple R_{b9} may all be the same or at least one thereof may be different. If n9 is 0, Y₅ is not present, and thus up to ten R_{b9} may be present. A case where n9 is 0, m9 is 10 and ten R_{b9} are all hydrogen atoms may be the same as a case where n9 is 1 and m9 is 0.

In Formula 1-B1, if n9 is 1, Y₅ is present, and thus up to eight R_{b9} may be present. A case where n9 is 1, m8 is 8, and eight R_{b9} are all hydrogen atoms may be the same as a case where n9 is 1 and m9 is 0.

In an embodiment, the fused polycyclic compound represented by Formula 1 may be any compound selected from Compound Group 1. In an embodiment, in the light-emitting element ED, the first compound may include at least one compound selected from Compound Group 1. In Compound Group 1, D represents a deuterium atom.

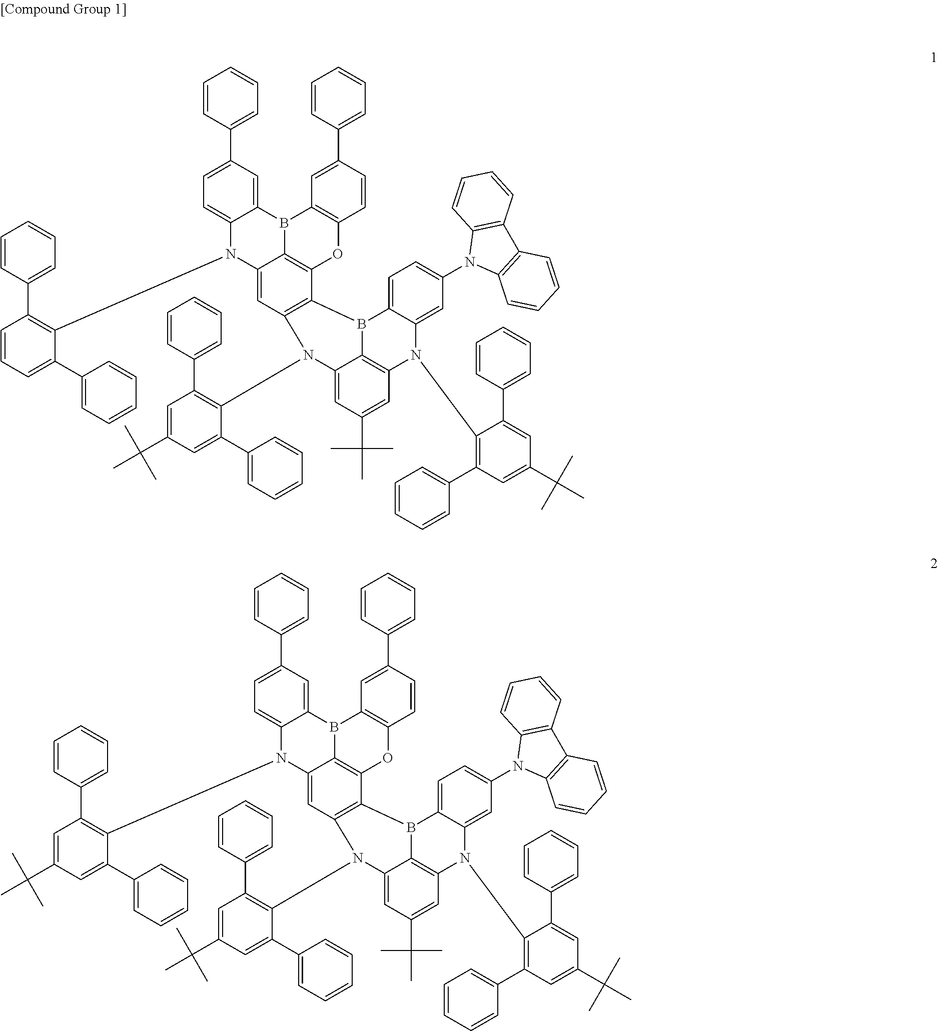

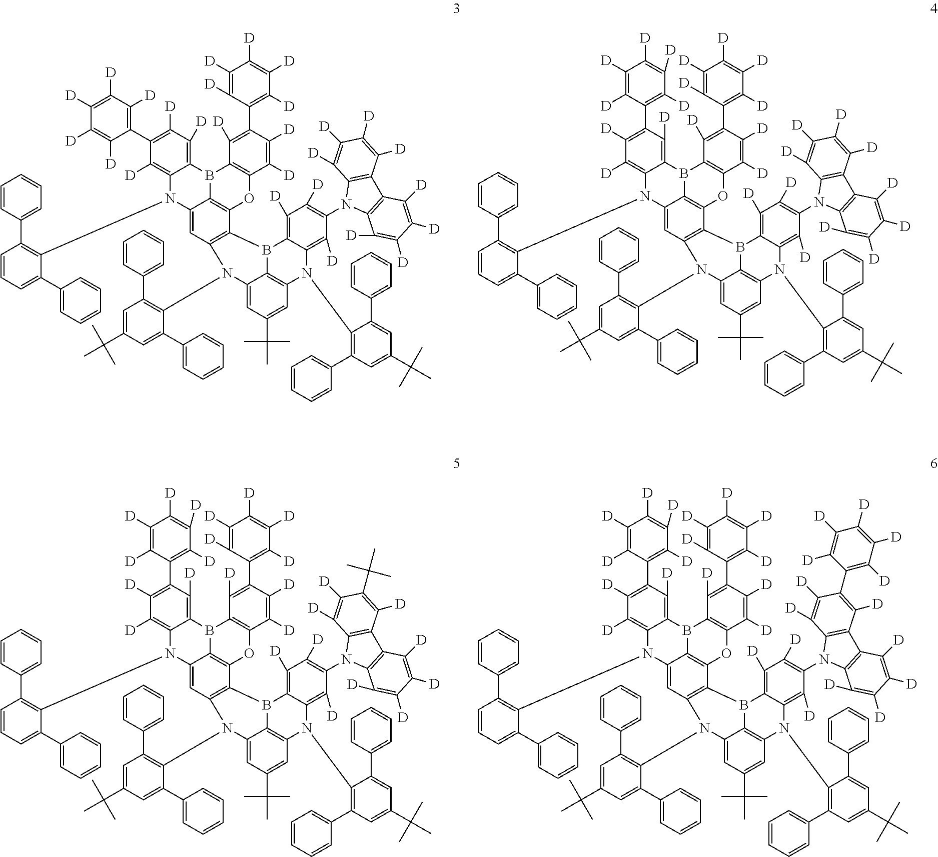

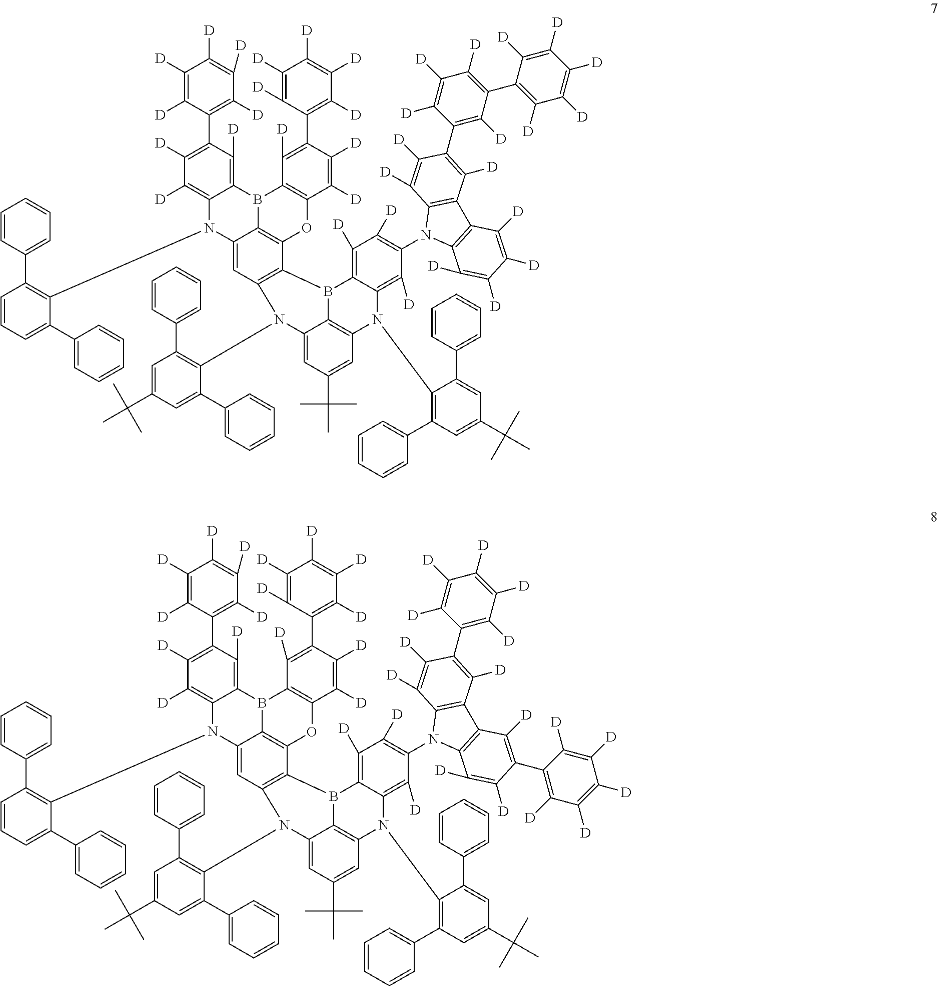

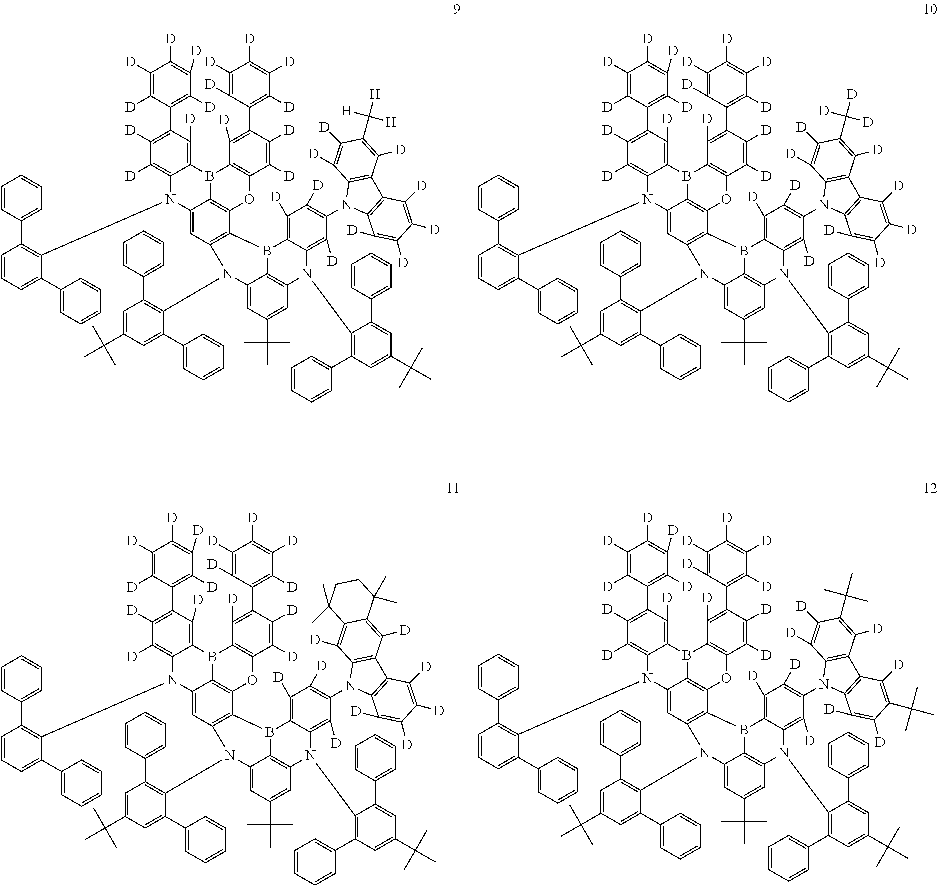

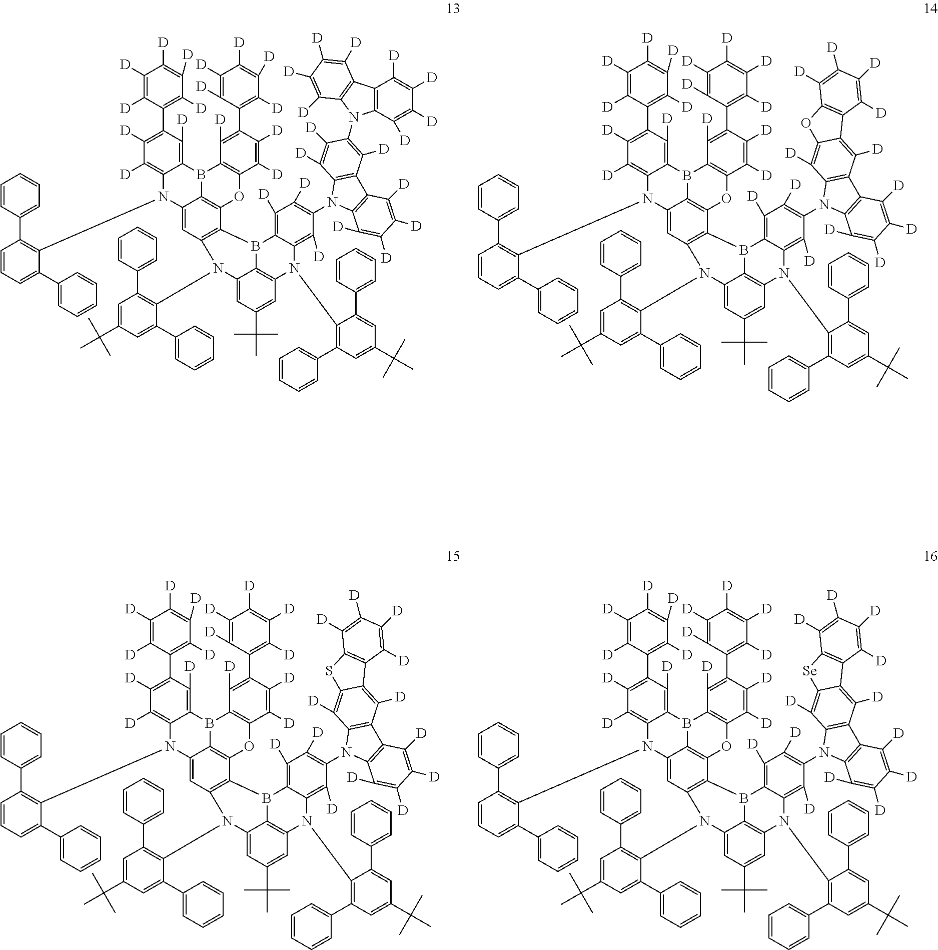

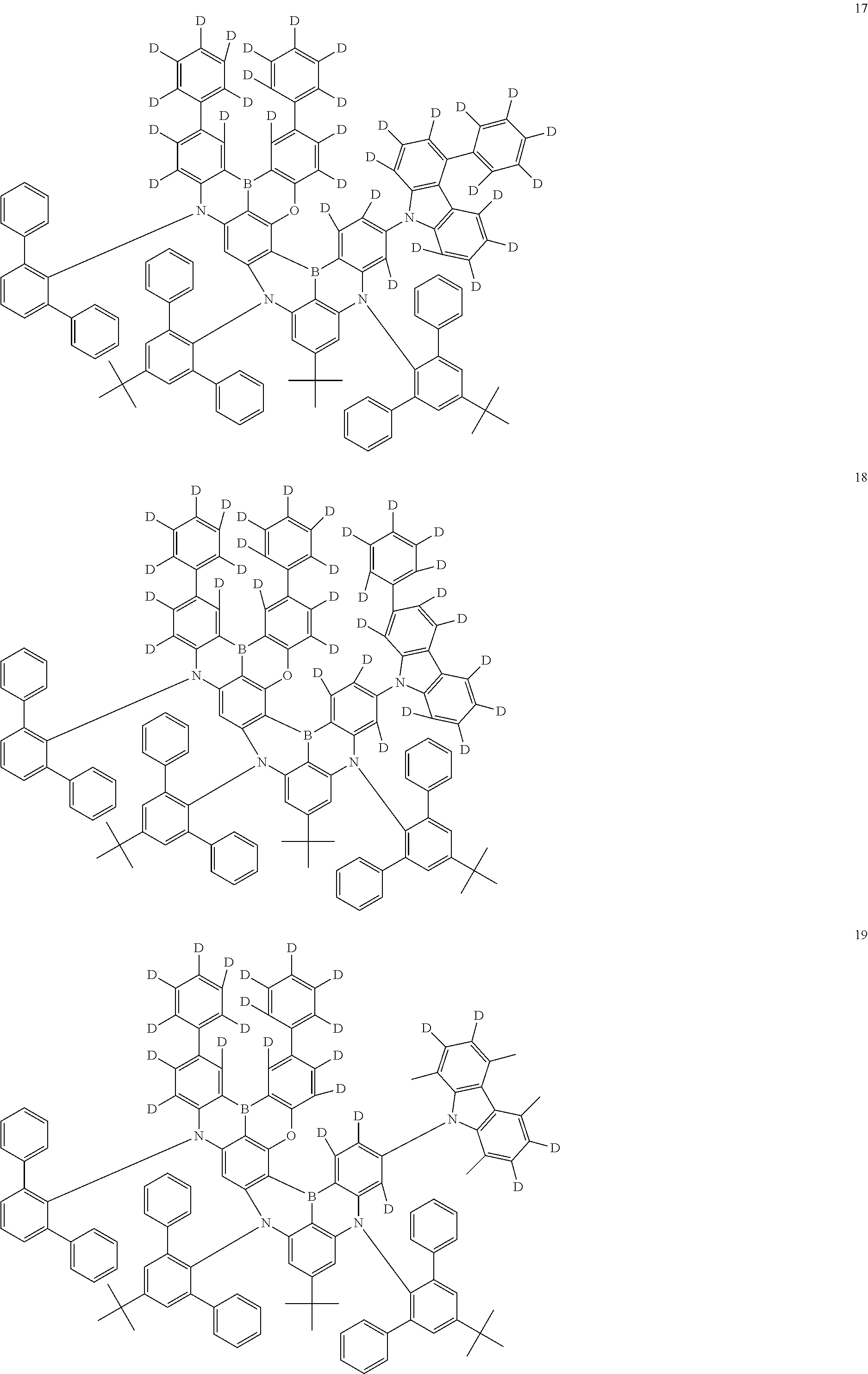

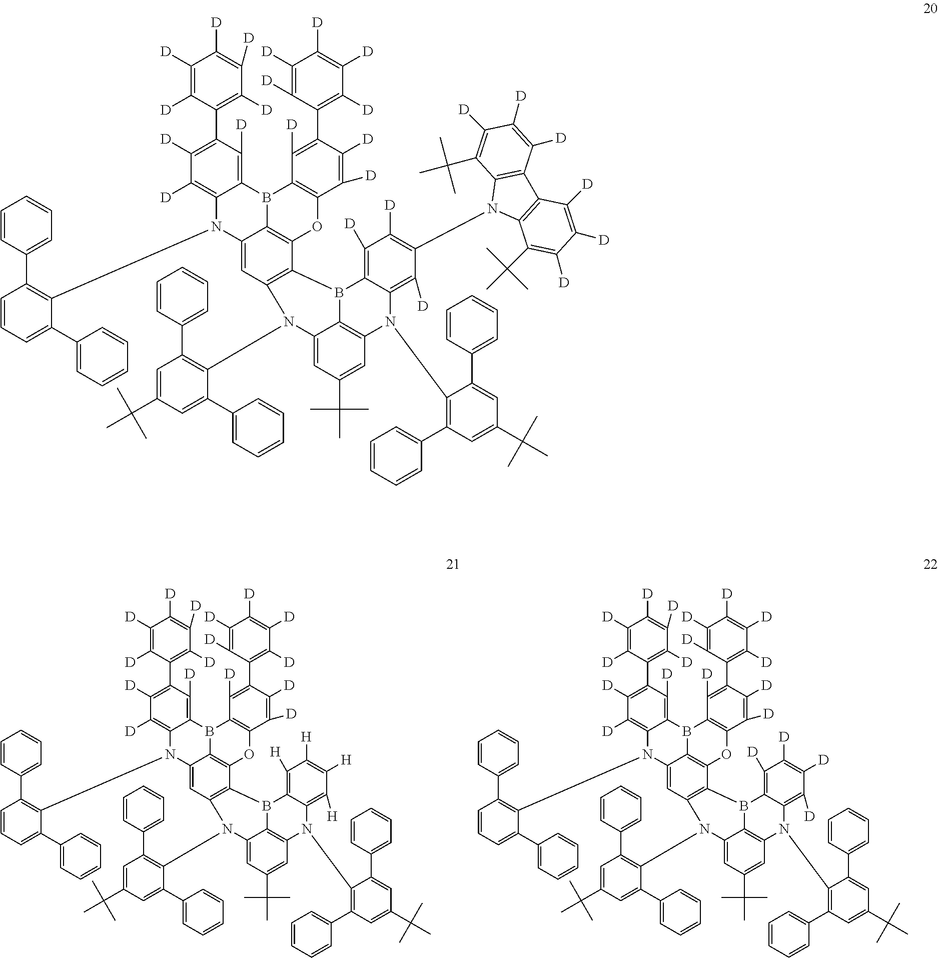

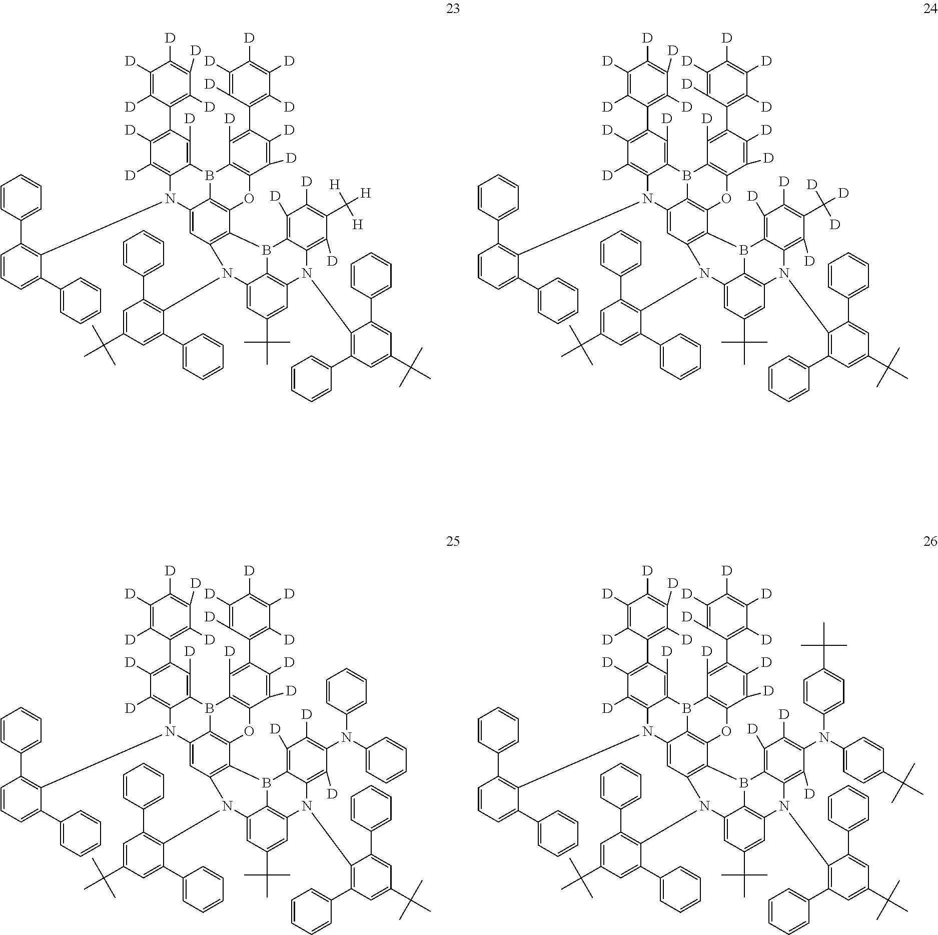

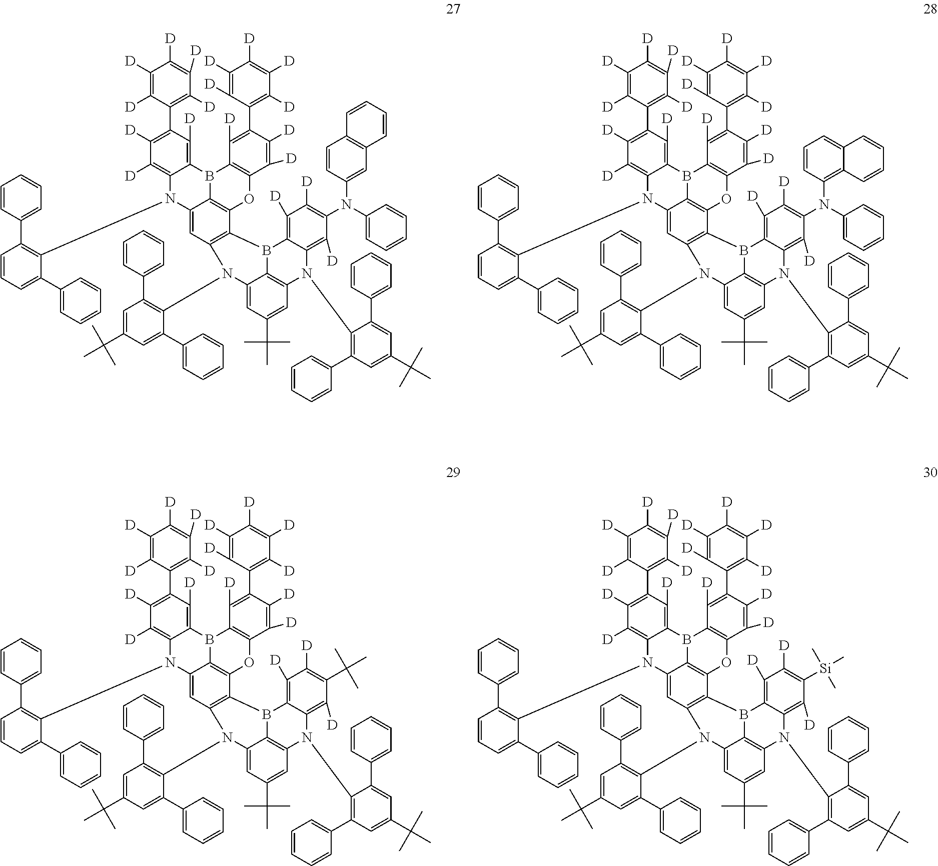

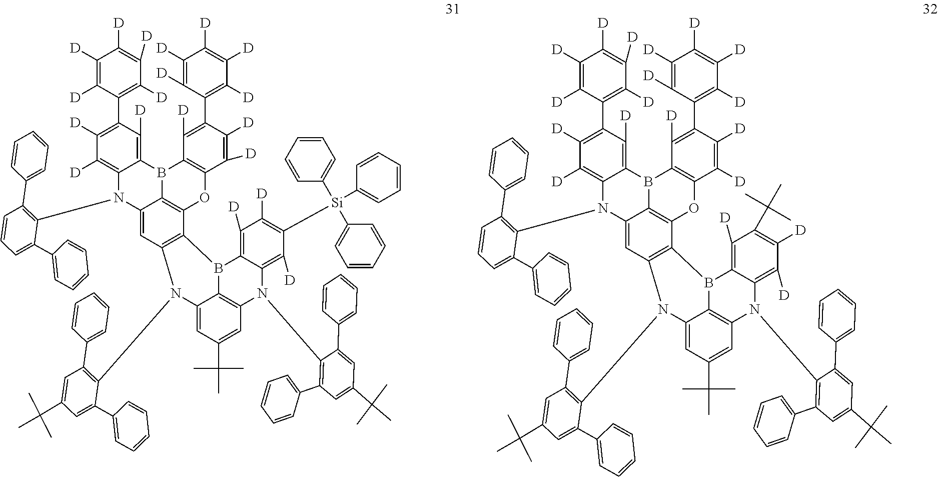

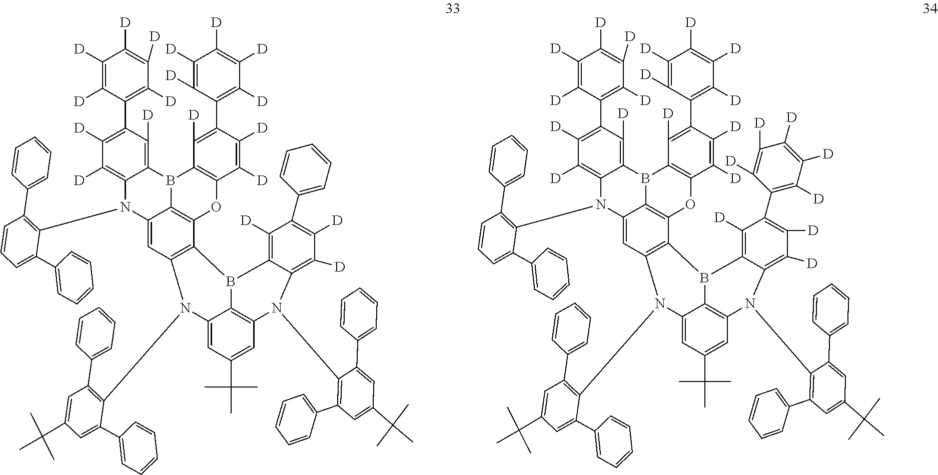

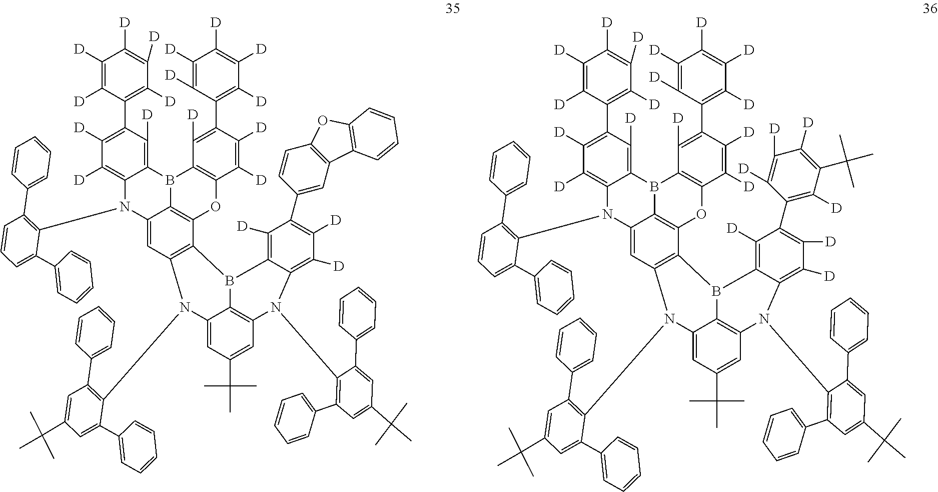

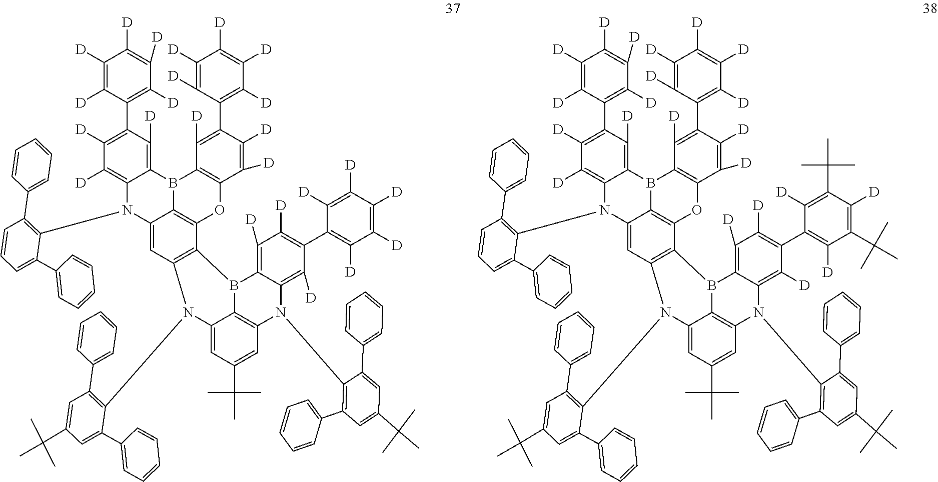

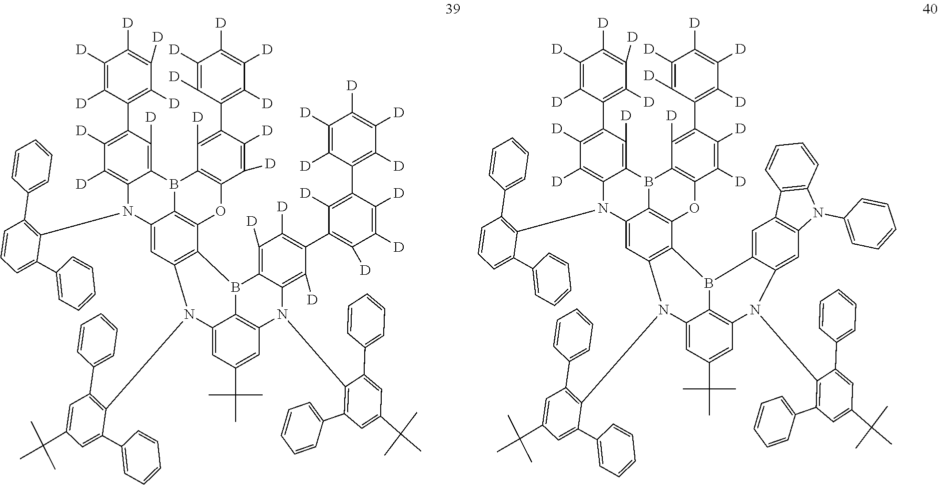

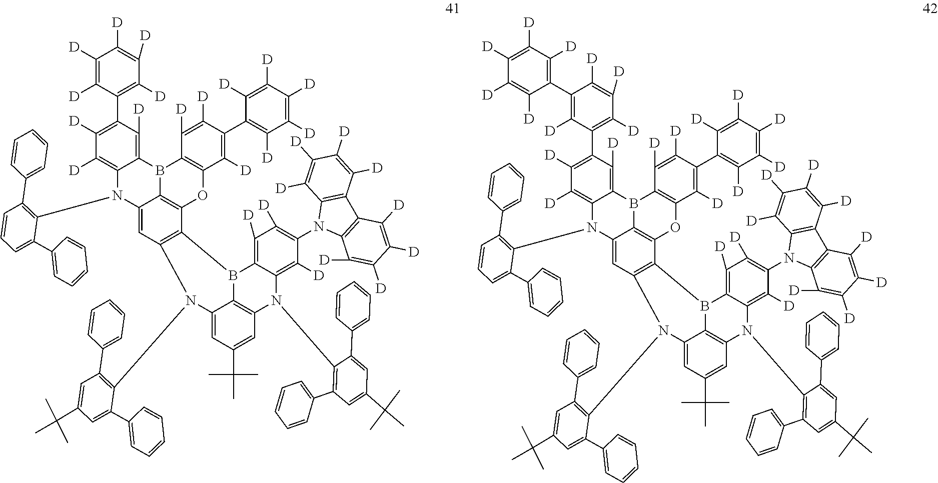

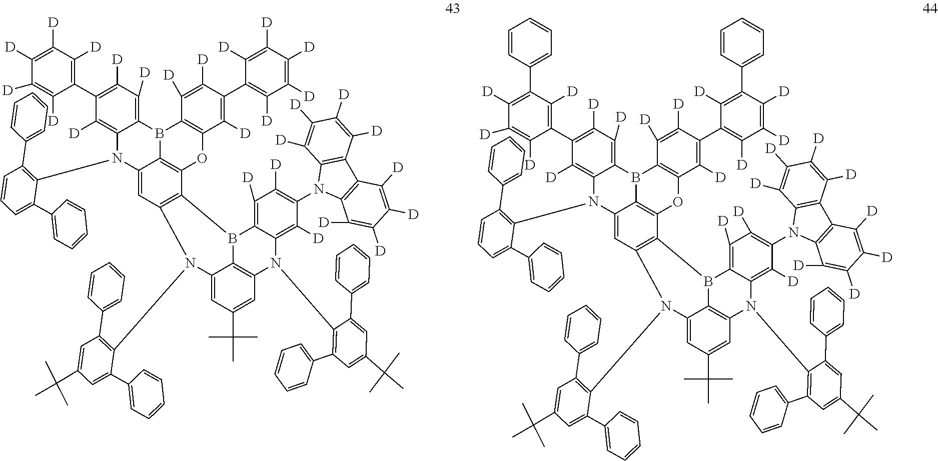

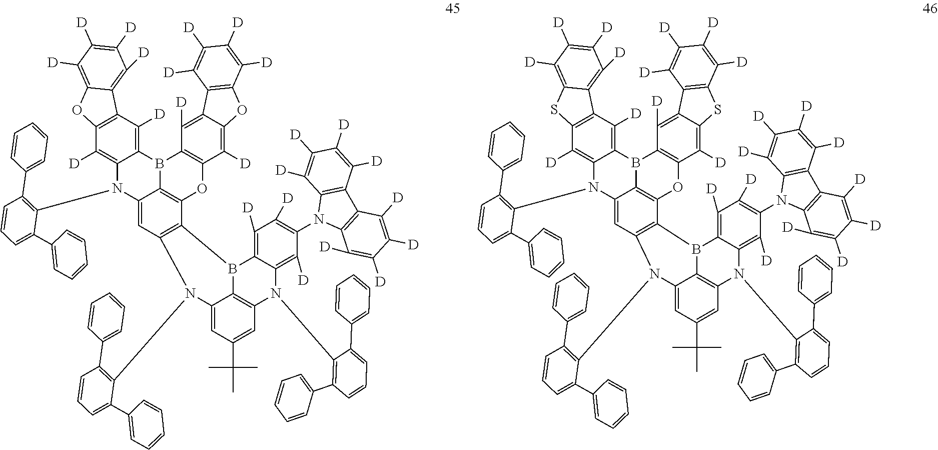

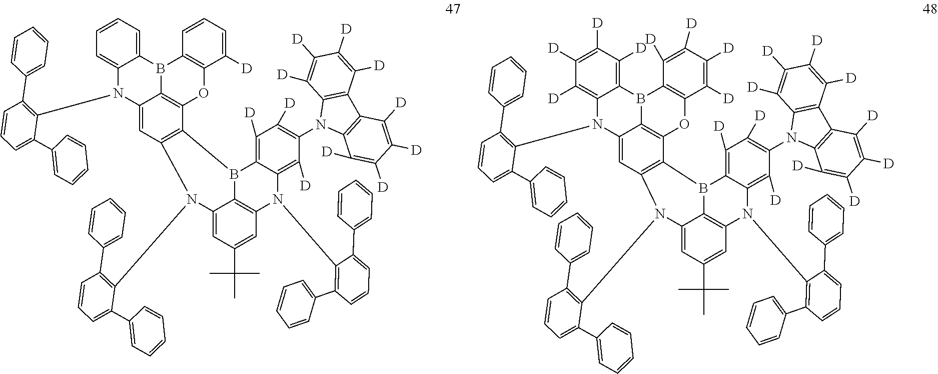

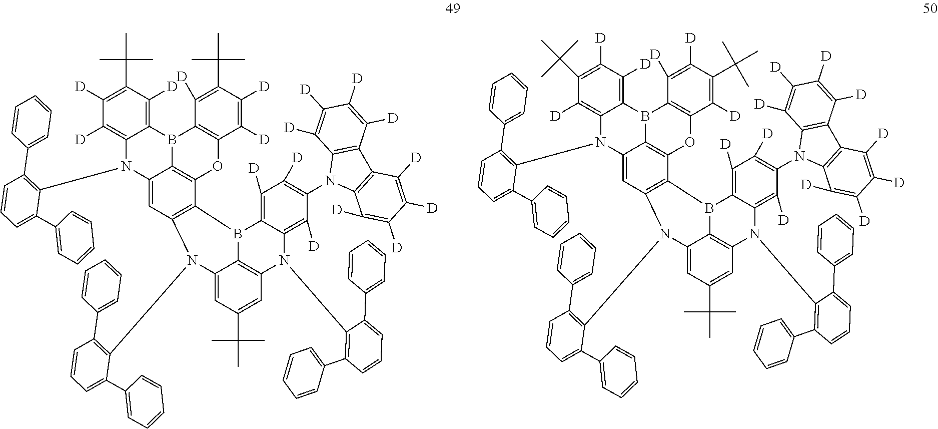

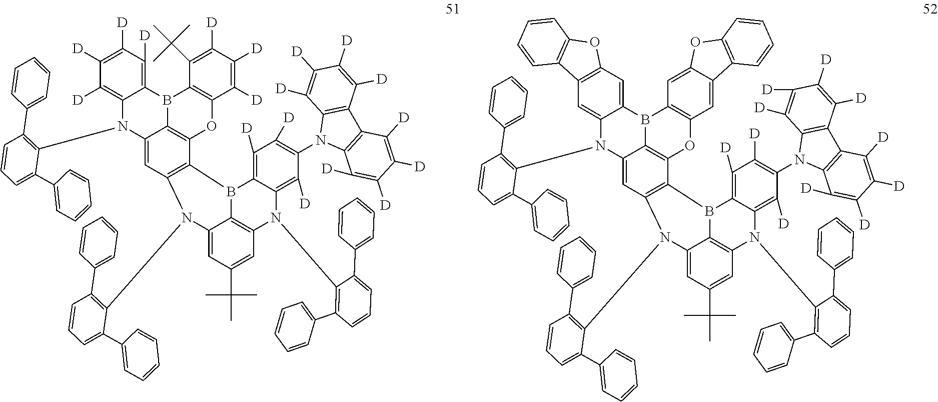

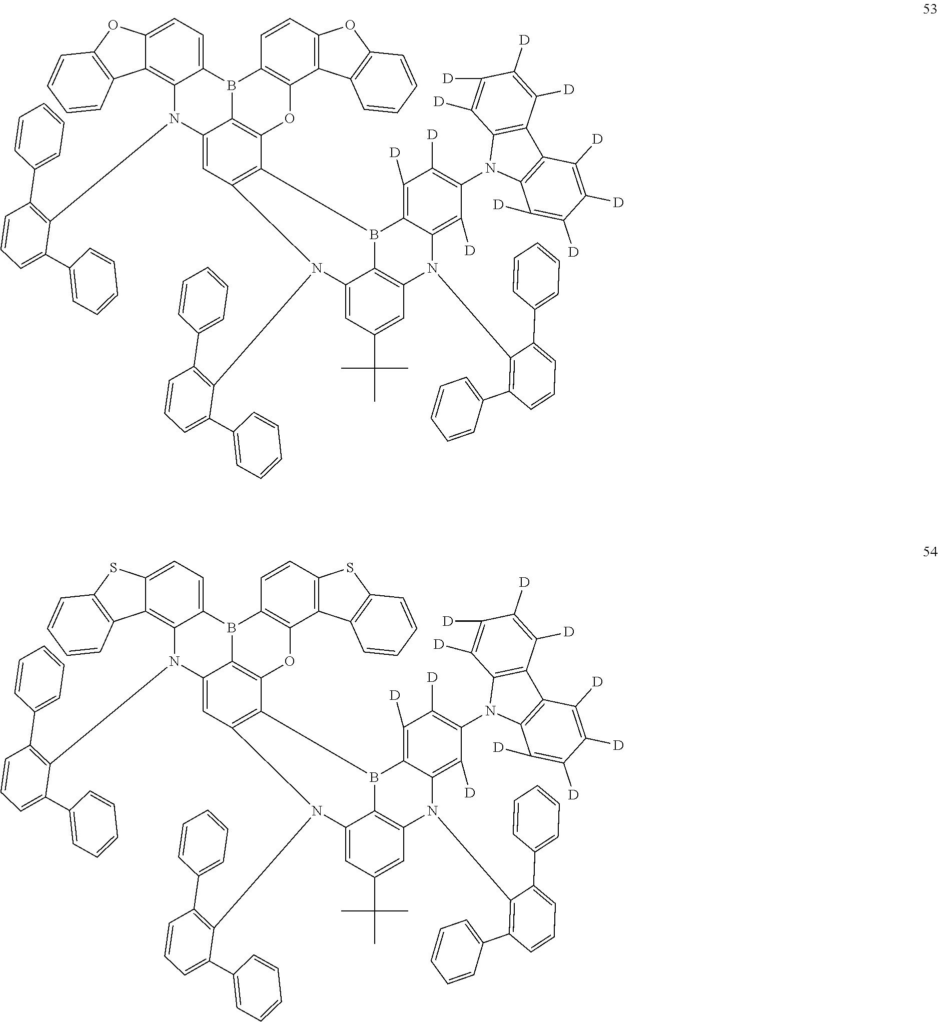

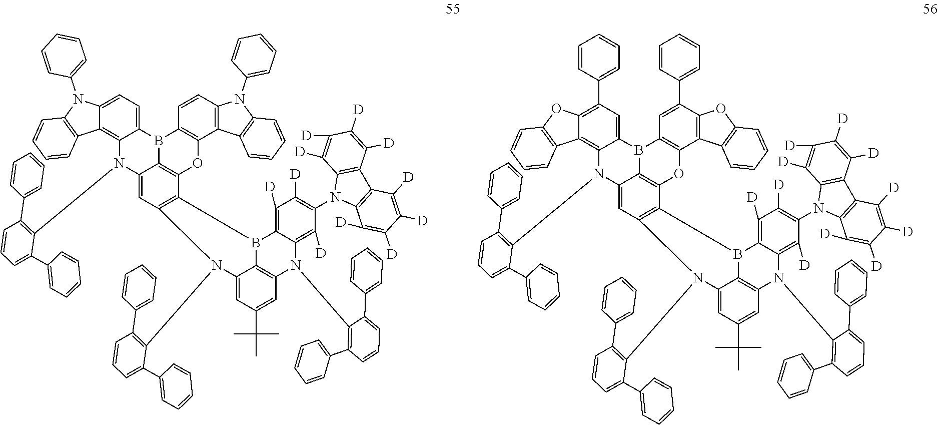

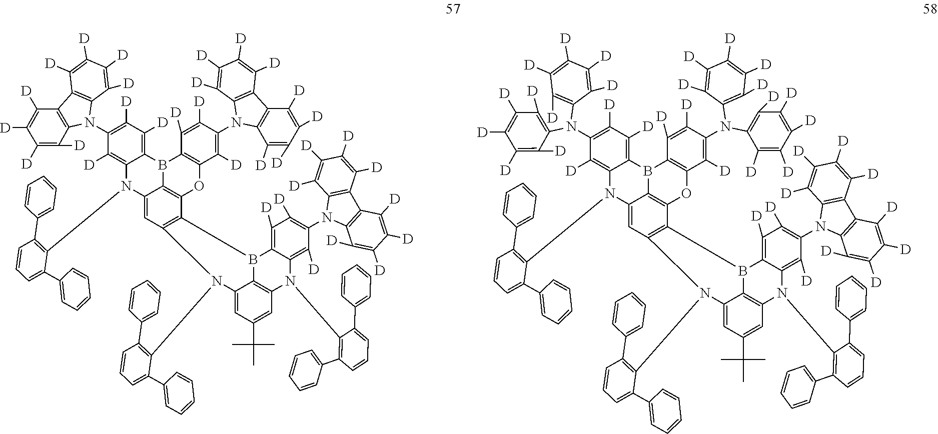

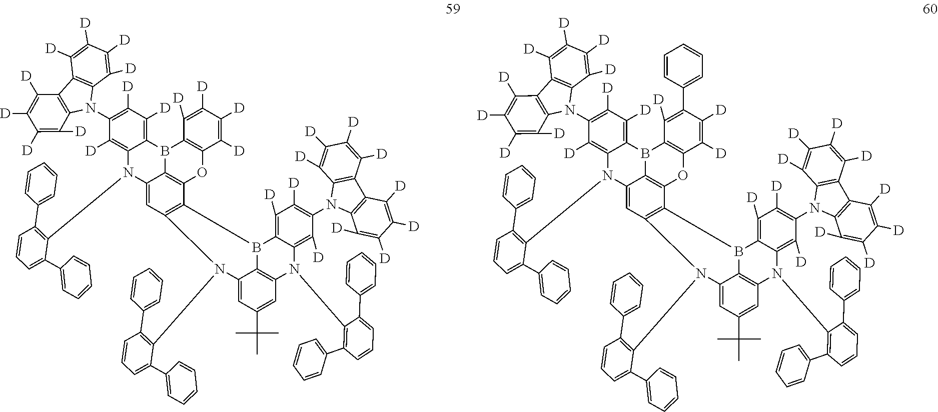

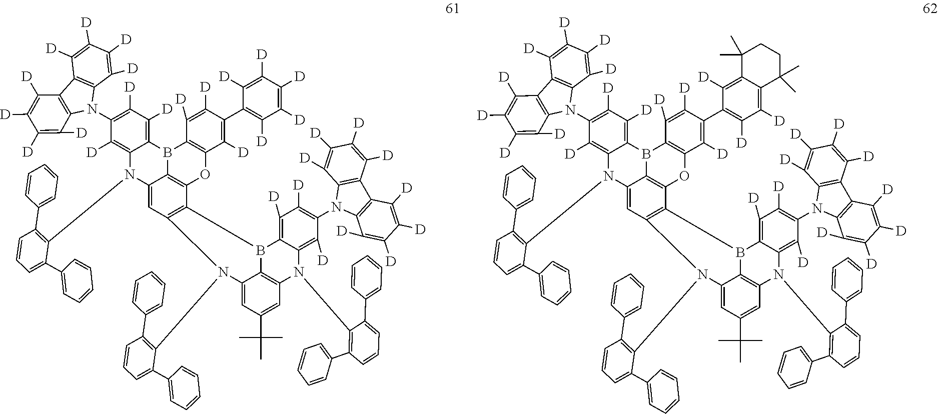

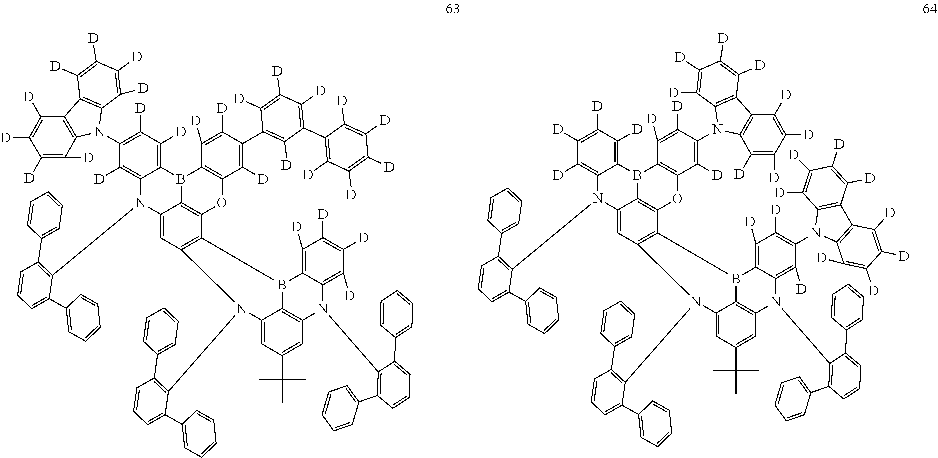

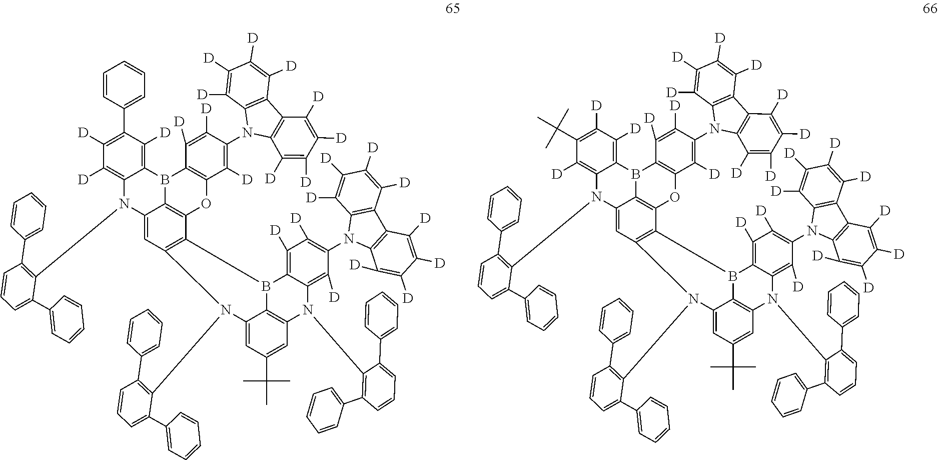

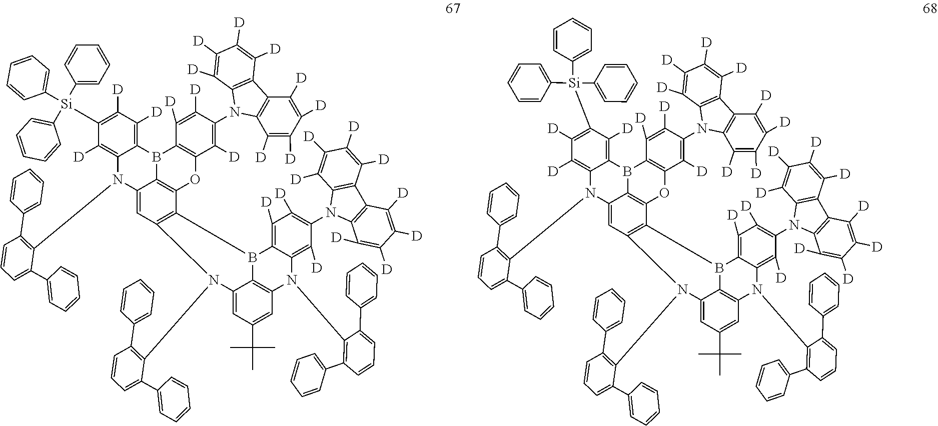

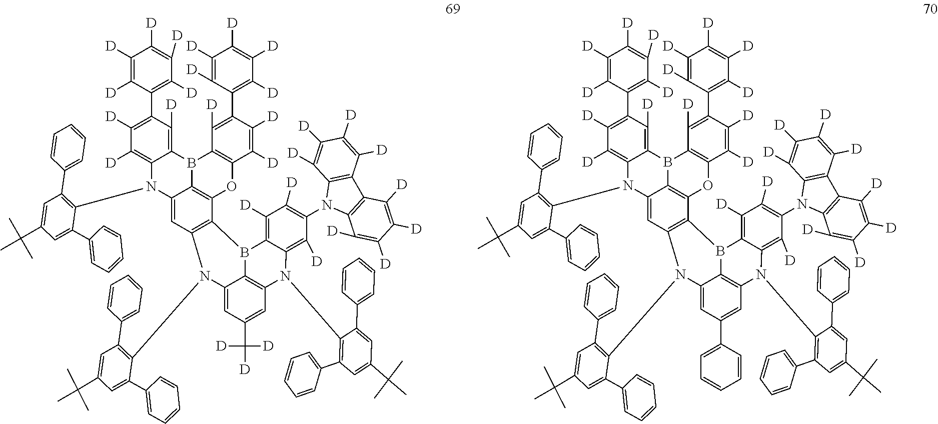

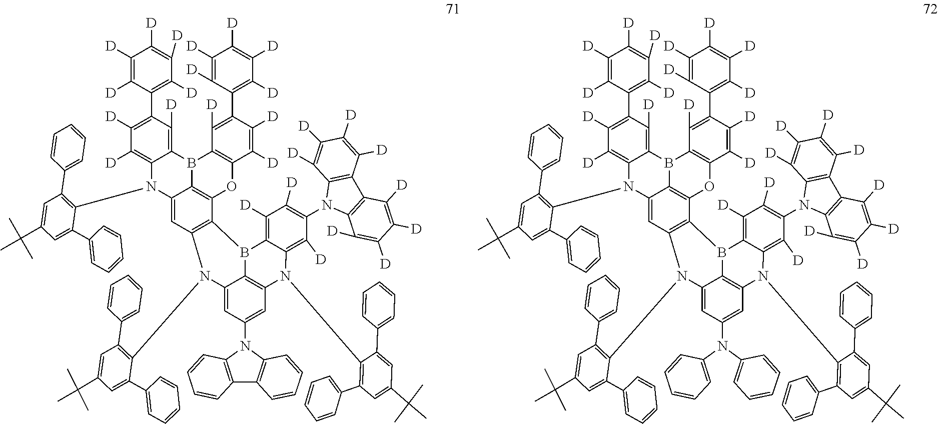

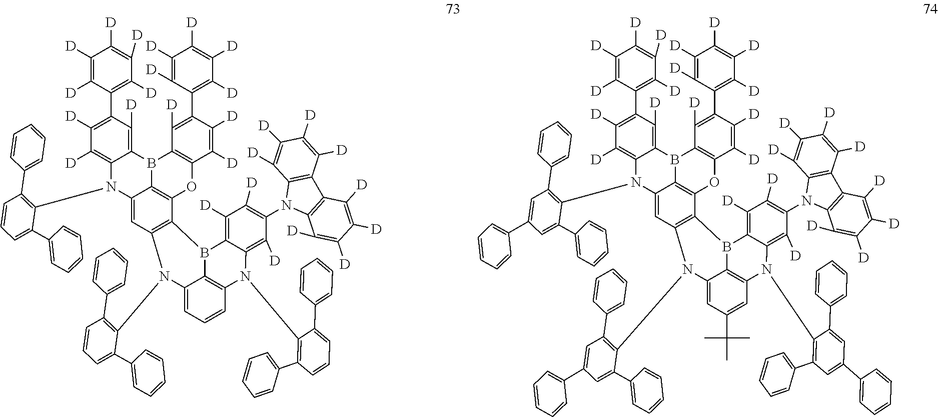

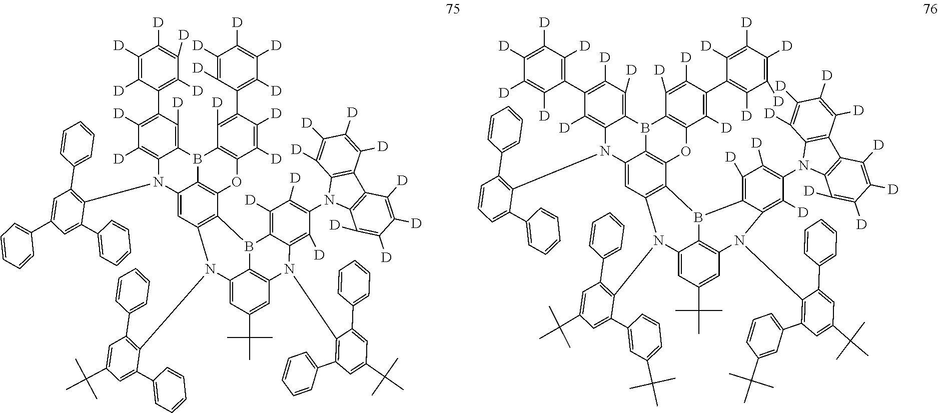

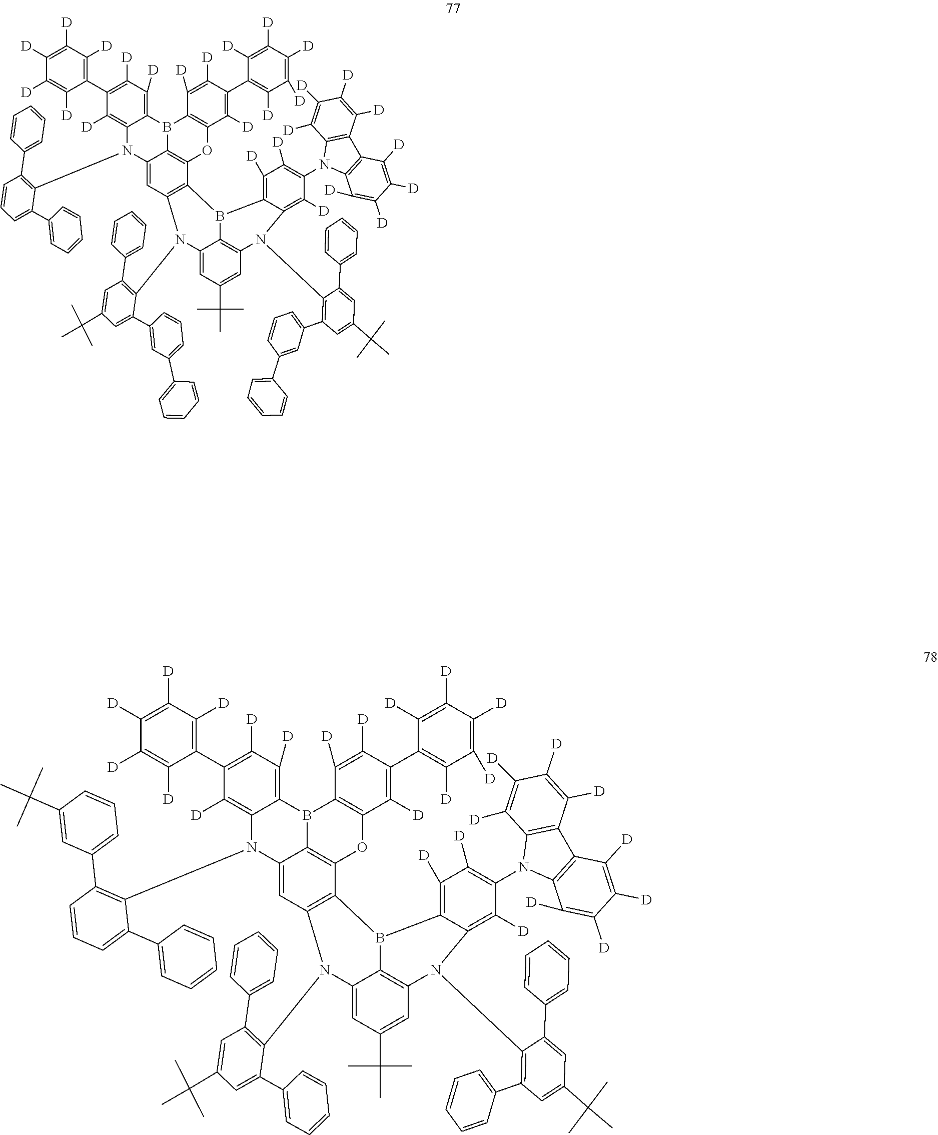

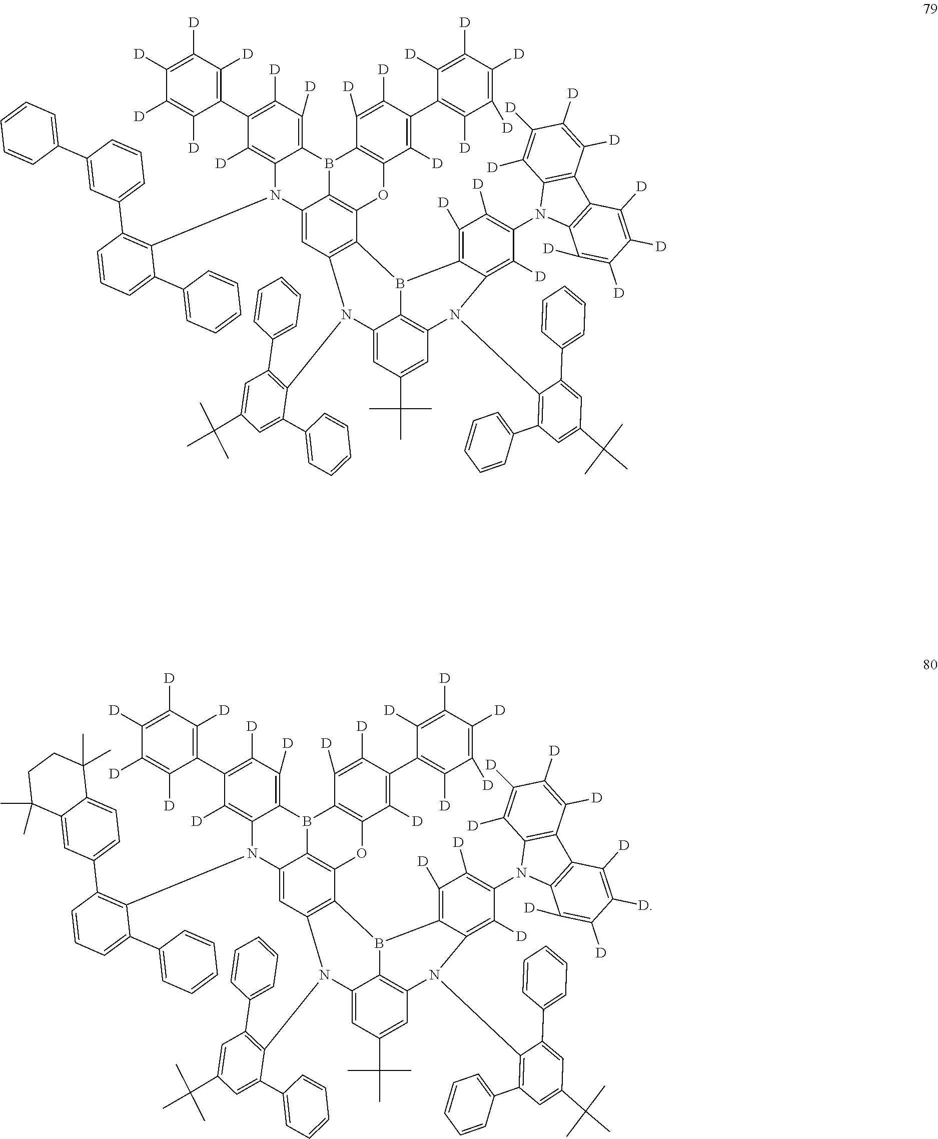

In an embodiment, the light-emitting element ED including the fused polycyclic compound according to an embodiment may have a peak emission wavelength in a range of about 430 nm to about 470 nm. The peak emission wavelength may be an emission wavelength at maximum emission intensity. The light-emitting element ED including the fused polycyclic compound according to an embodiment may emit blue light. A third light-emitting element ED-3 (see FIG. 2) that emits blue light may include the fused polycyclic compound according to an embodiment.

In an embodiment, the emission layer EML may include the fused polycyclic compound as a dopant. The fused polycyclic compound according to an embodiment may be a delayed fluorescent material. The fused polycyclic compound according to an embodiment may be a thermally activated delayed fluorescent (TADF) material. In the fused polycyclic compound according to an embodiment, triplet excitons may be converted into singlet excitons to emit light according to a reverse inter system crossing (RISC) mechanism.

The fused polycyclic compound according to an embodiment may have ΔE_{ST} less than or equal to about 0.2 eV. In the specification, ΔE_{ST} is an absolute value of an energy level difference between a triplet state and a singlet state. RISC may be accelerated in the fused polycyclic compound according to an embodiment having a ΔE_{ST} less than or equal to about 0.2 eV. Therefore, the light-emitting element ED including the fused polycyclic compound according to an embodiment may have improved efficiency and lifespan.

The fused polycyclic compound according to an embodiment may include a core structure that includes nine rings fused together, with three nitrogen atoms, two boron atoms, and an oxygen atom as ring-forming atoms. The fused polycyclic compound according to an embodiment may include three terphenyl moieties, each bonded to the three nitrogen atoms of the core structure. The fused polycyclic compound according to an embodiment may include a core structure represented by Formula Z1. In Formula Z1, N^{a}, N^{b}, and N^{c} are the nitrogen atoms designated with letters of a, b, and c for convenience of explanation.

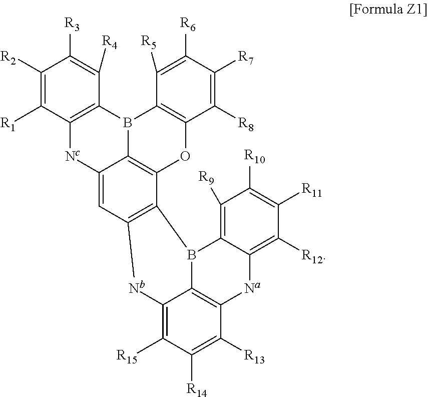

In Formula Z1, the terphenyl moieties may be bonded to each of N^{a}, N^{b}, and N^{c}. The above-described first to third terphenyl moieties may be respectively bonded to N^{a}, N^{b}, and N^{c}.

A compound of the related art that includes two boron atoms as ring-forming atoms, which exhibits mixed properties of multiple resonance (MR) and charge transfer (CT), may have a plate-shaped structure and a large molecular weight. In a compound of the related art that include such a plate-shaped structure, intermolecular interactions makes purification by sublimation for synthesis of the compound difficult, and thus the acquisition of a high-purity material may not be readily achieved. Therefore, such a compound of the related art exhibits poor heat stability.

In comparison to a compound of the related art, in the fused polycyclic compound according to an embodiment, the compound may have a low sublimation temperature and exhibit improved heat resistance and stability by the introduction of the three terphenyl moieties. A terphenyl moiety is a bulky substituent and may prevent intermolecular interactions to thereby enable the compound to be more readily synthesized. Therefore, purification by sublimation and high-purity material acquisition may be readily performed for synthesis of the fused polycyclic compound according to an embodiment, and thus excellent material stability may be exhibited. Due to the introduction of three or more terphenyl moieties, rigidity of the compound is improved, and thus high frequency vibration energy may be adjusted. Therefore, the fused polycyclic compound may exhibit a narrow full width at half maximum in an emission spectrum. The terphenyl moiety has low molecular rotating properties and a high steric hindrance, which may adjust vibration energy. Therefore, the light-emitting element ED including the fused polycyclic compound according to an embodiment may emit light having improved color purity.

In an embodiment, the emission layer EML may include the fused polycyclic compound according to an embodiment, and may further include at least one of a second compound, a third compound, and a fourth compound.

In an embodiment, the emission layer EML may further include a second compound represented by Formula HT-1. In an embodiment, the second compound may be used as a hole transporting host material in an emission layer EML.

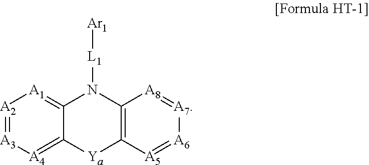

In an embodiment, in Formula HT-1, A₁ to A₈ may each independently be N or C(R₅₁). For example, A₁ to A₈ may each independently be C(R₅₁). In another embodiment, one of A₁ to A₈ may be N, and the remainder of A₁ to A₈ may each independently be C(R₅₁).

In Formula HT-1, L₁ may be a direct linkage, a substituted or unsubstituted arylene group having 6 to 30 ring-forming carbon atoms, or a substituted or unsubstituted heteroarylene group having 2 to 30 ring-forming carbon atoms. For example, L₁ may be a direct linkage, a substituted or unsubstituted phenylene group, a substituted or unsubstituted divalent biphenyl group, a substituted or unsubstituted divalent carbazole group, etc., but embodiments are not limited thereto.

In Formula HT-1, Yₐ may be a direct linkage, C(R₅₂)(R₅₃), or Si(R₅₄)(R₅₅). For example, the two benzene rings that are linked to the nitrogen atom in Formula HT-1 may be linked to each other via a direct linkage,

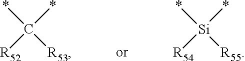

In Formula HT-1, when Yₐ is a direct linkage, the second compound represented by Formula HT-1 may include a carbazole moiety.

In Formula HT-1, An may be a substituted or unsubstituted aryl group having 6 to 30 ring-forming carbon atoms or a substituted or unsubstituted heteroaryl group having 2 to 30 ring-forming carbon atoms. For example, Ar₁ may be a substituted or unsubstituted carbazole group, a substituted or unsubstituted dibenzofuran group, a substituted or unsubstituted dibenzothiophene group, a substituted or unsubstituted biphenyl group, etc., but embodiments are not limited thereto.

In Formula HT-1, R₅₁ to R₅₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring. For example, R₅₁ to R₅₅ may each independently be a hydrogen atom or a deuterium atom. For example, R₅₁ to R₅₅ may each independently be an unsubstituted methyl group or an unsubstituted phenyl group.

In an embodiment, the second compound represented by Formula HT-1 may be selected from Compound Group 2. In an embodiment, in the light-emitting element ED, the second compound may include at least one compound selected from Compound Group 2.

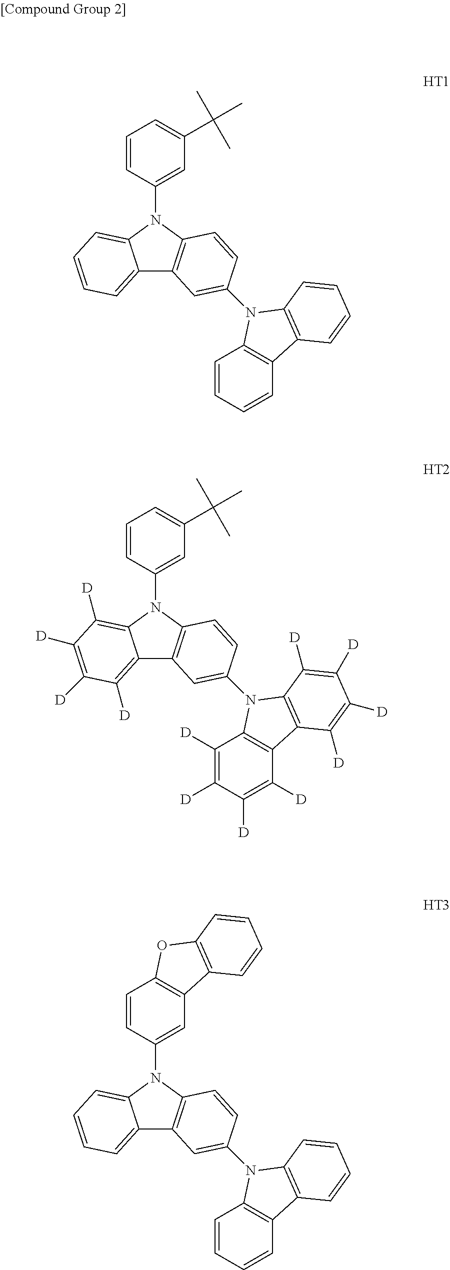 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12]

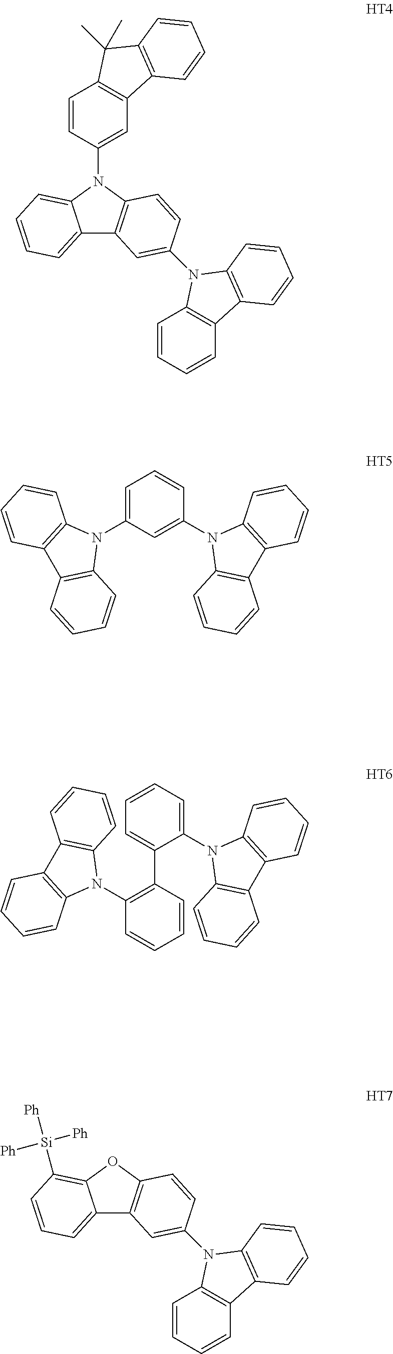 [SMILES: CC1(C)c2ccccc2-c2cc(-n3c4ccccc4c4cc(-n5c6ccccc6c6ccccc65)ccc43)ccc21 ; c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1]

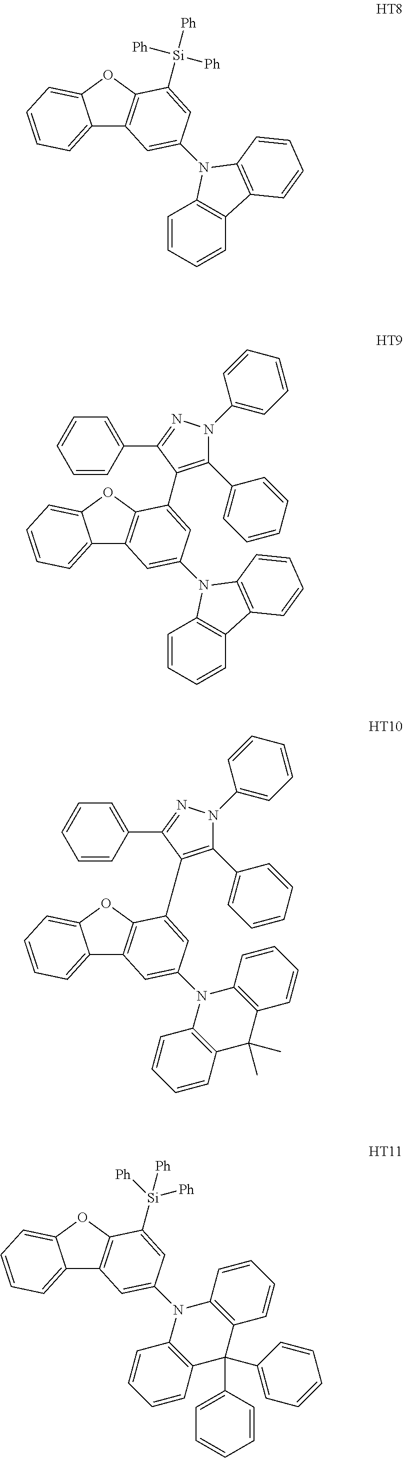 [SMILES: c1ccc([Si](c2ccccc2)(c2ccccc2)c2cc(-n3c4ccccc4c4ccccc43)cc3c2oc2ccccc23)cc1 ; c1ccc(-c2nn(-c3ccccc3)c(-c3ccccc3)c2-c2cc(-n3c4ccccc4c4ccccc43)cc3c2oc2ccccc23)cc1 ; CC1(C)c2ccccc2N(c2cc(-c3c(-c4ccccc4)nn(-c4ccccc4)c3-c3ccccc3)c3oc4ccccc4c3c2)c2ccccc21 ; c1ccc(C2(c3ccccc3)c3ccccc3N(c3cc([Si](c4ccccc4)(c4ccccc4)c4ccccc4)c4oc5ccccc5c4c3)c3ccccc32)cc1]

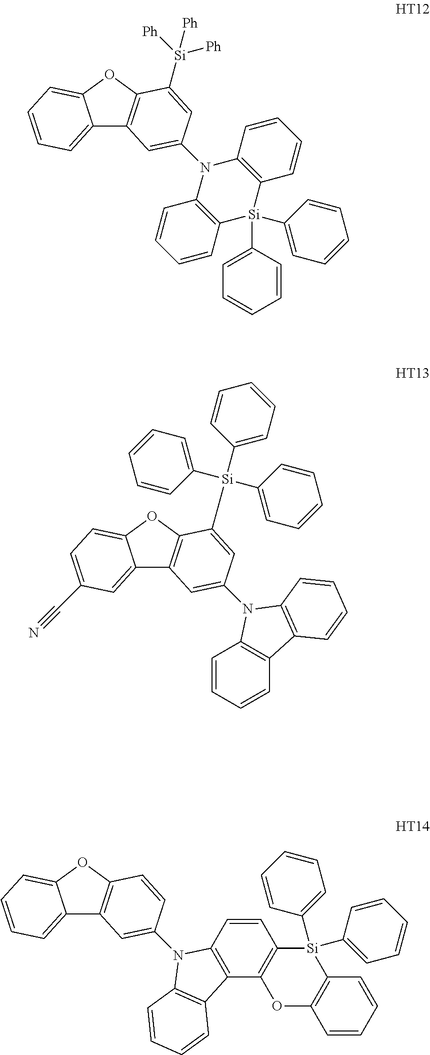 [SMILES: c1ccc([Si]2(c3ccccc3)c3ccccc3N(c3cc([Si](c4ccccc4)(c4ccccc4)c4ccccc4)c4oc5ccccc5c4c3)c3ccccc32)cc1 ; N#Cc1ccc2oc3c([Si](c4ccccc4)(c4ccccc4)c4ccccc4)cc(-n4c5ccccc5c5ccccc54)cc3c2c1 ; c1ccc([Si]2(c3ccccc3)c3ccccc3Oc3c2ccc2c3c3ccccc3n2-c2ccc3oc4ccccc4c3c2)cc1]

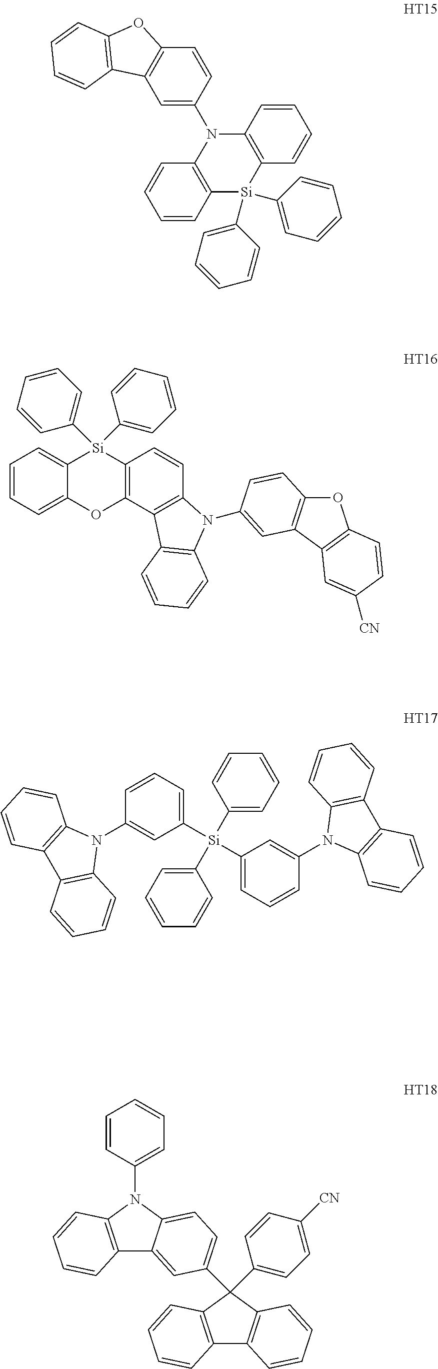 [SMILES: c1ccc([Si]2(c3ccccc3)c3ccccc3N(c3ccc4oc5ccccc5c4c3)c3ccccc32)cc1 ; N#Cc1ccc2oc3ccc(-n4c5ccccc5c5c6c(ccc54)[Si](c4ccccc4)(c4ccccc4)c4ccccc4O6)cc3c2c1 ; c1ccc([Si](c2ccccc2)(c2cccc(-n3c4ccccc4c4ccccc43)c2)c2cccc(-n3c4ccccc4c4ccccc43)c2)cc1 ; N#Cc1ccc(C2(c3ccc4c(c3)c3ccccc3n4-c3ccccc3)c3ccccc3-c3ccccc32)cc1]

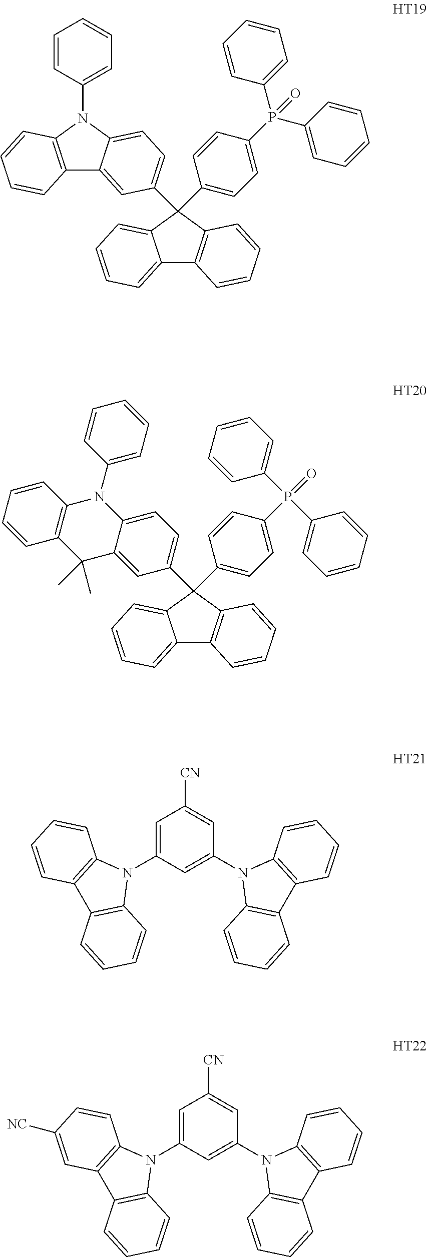 [SMILES: O=P(c1ccccc1)(c1ccccc1)c1ccc(C2(c3ccc4c(c3)c3ccccc3n4-c3ccccc3)c3ccccc3-c3ccccc32)cc1 ; CC1(C)c2ccccc2N(c2ccccc2)c2ccc(C3(c4ccc(P(=O)(c5ccccc5)c5ccccc5)cc4)c4ccccc4-c4ccccc43)cc21 ; N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1]

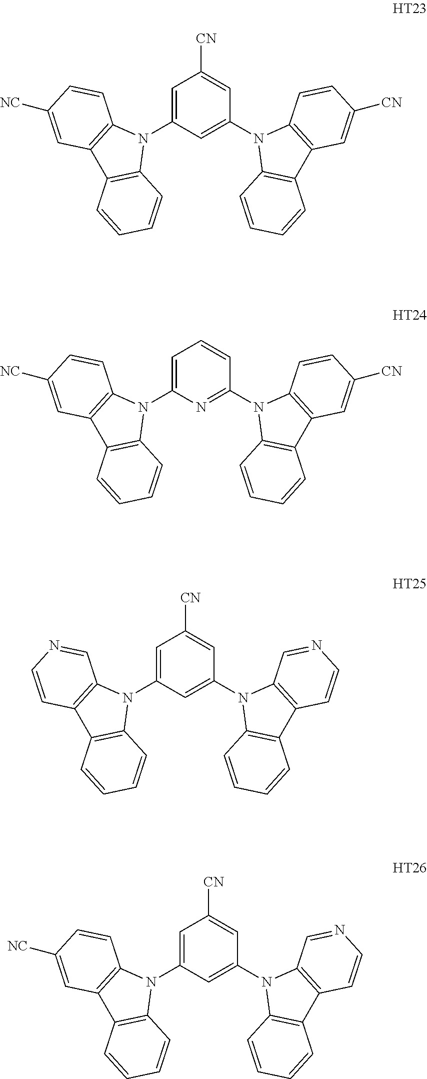 [SMILES: N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1 ; N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1]

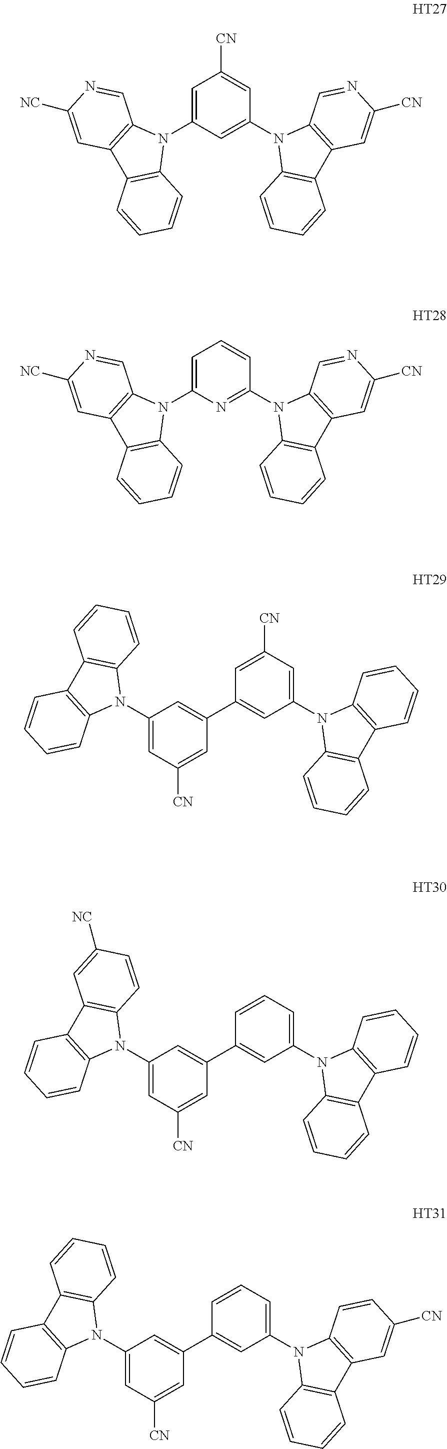 [SMILES: N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1 ; N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1]

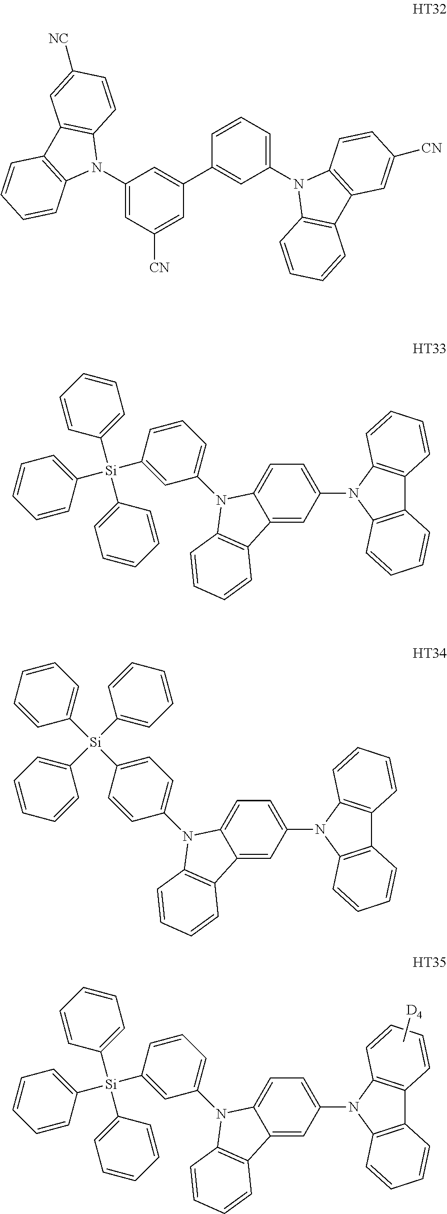

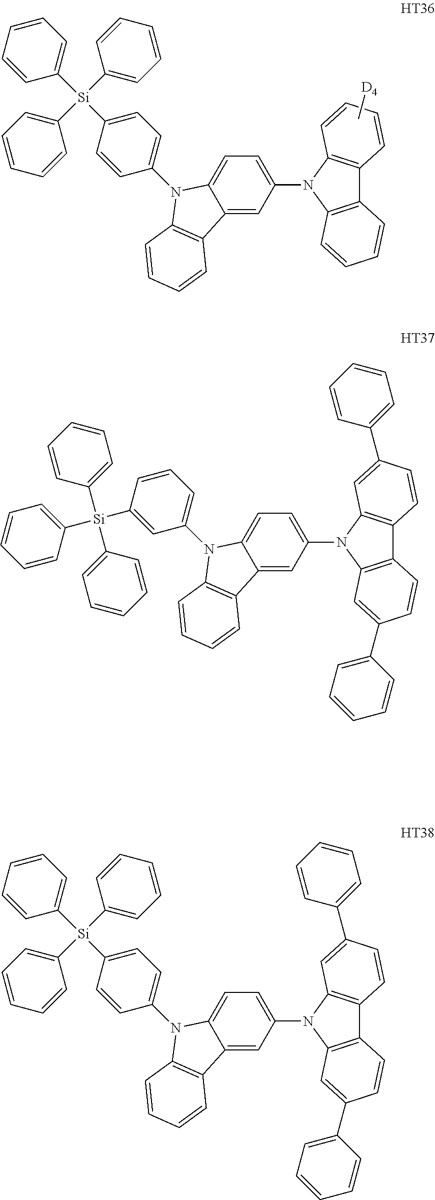

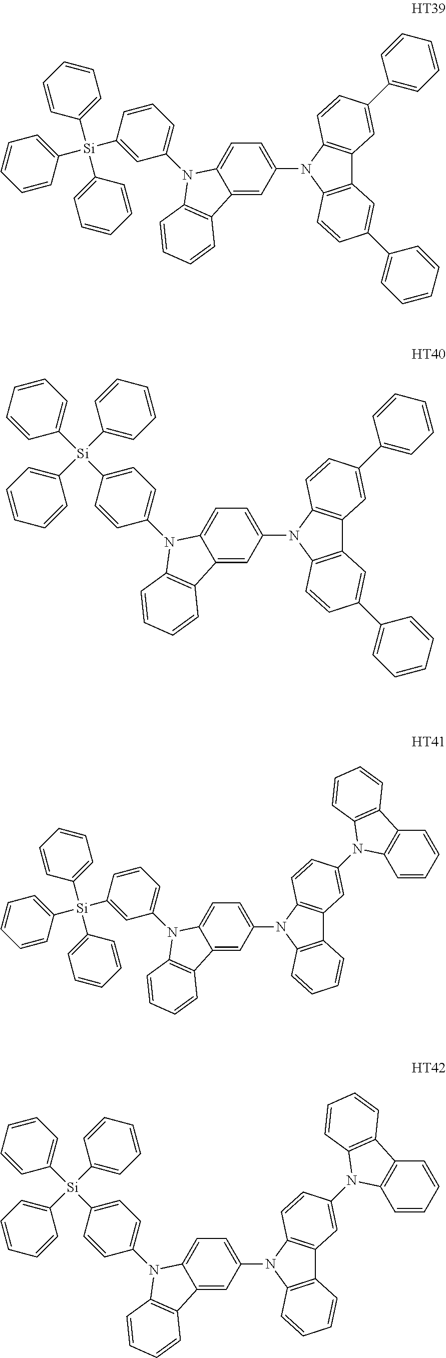 [SMILES: c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1 ; c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1]

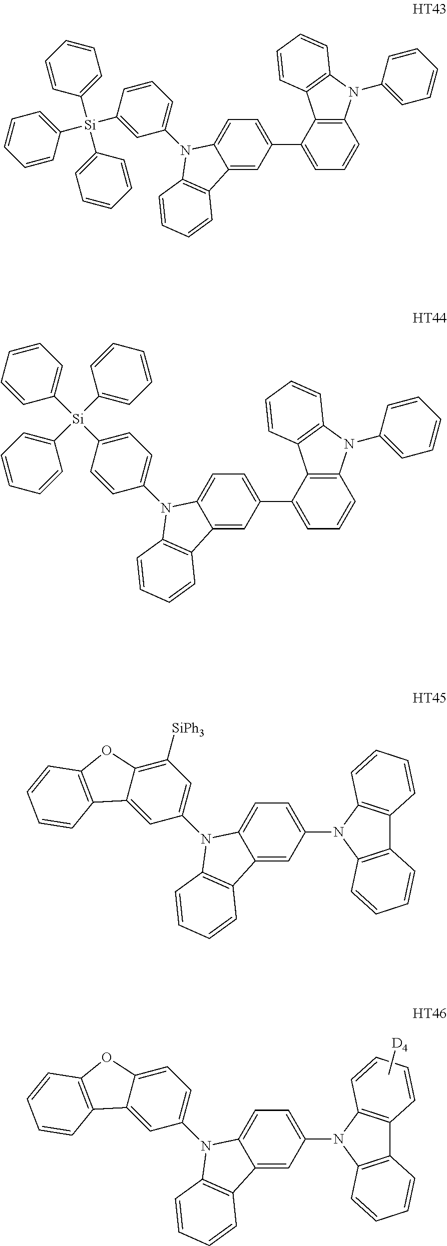

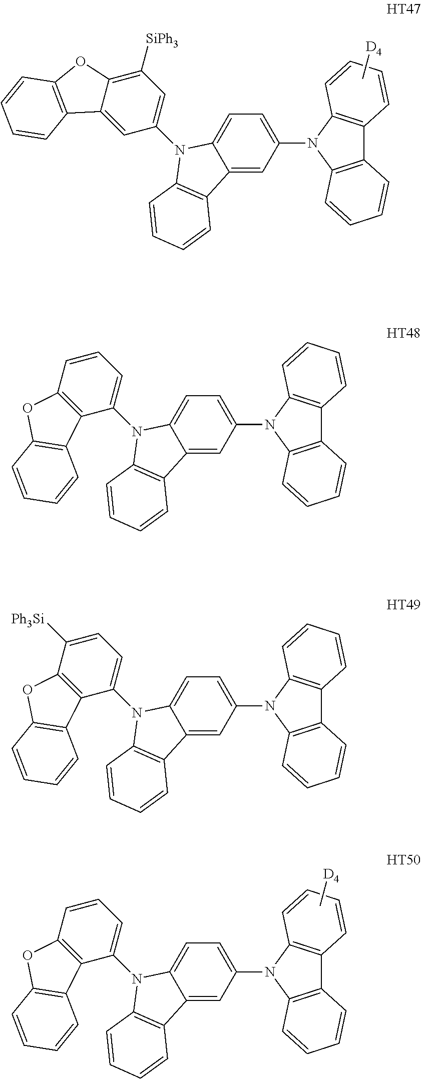

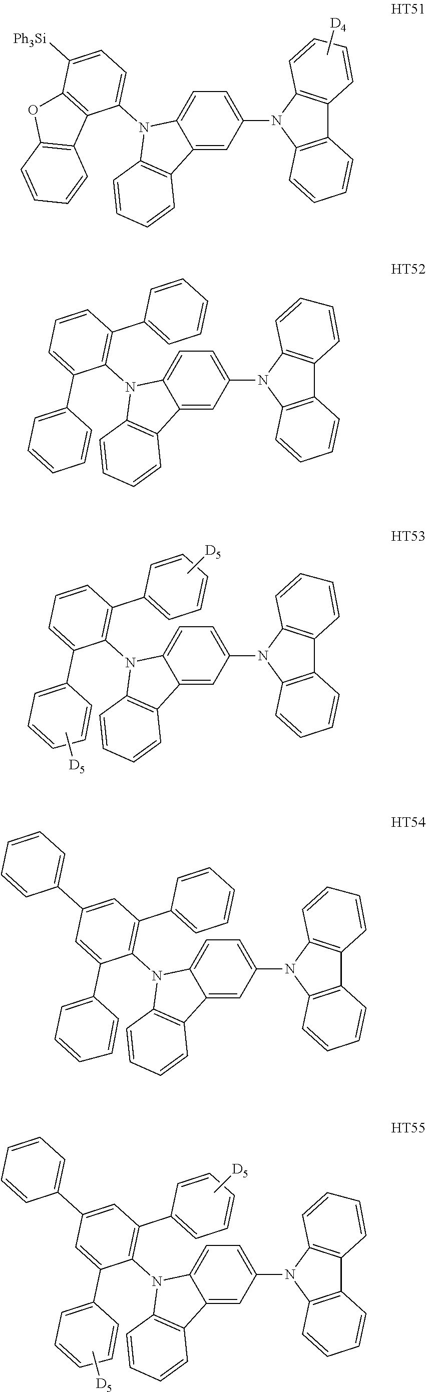

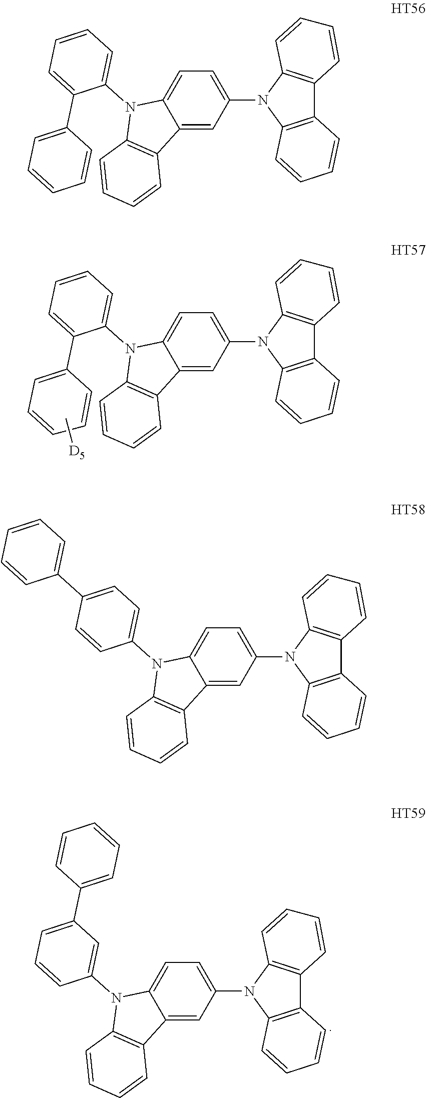

In Compound Group 2, D represents a deuterium atom, and Ph represents a substituted or unsubstituted phenyl group. For example, in Compound Group 2, Ph may be an unsubstituted phenyl group.

In an embodiment, the emission layer EML may further include a third compound represented by Formula ET-1. In an embodiment, the third compound may be used as an electron transport host material in an emission layer EML.

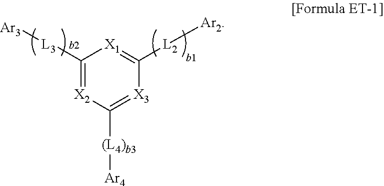

In Formula ET-1, at least one of X₁ to X₃ may be N; and the remainder of X₁ to X₃ may each independently be C(R₅₆). For example, one of X₁ to X₃ may be N, and the remainder of X₁ to X₃ may each independently be C(R₅₆). Thus, the third compound represented by Formula ET-1 may include a pyridine moiety. In another embodiment, two of X₁ to X₃ may be N, and the remainder of X₁ to X₃ may be C(R₅₆). Thus, the third compound represented by Formula ET-1 may include a pyrimidine moiety. In yet another embodiment, X₁ to X₃ may each be N. Thus, the third compound represented by Formula ET-1 may include a triazine moiety.

In Formula ET-1, R₅₆ may be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms.

In Formula ET-1, b1 to b3 may each independently be an integer from 0 to 10.

In Formula ET-1, Ar₂ to Ar₄ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Ar₂ to Ar₄ may each independently be a substituted or unsubstituted phenyl group or a substituted or unsubstituted carbazole group.

In Formula ET-1, L₂ to L₄ may each independently be a direct linkage, a substituted or unsubstituted arylene group having 6 to 30 ring-forming carbon atoms, or a substituted or unsubstituted heteroarylene group having 2 to 30 ring-forming carbon atoms. In Formula ET-1, when b1 to b3 are each 2 or greater, L₂ to L₄ may each independently be a substituted or unsubstituted arylene group having 6 to 30 ring-forming carbon atoms or a substituted or unsubstituted heteroarylene group having 2 to 30 ring-forming carbon atoms.

In an embodiment, the third compound represented by Formula ET-1 may be selected from Compound Group 3. In an embodiment, in the light-emitting element ED, the third compound may include at least one compound selected from Compound Group 3.

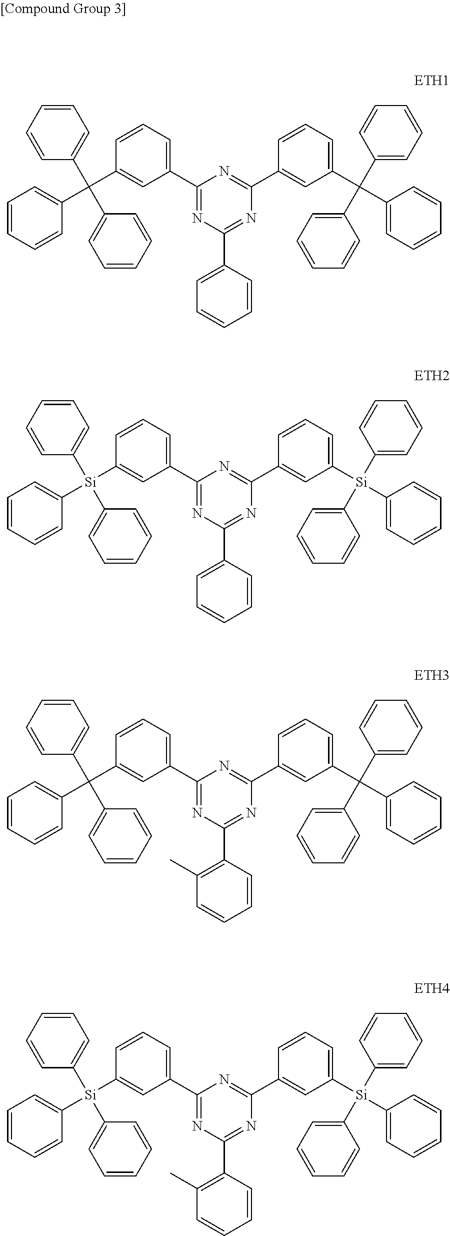 [SMILES: c1ccc(-c2nc(-c3cccc(C(c4ccccc4)(c4ccccc4)c4ccccc4)c3)nc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)nc(-c2cccc([Si](c3ccccc3)(c3ccccc3)c3ccccc3)c2)n1]

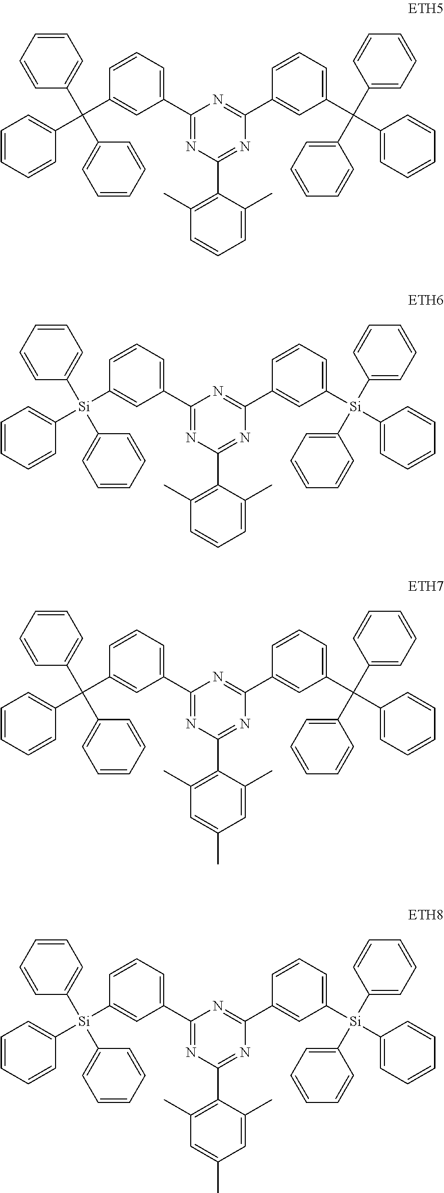 [SMILES: Cc1cccc(C)c1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)nc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)nc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)nc(-c3cccc([Si](c4ccccc4)(c4ccccc4)c4ccccc4)c3)n2)c(C)c1]

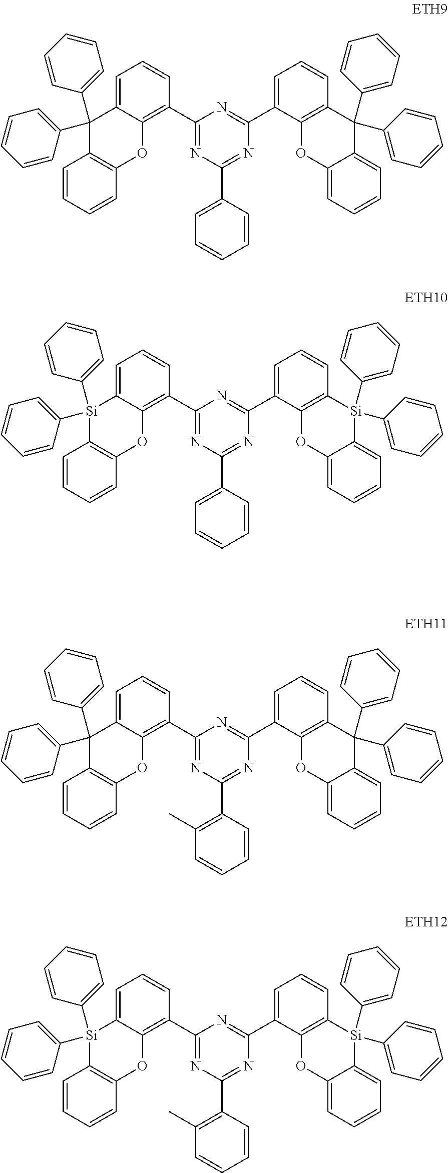 [SMILES: c1ccc(-c2nc(-c3cccc4c3Oc3ccccc3C4(c3ccccc3)c3ccccc3)nc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1]

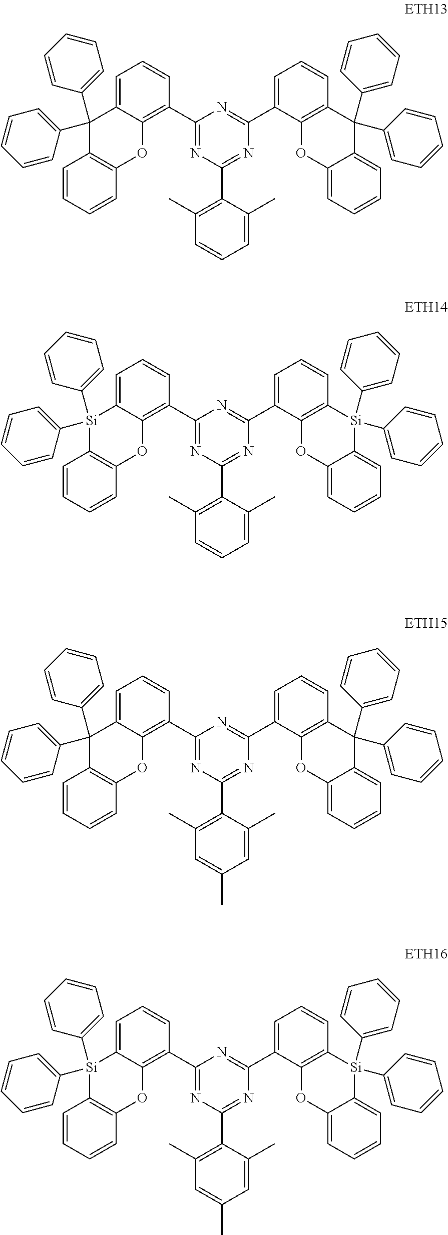 [SMILES: Cc1cccc(C)c1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)nc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)c(C)c1]

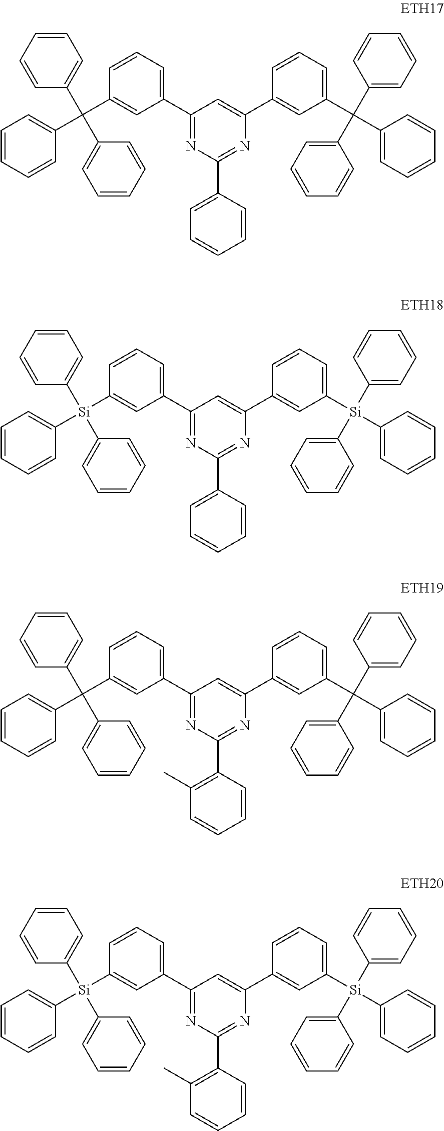 [SMILES: c1ccc(-c2nc(-c3cccc(C(c4ccccc4)(c4ccccc4)c4ccccc4)c3)cc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)cc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)cc(-c2cccc([Si](c3ccccc3)(c3ccccc3)c3ccccc3)c2)n1]

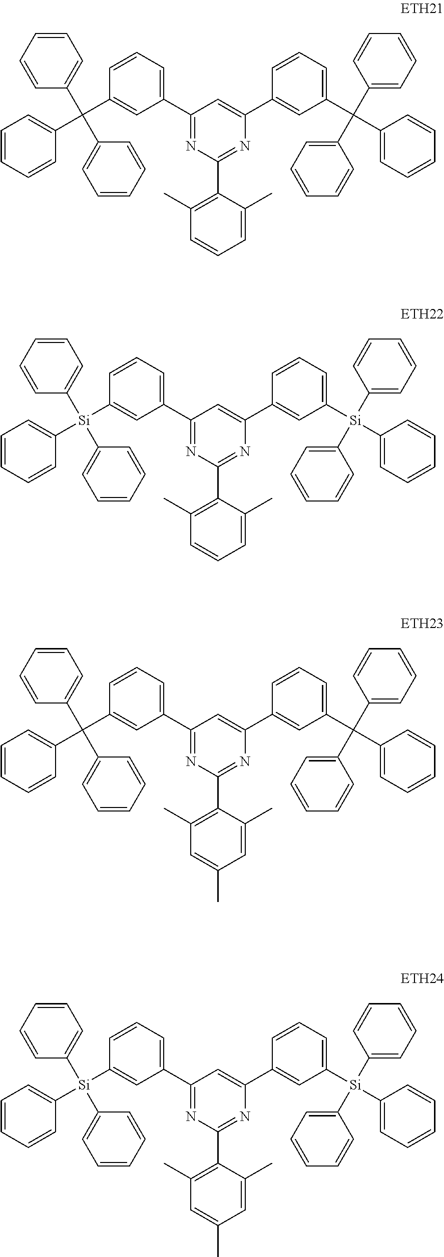 [SMILES: Cc1cccc(C)c1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)cc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)cc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)cc(-c3cccc([Si](c4ccccc4)(c4ccccc4)c4ccccc4)c3)n2)c(C)c1]

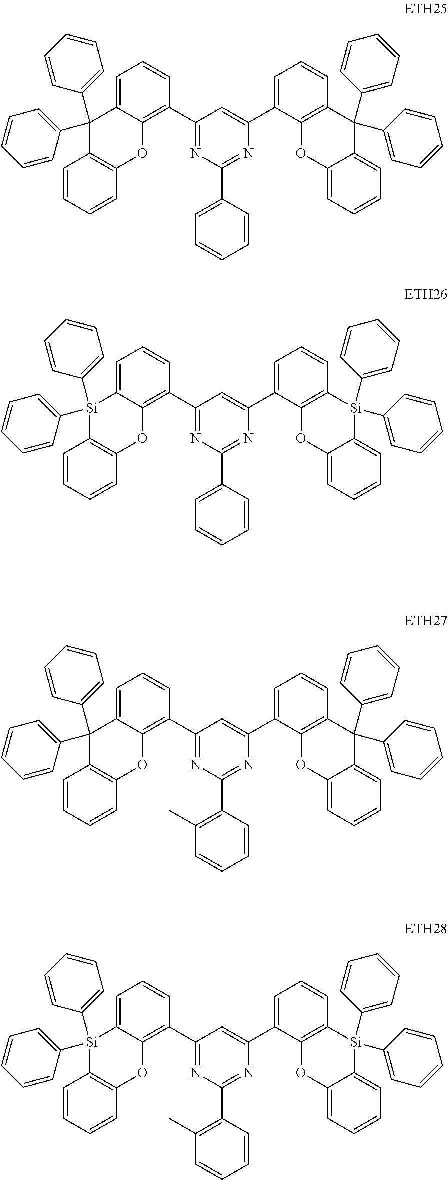 [SMILES: c1ccc(-c2nc(-c3cccc4c3Oc3ccccc3C4(c3ccccc3)c3ccccc3)cc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1]

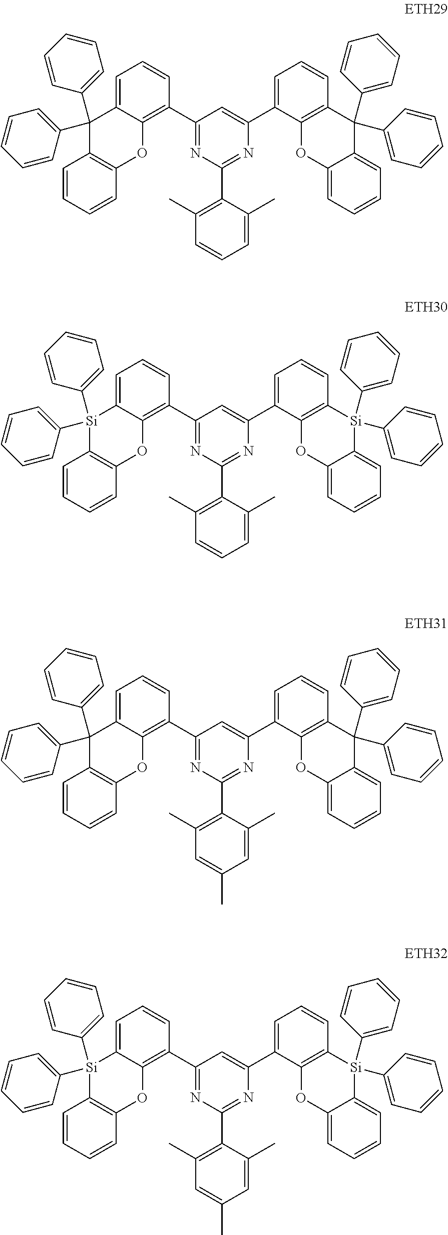 [SMILES: Cc1cccc(C)c1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)cc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)c(C)c1]

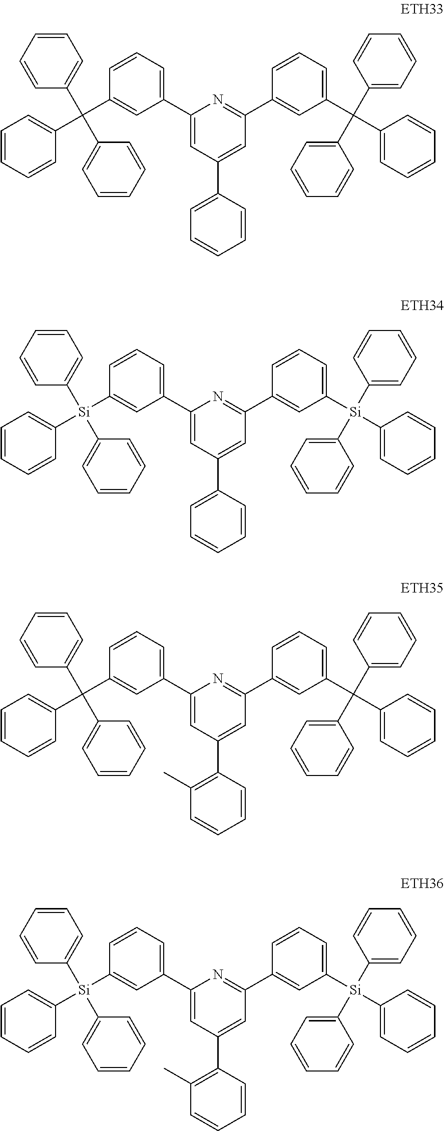 [SMILES: c1ccc(-c2cc(-c3cccc(C(c4ccccc4)(c4ccccc4)c4ccccc4)c3)nc(-c3cccc(C(c4ccccc4)(c4ccccc4)c4ccccc4)c3)c2)cc1 ; c1ccc(-c2cc(-c3cccc([Si](c4ccccc4)(c4ccccc4)c4ccccc4)c3)nc(-c3cccc([Si](c4ccccc4)(c4ccccc4)c4ccccc4)c3)c2)cc1 ; Cc1ccccc1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1ccccc1-c1cc(-c2cccc([Si](c3ccccc3)(c3ccccc3)c3ccccc3)c2)nc(-c2cccc([Si](c3ccccc3)(c3ccccc3)c3ccccc3)c2)c1]

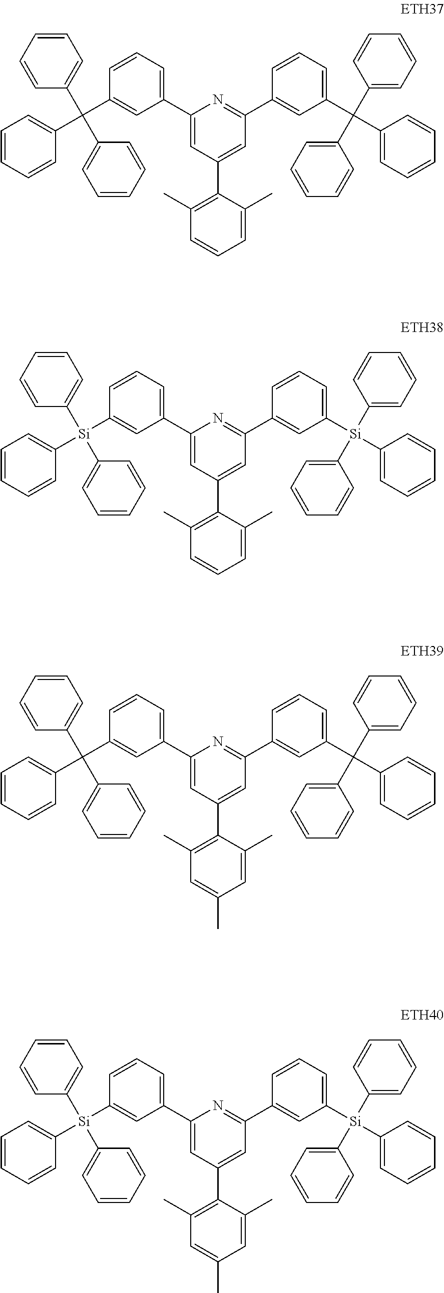 [SMILES: Cc1cccc(C)c1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1cccc(C)c1-c1cc(-c2cccc([Si](c3ccccc3)(c3ccccc3)c3ccccc3)c2)nc(-c2cccc([Si](c3ccccc3)(c3ccccc3)c3ccccc3)c2)c1 ; Cc1cc(C)c(-c2cc(-c3cccc(C(c4ccccc4)(c4ccccc4)c4ccccc4)c3)nc(-c3cccc(C(c4ccccc4)(c4ccccc4)c4ccccc4)c3)c2)c(C)c1 ; Cc1cc(C)c(-c2cc(-c3cccc([Si](c4ccccc4)(c4ccccc4)c4ccccc4)c3)nc(-c3cccc([Si](c4ccccc4)(c4ccccc4)c4ccccc4)c3)c2)c(C)c1]

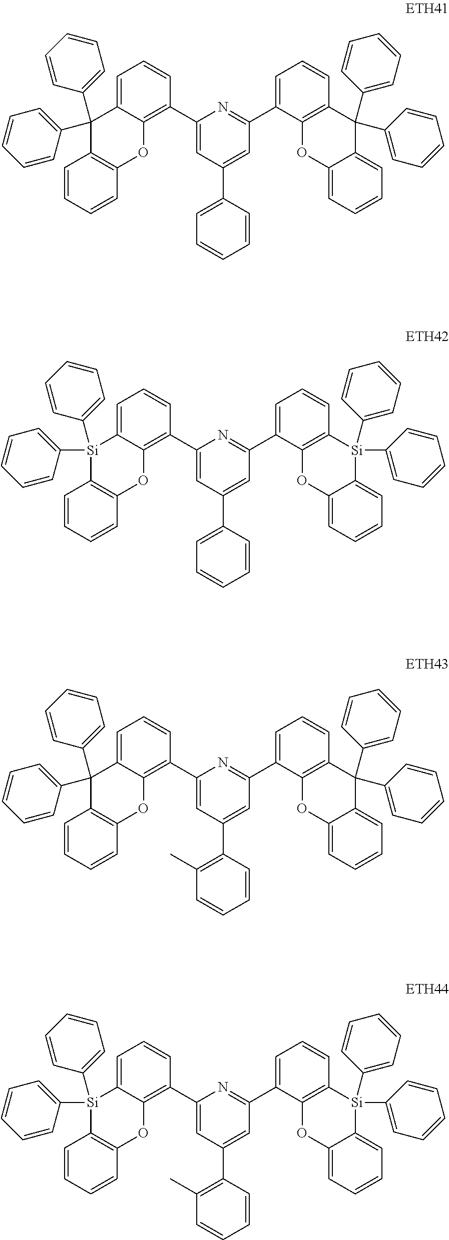 [SMILES: c1ccc(-c2cc(-c3cccc4c3Oc3ccccc3C4(c3ccccc3)c3ccccc3)nc(-c3cccc4c3Oc3ccccc3C4(c3ccccc3)c3ccccc3)c2)cc1 ; c1ccc(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)cc1 ; Cc1ccccc1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1ccccc1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1]

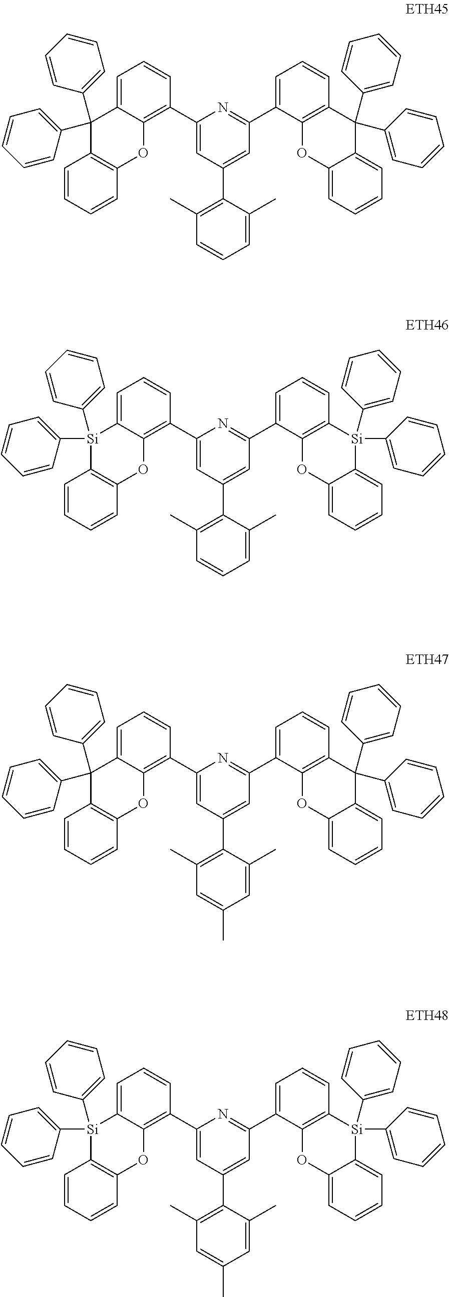 [SMILES: Cc1cccc(C)c1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1cccc(C)c1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1 ; Cc1cc(C)c(-c2cc(-c3cccc4c3Oc3ccccc3C4(c3ccccc3)c3ccccc3)nc(-c3cccc4c3Oc3ccccc3C4(c3ccccc3)c3ccccc3)c2)c(C)c1 ; Cc1cc(C)c(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)c(C)c1]

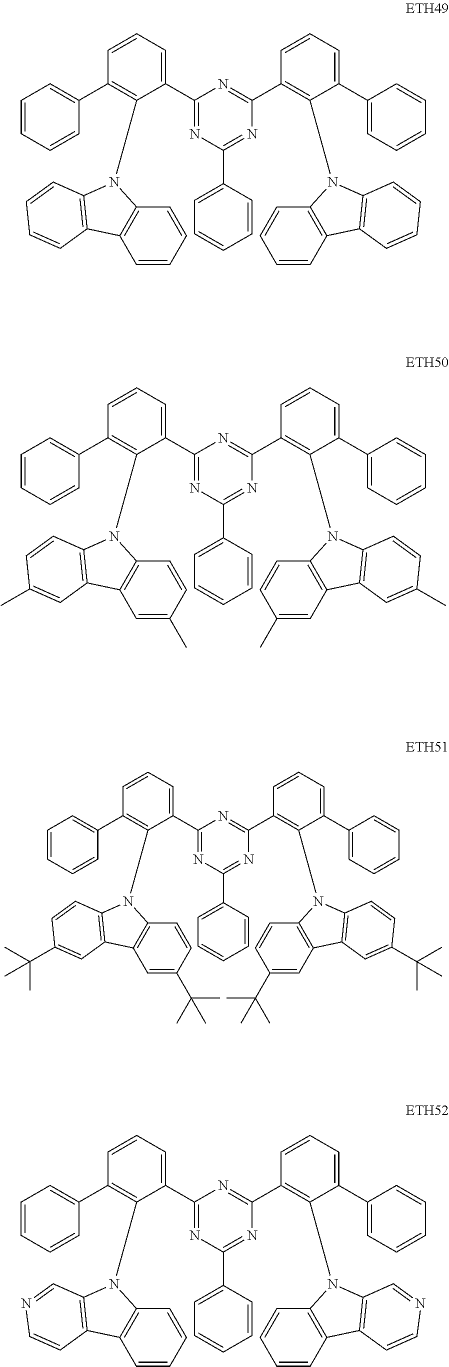

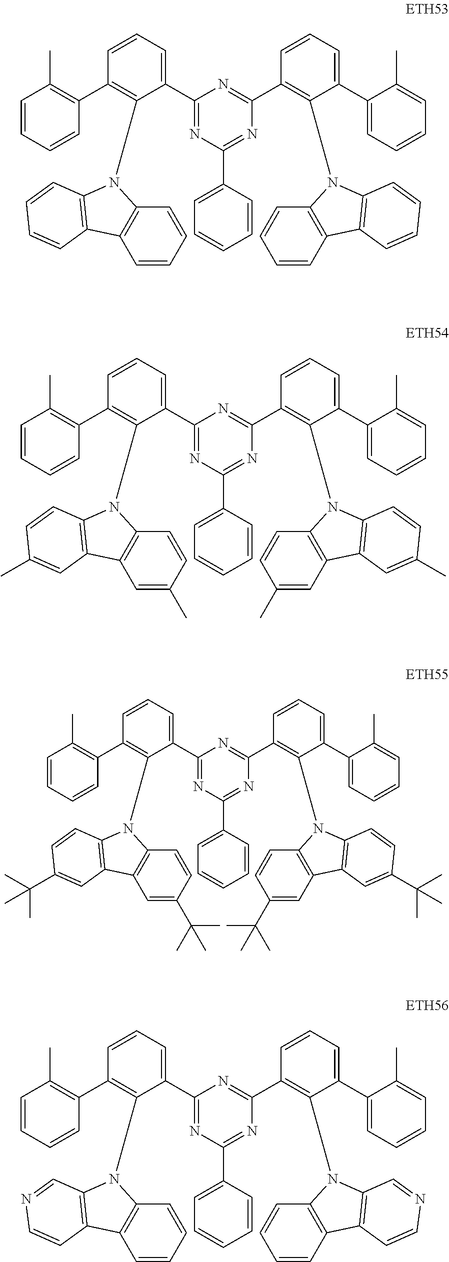

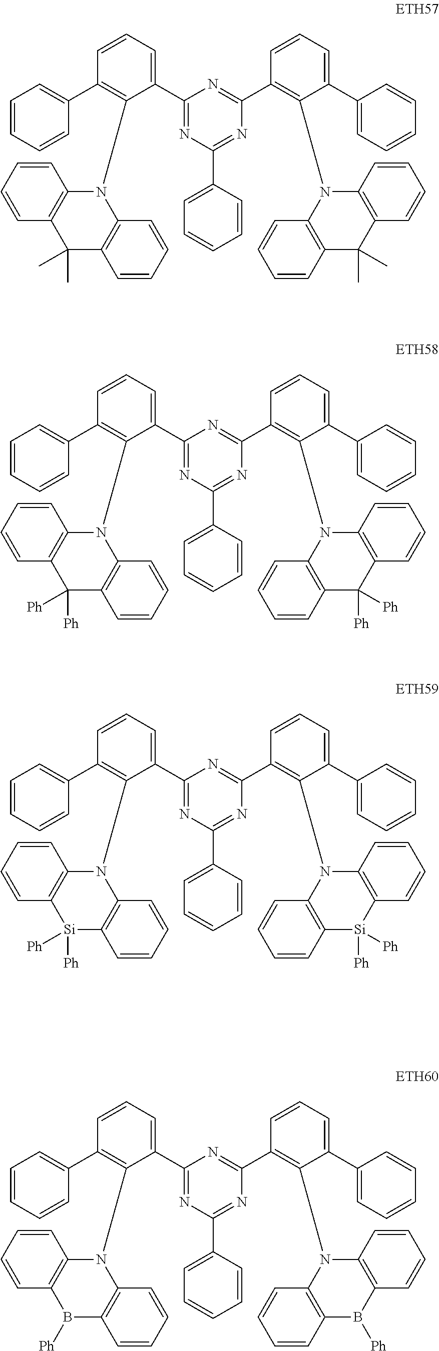

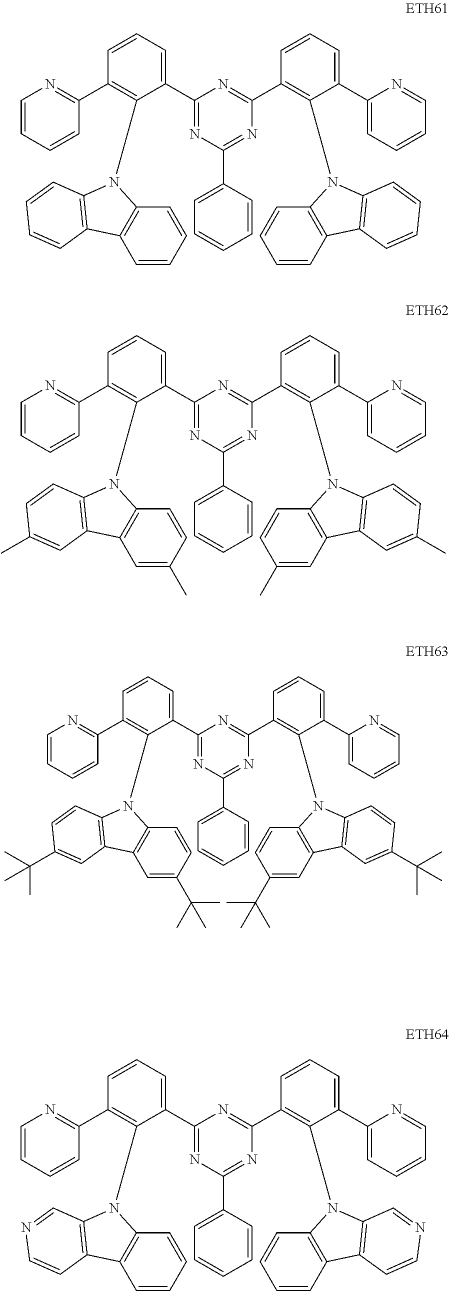

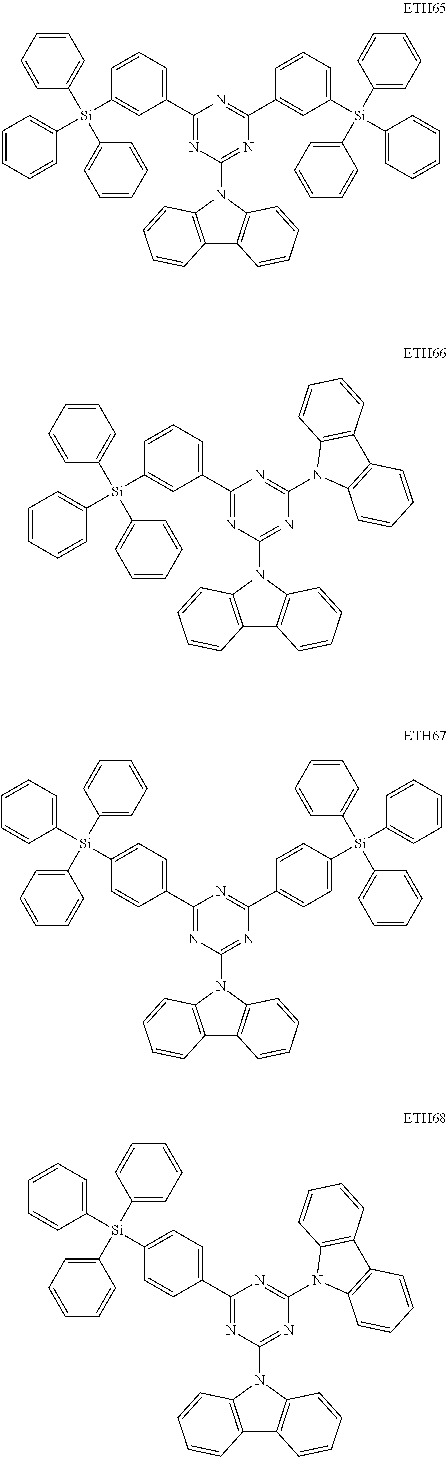 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5ccccc54)n3)cc2)cc1 ; c1ccc([Si](c2ccccc2)(c2ccccc2)c2ccc(-c3nc(-n4c5ccccc5c5ccccc54)nc(-n4c5ccccc5c5ccccc54)n3)cc2)cc1]

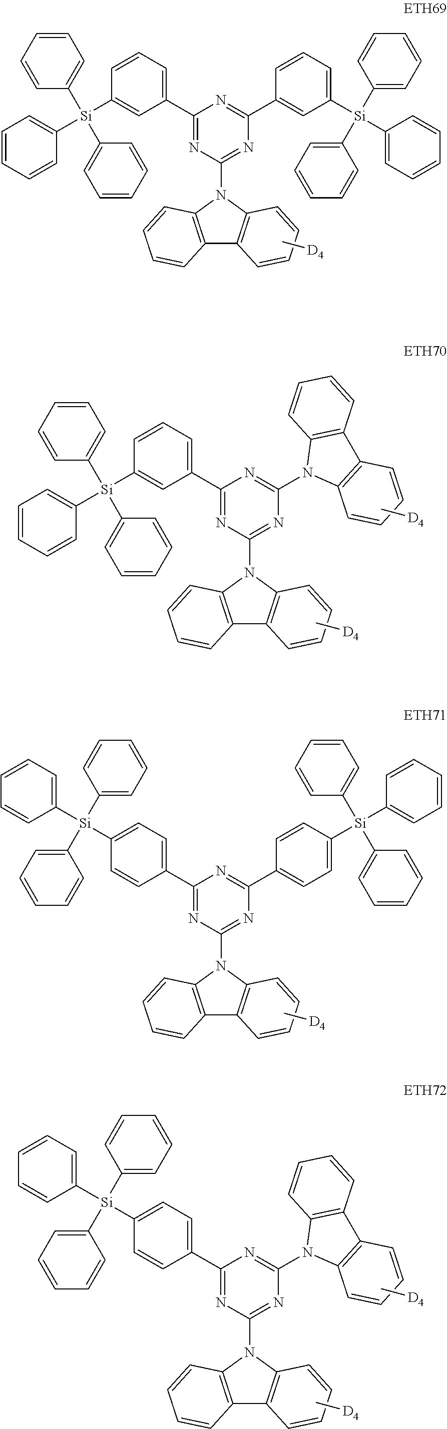

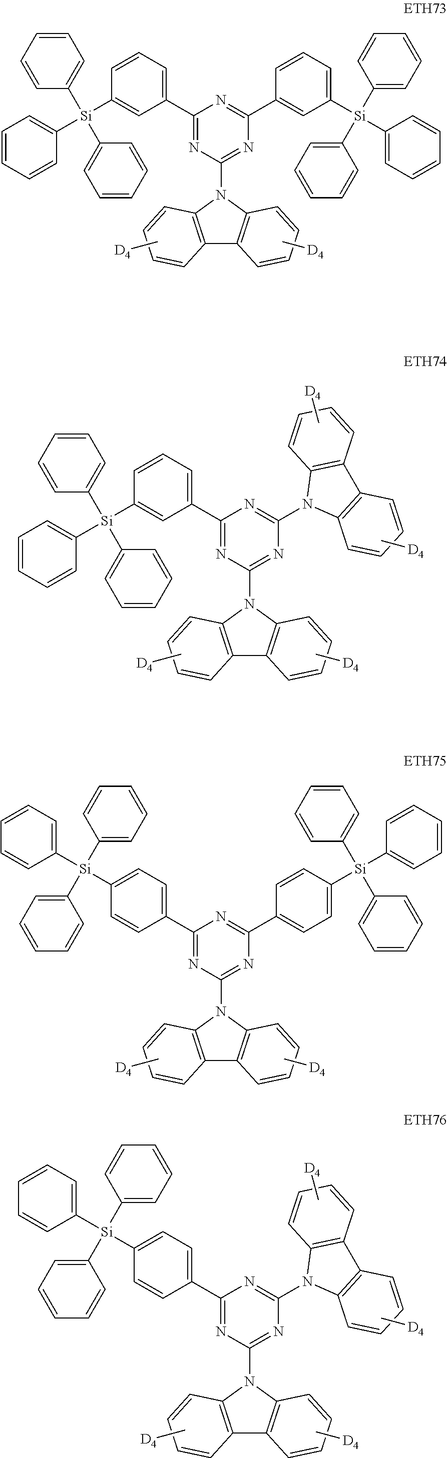

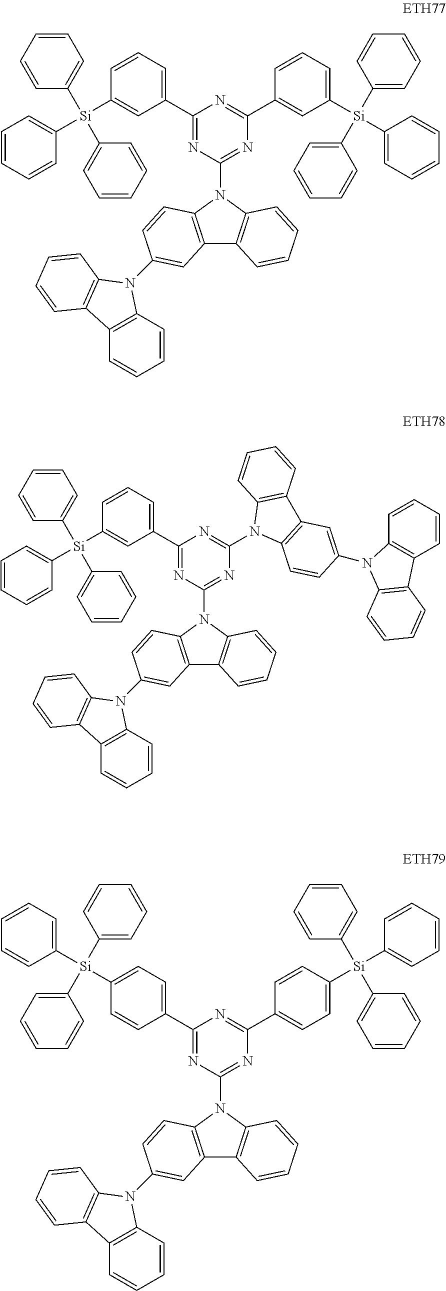 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5cc(-n6c7ccccc7c7ccccc76)ccc54)n3)c2)cc1 ; c1ccc([Si](c2ccccc2)(c2ccccc2)c2cccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5cc(-n6c7ccccc7c7ccccc76)ccc54)n3)cc2)cc1]

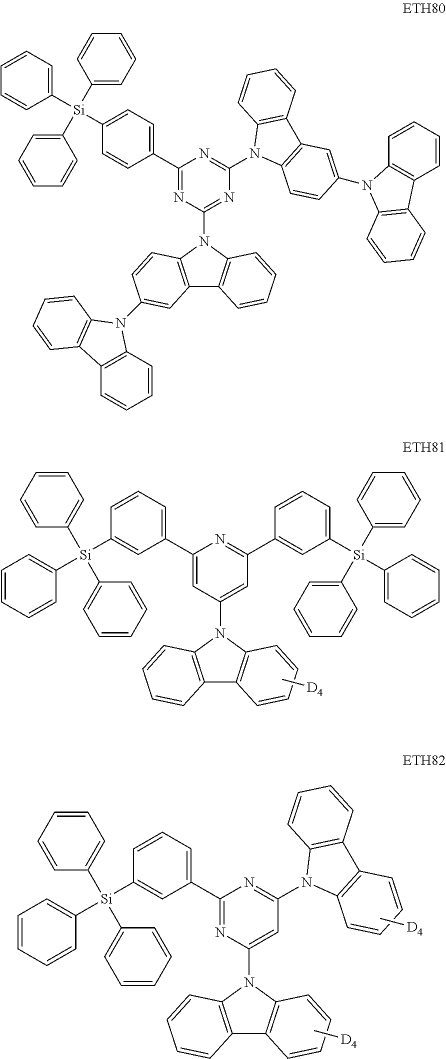

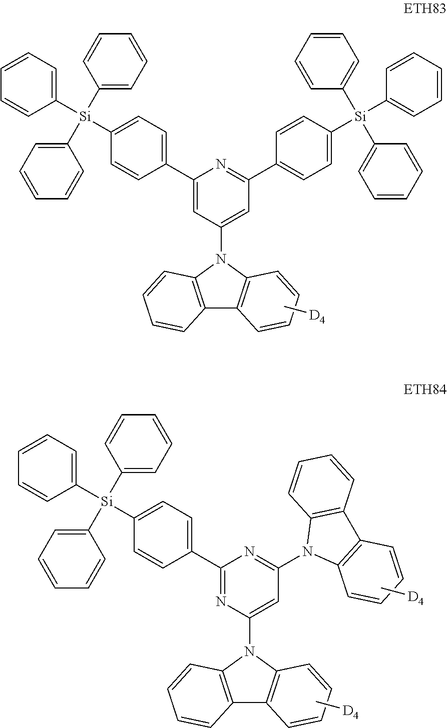

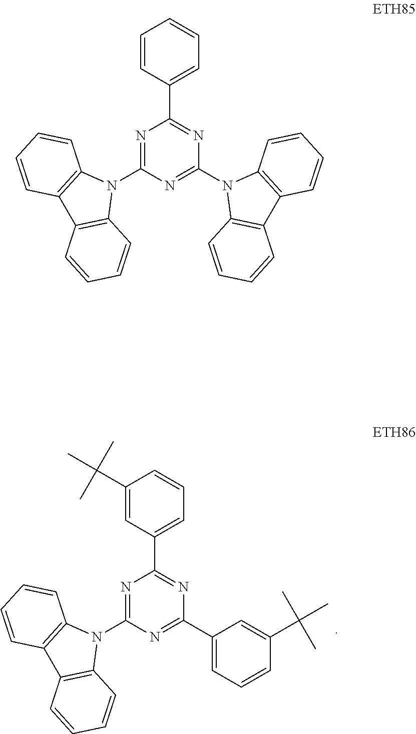 [SMILES: c1ccc(-c2nc(-n3c4ccccc4c4ccccc43)nc(-n3c4ccccc4c4ccccc43)n2)cc1 ; CC(C)(C)c1cccc(-c2nc(-c3cccc(C(C)(C)C)c3)nc(-n3c4ccccc4c4ccccc43)n2)c1]

In Compound Group 3, D represents a deuterium atom, and Ph represents an unsubstituted phenyl group.

In an embodiment, the emission layer EML may include the second compound and the third compound, and the second compound and the third compound may form an exciplex. In the emission layer EML, an exciplex may be formed by a hole transport host and an electron transport host. A triplet energy of the exciplex formed by a hole transporting host and an electron transporting host may correspond to a difference between a lowest unoccupied molecular orbital (LUMO) energy level of the electron transporting host and a highest occupied molecular orbital (HOMO) energy level of the hole transporting host.

For example, an absolute value of a triplet energy level (T1) of the exciplex formed by the hole transporting host and the electron transporting host may be in range of about 2.4 eV to about 3.0 eV. The triplet energy level of the exciplex may be a value that is less than an energy gap of each host material. The exciplex may have a triplet energy level less than or equal to about 3.0 eV, which is an energy gap between the hole transporting host and the electron transporting host.

In an embodiment, the emission layer EML may further include a fourth compound, in addition to the first compound, the second compound, and the third compound as described above. The fourth compound may be used as a phosphorescent sensitizer in the emission layer EML. Energy may be transferred from the fourth compound to the first compound, thereby emitting light.

In an embodiment, the emission layer EML may further include, as a fourth compound, an organometallic complex that includes platinum (Pt) as a central metal atom and ligands linked to the central metal atom. In an embodiment, the emission layer EML may include a fourth compound represented by Formula D-1:

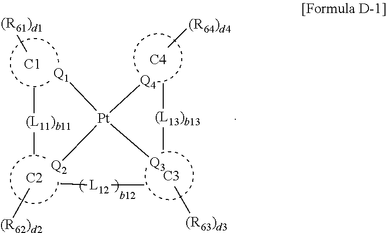

In Formula D-1, Q₁ to Q₄ may each independently be C or N.

In Formula D-1, C1 to C4 may each independently be a substituted or unsubstituted hydrocarbon ring having 5 to 30 ring-forming carbon atoms, a substituted or unsubstituted aryl group having 6 to 30 ring-forming carbon atoms, or a substituted or unsubstituted heterocycle having 2 to 30 ring-forming carbon atoms.

In Formula D-1, L₁₁ to L₁₃ may each independently be a direct linkage,

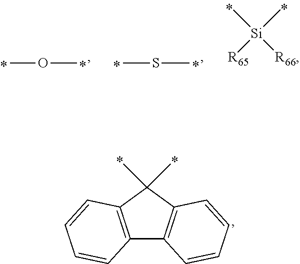

a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms. In L₁₁ to L₁₃, [symbol] represents a bond to one of C1 to C4.

In Formula D-1, b11 to b13 may each independently be 0 or 1. If b11 is 0, C1 and C2 may not be directly linked to each other. If b12 is 0, C2 and C3 may not be directly linked to each other. If b13 is 0, C3 and C4 may not be directly linked to each other.

In Formula D-1, R₆₁ to R₆₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring. For example, R₆₁ to R₆₆ may each independently be a substituted or unsubstituted methyl group or a substituted or unsubstituted t-butyl group.

In Formula D-1, d1 to d4 may each independently be an integer from 0 to 4. In Formula D-1, if di to d4 are each 0, the fourth compound may not be substituted with R₆₁ to R₆₄, respectively. A case where d1 to d4 are each 4 and four groups of each of R₆₁ to R₆₄ are all hydrogen atoms may be the same as a case where di to d4 are each 0. When di to d4 are each 2 or more, multiples of each of R₆₁ to R₆₄ may all be the same or at least one thereof may be different from the remainder.

In Formula D-1, C1 to C4 may each independently be a substituted or unsubstituted hydrocarbon ring or a substituted or unsubstituted heterocycle represented by one of Formula C-1 to Formula C-4:

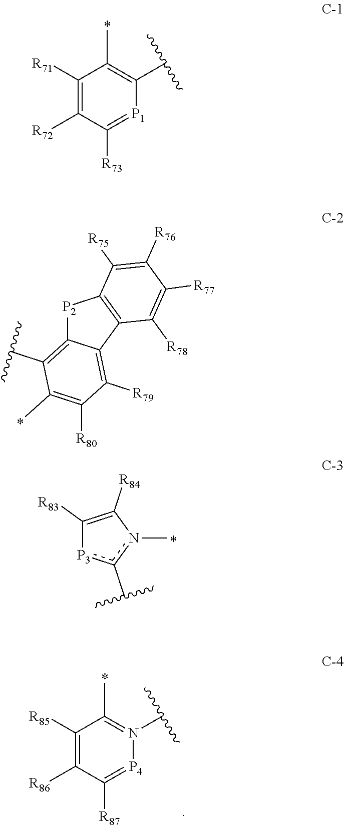

In Formula C-1 to Formula C-4, P₁ may be [symbol] or C(R₇₄), P₂ may be [symbol] or N(R₈₁), P₃ may be [symbol] or N(R₈₂), and P₄ may be [symbol] or C(R₈₈). In Formula C-1 to Formula C-4, R71 to Ras may each independently be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring.

In Formula C-1 to Formula C-4, [symbol] represents a bond to Pt, which is a central metal atom, and [symbol] represents a bond to a neighboring cyclic group (C1 to C4) or to a linking moiety (L₁₁ to L₁₃).

In an embodiment, the emission layer EML may include the first compound represented by Formula 1, and at least one of the second compound, the third compound, and the fourth compound. In an embodiment, the emission layer EML may include the first compound, the second compound, and the third compound. In the emission layer EML, the second compound and the third compound may form an exciplex, and energy may be transferred from the exciplex to the first compound, thereby emitting light.

In another embodiment, the emission layer EML may include the first compound, the second compound, the third compound, and the fourth compound. In the emission layer EML, the second compound and the third compound may form an exciplex, and energy may be transferred from the exciplex to the fourth compound and to the first compound, thereby emitting light. In an embodiment, the fourth compound may be a sensitizer. The fourth compound included in the emission layer EML in the light-emitting element ED according to an embodiment may serve as a sensitizer that transfers energy from a host (for example, an exciplex host) to the first compound, which is a light emitting dopant. For example, the fourth compound, which serves as an auxiliary dopant, may accelerate energy transfer to the first compound, which is a light-emitting dopant, thereby increasing an emission ratio of the first compound. Therefore, the emission layer EML may have improved luminous efficiency. When energy transfer to the first compound increases, excitons formed in the emission layer EML may not accumulate in the emission layer EML and may rapidly emit light, so that deterioration of the device may be reduced. Therefore, the service life of the light-emitting element ED may increase.

The light-emitting element ED may include the first compound, the second compound, the third compound, and the fourth compound, and the emission layer EML may include a combination of two host materials and two dopant materials. In the light-emitting element ED, the emission layer EML may include the second compound and the third compound, which are two different hosts, the first compound that emits delayed fluorescence, and the fourth compound that includes an organometallic complex, so that the light-emitting element ED may exhibit excellent luminous efficiency characteristics.

In an embodiment, the fourth compound represented by Formula D-1 may be selected from Compound Group 4. In an embodiment, in the light-emitting element ED, the fourth compound may include at least one compound selected from Compound Group 4.

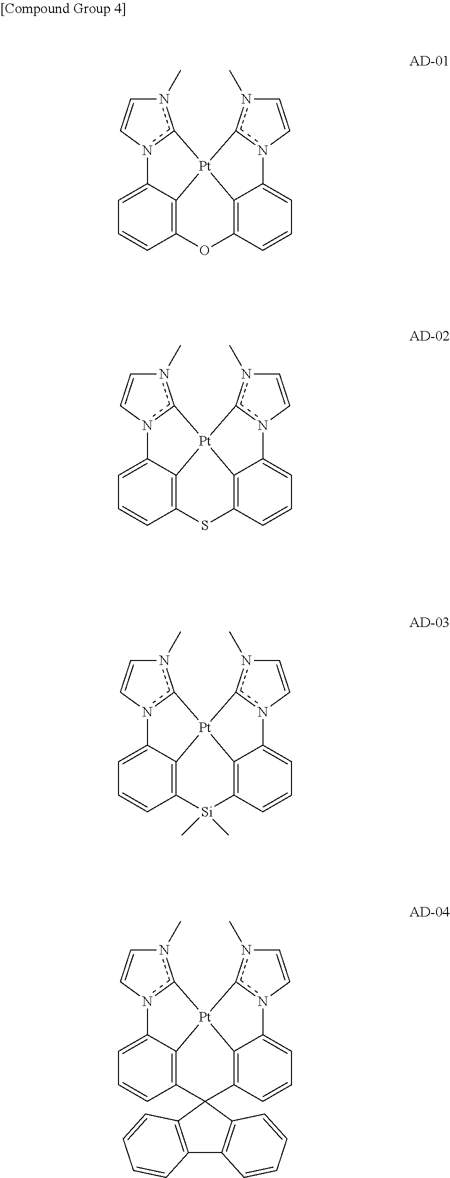

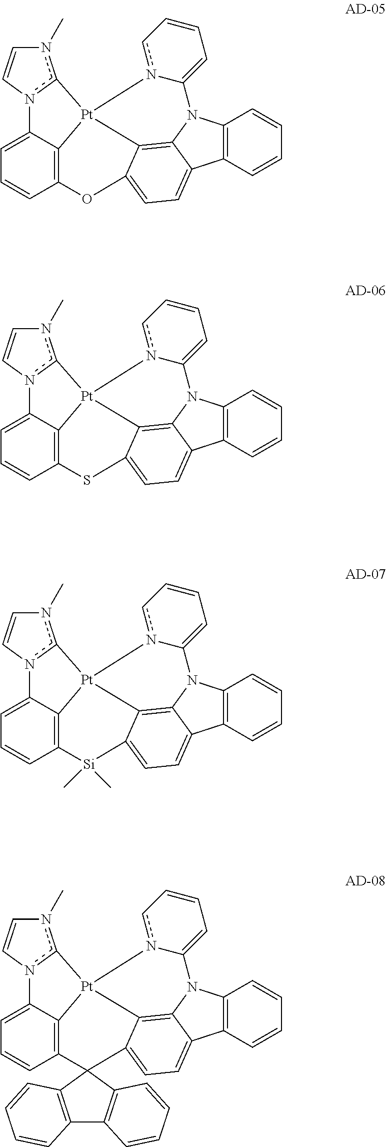

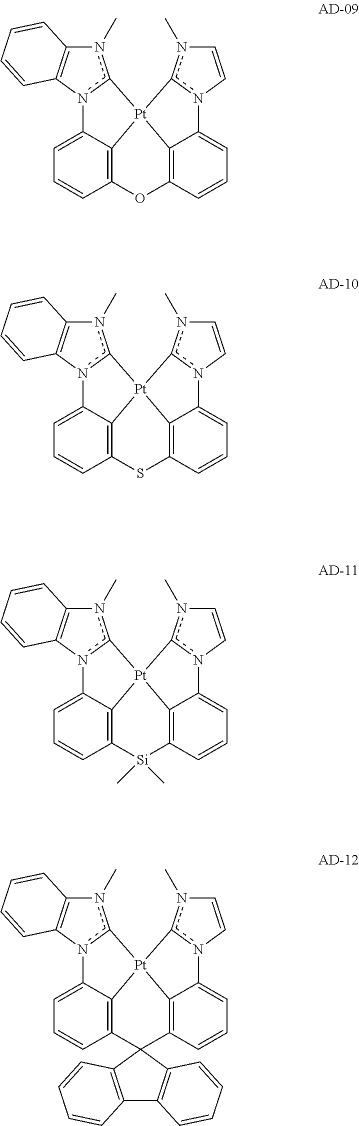

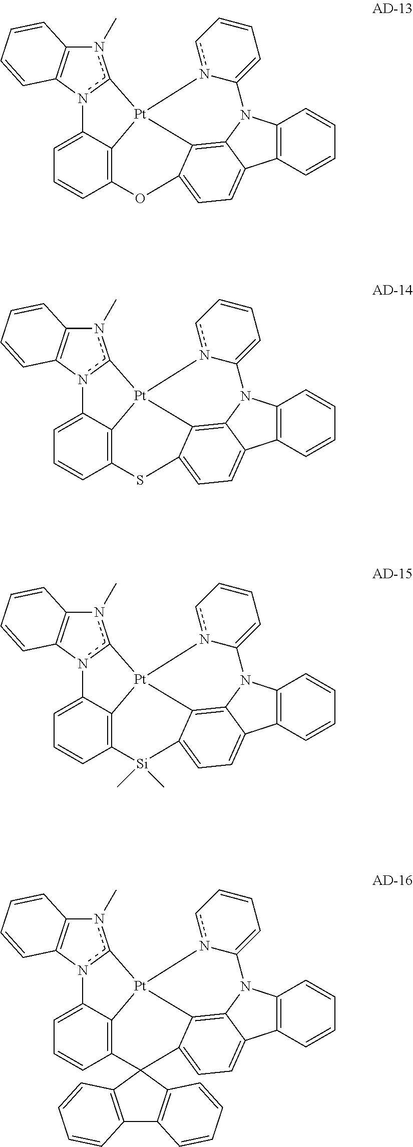

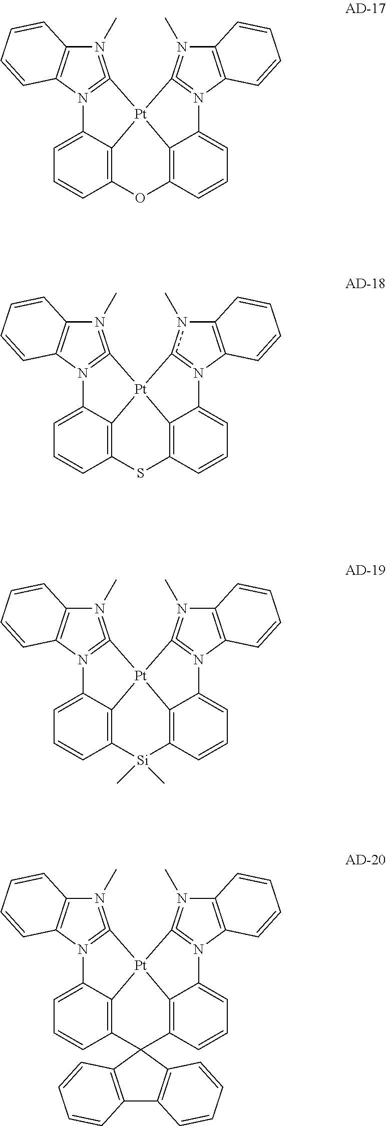

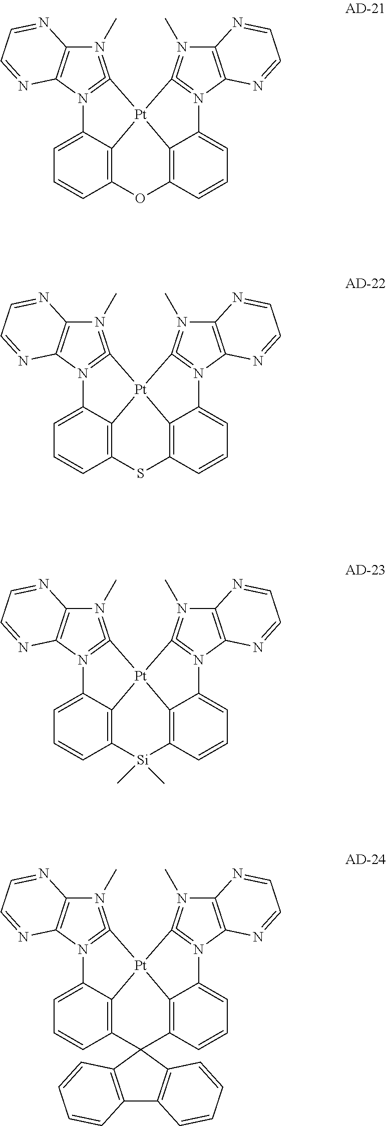

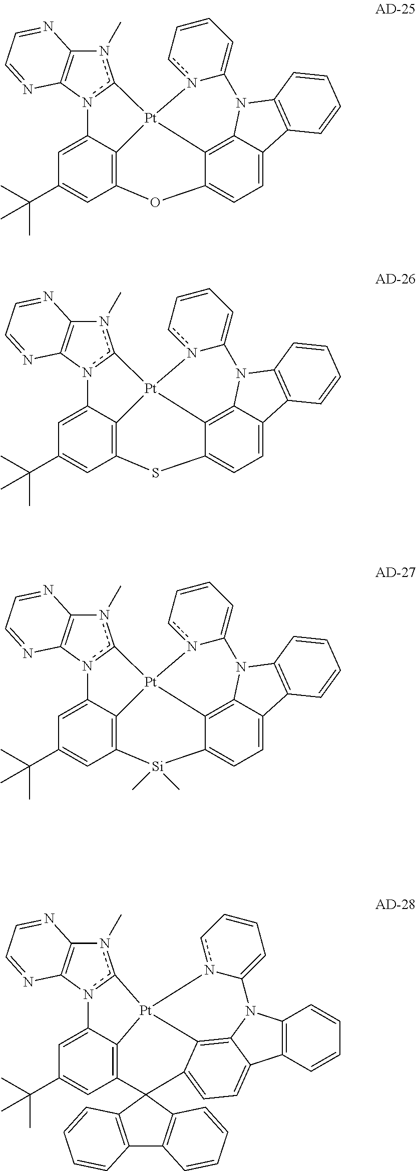

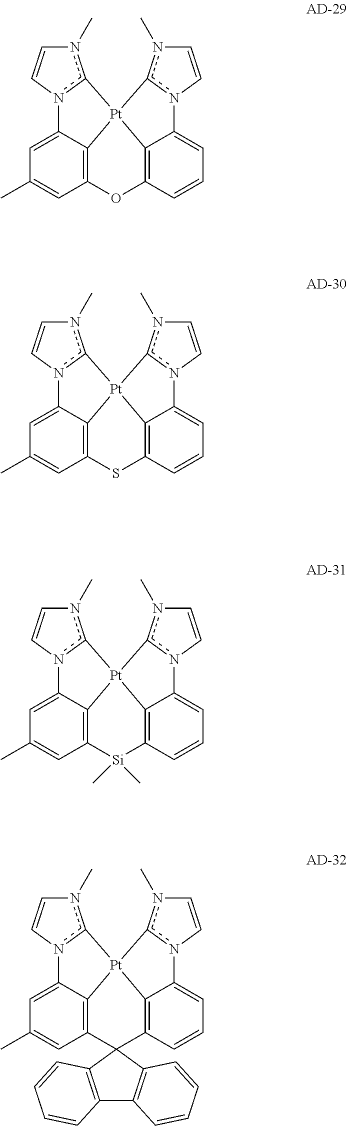

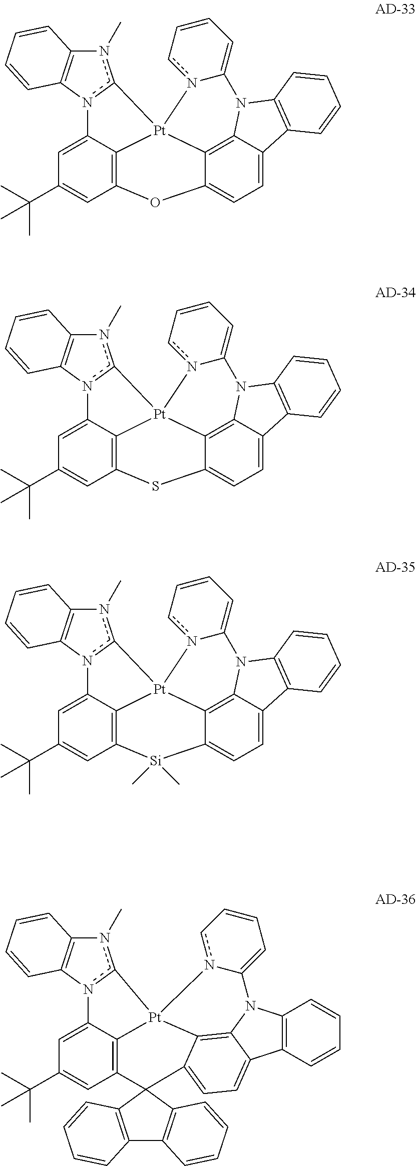

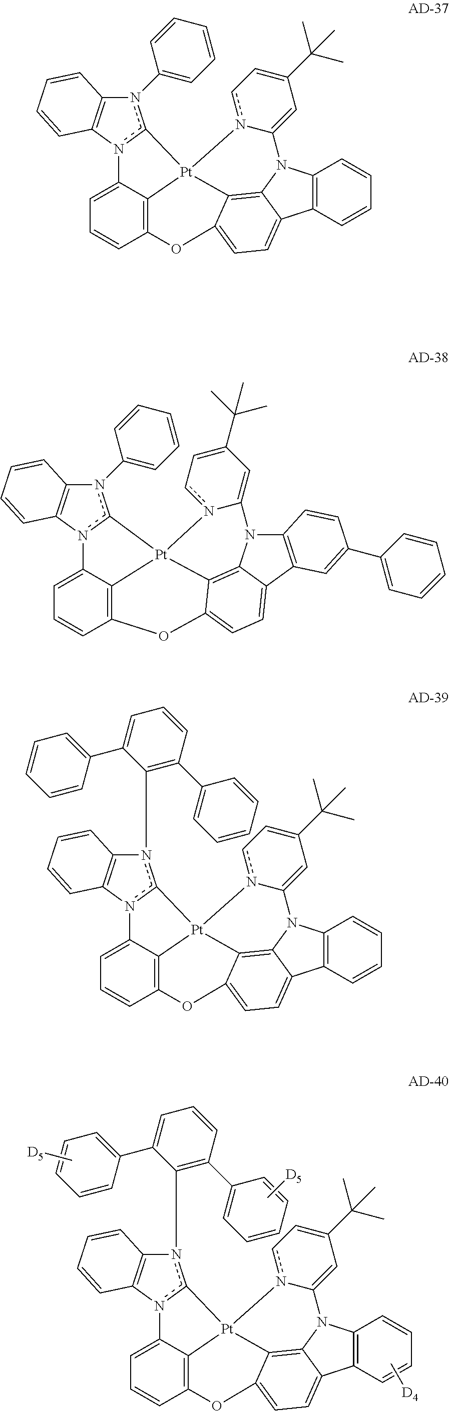

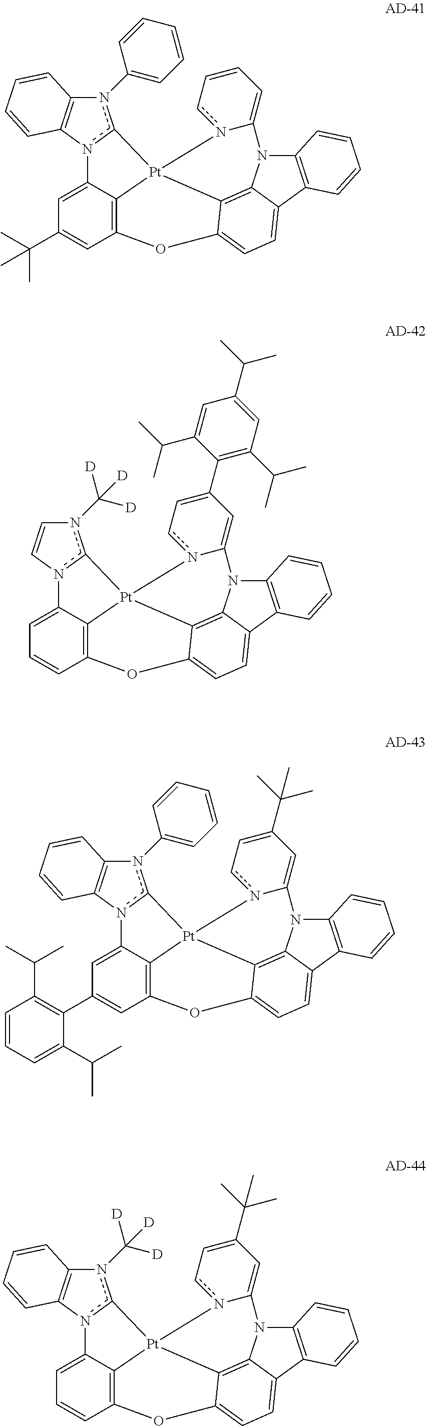

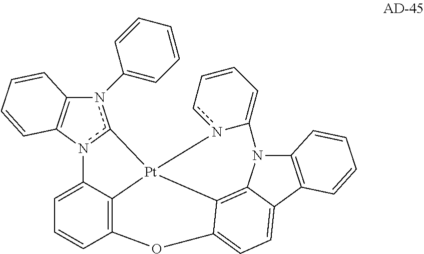

In Compound Group 4, D represents a deuterium atom.

When the emission layer EML in the light-emitting element ED includes the first compound, the second compound, and the third compound, an amount of the first compound may be in a range of about 0.1 wt % to about 5 wt %, based on a total weight of the first compound, the second compound, and the third compound. However, embodiments are not limited thereto. When an amount of the first compound satisfies the range described above, energy transfer from the second compound and the third compound to the first compound may increase, so that luminous efficiency and element service life may increase.

In the emission layer EML, a combined amount of the second compound and the third compound in the emission layer EML may be the remainder of the total weight of the first compound, the second compound, and the third compound, excluding the amount of the first compound. For example, a combined amount of the second compound and the third compound in the emission layer EML may be in a range about 65 wt % to about 95 wt %, based on a total weight of the first compound, the second compound, and the third compound.

Within the combined amount of the second compound and the third compound, a weight ratio of the second compound to the third compound may be in a range about 3:7 to about 7:3.

When the amounts of the second compound and the third compound satisfy the ranges and ratios described above, charge balance characteristics of the emission layer EML may be improved, and thus luminous efficiency and device service life may increase. When the amounts of the second compound and the third compound deviate from the ranges and ratios described above, charge balance in the emission layer EML may not be achieved, and thus luminous efficiency may be reduced and the device may readily deteriorate.

When the emission layer EML includes the fourth compound, an amount of the fourth compound in the emission layer EML may be in a range of about 10 wt % to about 30 wt %, based on a total weight of the first compound, the second compound, the third compound, and the fourth compound. However, embodiments are not limited thereto. When an amount of the fourth compound satisfies the range described above, energy transfer from a host (for example, an exciplex host) to the first compound, which is a light emitting dopant, may be increased, so that an emission ratio may be improved, and thus luminous efficiency of the emission layer EML may be improved. When the first compound, the second compound, the third compound, and the fourth compound included in the emission layer EML satisfy the ranges and ratios described above, excellent luminous efficiency and long device service life may be achieved.

The emission layer EML may be provided on the hole transport region HTR. The emission layer EML may have a thickness in a range of about 100 Å to about 1,000 Å. For example, the emission layer EML may have a thickness in a range of about 100 Å to about 300 Å. The emission layer EML may have a structure consisting of a layer consisting of a single material, a structure consisting of a layer including different materials, or a structure including multiple layers including different materials.

The emission layer EML may further include one or more of the compounds described below, in addition to the fused polycyclic compound according to an embodiment.

In the light-emitting element ED according to an embodiment, the emission layer EML may include an anthracene derivative, a pyrene derivative, a fluoranthene derivative, a chrysene derivative, a dihydrobenzanthracene derivative, or a triphenylene derivative. For example, the emission layer EML may include an anthracene derivative or a pyrene derivative.

In the light-emitting element ED according to embodiments as illustrated in FIGS. 3 to 6, the emission layer EML may further include a host and a dopant of the related art, in addition to the above-described host and dopant. In an embodiment, the emission layer EML may include a compound represented by Formula E-1. The compound represented by Formula E-1 below may be used as a fluorescent host material:

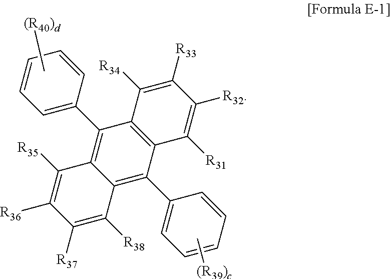

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring. For example, R₃₁ to R₄₀ may be bonded to an adjacent group to form a saturated hydrocarbon ring, an unsaturated hydrocarbon ring, a saturated heterocycle, or an unsaturated heterocycle.

In Formula E-1, c and d may each independently be an integer from 0 to 5.

In an embodiment, the compound represented by Formula E-1 may be any compound selected from Compound E1 to Compound E21:

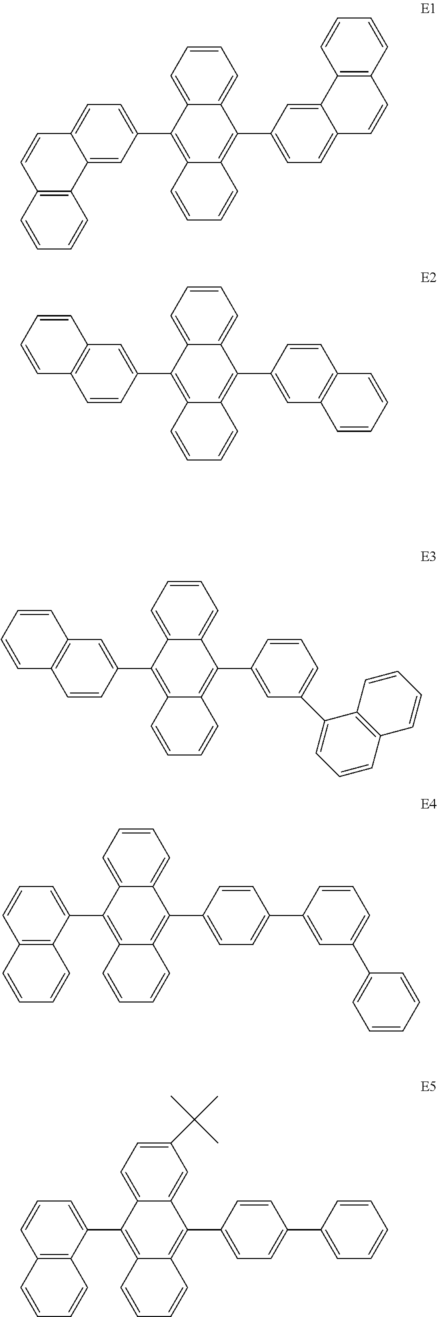

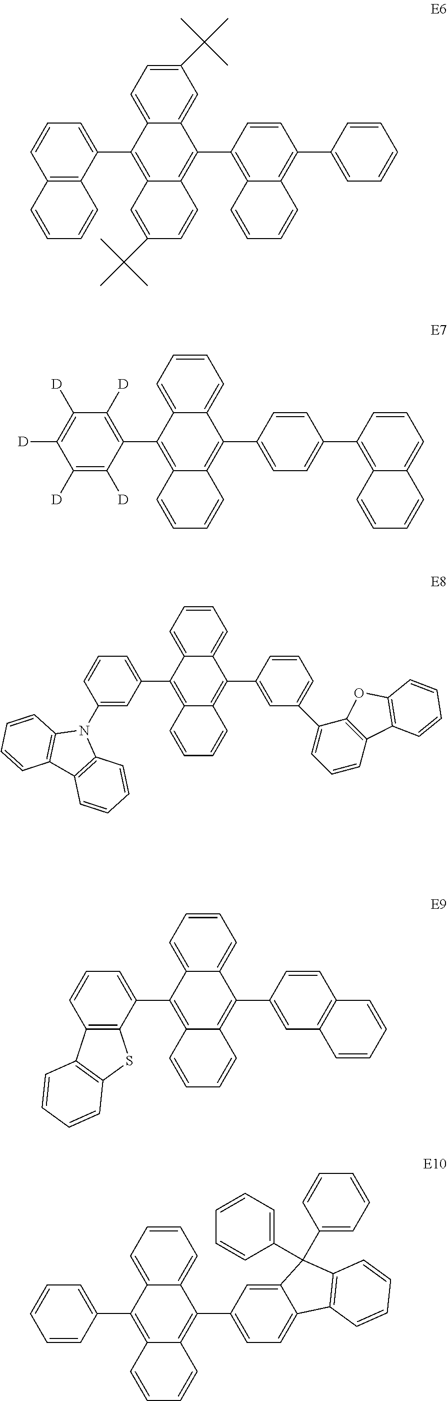

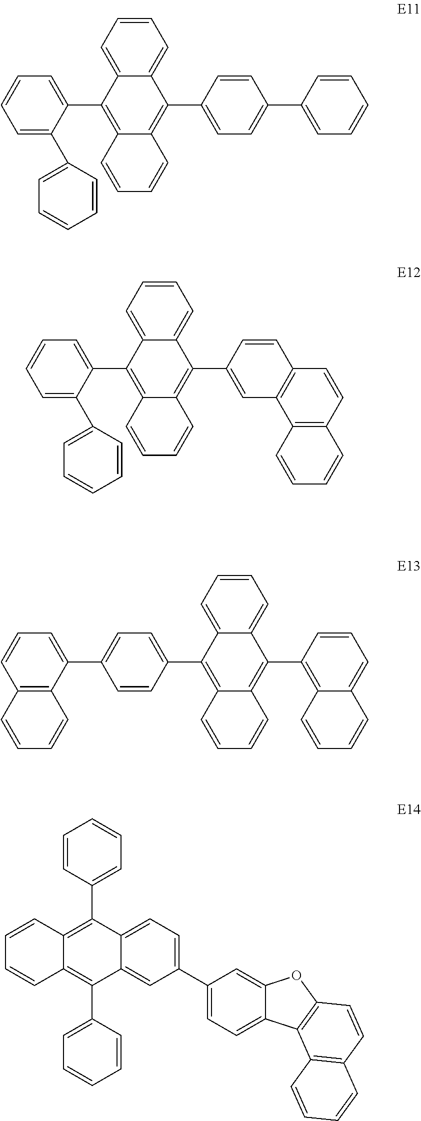

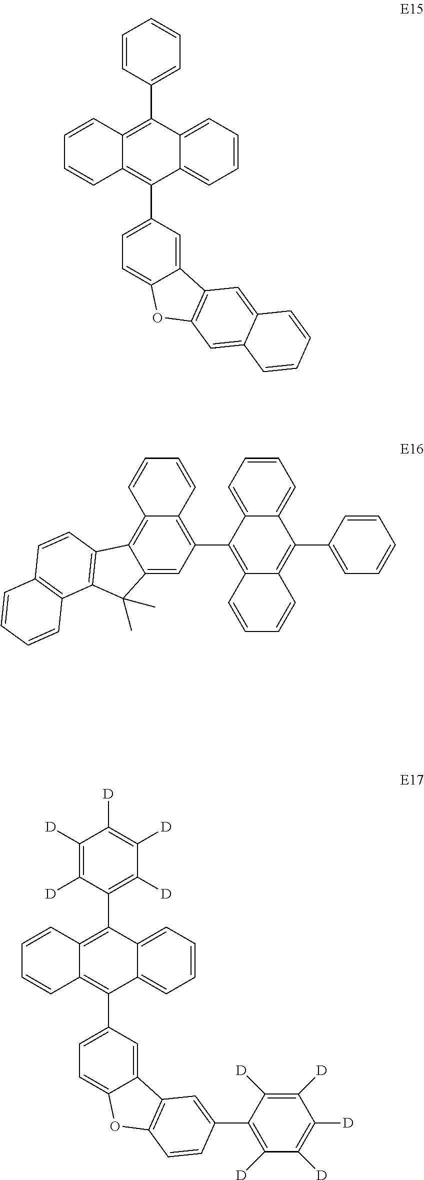

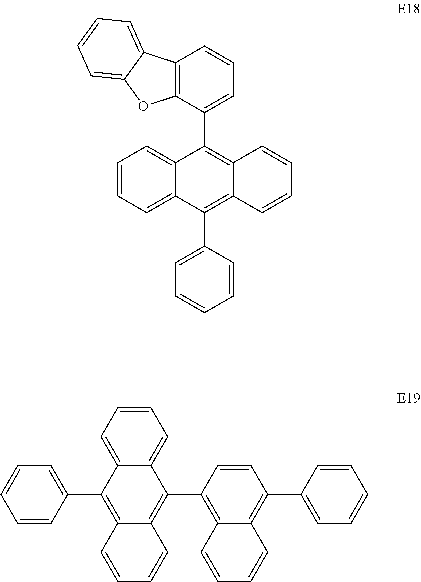

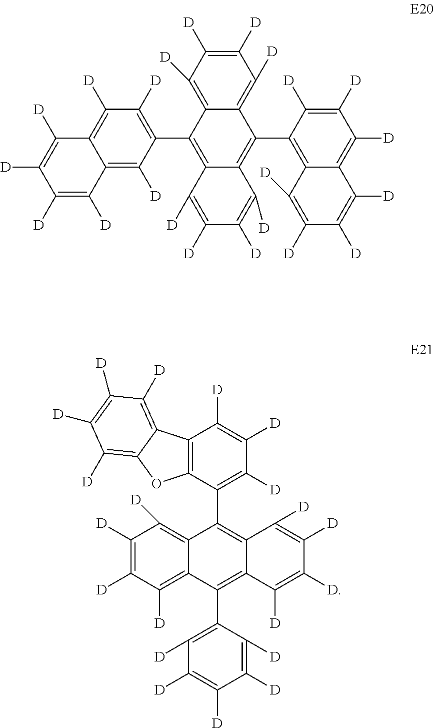

In an embodiment, the emission layer EML may include a compound represented by Formula E-2a or Formula E-2b. The compound represented by Formula E-2a or Formula E-2b may be used as a host material of a phosphorescent emission layer.

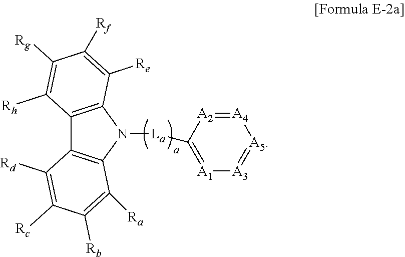

In Formula E-2a, a may be an integer from 0 to 10; and Lₐ may be a direct linkage, a substituted or unsubstituted arylene group having 6 to 30 ring-forming carbon atoms, or a substituted or unsubstituted heteroarylene group having 2 to 30 ring-forming carbon atoms. When a is 2 or greater, multiple Lₐ may each independently be a substituted or unsubstituted arylene group having 6 to 30 ring-forming carbon atoms or a substituted or unsubstituted heteroarylene group having 2 to 30 ring-forming carbon atoms.

In Formula E-2a, A₁ to A₅ may each independently be N or C(Rᵢ). In Formula E-2a, Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring. For example, Rₐ to Rᵢ may be bonded to an adjacent group to form a hydrocarbon ring or a heterocycle containing N, O, S, etc., as a ring-forming atom.

In Formula E-2a, two or three of A₁ to A₅ may each be N, and the remainder of A₁ to A₅ may each independently be C(Rᵢ).

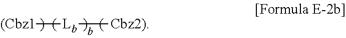

In Formula E-2b, Cbz1 and Cbz2 may each independently be an unsubstituted carbazole group, or a carbazole group substituted with an aryl group having 6 to 30 ring-forming carbon atoms. In Formula E-2b, L_{b} may be a direct linkage, a substituted or unsubstituted arylene group having 6 to 30 ring-forming carbon atoms, or a substituted or unsubstituted heteroarylene group having 2 to 30 ring-forming carbon atoms. In Formula E-2b, b may be an integer from 0 to 10. When b is 2 or more, multiple L_{b} may each independently be a substituted or unsubstituted arylene group having 6 to 30 ring-forming carbon atoms, or a substituted or unsubstituted heteroarylene group having 2 to 30 ring-forming carbon atoms.

In an embodiment, the compound represented by Formula E-2a or Formula E-2b may be any compound selected from Compound Group E-2. However, the compounds listed in Compound Group E-2 are only examples, and the compound represented by Formula E-2a or Formula E-2b is not limited to Compound Group E-2.

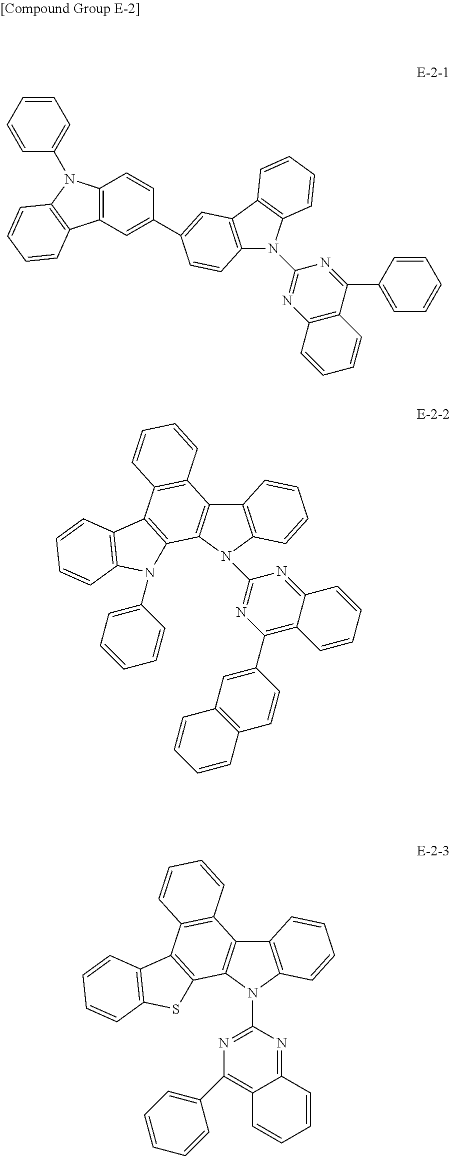 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-n2c3ccccc3c3c4ccccc4c4c5ccccc5n(-c5nc(-c6ccc7ccccc7c6)c6ccccc6n5)c4c32)cc1 ; c1ccc(-c2nc(-n3c4ccccc4c4c5ccccc5c5c6ccccc6sc5c43)nc3ccccc23)cc1]

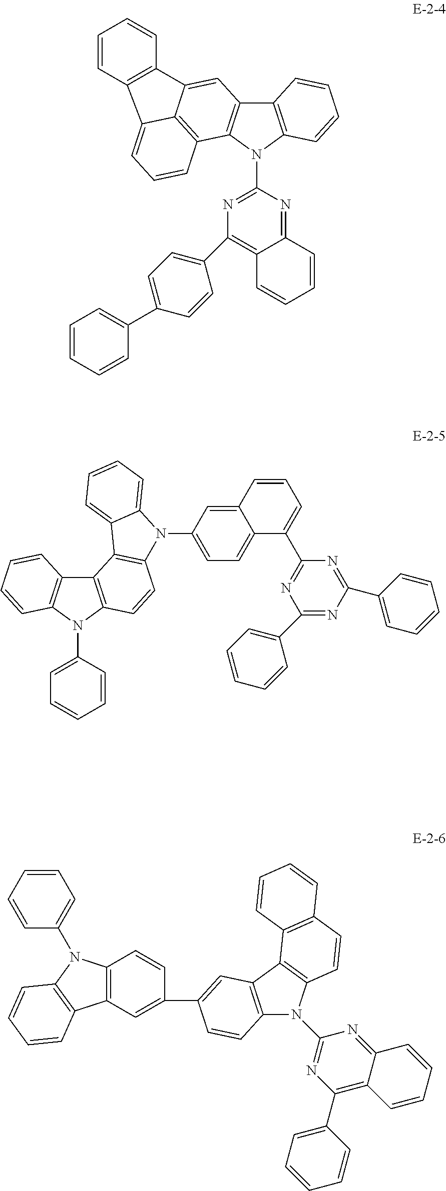 [SMILES: c1ccc(-c2ccc(-c3nc(-n4c5ccccc5c5cc6c7c(cccc7c54)-c4ccccc4-6)nc4ccccc34)cc2)cc1 ; c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1]

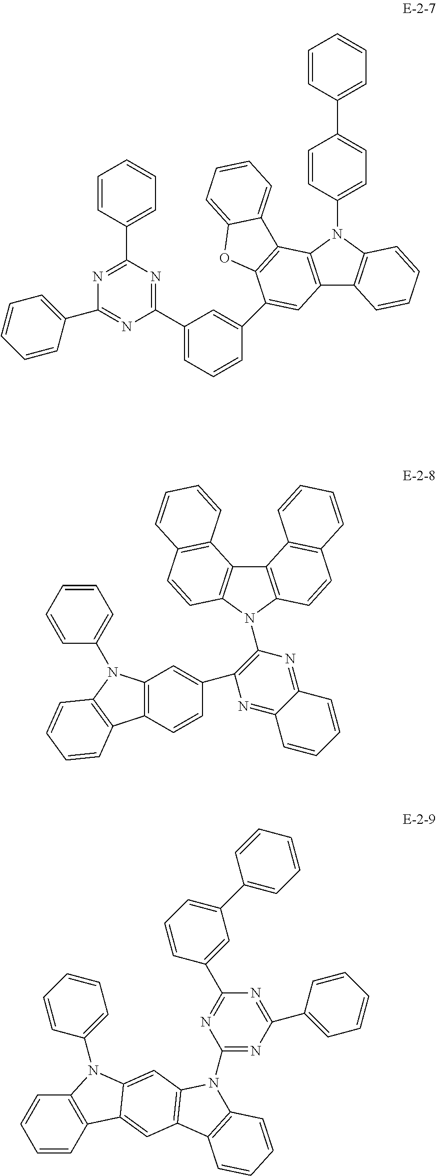 [SMILES: c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1 ; c1ccc(-c2cccc(-c3nc(-c4ccccc4)nc(-n4c5ccccc5c5cc6c7ccccc7n(-c7ccccc7)c6cc54)n3)c2)cc1]

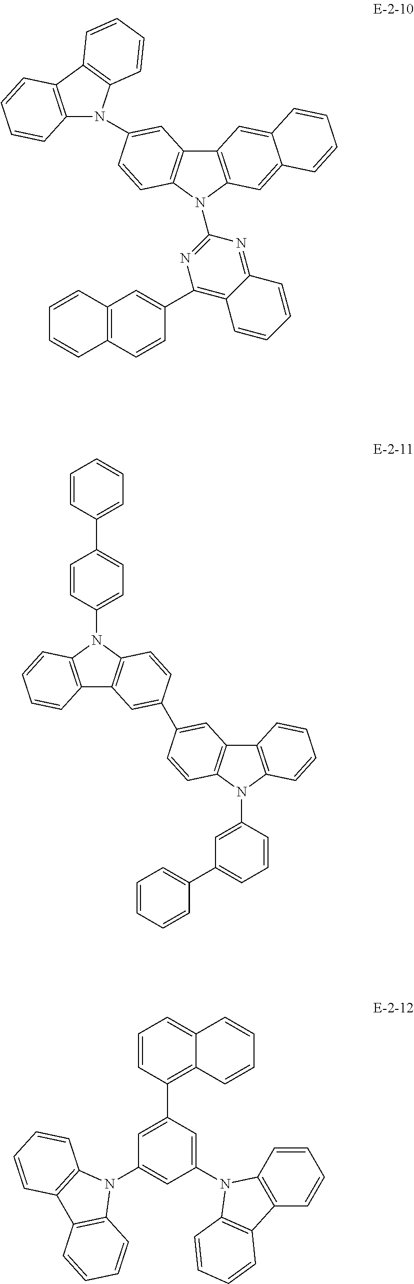 [SMILES: c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1 ; c1ccc2c(-c3cc(-n4c5ccccc5c5ccccc54)cc(-n4c5ccccc5c5ccccc54)c3)cccc2c1]

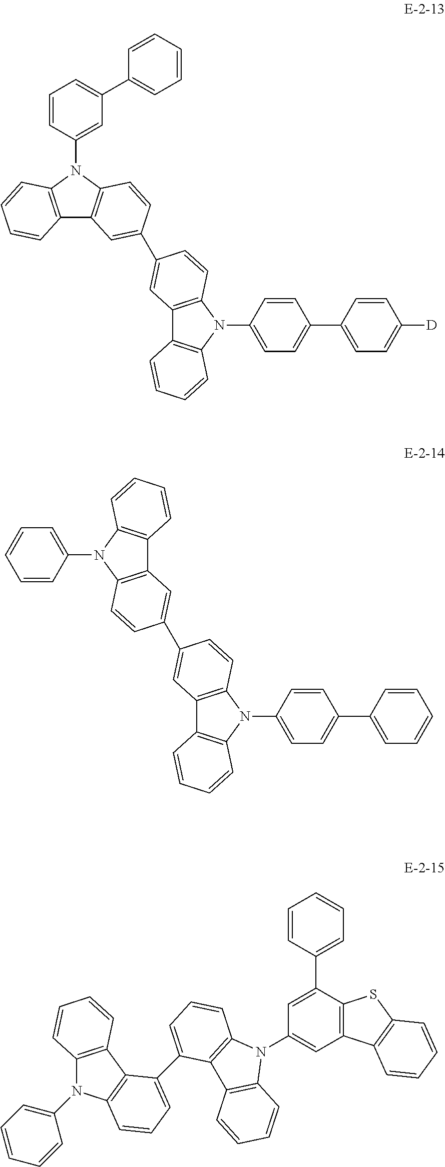 [SMILES: [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

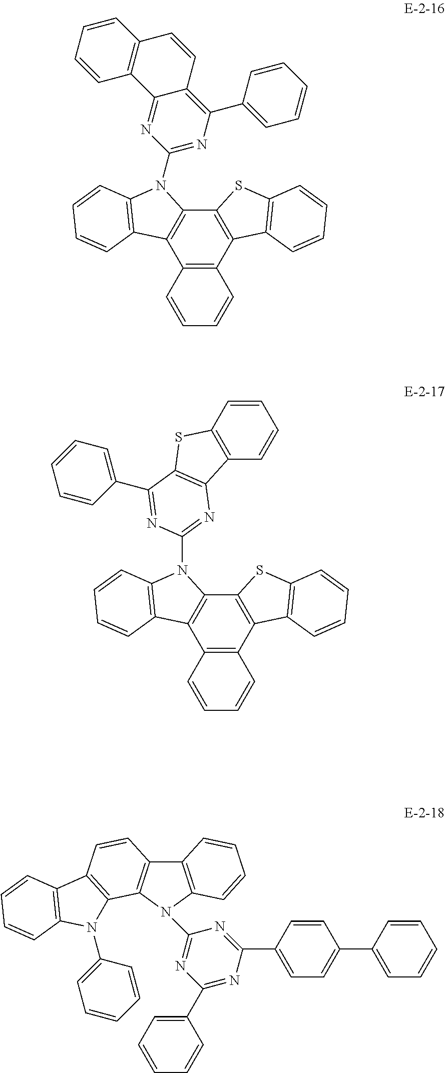 [SMILES: c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1]

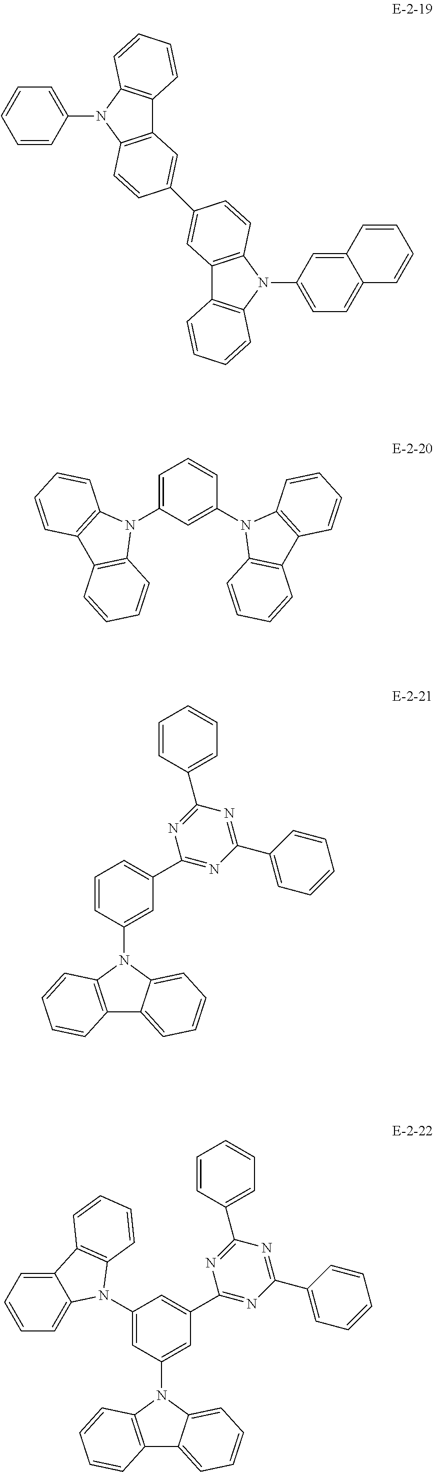 [SMILES: c1ccc(-n2c3ccccc3c3cc(-c4ccc5c(c4)c4ccccc4n5-c4ccc5ccccc5c4)ccc32)cc1 ; c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1]

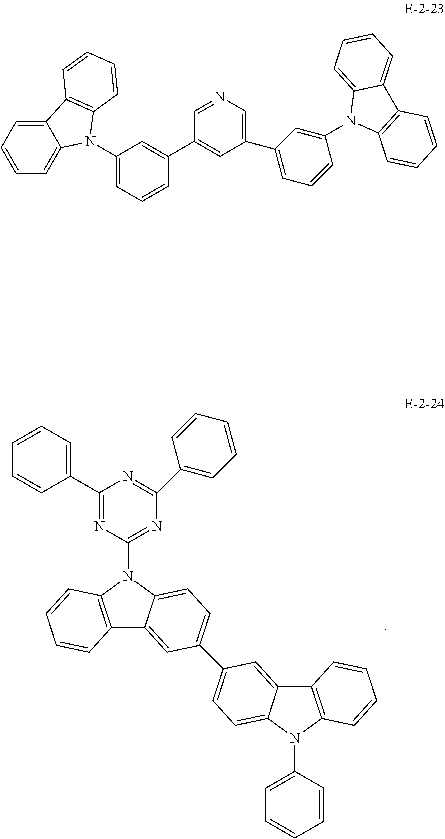 [SMILES: c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

In embodiments, the emission layer EML may further include a material of the related art as a host material. For example, the emission layer EML may include, as a host material, at least one of bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), and 1,3,5-tris(1-phenyl-1H-benzo[d]imidazole-2-yl)benzene (TPBi). However, embodiments are not limited thereto. For example, tris(8-hydroxyquinolino)aluminum (Alq₃), 9,10-di(naphthalen-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetrasiloxane (DPSiO₄), etc. may be used as a host material.

In an embodiment, the emission layer EML may include a compound represented by Formula M-a. The compound represented by Formula M-a may be used as a phosphorescent dopant material.

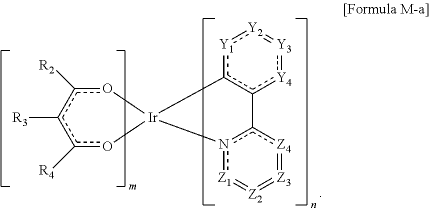

In Formula M-a, Y₁ to Y₄ and Z₁ to Z₄ may each independently be C(R₁) or N; and R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring. In Formula M-a, m may be 0 or 1, and n may be 2 or 3. In Formula M-a, when m is 0, n may be 3, and when m is 1, n may be 2.

In an embodiment, the compound represented by Formula M-a may be any compound selected from Compound M-a1 to Compound M-a25. However, Compounds M-a1 to M-a25 are only examples, and the compound represented by Formula M-a is not limited to Compounds M-a1 to M-a25.

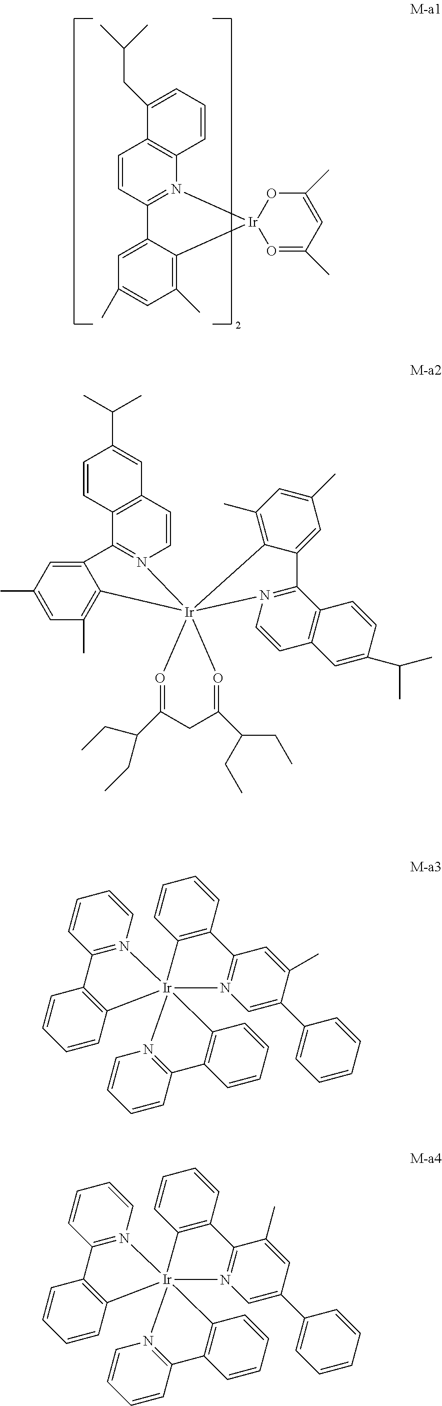

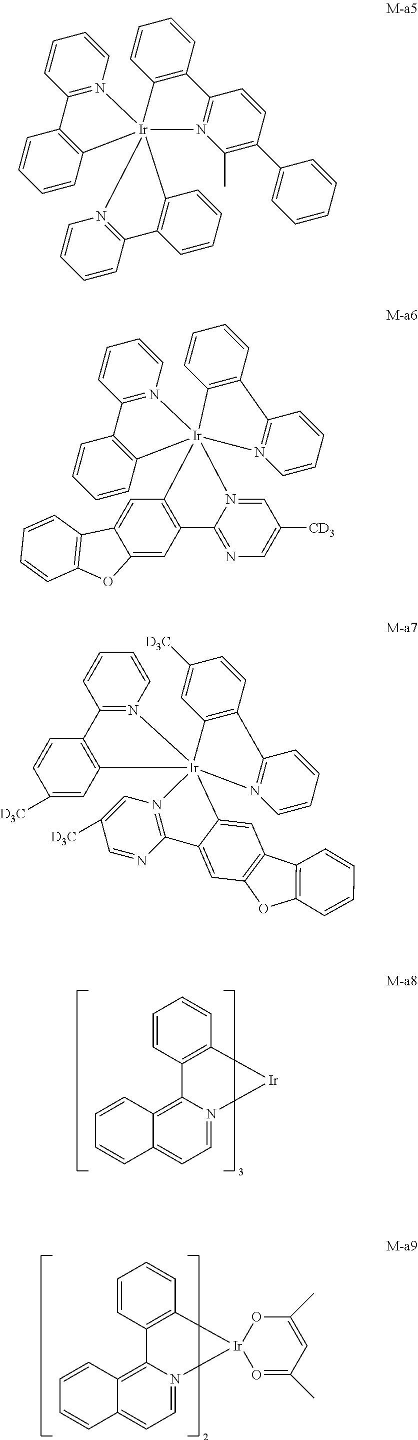

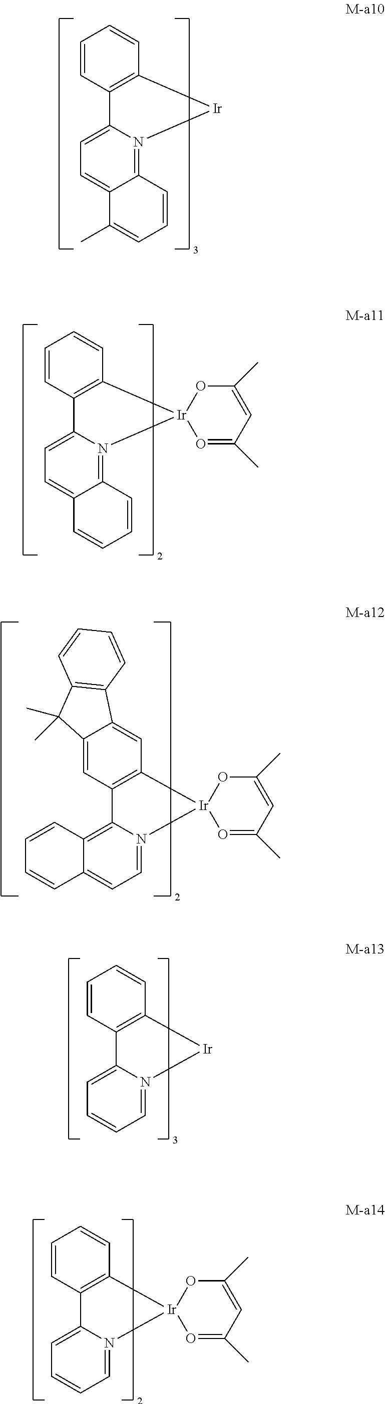

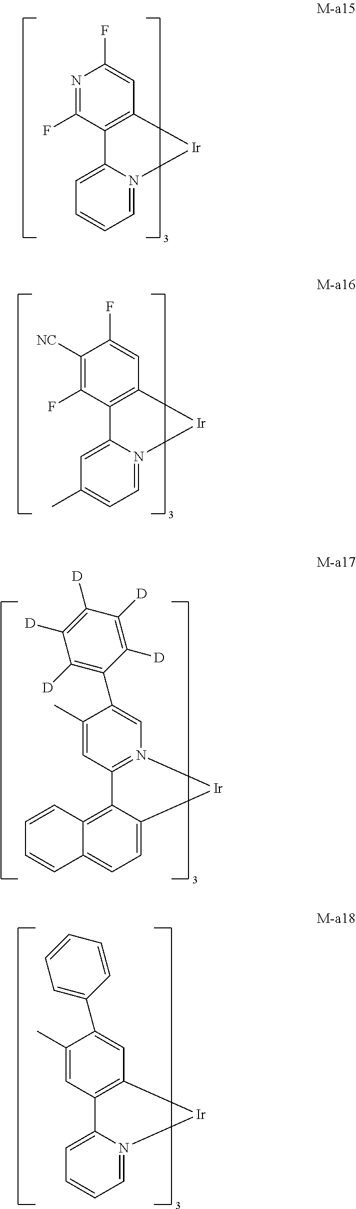

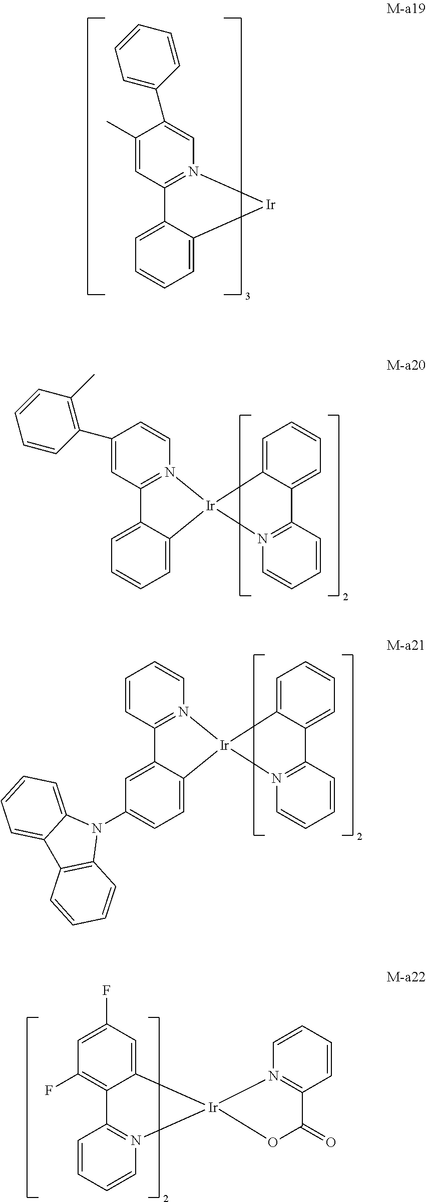

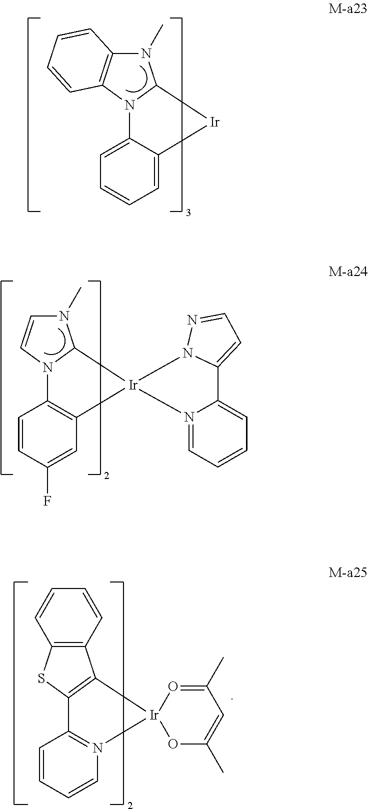

In an embodiment, the emission layer EML may include a compound represented by one of Formula F-a to Formula F-c. The compound represented by one of Formula F-a to Formula F-c may be used as a fluorescence dopant material.

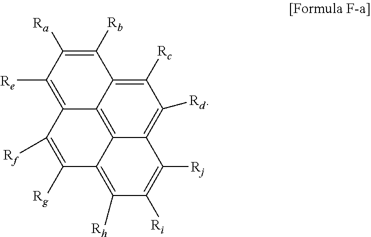

In Formula F-a above, two of Rₐ to Rⱼ may each independently be substituted with a group represented by

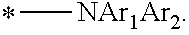

The remainder of Rₐ to Rⱼ that are not substituted with the group represented by

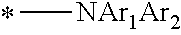

may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In the group represented by

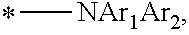

Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. For example, at least one of Ar₁ and Ar₂ may each independently be a heteroaryl group containing O or S as a ring-forming atom.

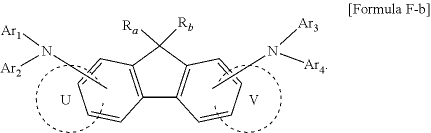

In Formula F-b, Rₐ and R_{b} may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring. In Formula F-b, Ar₁ to Ar₄ may each independently be a substituted or unsubstituted aryl group having 6 to 30 ring-forming carbon atoms or a substituted or unsubstituted heteroaryl group having 2 to 30 ring-forming carbon atoms. For example, at least one of Ar₁ to Ar₄ may each independently be a heteroaryl group including O or S as a ring-forming atom.

In Formula F-b, U and V may each independently be a substituted or unsubstituted hydrocarbon ring having 5 to 30 ring-forming carbon atoms or a substituted or unsubstituted heterocycle having 2 to 30 ring-forming carbon atoms.

In Formula F-b, the number of rings represented by U and V may each independently be 0 or 1. When the number of U or V is 1, a fused ring may be present at a portion respectively indicated by U or V, and when the number of U or V is 0, a fused ring may not be present at the portion respectively indicated by U or V. When the number of U is 0 and the number of V is 1, or when the number of U is 1 and the number of V is 0, a fused ring having a fluorene core of Formula F-b may be a cyclic compound having four rings. When the number of U and V is each 0, a fused ring having a fluorene core of Formula F-b may be a cyclic compound having three rings. When the number of U and V is each 1, a fused ring having a fluorene core of Formula F-b may be a cyclic compound having five rings.

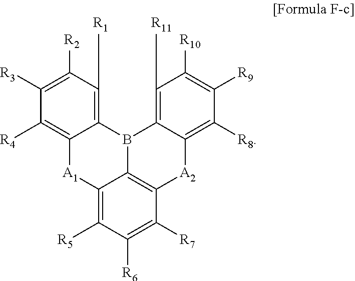

In Formula F-c, A₁ and A₂ may each independently be O, S, Se, or N(Rₘ); and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Formula F-c, R₁ to R₁₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring.

In Formula F-c, A₁ and A₂ may each independently be bonded to a substituent of an adjacent ring to form a fused ring. For example, when A₁ and A₂ are each independently N(Rₘ), A₁ may be bonded to R₄ or R₅ to form a ring, and/or A₂ may be bonded to R₇ or R₈ to form a ring.

In an embodiment, the emission layer EML may further include, as a dopant material of the related art, a styryl derivative (e.g., 1,4-bis[2-(3-N-ethylcarbazolyl)vinyl]benzene (BCzVB), 4-(di-p-tolylamino)-4′-[(di-p-tolylamino)styryl]stilbene (DPAVB), and N-(4-((E)-2-(6-((E)-4-(diphenylamino)styryl)naphthalen-2-yl)vinyl)phenyl)-N-phenylbenzenamine (N-BDAVBi), 4,4′-bis[2-(4-(N,N-diphenylamino)phenyl)vinyl]biphenyl (DPAVBi), perylene or a derivative thereof (e.g., 2,5,8,11-tetra-t-butylperylene (TBP)), pyrene or a derivative thereof (e.g., 1,1-dipyrene, 1,4-dipyrenylbenzene, 1,4-bis(N,N-diphenylamino)pyrene), etc.

The emission layer EML may further include a phosphorescence dopant material of the related art. For example, a metal complex that includes iridium (Ir), platinum (Pt), osmium (Os), gold (Au), titanium (Ti), zirconium (Zr), hafnium (Hf), europium (Eu), terbium (Tb), or thulium (Tm) may be used as a phosphorescent dopant material. For example, iridium(III) bis(4,6-difluorophenylpyridinato-N, C2′)picolinato) (FIrpic), bis(2,4-difluorophenylpyridinato)-tetrakis(1-pyrazolyl)borate iridium(III) (Fir6), or platinum octaethyl porphyrin (PtOEP) may be used as a phosphorescent dopant material. However, embodiments are not limited thereto.

In embodiments, the emission layer EML may include a quantum dot material. A quantum dot may include a Group II-VI compound, a Group I-II-VI compound, a Group II-IV-VI compound, a Group I-II-IV-VI compound, a Group II-IV-V compound, a Group III-VI compound, a Group I-III-VI compound, a Group III-V compound, a Group III-II-V compound, a Group IV-VI compound, a IV Group element, a Group IV compound, or any combination thereof.

Examples of a Group II-VI compound may include: a binary compound such as CdSe, CdTe, CdS, ZnS, ZnSe, ZnTe, ZnO, HgS, HgSe, HgTe, MgSe, MgS, and mixtures thereof; a ternary compound such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and mixtures thereof; a quaternary compound such as HgZnTeS, CdZnSeS, CdZnSeTe, CdZnSTe, CdHgSeS, CdHgSeTe, CdHgSTe, HgZnSeS, HgZnSeTe, and mixtures thereof; and any combination thereof.

In an embodiment, a Group II-VI compound may further include a Group I metal and/or a Group IV element. Examples of a Group I-II-VI compound may include CuSnS and CuZnS, and examples of a Group II-IV-VI compound may include ZnSnS and the like. Examples of a Group I-II-IV-VI compound may include a quaternary compound such as Cu₂ZnSnS₂, Cu₂ZnSnS₄, Cu₂ZnSnSe₄, Ag₂ZnSnS₂, and mixtures thereof.

Examples of a Group II-IV-V compound may include a ternary compound such as ZnSnP, ZnSnP₂, ZnSnAs₂, ZnGeP₂, ZnGeAs₂, CdSnP₂, CdGeP₂, and mixtures thereof.

Examples of a Group III-VI compound may include: a binary compound such as GaS, Ga₂S₃, GaSe, Ga₂Se₃, GaTe, InTe, InS, InSe, In₂S₃, and In₂Se₃; a ternary compound such as InGaS₃, and InGaSe₃; and any combination thereof.

Examples of a Group I-III-VI compound may include: a ternary compound such as AgInS, AgInS₂, CuInS, CuInS₂, AgGaS₂, CuGaS₂ CuGaO₂, AgGaO₂, AgAlO₂, and mixtures thereof; a quaternary compound such as AgInGaS₂ and CuInGaS₂; and any combination thereof.

Examples of a Group III-V compound may include: a binary compound such as GaN, GaP, GaAs, GaSb, AlN, AlP, AlAs, AlSb, InN, InP, InAs, InSb, and mixtures thereof; a ternary compound such as GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and mixtures thereof; a quaternary compound such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and mixtures thereof; and any combination thereof. In an embodiment, a Group III-V compound may further include a Group II metal. Examples of a Group III-II-V compound may include InZnP and the like.

Examples of a Group IV-VI compound may include: a binary compound such as SnS, SnSe, SnTe, PbS, PbSe, PbTe, and mixtures thereof; a ternary compound such as SnSeS, SnSeTe, SnSTe, PbSeS, PbSeTe, PbSTe, SnPbS, SnPbSe, SnPbTe, and mixtures thereof; a quaternary compound such as SnPbSSe, SnPbSeTe, SnPbSTe, and mixtures thereof; and any combination thereof.

Examples of a Group IV element may include Si, Ge, and mixtures thereof. Examples of a Group IV compound may include a binary compound such as SiC, SiGe, and mixtures thereof.

Each element included in a compound such as a binary compound, a ternary compound, or a quaternary compound may be present in a particle at a uniform concentration distribution or at a non-uniform concentration distribution. For example, a formula may indicate the elements that are included in a compound, but an elemental ratio within the compound may vary. For example, AgInGaS₂ may indicate AgInₓGa₁₋ₓS₂ (wherein x is a real number between 0 to 1).

In an embodiment, the quantum dot may have a single structure in which each element is present at a uniform concentration or the quantum dot may have a core-shell structure. For example, a material included in the core may be different from a material included in the shell.

The shell of the quantum dot may serve as a protective layer that prevents chemical deformation of the core to maintain semiconductor properties and/or may serve as a charging layer that imparts electrophoretic properties to the quantum dot. The shell may be single-layered or multilayered. An interface between the core and the shell may have a concentration gradient where the concentration of an element that is present in the shell decreases towards the center.

Examples of a shell of a quantum dot may include a metal oxide, a non-metal oxide, a semiconductor compound, and combinations thereof.

Examples of a metal oxide or a non-metal oxide may include: a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, and NiO; and a ternary compound such as MgAl₂O₄, CoFe₂O₄, NiFe₂O₄, and CoMn₂O₄, but embodiments are not limited thereto.

Examples of a semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but embodiments are not limited thereto.

A quantum dot may have a full width at half maximum (FWHM) of an emission wavelength spectrum less than or equal to about 45 nm. For example, the quantum dot may have an FWHM of an emission wavelength spectrum less than or equal to about 40 nm. For example, the quantum dot may have an FWHM of an emission wavelength spectrum less than or equal to about 30 nm. Within any of the above ranges, color purity or color reproductivity may be improved. A quantum dot may emit light in all directions, so that a viewing angle of light may be improved.

The shape of a quantum dot is not particularly limited and may be any shape used in the related art. For example, a quantum dot may be in the form of nanoparticles, nanotubes, nanowires, nanofibers, or nanoplates, or a quantum dot may have spherical shape, a pyramidal shape, a multi-arm shape, or a cubic shape.

By adjusting a size of the quantum dot or an elemental ratio within a quantum dot compound, an energy band gap may be adjusted, and thus light in various wavelength regions may be obtained from a quantum dot-emission layer. Therefore, by utilizing a quantum dot as described above (by having different sizes or different elemental ratios within a quantum dot compound), a light-emitting element emitting light with various wavelengths may be implemented. For example, a size of the quantum dot or an elemental ratio within the quantum dot compound may be selected so that red light, green light, and/or blue light is emitted. In an embodiment, the quantum dot may be configured to emit white light by combining light of various colors.

In the light-emitting elements ED according to embodiments illustrated in each of FIGS. 3 to 6, the electron transport region ETR may be provided on the emission layer EML. The electron transport region ETR may include at least one of a hole blocking layer HBL, an electron transport layer ETL, and an electron injection layer EIL, but embodiments are not limited thereto.

The electron transport region ETR may have a structure consisting of a layer consisting of a single material, a structure consisting of a layer including different materials, or a structure including multiple layers including different materials.

For example, the electron transport region ETR may have a single-layered structure of an electron injection layer EL or an electron transport layer ETL, or may have a single-layered structure that includes an electron injection material and an electron transport material. In embodiments, the electron transport region ETR may have an electron transport layer ETL/electron injection layer EIL structure, or a hole blocking layer HBL/electron transport layer ETL/electron injection layer EL structure, in which the layers of each structure may be stacked in its respective stated order from the emission layer EML, but embodiments are not limited thereto. The electron transport region ETR may have a thickness, for example, in a range of about 1,000 Å to about 1,500 Å.

The electron transport region ETR may be formed using various methods such as a vacuum deposition method, a spin coating method, a cast method, a Langmuir-Blodgett (LB) method, an inkjet printing method, a laser printing method, and a laser induced thermal imaging (LITI) method.

In the light-emitting element ED according to an embodiment, the electron transport region ETR may include a compound represented by Formula ET-2:

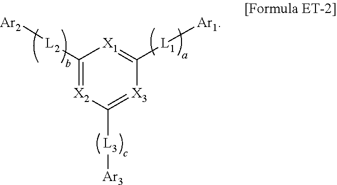

In Formula ET-2, at least one of X₁ to X₃ may each be N, and the remainder of X₁ to X₃ may each independently be C(Rₐ). In Formula ET-2, Rₐ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Formula ET-2, Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-2, a to c may each independently be an integer from 0 to 10. In Formula ET-2, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms. When a to c are each 2 or more, multiple groups of each of L₁ to L₃ may each independently be a substituted or unsubstituted arylene group having 6 to 30 ring-forming carbon atoms, or a substituted or unsubstituted heteroarylene group having 2 to 30 ring-forming carbon atoms.

The electron transport region ETR may include an anthracene-based compound. However, embodiments are not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(biphenyl-4-yl)-5-(4-tert-butylphenyl)-4-phenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), beryllium bis(benzoquinolin-10-olate) (Bebq₂), 9,10-di(naphthalen-2-yl)anthracene (ADN), 1,3-bis[3,5-di(pyridin-3-yl)phenyl]benzene (BmPyPhB), or a mixture thereof.

In an embodiment, the electron transport region ETR may include at least one of Compound ET1 to Compound ET36:

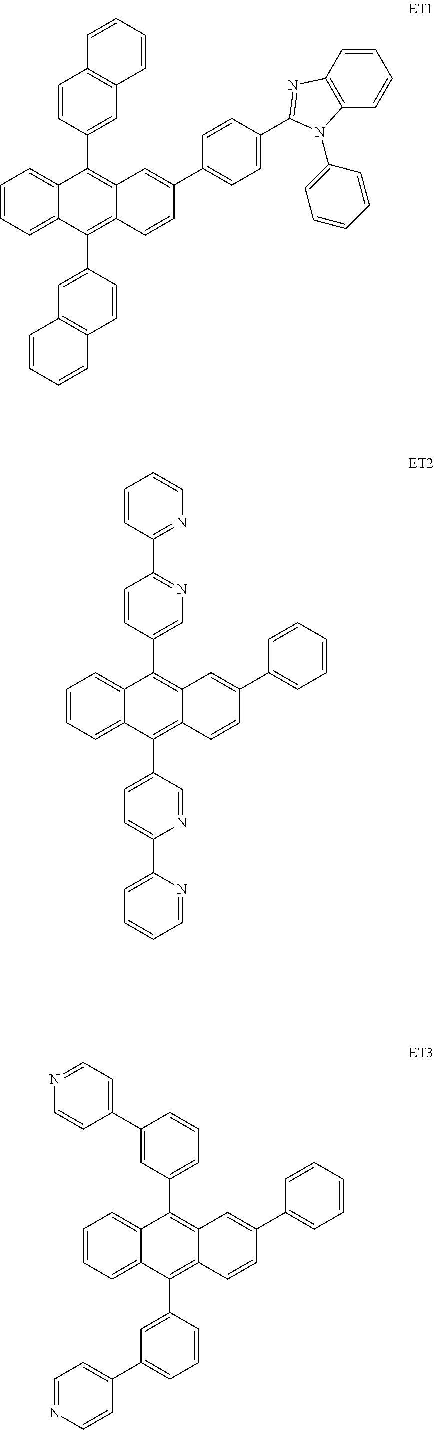 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

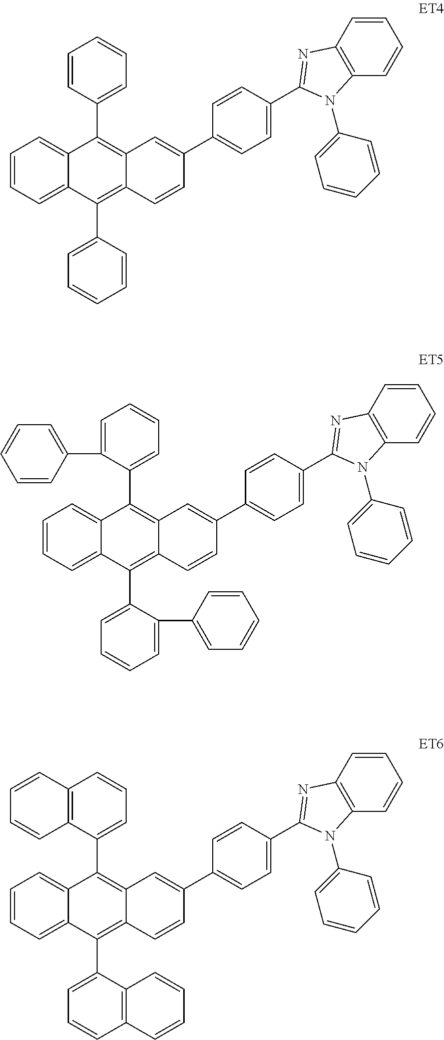 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

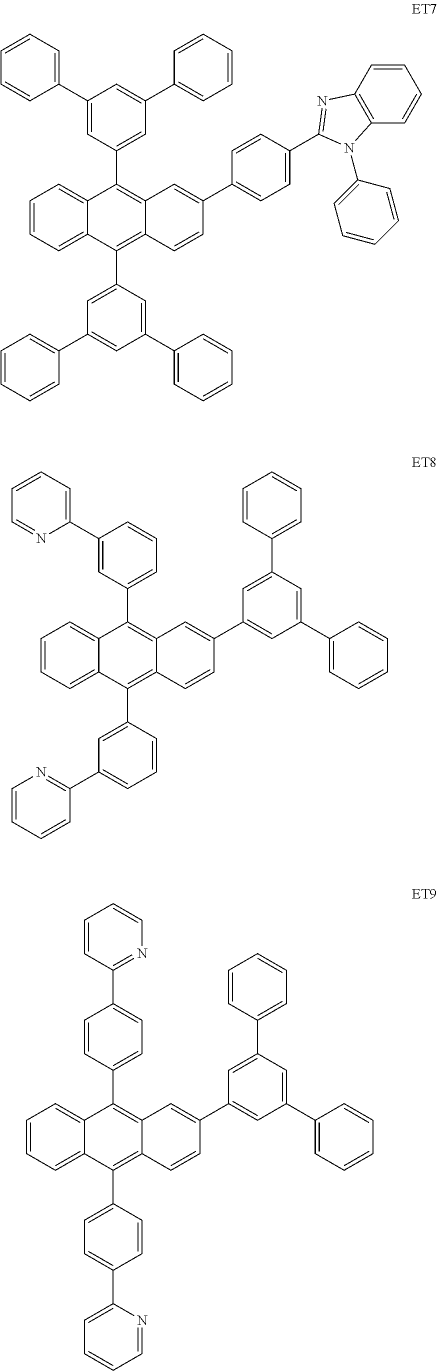 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

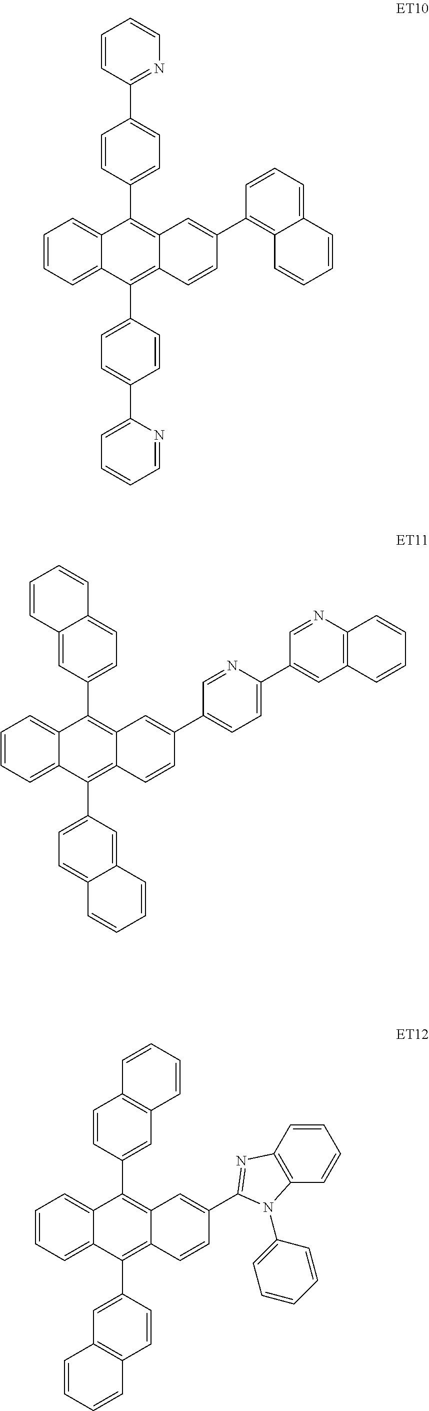 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

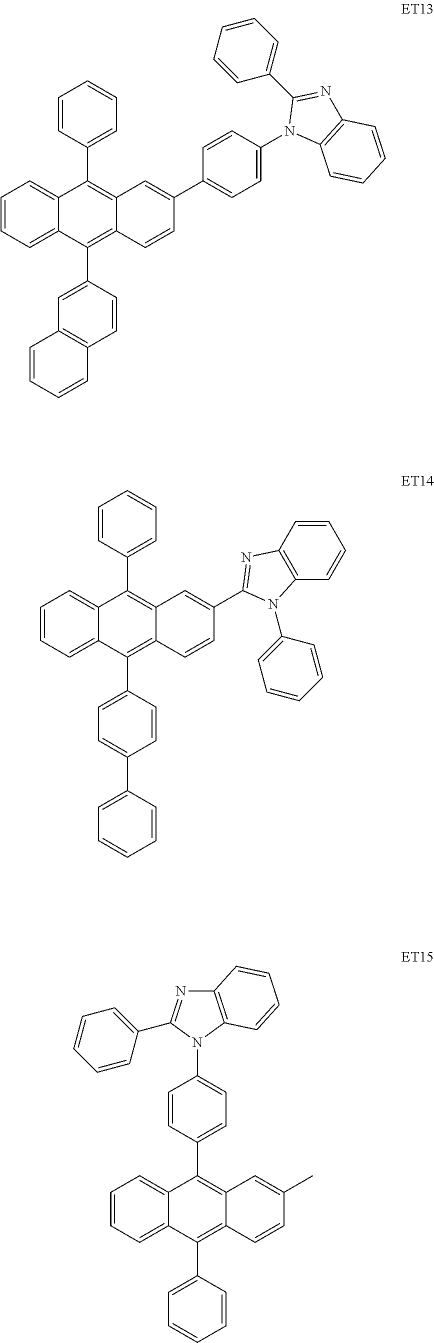 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

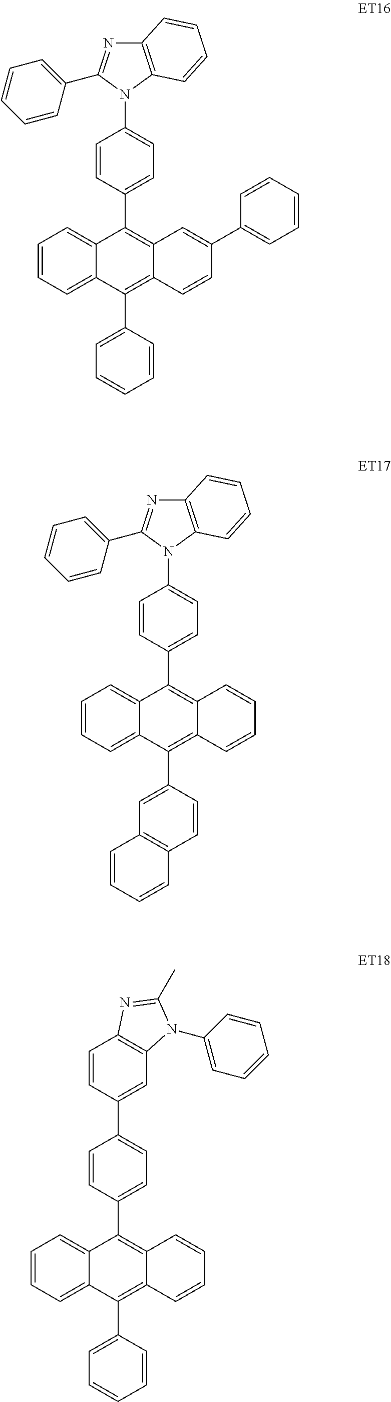 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

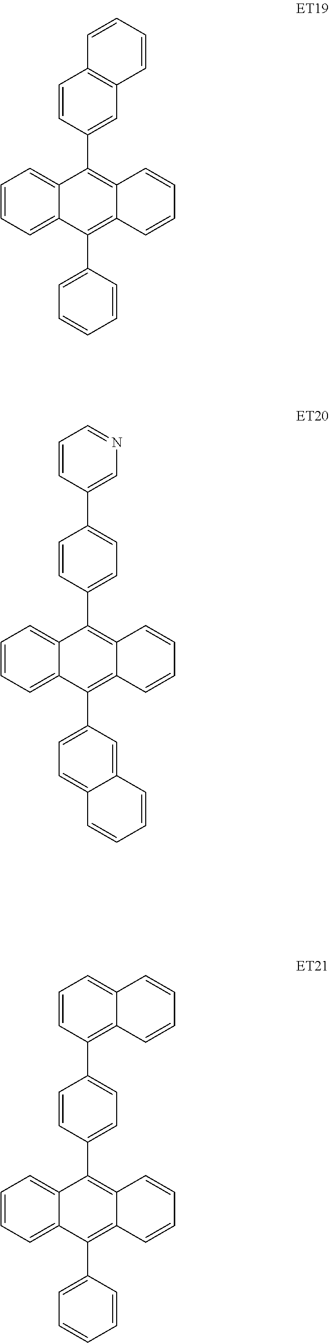

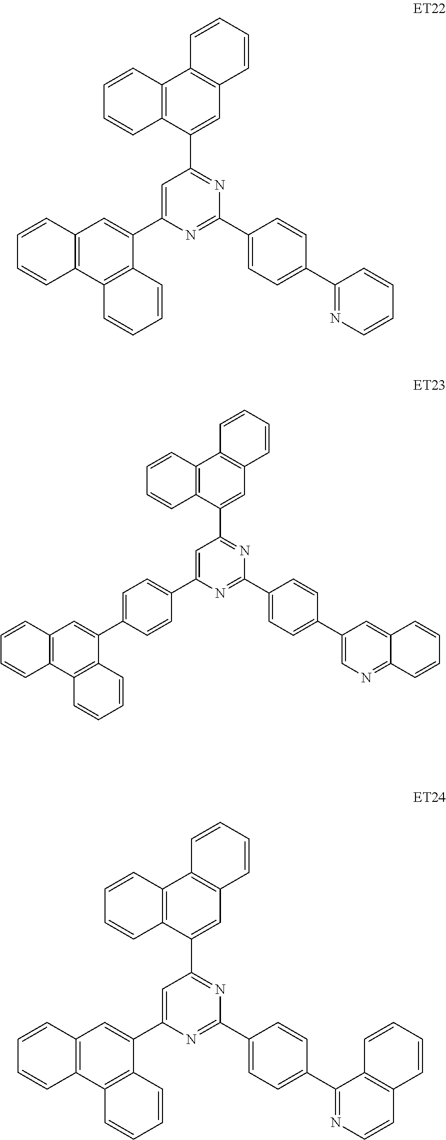 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1]

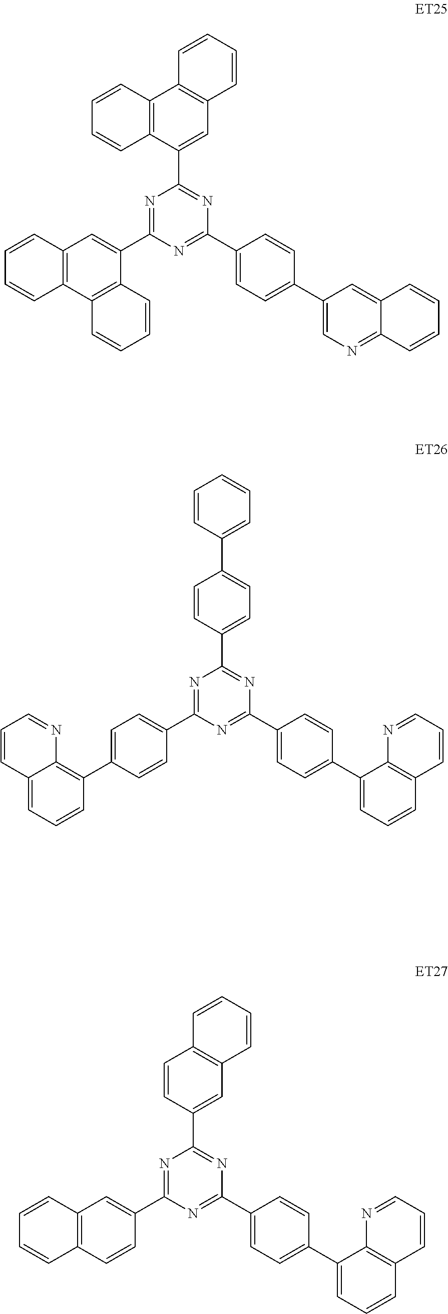 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

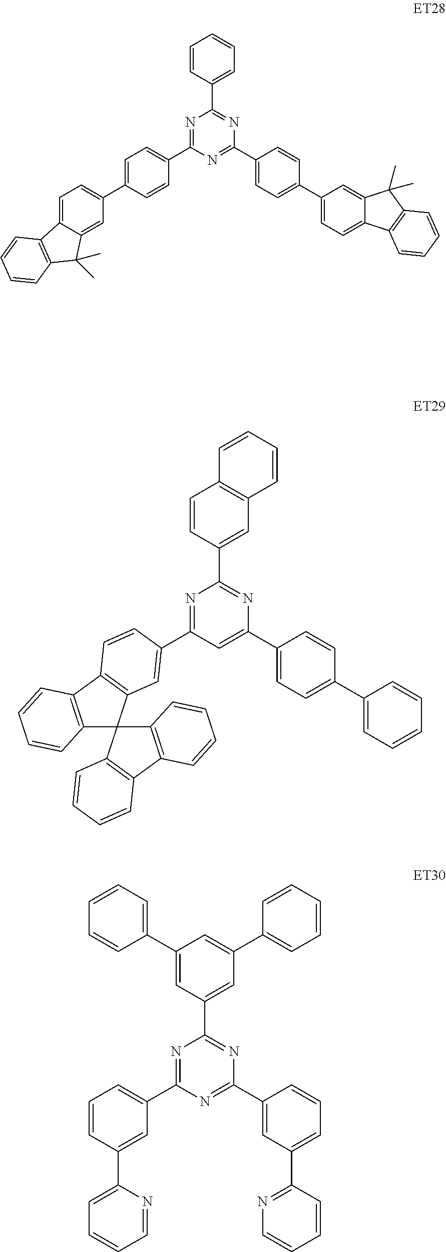 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

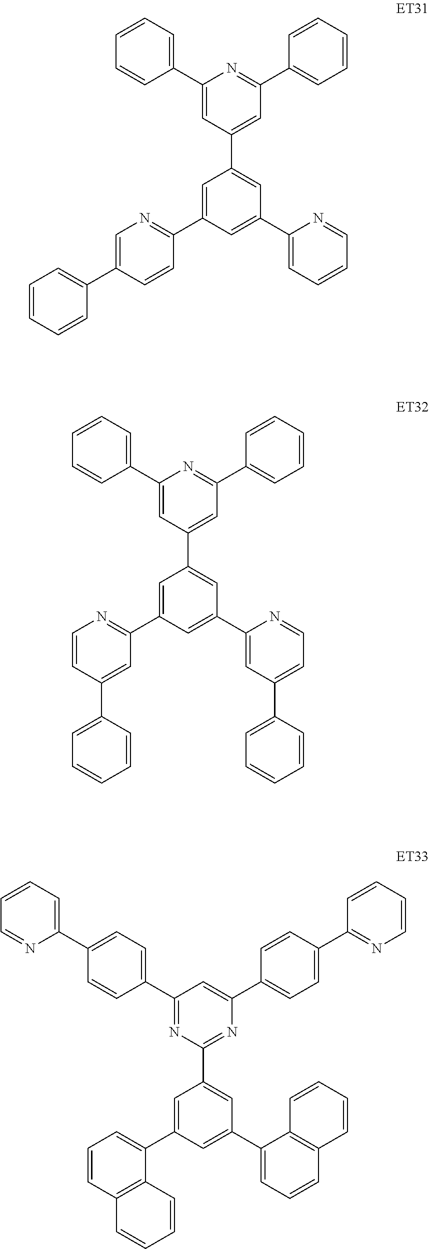 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

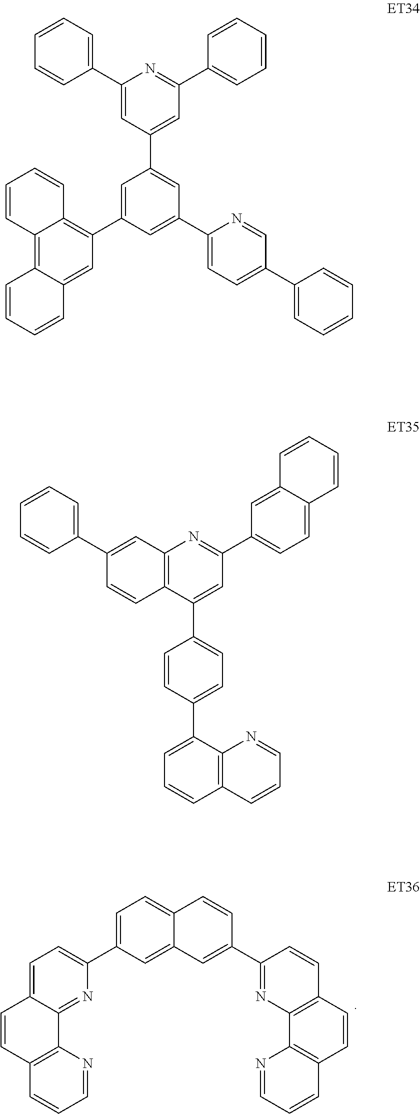 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

In an embodiment, the electron transport region ETR may include: a metal halide such as LiF, NaCl, CsF, RbCl, RbI, CuI, and KI; a lanthanide such as Yb; or a co-deposited material of a metal halide and a lanthanide. For example, the electron transport region ETR may include KI:Yb, RbI:Yb, LiF:Yb, etc., as a co-deposited material. The electron transport region ETR may include a metal oxide such as Li₂O or BaO, or 8-hydroxyl-lithium quinolate (Liq), etc., but embodiments are not limited thereto. The electron transport region ETR may include a mixture material of an electron transport material and an insulating organometallic salt. The organometallic salt may be a material having an energy band gap greater than or equal to about 4 eV. For example, the organometallic salt may include a metal acetate, a metal benzoate, a metal acetoacetate, a metal acetylacetonate, or a metal stearate.

The electron transport region ETR may further include at least one of 2,9-dimethyl-4,7-diphenyl-1,10-phenanthroline (BCP), diphenyl(4-(triphenylsilyl)phenyl)phosphine oxide (TSPO1), and 4,7-diphenyl-1,10-phenanthroline (Bphen) in addition to the above-described materials, but embodiments are not limited thereto.

The electron transport region ETR may include the above-described compounds of the hole transport region in at least one of an electron injection layer EIL, an electron transport layer ETL, and a hole blocking layer HBL.

When the electron transport region ETR includes an electron transport layer ETL, the electron transport layer ETL may have a thickness in a range of about 100 Å to about 1,000 Å. For example, the thickness of the electron transport layer ETL may be in a range of about 150 Å to about 500 Å. If the thickness of the electron transport layer ETL satisfies any of the aforementioned ranges, satisfactory electron transport characteristics may be obtained without a substantial increase in driving voltage. When the electron transport region ETR includes an electron injection layer EIL, the electron injection layer EIL may have a thickness in a range of about 1 Å to about 100 Å. For example, the thickness of the electron injection layer EIL may be in a range of about 3 Å to about 90 Å. If the thickness of the electron injection layer EIL satisfies any of the above-described ranges, satisfactory electron injection characteristics may be obtained without a substantial increase in driving voltage.

The second electrode EL2 may be provided on the electron transport region ETR. The second electrode EL2 may be a common electrode. The second electrode EL2 may be a cathode or an anode, but embodiments are not limited thereto. For example, when the first electrode EL1 is an anode, the second electrode EL2 may be a cathode, and when the first electrode EL1 is a cathode, the second electrode EL2 may be an anode.

The second electrode EL2 may be a transmissive electrode, a transflective electrode, or a reflective electrode. When the second electrode EL2 is a transmissive electrode, the second electrode EL2 may include a transparent metal oxide, for example, indium tin oxide (ITO), indium zinc oxide (IZO), zinc oxide (ZnO), indium tin zinc oxide (ITZO), etc.

When the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, a compound thereof, or a mixture thereof (e.g., AgMg, AgYb, or MgYb). In an embodiment, the second electrode EL2 may have a multilayer structure that includes a reflective film or a transflective film formed of the above-described materials, and a transparent conductive film formed of ITO, IZO, ZnO, ITZO, etc. For example, the second electrode EL2 may include the above-described metal materials, combinations of at least two of the above-described metal materials, oxides of the above-described metal materials, or the like.

Although not shown in the drawings, in an embodiment, the second electrode EL2 may be electrically connected to an auxiliary electrode. If the second electrode EL2 is electrically connected to an auxiliary electrode, resistance of the second electrode EL2 may decrease.

In an embodiment, the light-emitting element ED may further include a capping layer CPL disposed on the second electrode EL2. The capping layer CPL may have a multilayered structure or a single-layered structure.

In an embodiment, the capping layer CPL may include an organic layer or an inorganic layer. For example, when the capping layer CPL includes an inorganic material, the inorganic material may include an alkaline metal compound (e.g., LiF), an alkaline earth metal compound (e.g., MgF₂), SiON, SiNₓ, SiO_{y}, etc.

For example, when the capping layer CPL includes an organic material, the organic material may include α-NPD, NPB, TPD, m-MTDATA, Alq₃, CuPc, N4,N4,N4′,N4′-tetra(biphenyl-4-yl)biphenyl-4,4′-diamine (TPD15), 4,4′,4″-tris(carbazol-9-yl)triphenylamine (TCTA), etc., or may include an epoxy resin, or an acrylate such as methacrylate. However, embodiments are not limited thereto, and the capping layer CPL may include at least one of Compounds P1 to P5:

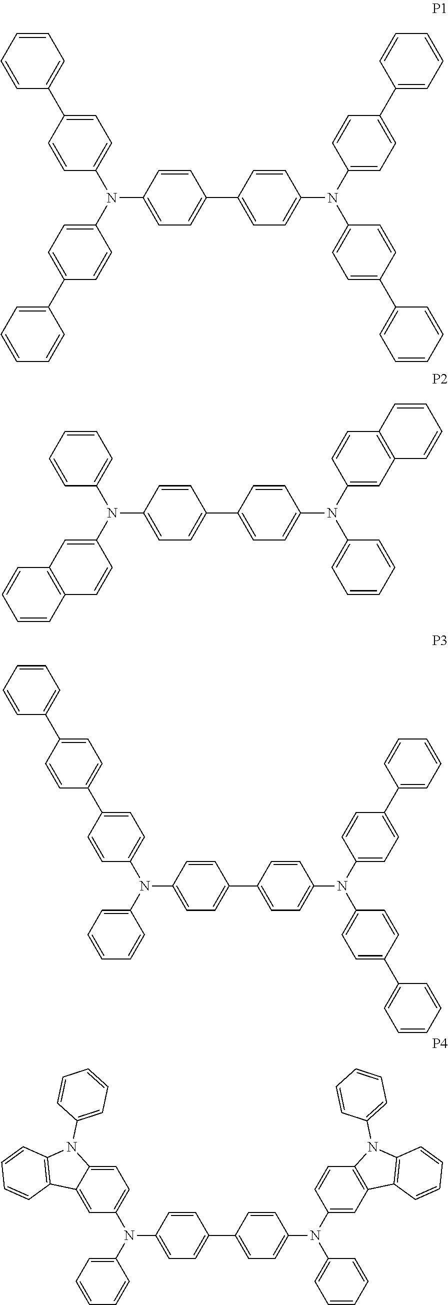 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

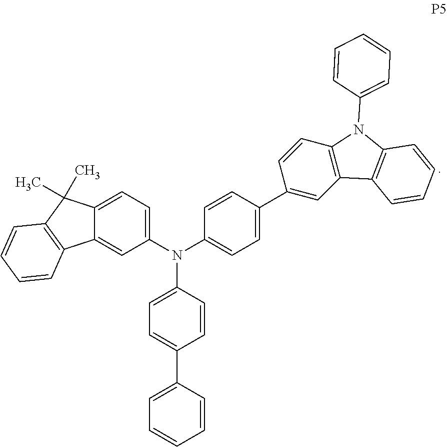 [SMILES: CC1(C)c2ccccc2-c2cc(N(c3ccc(-c4ccccc4)cc3)c3ccc(-c4ccc5c(c4)c4ccccc4n5-c4ccccc4)cc3)ccc21]

In an embodiment, a refractive index of the capping layer CPL may be greater than or equal to about 1.6. For example, the refractive index of the capping layer CPL may be greater than or equal to about 1.6 with respect to light in a wavelength range of about 550 nm to about 660 nm.

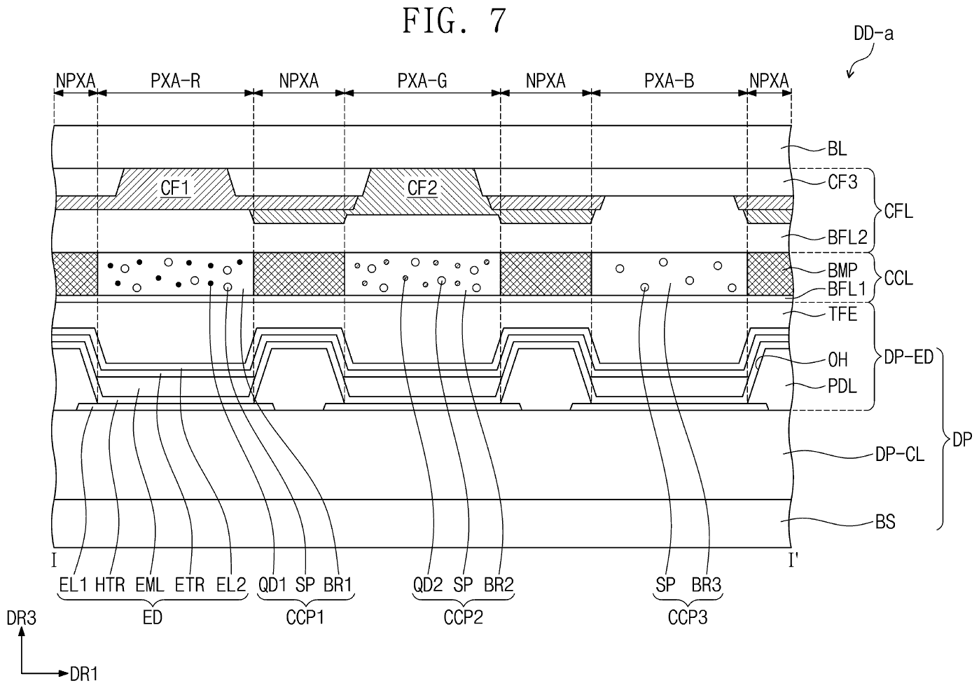

FIG. 7 to FIG. 10 are each a schematic cross-sectional view of a display device according to embodiments. Hereinafter, in the explanation on the display devices according to embodiments, referring to FIG. 7 to FIG. 10, the features that have been described above with respect to FIG. 1 to FIG. 6 will not be explained again, and differing features will be explained.

Referring to FIG. 7, a display device DD-a according to an embodiment may include a display panel DP that includes a display element layer DP-ED, a light control layer CCL disposed on the display panel DP, and a color filter layer CFL. In an embodiment shown in FIG. 7, the display panel DP may include a base layer BS, a circuit layer DP-CL provided on the base layer BS, and a display element layer DP-ED, and the display element layer DP-ED may include a light-emitting element ED.

The light-emitting element ED may include a first electrode EL1, a hole transport region HTR disposed on the first electrode EL1, an emission layer EML disposed on the hole transport region HTR, an electron transport region ETR disposed on the emission layer EML, and a second electrode EL2 disposed on the electron transport region ETR. In embodiments, a structure of the light-emitting element ED shown in FIG. 7 may be the same as a structure of a light-emitting element ED according to one of FIG. 3 to FIG. 6 as described above. The light-emitting element ED shown in FIG. 7 may include the fused polycyclic compound according to an embodiment. The light-emitting element ED including the fused polycyclic compound according to an embodiment may emit light having improved color purity and may exhibit long-life characteristics.

Referring to FIG. 7, the emission layer EML may be disposed in an opening OH defined in a pixel defining film PDL. For example, the emission layer EML, which is separated by the pixel defining film PDL and provided to correspond to each of the light emitting regions PXA-R, PXA-G, and PXA-B, may emit light in a same wavelength range. In the display device DD-a, the emission layer EML may emit blue light. Although not shown in the drawings, in an embodiment, the emission layer EML may be provided as a common layer throughout all of the light emitting regions PXA-R, PXA-G, and PXA-B.

The light control layer CCL may be disposed on the display panel DP. The light control layer CCL may include a light conversion body. The light conversion body may be a quantum dot, a phosphor, or the like. The light conversion body may convert the wavelength of a provided light and emit the resulting light. For example, the light control layer CCL may be a layer that includes a quantum dot or a layer that includes a phosphor.

The light control layer CCL may include light control parts CCP1, CCP2, and CCP3. The light control parts CCP1, CCP2, and CCP3 may be spaced apart from each other.

Referring to FIG. 7, divided patterns BMP may be disposed between the light control parts CCP1, CCP2, and CCP3, which are spaced apart from each other, but embodiments are not limited thereto. FIG. 7 shows that the divided patterns BMP do not overlap the light control parts CCP1, CCP2, and CCP3, but the edges of the light control parts CCP1, CCP2, and CCP3 may overlap at least a portion of the divided patterns BMP.

The light-emitting element ED may emit first color light. The light control layer CCL may include a first light control part CCP1 including a first quantum dot QD1 that converts first color light provided from the light-emitting element ED into second color light, a second light control part CCP2 including a second quantum dot QD2 that converts the first color light into third color light, and a third light control part CCP3 that transmits the first color light.

In an embodiment, the first light control part CCP1 may provide red light that is the second color light, and the second light control part CCP2 may provide green light that is the third color light. The third light control part CCP3 may provide blue light by transmitting the blue light that is the first color light provided from the light-emitting element ED. For example, the first quantum dot QD1 may be a red quantum dot, and the second quantum dot QD2 may be a green quantum dot. The quantum dots QD1 and QD2 may each be a quantum dot as described herein.

The light control layer CCL may further include a scatterer SP. The first light control part CCP1 may include the first quantum dot QD1 and the scatterer SP, the second light control part CCP2 may include the second quantum dot QD2 and the scatterer SP, and the third light control part CCP3 may not include a quantum dot but may include the scatterer SP.

The scatterer SP may be inorganic particles. For example, the scatterer SP may include at least one of TiO₂, ZnO, Al₂O₃, SiO₂, and hollow silica. The scatterer SP may include one of TiO₂, ZnO, Al₂O₃, SiO₂, and hollow silica, or may be a mixture of at least two of TiO₂, ZnO, Al₂O₃, SiO₂, and hollow silica.

The first light control part CCP1, the second light control part CCP2, and the third light control part CCP3 may respectively include base resins BR1, BR2, and BR3 in which the quantum dots QD1 and QD2 and the scatterer SP are dispersed. In an embodiment, the first light control part CCP1 may include the first quantum dot QD1 and the scatterer SP dispersed in a first base resin BR1, the second light control part CCP2 may include the second quantum dot QD2 and the scatterer SP dispersed in a second base resin BR2, and the third light control part CCP3 may include the scatterer SP dispersed in a third base resin BR3.

The base resins BR1, BR2, and BR3 are mediums in which the quantum dots QD1 and QD2 and the scatterer SP are dispersed, and may include various resin compositions, which may be referred to as a binder. For example, the base resins BR1, BR2, and BR3 may be acrylic-based resins, urethane-based resins, silicone-based resins, epoxy-based resins, etc. The base resins BR1, BR2, and BR3 may each be a transparent resin. In an embodiment, the first base resin BRI, the second base resin BR2, and the third base resin BR3 may be the same as or different from each other.

The light control layer CCL may include a barrier layer BFL1. The barrier layer BFL1 may prevent the penetration of moisture and/or oxygen (hereinafter, referred to as ‘moisture/oxygen’). The barrier layer BFL1 may block the light control parts CCP1, CCP2, and CCP3 from exposure to moisture/oxygen. The barrier layer BFL1 may cover the light control parts CCP1, CCP2, and CCP3. In an embodiment, the barrier layer BFL2 may be provided between the light control parts CCP1, CCP2, and CCP3, and the color filter layer CFL.

The barrier layers BFL1 and BFL2 may each independently include at least one inorganic layer. For example, the barrier layers BFL1 and BFL2 may each independently include an inorganic material. For example, the barrier layers BFL1 and BFL2 may each independently include a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, a silicon oxynitride, a metal thin film that secures light transmittance, etc. The barrier layers BFL1 and BFL2 may each independently further include an organic film. The barrier layers BFL1 and BFL2 may have a single-layered structure or a multilayered structure.

In the display device DD-a, the color filter layer CFL may be disposed on the light control layer CCL. In an embodiment, the color filter layer CFL may be disposed (e.g., directly disposed) on the light control layer CCL. For example, the barrier layer BFL2 may be omitted.

The color filter layer CFL may include filters CF1, CF2, and CF3. The color filter layer CFL may include a first filter CF1 that transmits the second color light, a second filter CF2 that transmits the third color light, and a third filter CF3 that transmits the first color light. For example, the first filter CF1 may be a red filter, the second filter CF2 may be a green filter, and the third filter CF3 may be a blue filter. The filters CF1, CF2, and CF3 may each include a polymeric photosensitive resin and a pigment or dye. The first filter CF1 may include a red pigment or dye, the second filter CF2 may include a green pigment or dye, and the third filter CF3 may include a blue pigment or dye.

However, embodiments are not limited thereto, and the third filter CF3 may not include a pigment or dye. The third filter CF3 may include a polymeric photosensitive resin and may not include a pigment or dye. The third filter CF3 may be transparent. The third filter CF3 may be formed of a transparent photosensitive resin.

In an embodiment, the first filter CF1 and the second filter CF2 may each be a yellow filter. The first filter CF1 and the second filter CF2 may not be provided as separate filters and may be provided as a unitary filter.

Although not shown in the drawings, in an embodiment, the color filter layer CFL may further include a light shielding part (not shown). The light shielding part (not shown) may be a black matrix. The light shielding part (not shown) may include an organic light shielding material or an inorganic light shielding material, each including a black pigment or a black dye. The light shielding part (not shown) may prevent light leakage, and may separate boundaries between adjacent filters CF1, CF2, and CF3. In an embodiment, the light shielding part (not shown) may be formed of a blue filter.

The first, second, and third filters CF1, CF2, and CF3 may be respectively disposed in the red light emitting region PXA-R, the green light emitting region PXA-G, and the blue light emitting region PXA-B.

A base substrate BL may be disposed on the color filter layer CFL. The base substrate BL may provide a base surface on which the color filter layer CFL, the light control layer CCL, and the like are disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

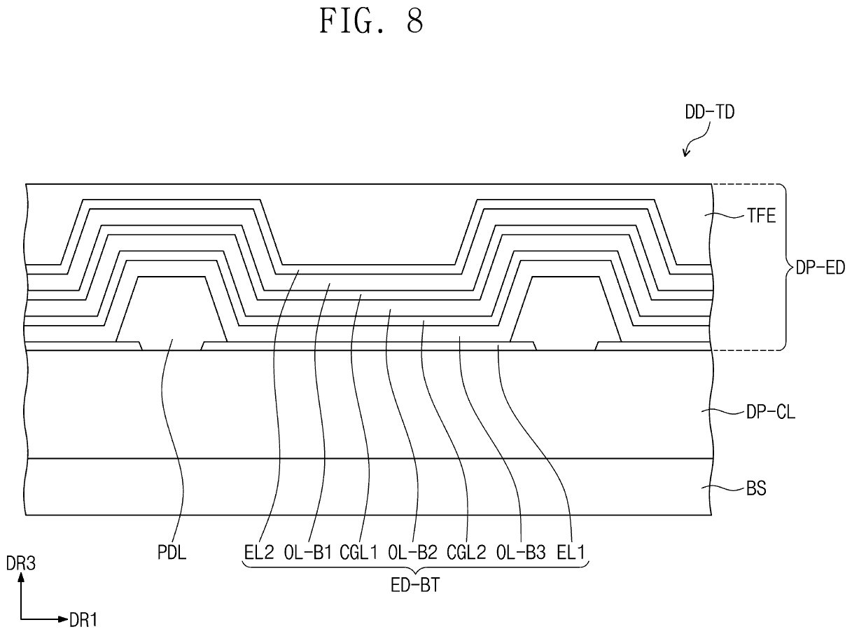

FIG. 8 is a schematic cross-sectional view of a portion of a display device according to an embodiment. In the display device DD-TD according to an embodiment, a light-emitting element ED-BT may include light emitting structures OL-B1, OL-B2, and OL-B3. The light-emitting element ED-BT may include a first electrode EL1 and a second electrode EL2 that face each other, and light emitting structures OL-B1, OL-B2, and OL-B3, which are stacked in a thickness direction between the first electrode EL1 and the second electrode EL2. The light emitting structures OL-B1, OL-B2, and OL-B3 may each include a hole transport region HTR, an emission layer EML (FIG. 7), and an electron transport region ETR, which may be disposed in that order between the first electrode EL1 and the second electrode EL2.

For example, the light-emitting element ED-BT included in the display device DD-TD may be a light-emitting element having a tandem structure that includes multiple emission layers.

At least one of the light emitting structures OL-B1, OL-B2, and OL-B3 may include the fused polycyclic compound according to an embodiment. The light-emitting element ED-BT including the fused polycyclic compound according to an embodiment may emit light having improved color purity and exhibit long-life characteristics.

In an embodiment illustrated in FIG. 8, light emitted from the light emitting structures OL-B1, OL-B2, and OL-B3 may each be blue light. However, embodiments are not limited thereto, and the light emitted from the light emitting structures OL-B1, OL-B2, and OL-B3 may have wavelength ranges that are different from each other. For example, the light-emitting element ED-BT that includes the light emitting structures OL-B1, OL-B2, and OL-B3, which emit light having wavelength ranges that are different from each other, may emit white light.

Charge generation layers CGL1 and CGL2 may be respectively disposed between two adjacent light emitting structures among the light emitting structures OL-B1, OL-B2, and OL-B3. The charge generation layers CGL1 and CGL2 may each independently include a p-type charge generation layer and/or an n-type charge generation layer.

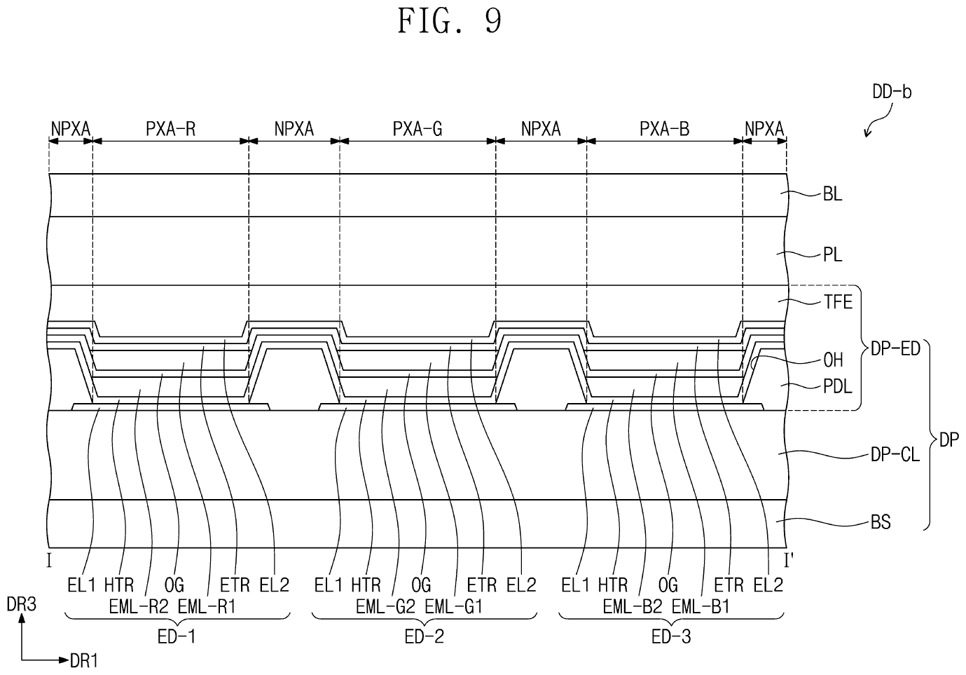

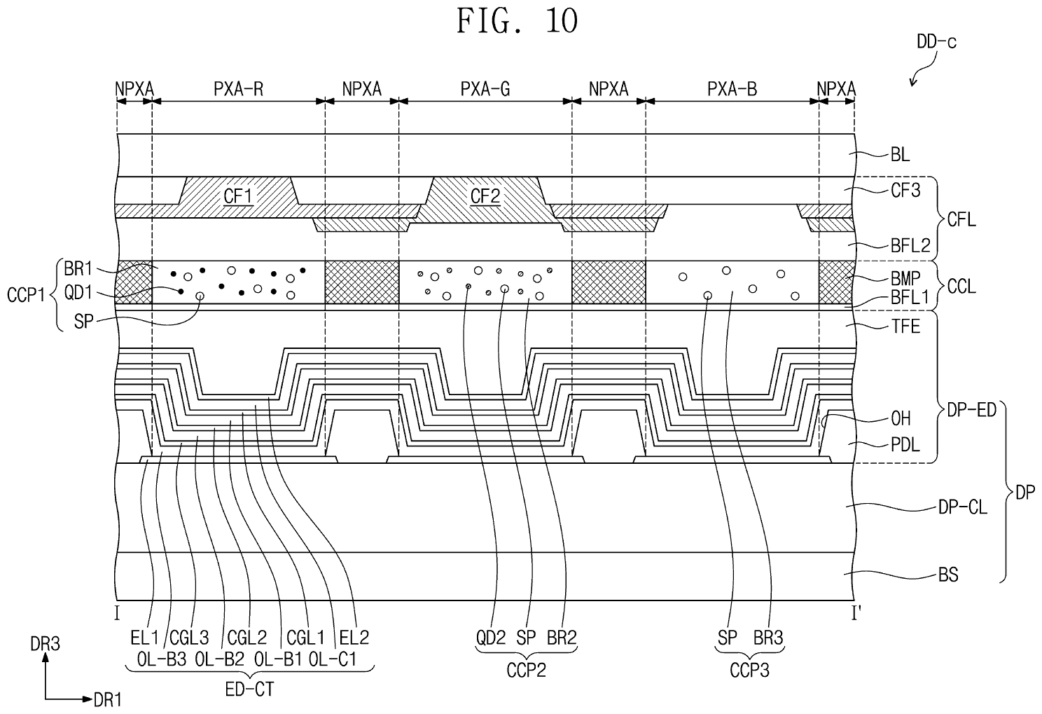

Referring to FIG. 9, a display device DD-b according to an embodiment may include light-emitting elements ED-1, ED-2, and ED-3, in which two emission layers are stacked. In comparison to the display device DD shown in FIG. 2, an embodiment shown in FIG. 9 is different at least in that the first to third light-emitting elements ED-1, ED-2, and ED-3 each include two emission layers that are stacked in a thickness direction. The two emission layers in each of the first to third light-emitting elements ED-1, ED-2, and ED-3 may emit light having a same wavelength range.

At least one of the light-emitting elements ED-1, ED-2, and ED-3 may include the fused polycyclic compound according to an embodiment. At least one of the light-emitting elements ED-1, ED-2, and ED-3, including the fused polycyclic compound according to an embodiment may emit light having improved color purity and exhibit long-life characteristics.

The first light-emitting element ED-1 may include a first red emission layer EML-R1 and a second red emission layer EML-R2. The second light-emitting element ED-2 may include a first green emission layer EML-G1 and a second green emission layer EML-G2. The third light-emitting element ED-3 may include a first blue emission layer EML-B1 and a second blue emission layer EML-B2. An emission auxiliary part OG may be disposed between the first red emission layer EML-R1 and the second red emission layer EML-R2, between the first green emission layer EML-G1 and the second green emission layer EML-G2, and between the first blue emission layer EML-B1 and the second blue emission layer EML-B2.

The emission auxiliary part OG may have a single-layered structure or a multilayered structure. The emission auxiliary part OG may include a charge generation layer. For example, the emission auxiliary part OG may include an electron transport region, a charge generation layer, and a hole transport region, which may be stacked in that order. The emission auxiliary part OG may be provided as a common layer throughout the first to third light-emitting elements ED-1, ED-2, and ED-3. However, embodiments are not limited thereto, and the emission auxiliary part OG may be provided by being patterned within the openings OH defined in the pixel defining film PDL.

The first red emission layer EML-R1, the first green emission layer EML-G1, and the first blue emission layer EML-B1 may each be disposed between the emission auxiliary part OG and the electron transport region ETR. The second red emission layer EML-R2, the second green emission layer EML-G2, and the second blue emission layer EML-B2 may each be disposed between the hole transport region HTR and the emission auxiliary part OG.

The first light-emitting element ED-1 may include the first electrode EL1, the hole transport region HTR, the second red emission layer EML-R2, the emission auxiliary part OG, the first red emission layer EML-R1, the electron transport region ETR, and the second electrode EL2, which may be stacked in that order. The second light-emitting element ED-2 may include the first electrode EL1, the hole transport region HTR, the second green emission layer EML-G2, the emission auxiliary part OG, the first green emission layer EML-G1, the electron transport region ETR, and the second electrode EL2, which may be stacked in that order. The third light-emitting element ED-3 may include the first electrode EL1, the hole transport region HTR, the second blue emission layer EML-B2, the emission auxiliary part OG, the first blue emission layer EML-B1, the electron transport region ETR, and the second electrode EL2, which may be stacked in that order.

An optical auxiliary layer PL may be disposed on the display element layer DP-ED. The optical auxiliary layer PL may include a polarizing layer. The optical auxiliary layer PL may be disposed on the display panel DP and may control light that is reflected at the display panel DP from an external light. Although not shown in the drawings, the optical auxiliary layer PL in the display device DD-b may be omitted.

In contrast to FIG. 8 and FIG. 9, FIG. 10 shows a display device DD-c that is different at least in that it includes four light emitting structures OL-B1, OL-B2, OL-B3, and OL-C1. A light-emitting element ED-CT may include a first electrode EL1 and a second electrode EL2 that face each other, and first to fourth light emitting structures OL-B1, OL-B2, OL-B3, and OL-C1 that are stacked in a thickness direction between the first electrode EL1 and the second electrode EL2. At least one of the first to fourth light emitting structures OL-B1, OL-B2, OL-B3, and OL-C1 may include the fused polycyclic compound according to an embodiment. The light-emitting element ED-CT including the fused polycyclic compound according to an embodiment may emit light having improved color purity and exhibit long-life characteristics.

Charge generation layers CGL1, CGL2, and CGL3 may be respectively disposed between two adjacent light emitting structures among the first to fourth light emitting structures OL-B1, OL-B2, OL-B3, and OL-C1. Among the four light emitting structures, the first to third light emitting structures OL-B1, OL-B2, and OL-B3 may each emit blue light, and the fourth light emitting structure OL-C1 may emit green light. However, embodiments are not limited thereto, and the first to fourth light emitting structures OL-B1, OL-B2, OL-B3, and OL-C1 may emit light having wavelength regions that are different from each other.

The charge generation layers CGL1, CGL2, and CGL3 may each independently include a p-type charge generation layer and/or an n-type charge generation layer.

In an embodiment, an electronic apparatus may include a display device that includes multiple light-emitting elements, and a control part that controls the display device. The electronic apparatus may be a device that is activated according to electrical signals. The electronic apparatus may include display devices according to various embodiments. Examples of an electronic apparatus may include large, medium-sized, and small devices, such as a television, a monitor, a billboard, a personal computer, a laptop computer, a personal digital terminal, a display apparatus for a vehicle, a game console, a portable electronic apparatus, and a camera.

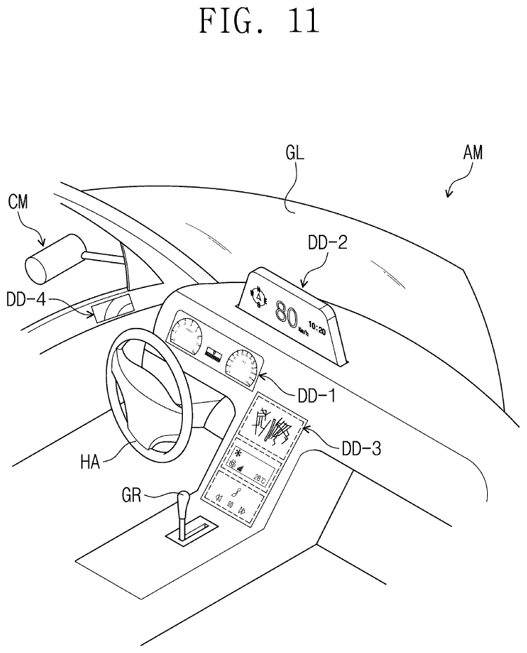

FIG. 11 is a schematic diagram of a vehicle AM in which first to fourth display devices DD-1, DD-2, DD-3, and DD-4 are disposed. At least one of the first to fourth display devices DD-1, DD-2, DD-3, and DD-4 may have a structure according to one of display devices DD, DD-TD, DD-a, DD-b, and DD-c, as described above with reference to FIGS. 1, 2, and 7 to 10.

In FIG. 11, an automobile is shown as a vehicle AM, but this is only an example, and the first to fourth display devices DD-1, DD-2, DD-3, and DD-4 may be disposed in various transportation means such as a bicycle, a motorcycle, a train, a ship, and an airplane. In an embodiment, at least one of the first to fourth display devices DD-1, DD-2, DD-3, and DD-4 having a structure according to one of display devices DD, DD-TD, DD-a, DD-b, and DD-c may be included in a personal computer, a laptop computer, a personal digital terminal, a game console, a portable electronic apparatus, a television, a monitor, a billboard, or the like. However, these are only examples, and the display device may be included in other electronic apparatuses.

At least one of the first to fourth display devices DD-1, DD-2, DD-3, and DD-4 may each independently include the light-emitting element ED according to an embodiment as described in reference to any of FIG. 3 to FIG. 6. At least one of the first to fourth display devices DD-1, DD-2, DD-3, and DD-4 may include the fused polycyclic compound according to an embodiment. A display device that includes the fused polycyclic compound according to an embodiment (e.g., at least one of the first to fourth display devices DD-1, DD-2, DD-3, and DD-4) may exhibit excellent display quality.

Referring to FIG. 11, the vehicle AM may include a steering wheel HA and a gearshift GR for driving the vehicle AM. The vehicle AM may include a front window GL that is disposed so as to face a driver.

A first display device DD-1 may be disposed in a first region that overlaps the steering wheel HA. For example, the first display device DD-1 may be a digital cluster that displays first information of the vehicle AM. The first information may include a first scale that indicates a driving speed of the vehicle AM, a second scale that indicates an engine speed (for example, revolutions per minute (RPM)), an image that represents a fuel gauge, etc. The first scale and the second scale may each be represented as a digital image.

A second display device DD-2 may be disposed in a second region facing the driver's seat that overlaps the front window GL. The driver's seat may be a seat in which the steering wheel HA is disposed. For example, the second display device DD-2 may be a head up display (HUD) that displays second information of the vehicle AM. The second display device DD-2 may be optically transparent. The second information may include digital numbers that indicate a driving speed, and may further include information such as the current time. Although not shown in the drawings, the second information of the second display device DD-2 may be projected onto the front window GL to be displayed.

A third display device DD-3 may be disposed in a third region that is adjacent to the gearshift GR. For example, the third display device DD-3 may be disposed between the driver's seat and the passenger seat and may be a center information display (CID) for a vehicle which displays third information. The passenger seat may be a seat that is spaced apart from the driver's seat, and the gearshift GR may be disposed between the driver's seat and the passenger seat. The third information may include information about traffic (e.g., navigation information), about music or radio that is playing, or a video (or an image) that is displayed, about temperatures inside the vehicle AM, etc.

A fourth display device DD-4 may be spaced apart from the steering wheel HA and the gearshift GR, and may be disposed in a fourth region adjacent to a side of the vehicle AM. For example, the fourth display device DD-4 may be a digital side-view mirror that displays fourth information. The fourth display device DD-4 may display an image that is external to the vehicle AM, which may be taken by a camera module CM disposed on the exterior of the vehicle AM. The fourth information may include an external image of the vehicle AM.

The first to fourth information as described above are only provided as examples, and the first to fourth display devices DD-1, DD-2, DD-3, and DD-4 may further display information about the interior and exterior of the vehicle AM. The first to fourth information may include information that is different from each other. However, embodiments are not limited thereto, and a portion of the first to fourth information may include a same information as one another.

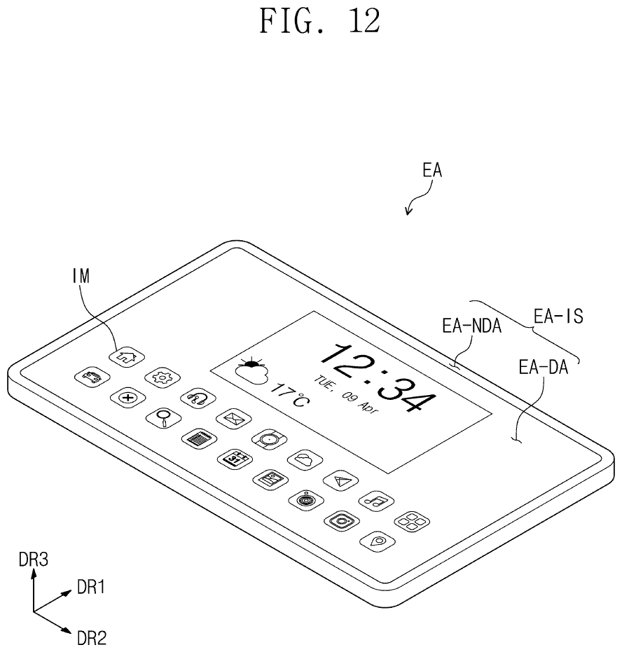

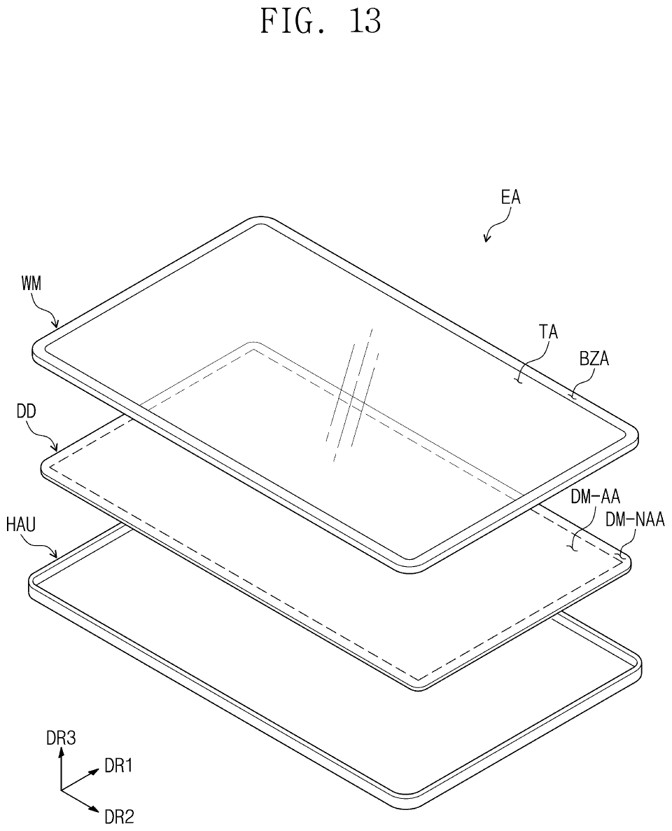

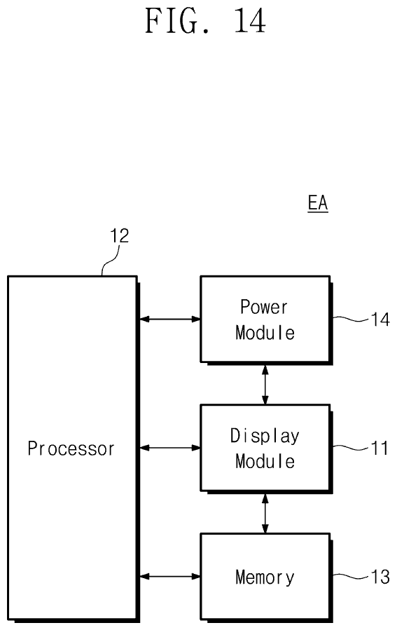

FIG. 12 is a schematic perspective view of an electronic apparatus according to an embodiment. FIG. 13 is an exploded schematic perspective view of an electronic apparatus according to an embodiment.

As shown in FIG. 12, an electronic apparatus EA may display an image IM through a display surface EA-IS. The image IM may be a dynamic image or a static image. The display surface EA-IS may be parallel to a plane defined by a first direction axis DR1 and a second direction axis DR2. FIG. 12 shows that the electronic apparatus EA has a flat display surface EA-IS, but embodiments are not limited thereto. For example, the electronic apparatus EA may have a curved display surface or a three-dimensional display surface. In an embodiment, a three-dimensional display surface may include multiple display areas that are disposed or positioned in different directions from each other.

The display surface EA-IS may include a display area EA-DA and a non-display area EA-NDA. The electronic apparatus EA may display an image IM through the display area EA-DA.

The non-display area EA-NDA may have a selected or given color. The non-display area EA-NDA may be adjacent to the display area EA-DA. In an embodiment, the non-display area EA-NDA may surround the display area EA-DA. Accordingly, the shape of the display area EA-DA may be substantially defined by the non-display area EA-NDA. However, FIG. 12 is only an illustration, and the non-display area EA-NDA may be disposed so that it is adjacent to only a side of the display area EA-DA, or the non-display area EA-NDA may be omitted.

Referring to FIG. 13, the electronic apparatus EA may include a display device DD, a window member WM, and a housing HAU.

The window member WM may cover an outer surface of the electronic apparatus EA. For example, the window member WM may cover the entire outer surface of the electronic apparatus EA. The window member WM may include a transparent area TA and a bezel area BZA. The front surface of the window member WM that includes the transparent area TA and the bezel area BZA may correspond to a front surface of the electronic apparatus EA. The transparent area TA may correspond to the display area EA-DA of the electronic apparatus EA shown in FIG. 12, and the bezel area BZA may correspond to the non-display area EA-NDA of the electronic apparatus EA shown in FIG. 12.

The transparent area TA may be an optically transparent area. The bezel area BZA may be an area having a relatively low light transmittance, as compared to the transparent area TA. The bezel area BZA may have a selected or given color. The bezel area BZA may be adjacent to the transparent area TA and may surround the transparent area TA. The bezel area BZA may define the shape of the transparent area TA. However, embodiments are not limited thereto, and the bezel area BZA may be disposed so that it is adjacent to only a side of the transparent area TA, or a portion thereof may be omitted.

The housing HAU may include a material having relatively high rigidity. For example, the housing HAU may include a frame and/or a plate made of glass, plastic, or metal. The frames and/or plates may be provided as multiple pieces. The housing HAU may provide an enclosure for the display device DD. The display device DD may be contained in the enclosure and protected from external impact.

The display device DD may have a configuration according to one of display devices DD, DD-TD, DD-a, DD-b, and DD-c as described above with reference to FIGS. 1, 2, and 7 to 10. The display device DD may include at least one light emitting element ED according to an embodiment, as described with reference to any of FIGS. 3 to 6. Accordingly, the electronic apparatus EA including the display device DD according to an embodiment may exhibit excellent reliability.

An active area DM-AA and a peripheral area DM-NAA may be defined in the display device DD. The active area DM-AA may overlap the display area EA-DA shown in FIG. 12, and the peripheral area DM-NAA may overlap the non-display area EA-NDA shown in FIG. 12.

The active area DM-AA may be an area that is activated according to an electrical signal. The peripheral area DM-NAA may be an area that is adjacent to at least one side of the active area DM-AA. The active area DM-AA may include the non-light emitting region NPXA and the light emitting regions PXA-R, PXA-G, and PXA-B, illustrated in FIG. 1. The peripheral area DM-NAA may surround the active area DM-AA. However, embodiments are not limited thereto. In another embodiment, at least a portion of the peripheral areas DM-NAA may be omitted. A driving circuit or driving wiring for driving the active area DM-AA may be disposed in the peripheral area DM-NAA.

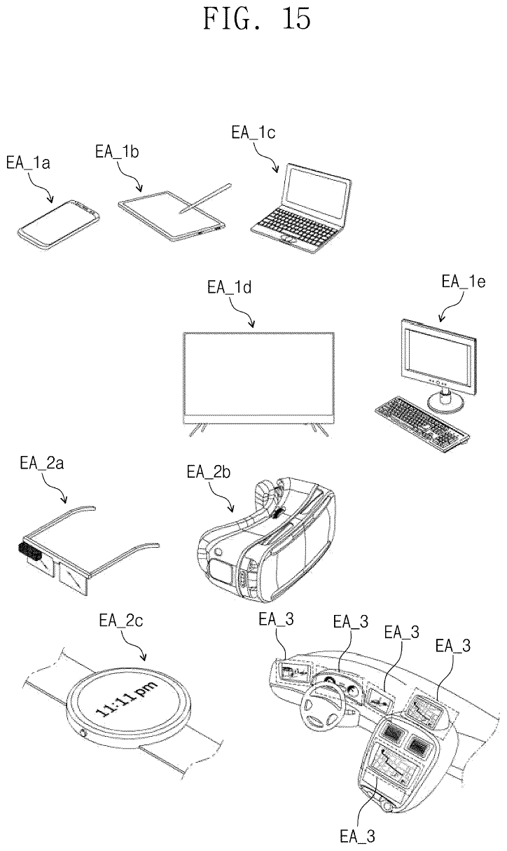

The electronic apparatus EA according to an embodiment includes the display device DD as described above, and may further include a module or device having an additional function. FIG. 14 is a block diagram of an electronic apparatus EA according to an embodiment. Referring to FIG. 14, an electronic apparatus EA according to an embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), or a controller. The power module 14 may include a power supply module such as a power adapter or a battery device, and a power conversion module that converts the power supplied by the power supply module and generates power necessary for operation of the electronic apparatus EA.

The memory 13 may store data for operation of the processor 12 or the display module 11. When the processor 12 executes an application stored in the memory 13, an image data signal and/or an input control signal may be transmitted to the display module 11, and the display module 11 may process the received signal and output image information through a display screen.

In an embodiment, one or more components of the electronic apparatus EA may be included in the display module 11 according to an embodiment. In an embodiment, one or more of the individual modules that are functionally included in one module may be included in the display device DD, and other modules may be provided separately from the display device DD. For example, the display device DD may include the display module 11, and the processor 12, the memory 13, and the power module 14 may be included in another portion of the electronic apparatus EA.

FIG. 15 is a schematic diagram of electronic apparatuses according to embodiments. Referring to FIG. 15, examples of an electronic apparatus EA according to an embodiment may include not only electronic apparatuses for displaying images, e.g., a smartphone EA_1a, a tablet computer EA_1b, a laptop computer EA_1c, TV EA_1d, and a monitor for a desk computer EA_1e, and examples of such electronic apparatuses may also include wearable electronic apparatuses including display devices, e.g., smart glasses EA_2a, a head mounted display EA_2b, and a smart watch EA_2c, and vehicle electronic apparatuses EA_3 including display devices, e.g., a vehicle instrument panel, a center fascia, a center information display (CID) disposed on a dashboard, and a room mirror display.

Hereinafter, a fused polycyclic compound according to an embodiment and a light-emitting element according to an embodiment will be described with reference to the Examples and the Comparative Examples. The Examples described below are only provided to assist in understanding the disclosure, and the scope thereof is not limited thereto.

### EXAMPLES AND COMPARATIVE EXAMPLES

### 1. Synthesis of Fused Polycyclic Compound

A synthesis method of the fused polycyclic compound according to an embodiment will be explained in detail by describing synthesis methods for Compounds 4, 22, 24, 34, 37, 43, 73, and 79. The synthesis methods of the fused polycyclic compound according to embodiments are provided as examples, and the synthesis method of the fused polycyclic compound according to embodiments are not limited to the Examples.

### (1) Synthesis of Compound 4

Compound 4 according to an embodiment may be synthesized by, for example, Reaction Scheme 1.

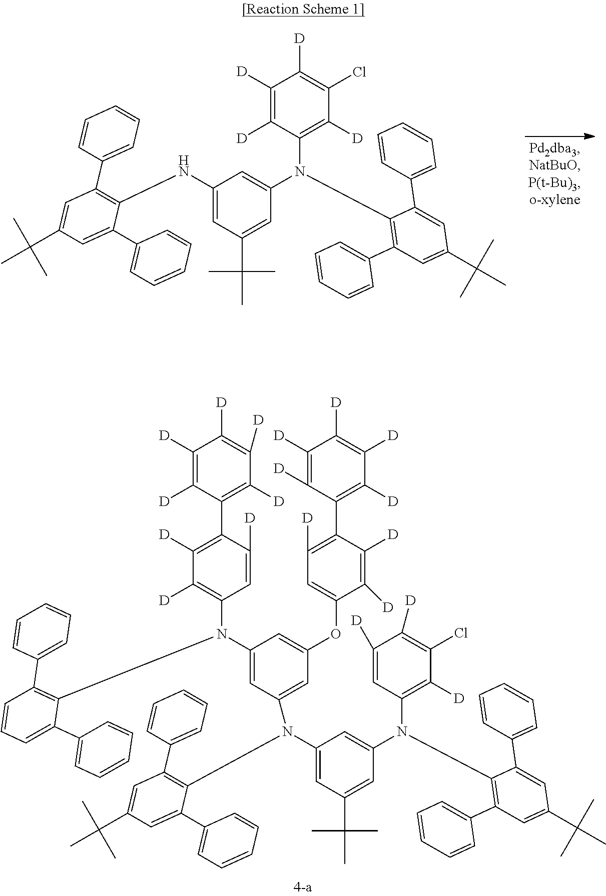 [SMILES: [2H]c1c([2H])c(Cl)c([2H])c(N(c2cc(Nc3c(-c4ccccc4)cc(C(C)(C)C)cc3-c3ccccc3)cc(C(C)(C)C)c2)c2c(-c3ccccc3)cc(C(C)(C)C)cc2-c2ccccc2)c1[2H] ; [2H]c1cc(N(c2cc(N(c3cc(Oc4cc([2H])c(-c5c([2H])c([2H])c([2H])c([2H])c5[2H])c([2H])c4[2H])cc(N(c4cc([2H])c(-c5c([2H])c([2H])c([2H])c([2H])c5[2H])c([2H])c4[2H])c4c(-c5ccccc5)cccc4-c4ccccc4)c3)c3c(-c4ccccc4)cc(C(C)(C)C)cc3-c3ccccc3)cc(C(C)(C)C)c2)c2c(-c3ccccc3)cc(C(C)(C)C)cc2-c2ccccc2)c([2H])c(Cl)c1[2H]]

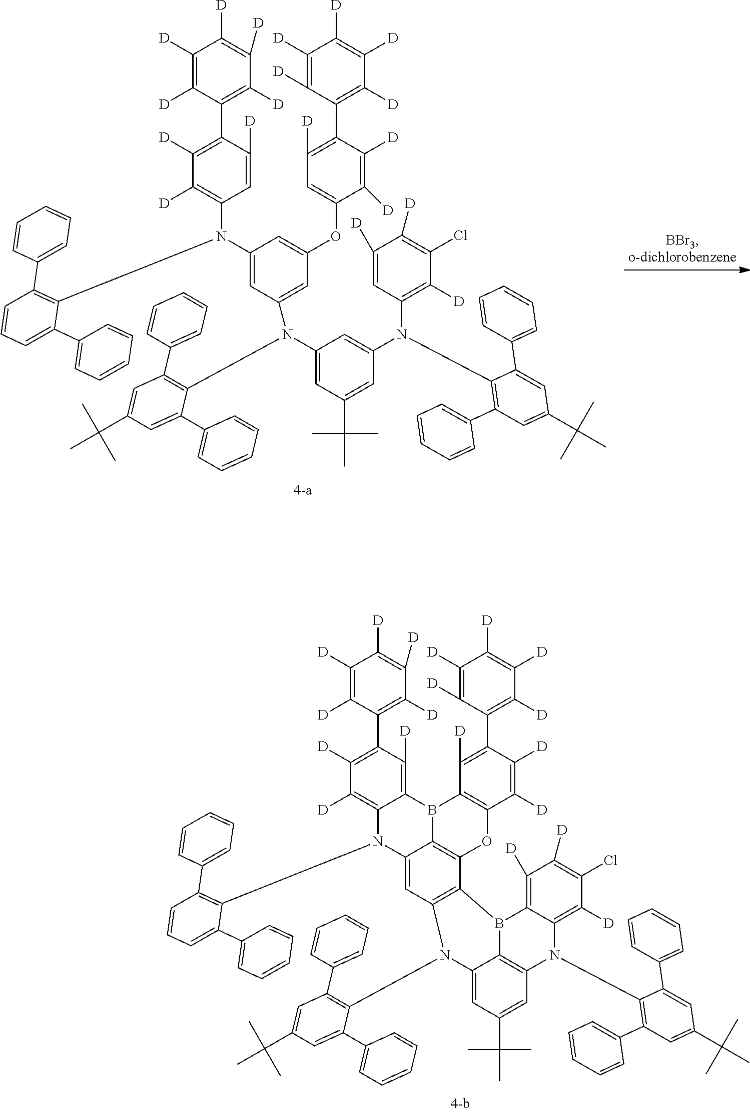

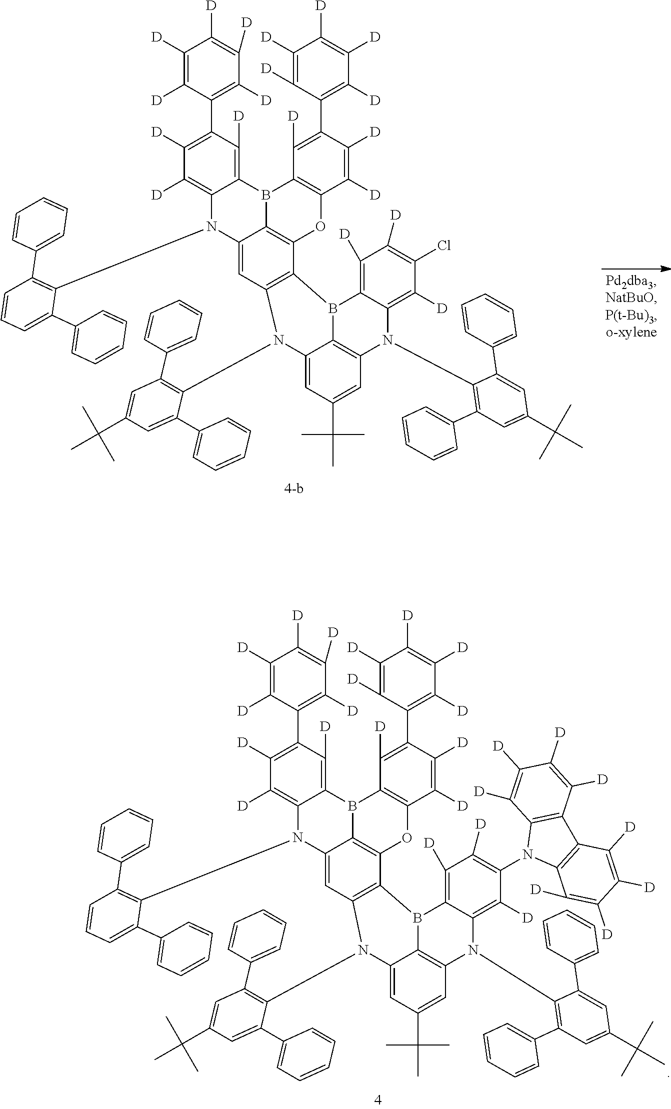

### Synthesis of Intermediate Compound 4-a

Under an argon atmosphere, in a flask of 2 L, 5-(tert-butyl)-N1,N3-bis(5′-(tert-butyl)-[1,1′:3′,1″-terphenyl]-2′-yl)-N1-(3-chlorophenyl-2,4,5,6-d4)benzene-1,3-diamine (10 g, 11.7 mmol), N-([1,1′-biphenyl]-4-yl-2,2′,3,3′,4′,5′,6,6′-d8)-N-(3-(([1,1′-biphenyl]-4-yl-2,2′,3,3′,4′,5′,6,6′-d8)oxy)-5-bromophenyl)-[1,1′:3′,1″-terphenyl]-2′-amine (8.7 g, 11.7 mmol), Pd₂dba₃ (1.6 g, 1.9 mmol), tris-tert-butyl phosphine (P(t-Bu)₃, 1.6 mL, 3.8 mmol), and sodium tert-butoxide (Na tBuO, 5.8 g, 60 mmol) were added and dissolved in 200 mL of o-xylene, and the reaction solution was stirred at about 140° C. for about 2 hours. After cooling the solution, water (1 L) and ethyl acetate (300 mL) were added, and the obtained mixture was subjected to extraction to collect an organic layer, dried over MgSO₄, and filtered. A solvent was removed from the filtered solution under reduced pressure, and the obtained solid was purified and separated by column chromatography using silica gel with dichloromethane (CH₂Cl₂) and hexane as a developing solvent to obtain Intermediate Compound 4-a (white solids, 9.3 g, 53%).

ESI-LCMS: [M]⁺: C₁₀₈H₇₃D₁₉ClN₃O. 1502.5181.

### Synthesis of Intermediate Compound 4-b

Under an argon atmosphere, in a flask of 1 L, Intermediate Compound 4-a (9 g, 6 mmol) was added and dissolved in 50 mL of o-dichlorobenzene, and BBr₃ (2.5 equiv.) was added. The reaction solution was stirred at about 140° C. for about 12 hours. After cooling the solution, triethylamine was added to terminate the reaction, and a solvent was removed under reduced pressure. The obtained solids were purified and separated by column chromatography using silica gel with CH₂Cl₂ and hexane as a developing solvent to obtain Intermediate Compound 4-b (yellow solids: 2.9 g, 32%).

ESI-LCMS: [M]⁺: C₁₀₈H₆₇D₁₉B₂ClN₃O. 1516.7862

### Synthesis of Compound 4

Under an argon atmosphere, in a flask of 2 L, Intermediate Compound 4-b (2.5 g, 1.6 mmol), 9H-carbazole-1,2,3,4,5,6,7,8-d8 (0.28 g, 1.6 mmol), Pd₂dba₃ (0.14 g, 0.16 mmol), tris-tert-butyl phosphine (P(t-Bu)₃, 0.14 mL, 0.32 mmol), and sodium tert-butoxide (Na tBuO, 0.5 g, 5 mmol) were added and dissolved in 20 mL of o-xylene, and the reaction solution was stirred at about 140° C. for about 2 hours. After cooling the solution, water (1 L) and ethyl acetate (300 mL) were added, and the obtained mixture was subjected to extraction to collect an organic layer, was dried over MgSO₄, and filtered. A solvent was removed from the filtered solution under reduced pressure, and the obtained solid was purified and separated by column chromatography using silica gel with CH₂Cl₂ and hexane as a developing solvent to obtain Compound 4 (yellow solids, 2 g, 75%).

ESI-LCMS: [M]⁺: C₁₂₀H₆₇D₂₇B₂N₄O. 1656.8826.

1H-NMR (CDCl₃): δ=8.22 (d, 2H), 7.99 (s, 4H), 7.46 (m, 18H), 7.08 (m, 12H), 7.00 (s, 2H), 6.55 (s, 1H), 1.32 (s, 9H), 1.22 (s, 18H)

### (2) Synthesis of Compound 22

Compound 22 according to an embodiment may be synthesized by, for example, Reaction Scheme 2.

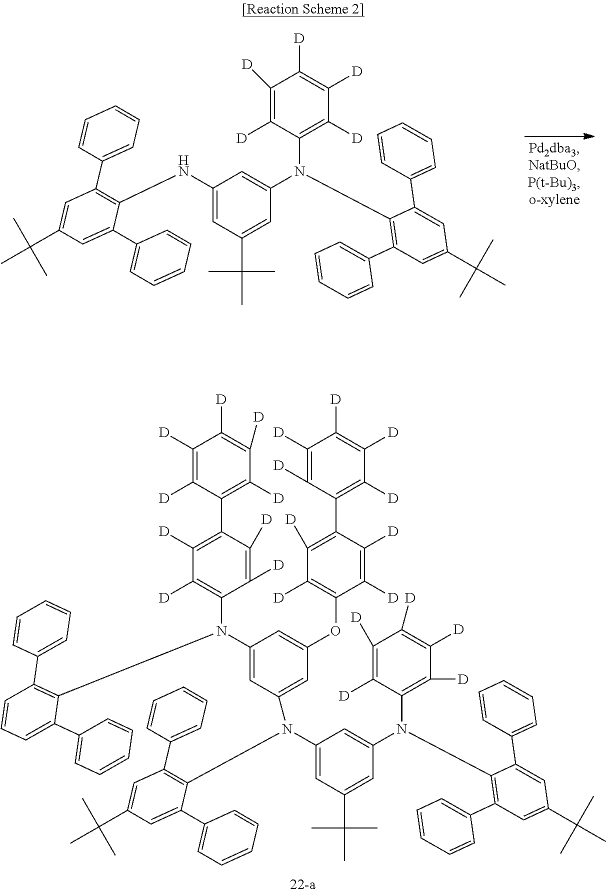 [SMILES: [2H]c1c([2H])c([2H])c(N(c2cc(Nc3c(-c4ccccc4)cc(C(C)(C)C)cc3-c3ccccc3)cc(C(C)(C)C)c2)c2c(-c3ccccc3)cc(C(C)(C)C)cc2-c2ccccc2)c([2H])c1[2H] ; [2H]c1c([2H])c([2H])c(-c2c([2H])c([2H])c(Oc3cc(N(c4cc(N(c5c(-c6ccccc6)cc(C(C)(C)C)cc5-c5ccccc5)c5c([2H])c([2H])c([2H])c([2H])c5[2H])cc(C(C)(C)C)c4)c4c(-c5ccccc5)cc(C(C)(C)C)cc4-c4ccccc4)cc(N(c4c(-c5ccccc5)cccc4-c4ccccc4)c4c([2H])c([2H])c(-c5c([2H])c([2H])c([2H])c([2H])c5[2H])c([2H])c4[2H])c3)c([2H])c2[2H])c([2H])c1[2H]]

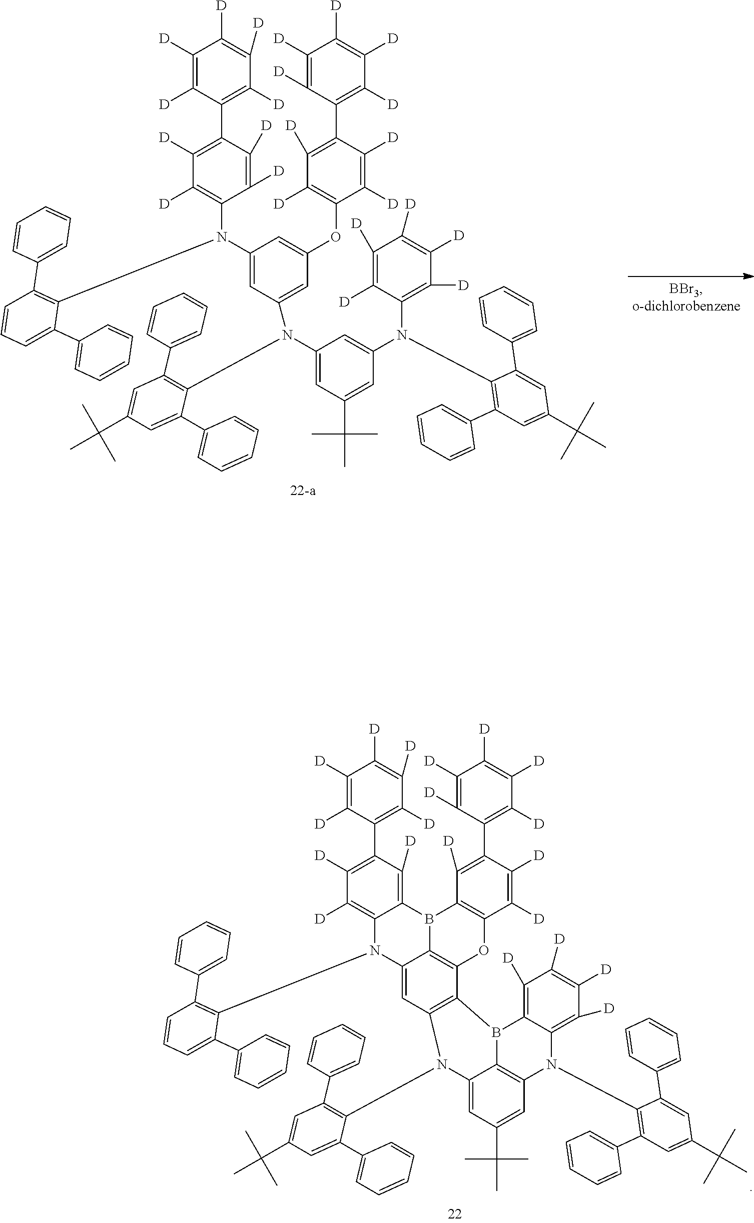

### Synthesis of Intermediate Compound 22-a

Under an argon atmosphere, in a flask of 2 L, 5-(tert-butyl)-N1,N3-bis(5′-(tert-butyl)-[1,1′:3′,1″-terphenyl]-2′-yl)-N1-(phenyl-d5)benzene-1,3-diamine (10 g, 12.2 mmol), N-([1,1′-biphenyl]-4-yl-d9)-N-(3-(([1,1′-biphenyl]-4-yl-d9)oxy)-5-bromophenyl)-[1,1′:3′,1″-terphenyl]-2′-amine (9 g, 12.2 mmol), Pd₂dba₃ (1.6 g, 1.9 mmol), tris-tert-butyl phosphine (P(t-Bu)₃, 1.6 mL, 3.8 mmol), and sodium tert-butoxide (Na tBuO, 5.8 g, 60 mmol) were added and dissolved in 200 mL of o-xylene, and the reaction solution was stirred at about 140° C. for about 2 hours. After cooling the solution, water (1 L) and ethyl acetate (300 mL) were added, and the obtained mixture was subjected to extraction to collect an organic layer, was dried over MgSO₄, and filtered. A solvent was removed from the filtered solution under reduced pressure, and the obtained solid was purified and separated by column chromatography using silica gel with CH₂Cl₂ and hexane as a developing solvent to obtain Intermediate Compound 22-a (white solids, 11.5 g, 64%).

ESI-LCMS: [M]⁺: C₁₀₈H₇₀D₂₃N₃O. 1470.8818

### Synthesis of Compound 22

Under an argon atmosphere, in a flask of 1 L, Intermediate Compound 22-a (11 g, 7.5 mmol) was added and dissolved in 50 mL of o-dichlorobenzene, and BBr₃ (2.5 equiv.) was added. The reaction solution was stirred at about 140° C. for about 12 hours. After cooling the solution, triethylamine was added to terminate the reaction, and a solvent was removed under reduced pressure, and the obtained solid was purified and separated by column chromatography using silica gel with CH₂C2 and hexane as a developing solvent to obtain Compound 22 (yellow solids, 2.8 g, 25%).

ESI-LCMS: [M]⁺: C₁₀₈H₆₇D₂₀B₂N₃O. 1483.8382

1H-NMR (CDCl₃): δ=8.32 (t, 2H), 7.99 (s, 4H), 7.44 (t, 1H), 7.38 (m, 18H), 7.06 (m, 12H), 7.01 (s, 2H), 6.55 (s, 1H), 1.32 (s, 18H), 1.22 (s, 9H)

### (3) Synthesis of Compound 24

Compound 24 according to an embodiment may be synthesized by, for example, Reaction Scheme 3.

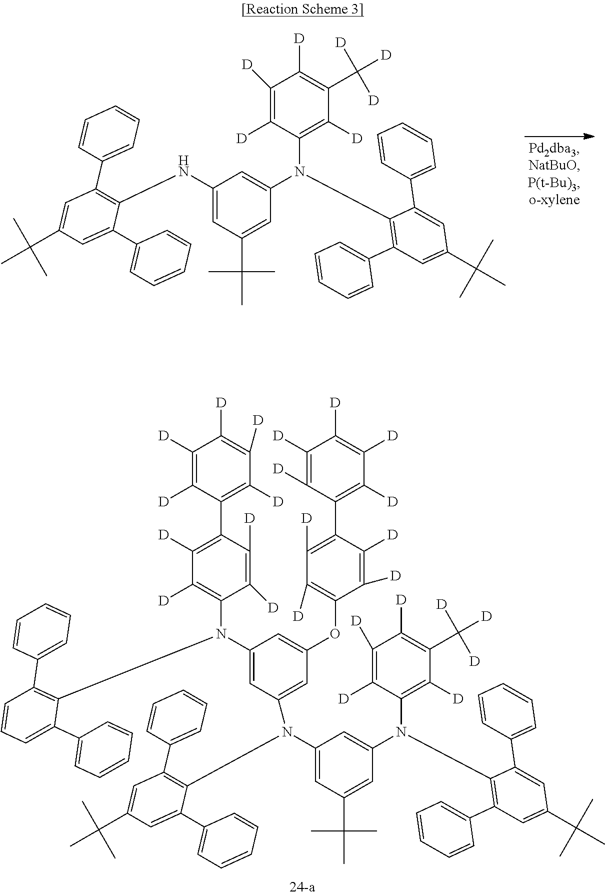 [SMILES: [2H]c1c([2H])c(N(c2cc(Nc3c(-c4ccccc4)cc(C(C)(C)C)cc3-c3ccccc3)cc(C(C)(C)C)c2)c2c(-c3ccccc3)cc(C(C)(C)C)cc2-c2ccccc2)c([2H])c(C([2H])([2H])[2H])c1[2H] ; [2H]c1c([2H])c([2H])c(-c2c([2H])c([2H])c(Oc3cc(N(c4cc(N(c5c(-c6ccccc6)cc(C(C)(C)C)cc5-c5ccccc5)c5c([2H])c([2H])c([2H])c(C([2H])([2H])[2H])c5[2H])cc(C(C)(C)C)c4)c4c(-c5ccccc5)cc(C(C)(C)C)cc4-c4ccccc4)cc(N(c4c(-c5ccccc5)cccc4-c4ccccc4)c4c([2H])c([2H])c(-c5c([2H])c([2H])c([2H])c([2H])c5[2H])c([2H])c4[2H])c3)c([2H])c2[2H])c([2H])c1[2H]]

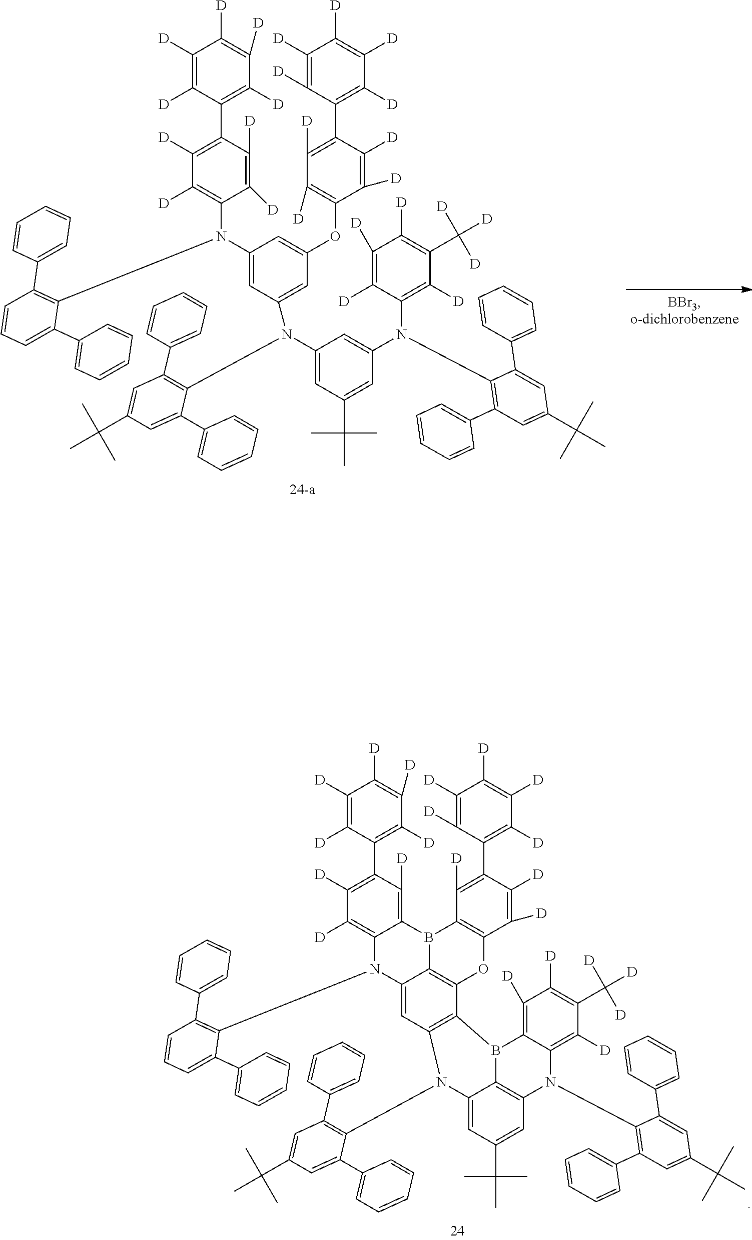

### Synthesis of Intermediate Compound 24-a

Under an argon atmosphere, in a flask of 2 L, 5-(tert-butyl)-N1,N3-bis(5′-(tert-butyl)-[1,1′:3′,1″-terphenyl]-2′-yl)-N1-(3-(methyl-d3)phenyl-2,4,5,6-d4)benzene-1,3-diamine (10 g, 12 mmol), N-([1,1′-biphenyl]-4-yl-d9)-N-(3-(([1,1′-biphenyl]-4-yl-d9)oxy)-5-bromophenyl)-[1,1′:3′,1″-terphenyl]-2′-amine (8.9 g, 12 mmol), Pd₂dba₃ (1.6 g, 1.9 mmol), tris-tert-butyl phosphine (P(t-Bu)₃, 1.6 mL, 3.8 mmol), and sodium tert-butoxide (Na tBuO, 5.8 g, 60 mmol) were added and dissolved in 200 mL of o-xylene, and the reaction solution was stirred at about 140° C. for about 2 hours. After cooling the solution, water (1 L) and ethyl acetate (300 mL) were added, and the obtained mixture was subjected to extraction to collect an organic layer, was dried over MgSO₄, and filtered. A solvent was removed from the filtered solution under reduced pressure, and the obtained solid was purified and separated by column chromatography using silica gel with CH₂Cl₂ and hexane as a developing solvent to obtain Intermediate Compound 24-a (white solids, 12.5 g, 70%).

ESI-LCMS: [M]⁺: C₁₀₉H₇₀D₂₅N₃O. 1486.9028

### Synthesis of Compound 24

Under an argon atmosphere, in a flask of 1 L, Intermediate Compound 24-a (12 g, 8 mmol) was added and dissolved in 50 mL of o-dichlorobenzene, and BBr₃ (2.5 equiv.) was added. The reaction solution was stirred at about 140° C. for about 12 hours. After cooling the solution, triethylamine was added to terminate the reaction, and a solvent was removed under reduced pressure, and the obtained solid was purified and separated by column chromatography using silica gel with CH₂C2 and hexane as a developing solvent to obtain Compound 24 (yellow solids, 2.8 g, 23%).

ESI-LCMS: [M]⁺: C₁₀₉H₆₇D₂₂B₂N₃O. 1499.8669

1H-NMR (CDCl₃): δ=8.34 (t, 2H), 8.03 (s, 4H), 7.41 (t, 1H), 7.35 (m, 18H), 7.11 (m, 12H), 7.04 (s, 2H), 6.38 (s, 1H), 1.34 (s, 18H)

### (4) Synthesis of Compound 34

Compound 34 according to an embodiment may be synthesized by, for example, Reaction Scheme 4.

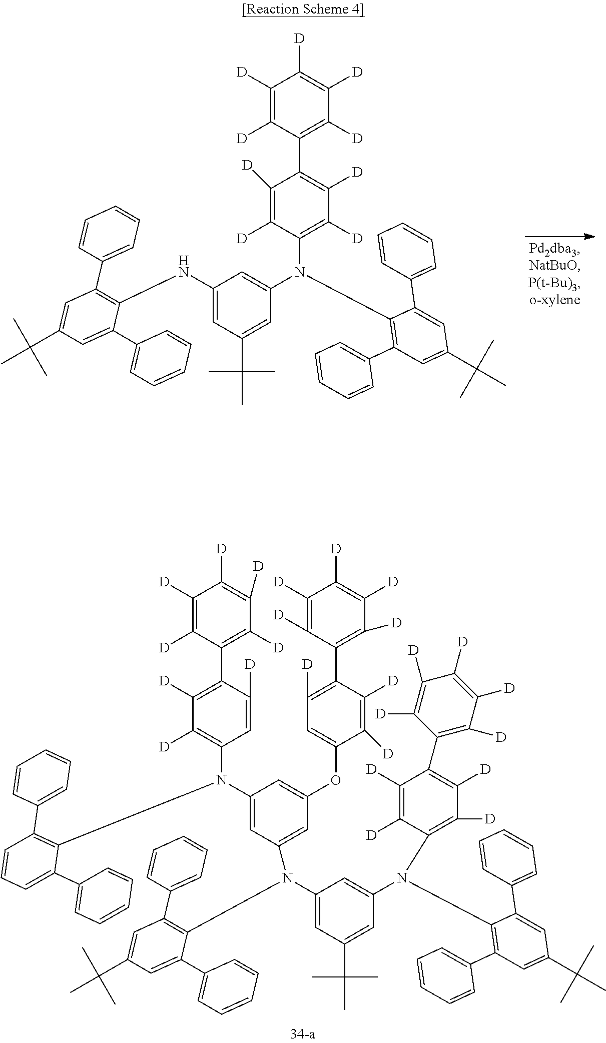

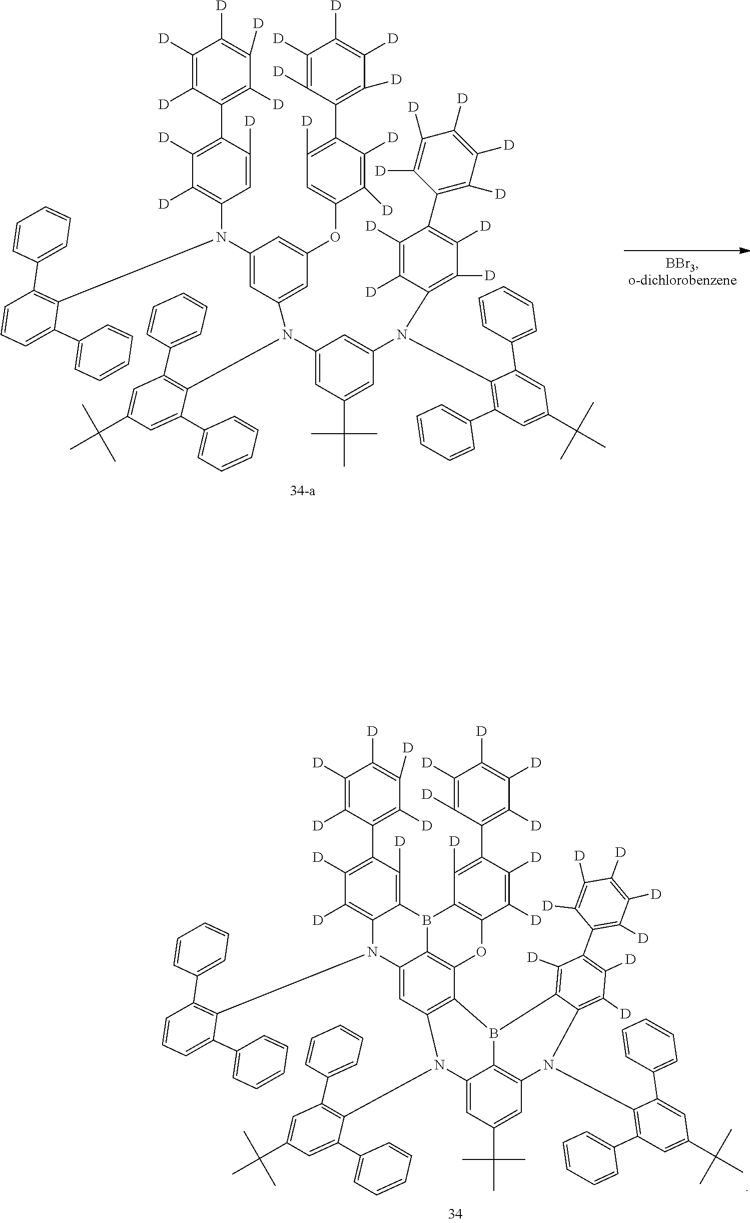

### Synthesis of Intermediate Compound 24-a

Under an argon atmosphere, in a flask of 2 L, N1-([1,1′-biphenyl]-4-yl-d9)-5-(tert-butyl)-N1,N3-bis(5′-(tert-butyl)-[1,1′:3′,1″-terphenyl]-2′-yl)benzene-1,3-diamine (10 g, 11 mmol), N-([1,1′-biphenyl]-4-yl-2,2′,3,3′,4′,5′,6,6′-d8)-N-(3-(([1,1′-biphenyl]-4-yl-2,2′,3,3′,4′,5′,6,6′-d8)oxy)-5-bromophenyl)-[1,1′:3′,1″-terphenyl]-2′-amine (8.2 g, 11 mmol), Pd₂dba₃ (1.6 g, 1.9 mmol), tris-tert-butyl phosphine (P(t-Bu)₃, 1.6 mL, 3.8 mmol), and sodium tert-butoxide (Na tBuO, 5.8 g, 60 mmol) were added and dissolved in 200 mL of o-xylene, and the reaction solution was stirred at about 140° C. for about 2 hours. After cooling the solution, water (1 L) and ethyl acetate (300 mL) were added, and the obtained mixture was subjected to extraction to collect an organic layer, was dried over MgSO₄, and filtered. A solvent was removed from the filtered solution under reduced pressure, and the obtained solid was purified and separated by column chromatography using silica gel with CH₂Cl₂ and hexane as a developing solvent to obtain Intermediate Compound 34-a (white solids, 11.2 g, 66%).

ESI-LCMS: [M]⁺: C₁₁₄H₇₂D₂₅N₃O. 1550.0231

### Synthesis of Compound 34

Under an argon atmosphere, in a flask of 1 L, Intermediate Compound 34-a (11 g, 7 mmol) was added and dissolved in 50 mL of o-dichlorobenzene, and BBr₃ (2.5 equiv.) was added. The reaction solution was stirred at about 140° C. for about 12 hours. After cooling the solution, triethylamine was added to terminate the reaction, and a solvent was removed under reduced pressure, and the obtained solid was purified and separated by column chromatography using silica gel with CH₂C2 and hexane as a developing solvent to obtain Compound 34 (yellow solids, 3 g, 27%).

ESI-LCMS: [M]⁺: C₁₁₄H₆₇D₂₄B₂N₃O. 1563.8920

1H-NMR (CDCl₃): δ=8.28 (t, 2H), 7.97 (s, 4H), 7.43 (t, 1H), 7.38 (m, 18H), 7.09 (m, 12H), 7.01 (s, 2H), 6.38 (s, 1H), 1.31 (s, 18H)

### (5) Synthesis of Compound 37

Compound 37 according to an embodiment may be synthesized by, for example, Reaction Scheme 5.

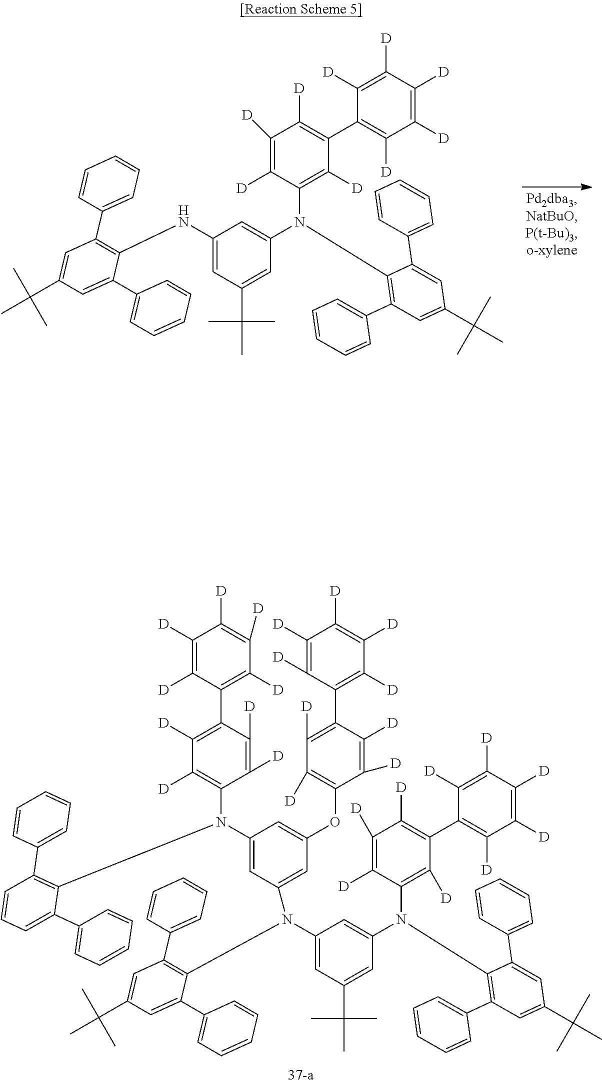

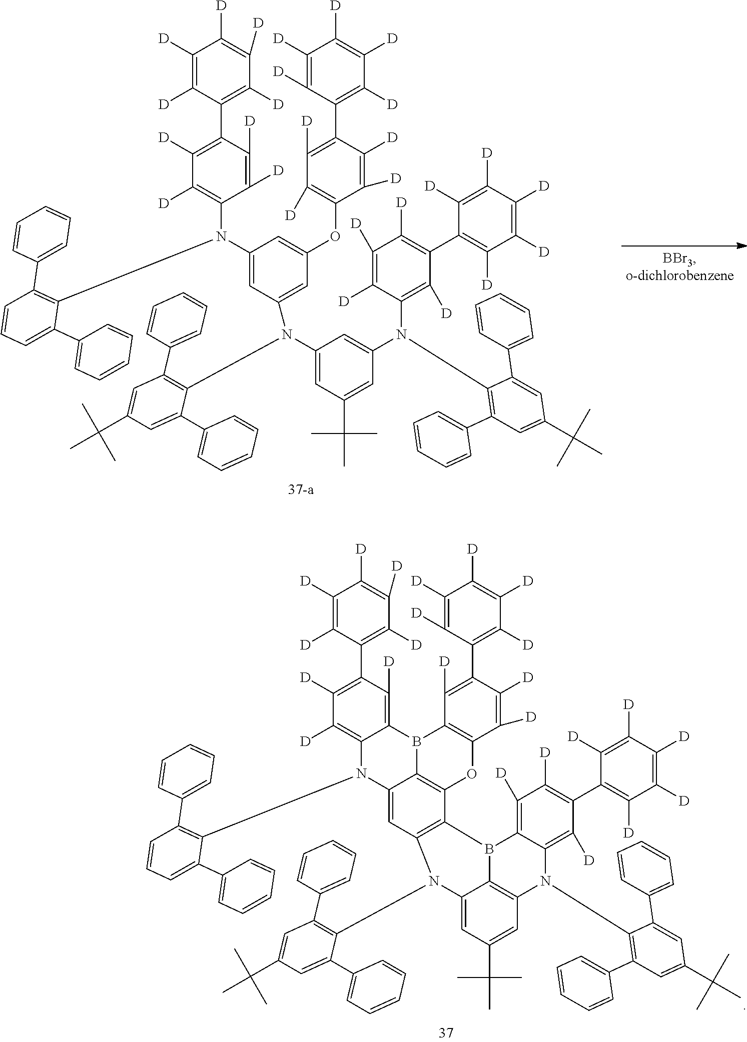

### Synthesis of Intermediate Compound 37-a

Under an argon atmosphere, in a flask of 2 L, N1-([1,1′-biphenyl]-3-yl-d9)-5-(tert-butyl)-N1,N3-bis(5′-(tert-butyl)-[1,1′:3′,1″-terphenyl]-2′-yl)benzene-1,3-diamine (10 g, 11 mmol), N-([1,1′-biphenyl]-4-yl-2,2′,3,3′,4′,5′,6,6′-d8)-N-(3-(([1,1′-biphenyl]-4-yl-2,2′,3,3′,4′,5′,6,6′-d8)oxy)-5-bromophenyl)-[1,1′:3′,1″-terphenyl]-2′-amine (8.2 g, 11 mmol), Pd₂dba₃ (1.6 g, 1.9 mmol), tris-tert-butyl phosphine (P(t-Bu)₃, 1.6 mL, 3.8 mmol), and sodium tert-butoxide (Na tBuO, 5.8 g, 60 mmol) were added and dissolved in 200 mL of o-xylene, and the reaction solution was stirred at about 140° C. for about 2 hours. After cooling the solution, water (1 L) and ethyl acetate (300 mL) were added, and the obtained mixture was subjected to extraction to collect an organic layer, was dried over MgSO₄, and filtered. A solvent was removed from the filtered solution under reduced pressure, and the obtained solid was purified and separated by column chromatography using silica gel with CH₂Cl₂ and hexane as a developing solvent to obtain Intermediate Compound 37-a (white solids, 11 g, 65%).

ESI-LCMS: [M]⁺: C₁₁₄H₇₀D₂₇N₃O. 1550.9313.

### Synthesis of Compound 37

Under an argon atmosphere, in a flask of 1 L, Intermediate Compound 37-a (11 g, 7 mmol) was added and dissolved in 50 mL of o-dichlorobenzene, and BBr₃ (2.5 equiv.) was added. The reaction solution was stirred at about 140° C. for about 12 hours. After cooling the solution, triethylamine was added to terminate the reaction, and a solvent was removed under reduced pressure, and the obtained solid was purified and separated by column chromatography using silica gel with CH₂C2 and hexane as a developing solvent to obtain Compound 37 (yellow solids, 2.6 g, 24%).

ESI-LCMS: [M]⁺: C₁₁₄H₆₇D₂₄B₂N₃O. 1563.2639

1H-NMR (CDCl₃): δ=8.25 (t, 2H), 7.99 (s, 4H), 7.42 (t, 1H), 7.35 (m, 18H), 7.08 (m, 12H), 7.03 (s, 2H), 6.44 (s, 1H), 1.26 (s, 18H)

### (6) Synthesis of Compound 43

Compound 43 according to an embodiment may be synthesized by, for example, Reaction Scheme 6.

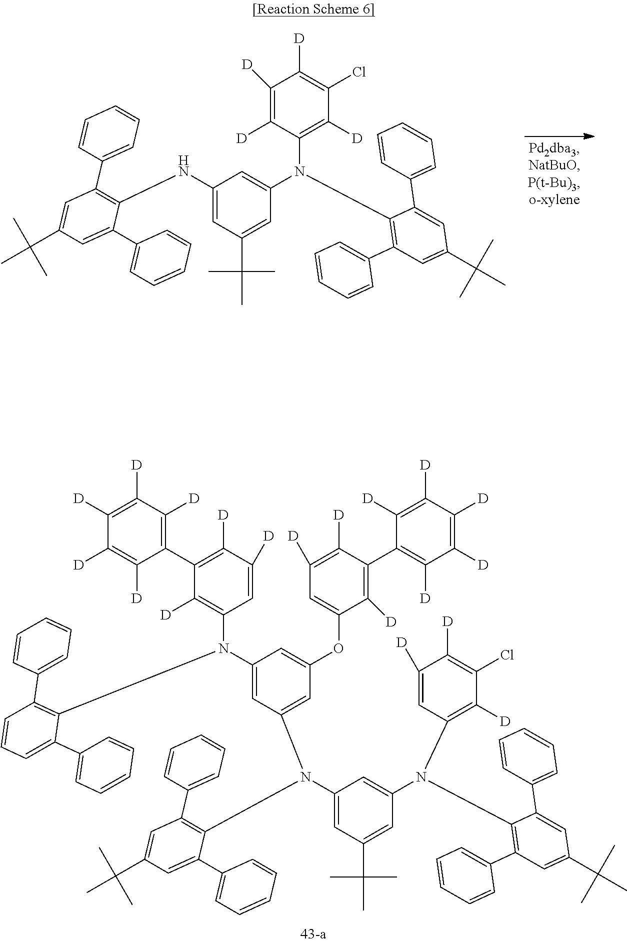 [SMILES: [2H]c1c([2H])c(Cl)c([2H])c(N(c2cc(Nc3c(-c4ccccc4)cc(C(C)(C)C)cc3-c3ccccc3)cc(C(C)(C)C)c2)c2c(-c3ccccc3)cc(C(C)(C)C)cc2-c2ccccc2)c1[2H] ; [2H]c1cc(N(c2cc(N(c3cc(Oc4cc([2H])c([2H])c(-c5c([2H])c([2H])c([2H])c([2H])c5[2H])c4[2H])cc(N(c4cc([2H])c([2H])c(-c5c([2H])c([2H])c([2H])c([2H])c5[2H])c4[2H])c4c(-c5ccccc5)cccc4-c4ccccc4)c3)c3c(-c4ccccc4)cc(C(C)(C)C)cc3-c3ccccc3)cc(C(C)(C)C)c2)c2c(-c3ccccc3)cc(C(C)(C)C)cc2-c2ccccc2)c([2H])c(Cl)c1[2H]]

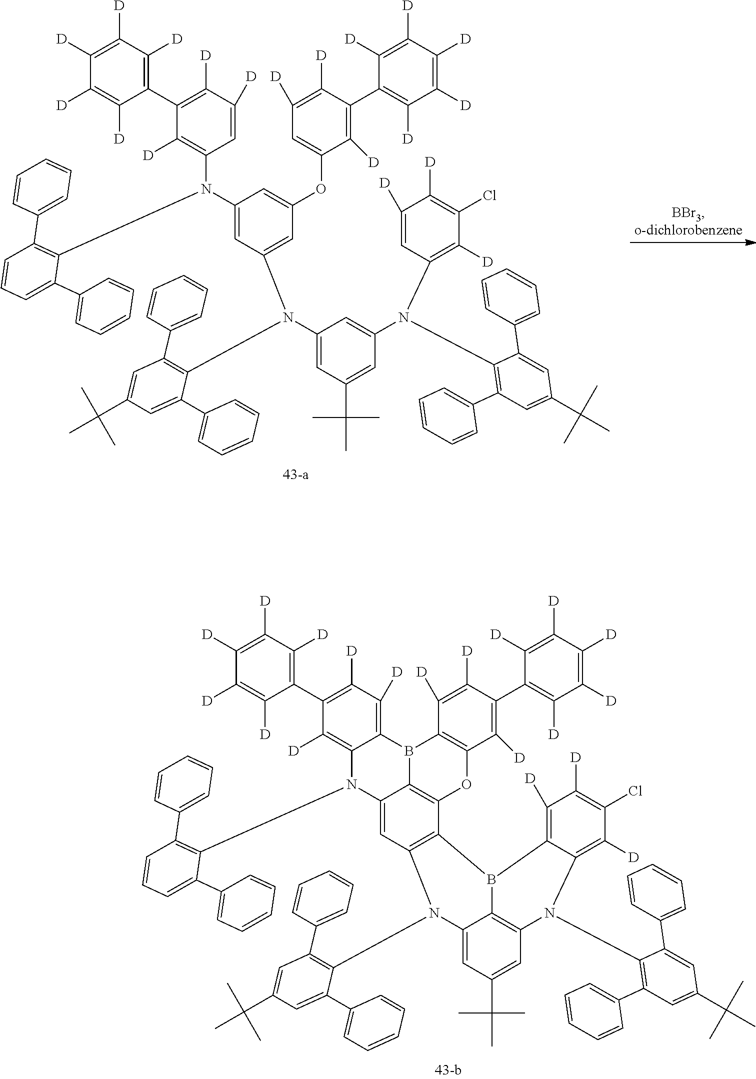

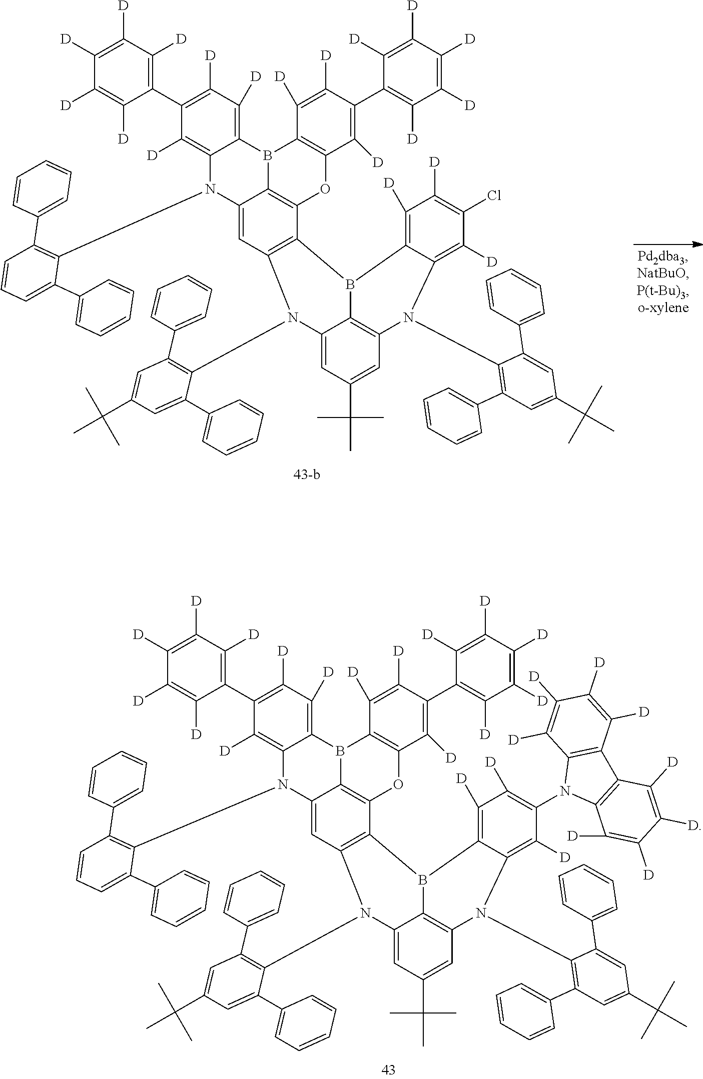

### Synthesis of Intermediate Compound 43-a

Under an argon atmosphere, in a flask of 2 L, 5-(tert-butyl)-N1,N3-bis(5′-(tert-butyl)-[1,1′:3′,1″-terphenyl]-2′-yl)-N1-(3-chlorophenyl-2,4,5,6-d4)benzene-1,3-diamine (10 g, 11.7 mmol), N-([1,1′-biphenyl]-3-yl-2,2′,3′,4′,5,5′,6,6′-d8)-N-(3-(([1,1′-biphenyl]-3-yl-2,2′,3′,4′,5,5′,6,6′-d8)oxy)-5-bromophenyl)-[1,1′:3′,1″-terphenyl]-2′-amine (8.7 g, 11.7 mmol), Pd₂dba₃ (1.6 g, 1.9 mmol), tris-tert-butyl phosphine (P(t-Bu)₃, 1.6 mL, 3.8 mmol), and sodium tert-butoxide (Na tBuO, 5.8 g, 60 mmol) were added and dissolved in 200 mL of o-xylene, and the reaction solution was stirred at about 140° C. for about 2 hours. After cooling the solution, water (1 L) and ethyl acetate (300 mL) were added, and the obtained mixture was subjected to extraction to collect an organic layer, was dried over MgSO₄, and filtered. A solvent was removed from the filtered solution under reduced pressure, and the obtained solid was purified and separated by column chromatography using silica gel with CH₂Cl₂ and hexane as a developing solvent to obtain Intermediate Compound 43-a (white solids, 10 g, 57%).

ESI-LCMS: [M]⁺: C₁₀₈H₇₃D₁₉ClN₃O. 1502.6483.

### Synthesis of Intermediate Compound 43-b

Under an argon atmosphere, in a flask of 1 L, Intermediate Compound 43-a (10 g, 6.6 mmol) was put and dissolved in 50 mL of o-dichlorobenzene, and BBr₃ (2.5 equiv.) was added. The reaction solution was stirred at about 140° C. for about 12 hours. After cooling the solution, triethylamine was added to terminate the reaction, and a solvent was removed under reduced pressure, and the obtained solid was purified and separated by column chromatography using silica gel with CH₂Cl₂ and hexane as a developing solvent to obtain Intermediate Compound 43-b (yellow solids, 2.9 g, 29%).

ESI-LCMS: [M]⁺: C₁₀₈H₆₇D₁₉B₂ClN₃O. 1516.7862

### Synthesis of Compound 43

Under an argon atmosphere, in a flask of 2 L, Intermediate Compound 43-b (2.5 g, 1.6 mmol), 9H-carbazole-1,2,3,4,5,6,7,8-d8 (0.28 g, 1.6 mmol), Pd₂dba₃ (0.14 g, 0.16 mmol), tris-tert-butyl phosphine (P(t-Bu)₃, 0.14 mL, 0.32 mmol), and sodium tert-butoxide (Na tBuO, 0.5 g, 5 mmol) were added and dissolved in 20 mL of o-xylene, and the reaction solution was stirred at about 140° C. for about 2 hours. After cooling the solution, water (1 L) and ethyl acetate (300 mL) were added, and the obtained mixture was subjected to extraction to collect an organic layer, was dried over MgSO₄, and filtered. A solvent was removed from the filtered solution under reduced pressure, and the obtained solid was purified and separated by column chromatography using silica gel with CH₂Cl₂ and hexane as a developing solvent to obtain Compound 43 (yellow solids, 1.9 g, 71%).

ESI-LCMS: [M]⁺: C₁₂₀H₆₇D₂₇B₂N₄O. 1656.8826.

1H-NMR (CDCl₃): δ=8.19 (d, 2H), 8.04 (s, 4H), 7.41 (m, 18H), 7.12 (m, 12H), 7.06 (s, 2H), 6.49 (s, 1H), 1.36 (s, 9H), 1.25 (s, 18H)

### (7) Synthesis of Compound 73

Compound 73 according to an embodiment may be synthesized by, for example, Reaction Scheme 7.

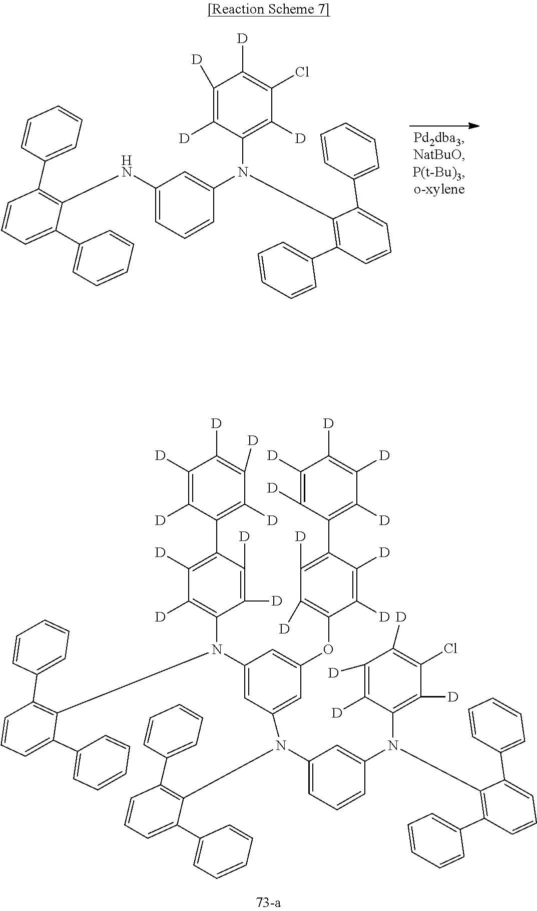 [SMILES: [2H]c1c([2H])c(Cl)c([2H])c(N(c2cccc(Nc3c(-c4ccccc4)cccc3-c3ccccc3)c2)c2c(-c3ccccc3)cccc2-c2ccccc2)c1[2H] ; [2H]c1c([2H])c([2H])c(-c2c([2H])c([2H])c(Oc3cc(N(c4cccc(N(c5c(-c6ccccc6)cccc5-c5ccccc5)c5c([2H])c([2H])c([2H])c(Cl)c5[2H])c4)c4c(-c5ccccc5)cccc4-c4ccccc4)cc(N(c4c(-c5ccccc5)cccc4-c4ccccc4)c4c([2H])c([2H])c(-c5c([2H])c([2H])c([2H])c([2H])c5[2H])c([2H])c4[2H])c3)c([2H])c2[2H])c([2H])c1[2H]]

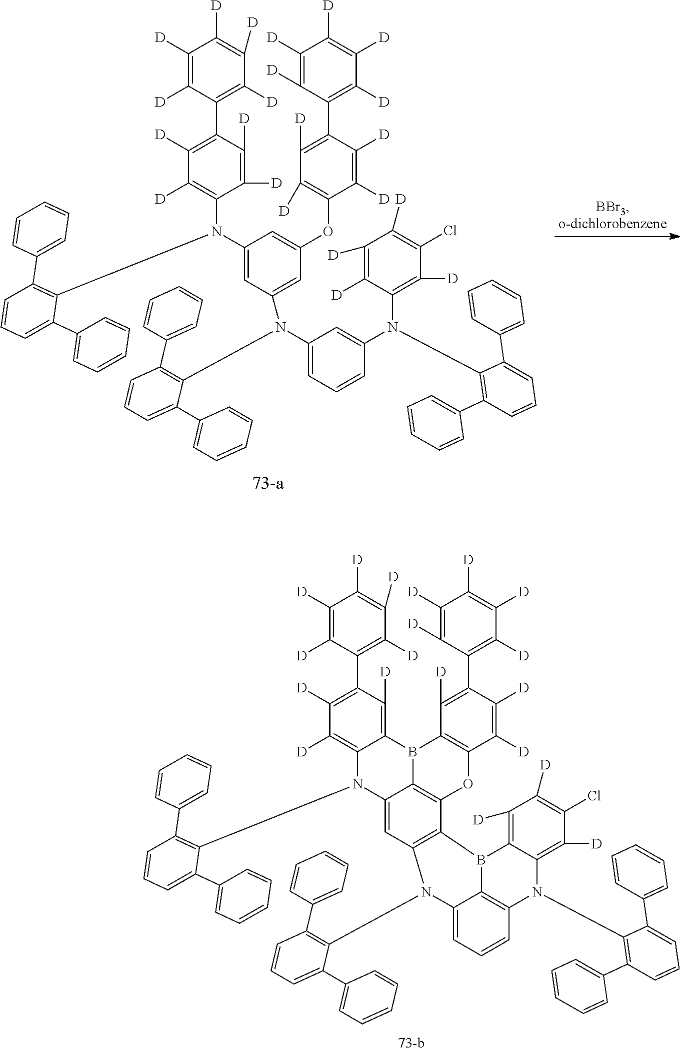

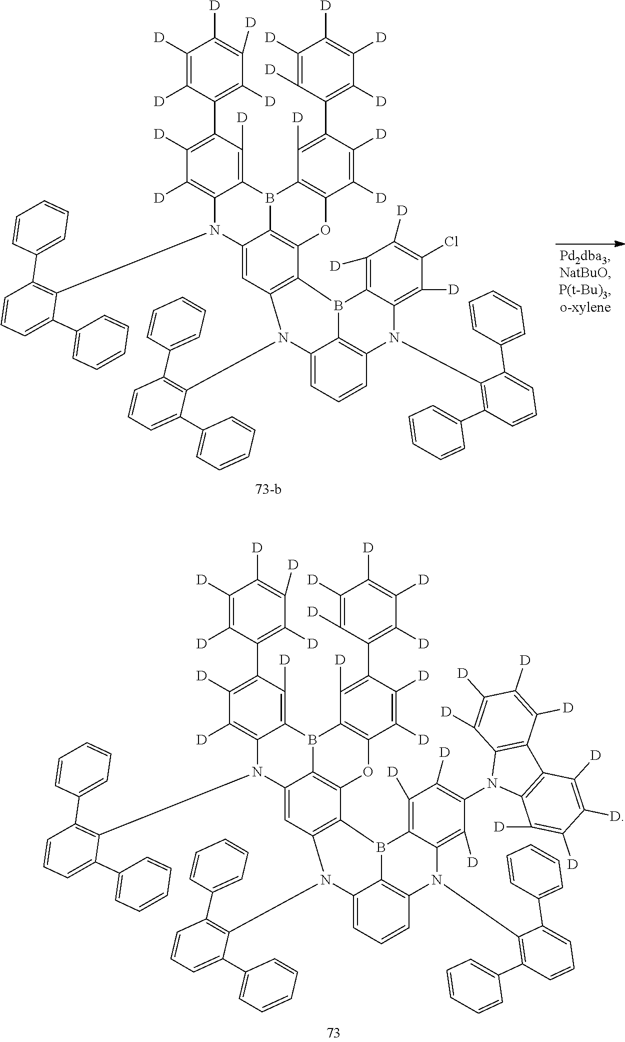

### Synthesis of Intermediate Compound 73-a

Under an argon atmosphere, in a flask of 2 L, 5 N1,N3-di([1,1′:3′,1″-terphenyl]-2′-yl)-N1-(3-chlorophenyl-2,4,5,6-d4)benzene-1,3-diamine (10 g, 14.7 mmol), N-([1,1′-biphenyl]-3-yl-2,2′,3′,4′,5,5′,6,6′-d8)-N-(3-(([1,1′-biphenyl]-3-yl-2,2′,3′,4′,5,5′,6,6′-d8)oxy)-5-bromophenyl)-[1,1′:3′,1″-terphenyl]-2′-amine (10.8 g, 14.7 mmol), Pd₂dba₃ (1.6 g, 1.9 mmol), tris-tert-butyl phosphine (P(t-Bu)₃, 1.6 mL, 3.8 mmol), and sodium tert-butoxide (Na tBuO, 5.8 g, 60 mmol) were added and dissolved in 200 mL of o-xylene, and the reaction solution was stirred at about 140° C. for about 2 hours. After cooling the solution, water (1 L) and ethyl acetate (300 mL) were added, and the obtained mixture was subjected to extraction to collect an organic layer, was dried over MgSO₄, and filtered. A solvent was removed from the filtered solution under reduced pressure, and the obtained solid was purified and separated by column chromatography using silica gel with CH₂Cl₂ and hexane as a developing solvent to obtain Intermediate Compound 73-a (white solids, 13.7 g, 70%).

ESI-LCMS: [M]⁺: C₉₆H₄₆D₂₂ClN₃O. 1335.6430.

### Synthesis of Intermediate Compound 73-b

Under an argon atmosphere, in a flask of 1 L, Intermediate Compound 73-a (13 g, 9.7 mmol) was added and dissolved in 100 mL of o-dichlorobenzene, and BBr₃ (2.5 equiv.) was added. The reaction solution was stirred at about 140° C. for about 12 hours. After cooling the solution, triethylamine was added to terminate the reaction, and a solvent was removed under reduced pressure, and the obtained solid was purified and separated by column chromatography using silica gel with CH₂Cl₂ and hexane as a developing solvent to obtain Intermediate Compound 73-b (yellow solids, 2.5 g, 19%).

ESI-LCMS: [M]⁺: C₉₉H₄₃D₁₉B₂ClN₃O. 1348.6406

### Synthesis of Compound 73

Under an argon atmosphere, in a flask of 2 L, Intermediate Compound 73-b (2.5 g, 1.8 mmol), 9H-carbazole-1,2,3,4,5,6,7,8-d8 (0.32 g, 1.8 mmol), Pd₂dba₃ (0.14 g, 0.16 mmol), tris-tert-butyl phosphine (P(t-Bu)₃, 0.14 mL, 0.32 mmol), and sodium tert-butoxide (Na tBuO, 0.5 g, 5 mmol) were added and dissolved in 20 mL of o-xylene, and the reaction solution was stirred at about 140° C. for about 2 hours. After cooling the solution, water (1 L) and ethyl acetate (300 mL) were added, and the obtained mixture was subjected to extraction to collect an organic layer, was dried over MgSO₄, and filtered. A solvent was removed from the filtered solution under reduced pressure, and the obtained solid was purified and separated by column chromatography using silica gel with CH₂Cl₂ and hexane as a developing solvent to obtain Compound 73 (yellow solids, 1.7 g, 65%).

ESI-LCMS: [M]⁺: C₁₀₈H₄₃D₂₇B₂N₄O. 1487.7417.

1H-NMR (CDCl₃): δ=8.20 (m, 6H), 7.43 (m, 18H), 7.39 (m, 3H), 7.25 (m, 1H), 7.11 (m, 12H), 6.84 (d, 2H), 6.55 (s, 1H)

### (8) Synthesis of Compound 79

Compound 79 according to an embodiment may be synthesized by, for example, Reaction Scheme 8.

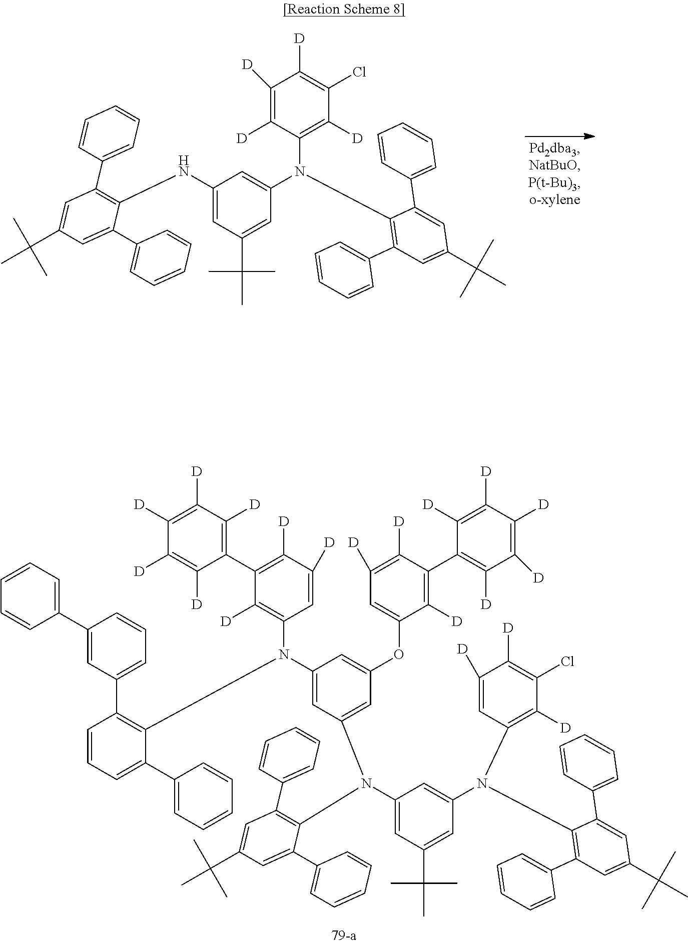 [SMILES: [2H]c1c([2H])c(Cl)c([2H])c(N(c2cc(Nc3c(-c4ccccc4)cc(C(C)(C)C)cc3-c3ccccc3)cc(C(C)(C)C)c2)c2c(-c3ccccc3)cc(C(C)(C)C)cc2-c2ccccc2)c1[2H] ; [2H]c1cc(N(c2cc(N(c3cc(Oc4cc([2H])c([2H])c(-c5c([2H])c([2H])c([2H])c([2H])c5[2H])c4[2H])cc(N(c4cc([2H])c([2H])c(-c5c([2H])c([2H])c([2H])c([2H])c5[2H])c4[2H])c4c(-c5ccccc5)cccc4-c4cccc(-c5ccccc5)c4)c3)c3c(-c4ccccc4)cc(C(C)(C)C)cc3-c3ccccc3)cc(C(C)(C)C)c2)c2c(-c3ccccc3)cc(C(C)(C)C)cc2-c2ccccc2)c([2H])c(Cl)c1[2H]]

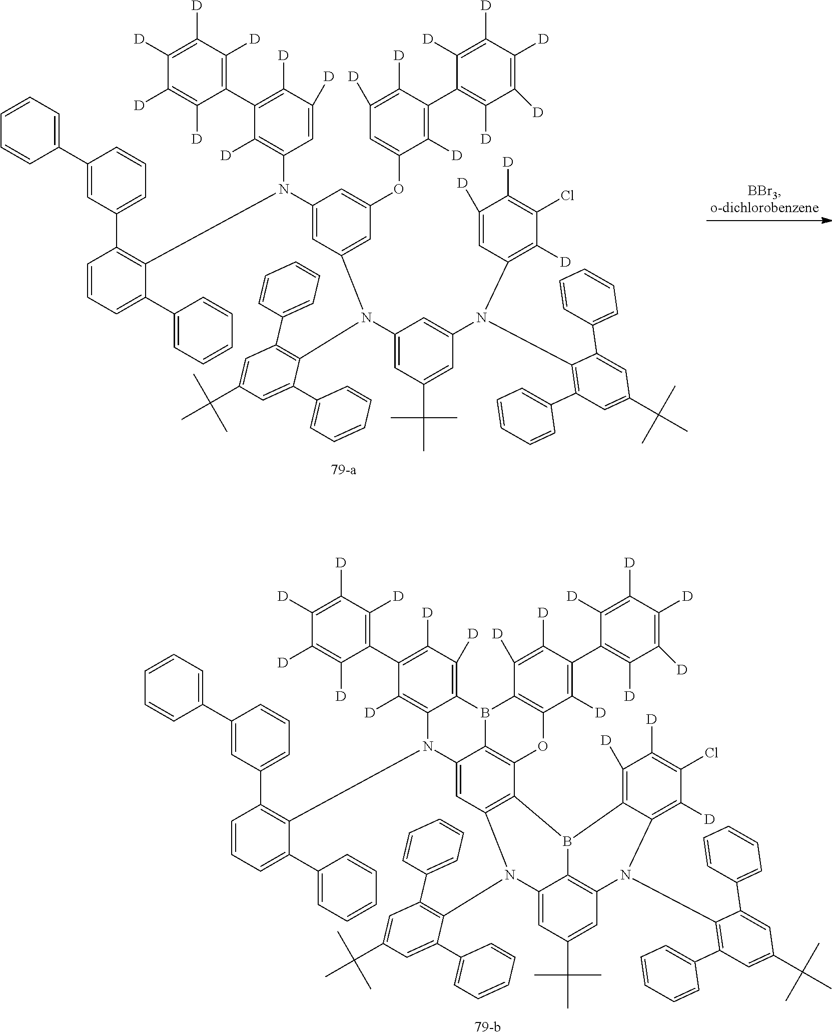

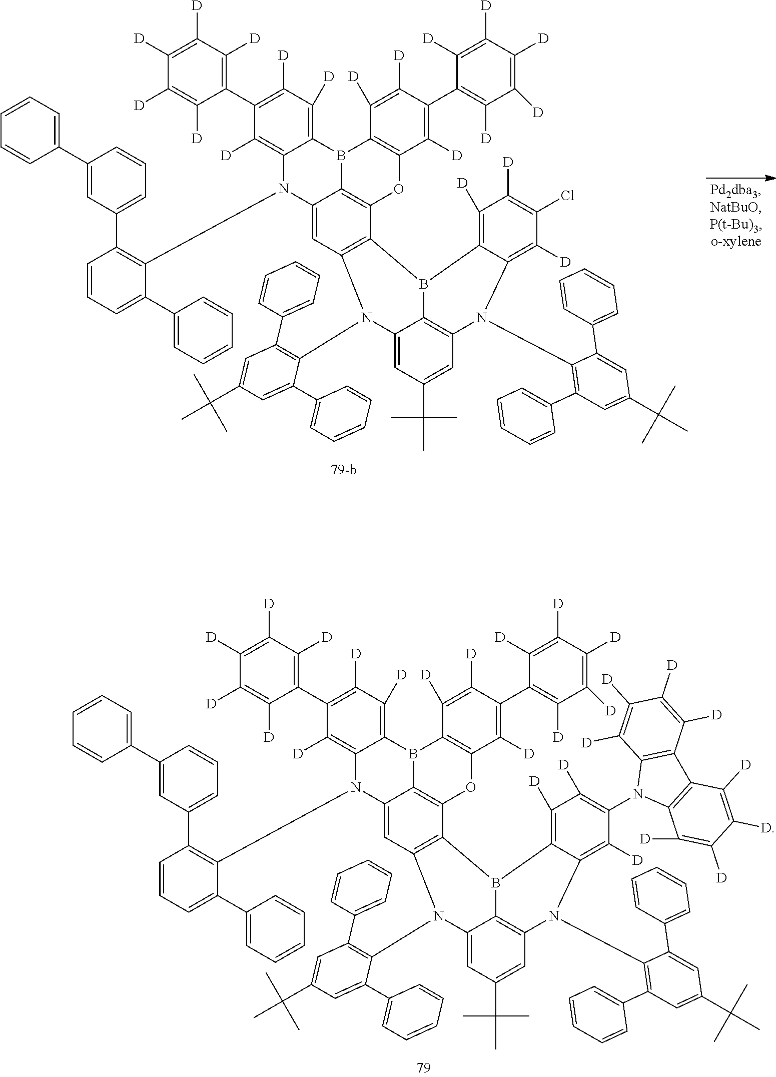

### Synthesis of Intermediate Compound 79-a

Under an argon atmosphere, in a flask of 2 L, 5-(tert-butyl)-N1,N3-bis(5′-(tert-butyl)-[1,1′:3′,1″-terphenyl]-2′-yl)-N1-(3-chlorophenyl-2,4,5,6-d4)benzene-1,3-diamine (10 g, 11.7 mmol), N-([1,1′-biphenyl]-3-yl-d9)-N-(3-(([1,1′-biphenyl]-3-yl-d9)oxy)-5-bromophenyl)-[1,1′:3′,1″:3″,1′″-quaterphenyl]-2′-amine (9.6 g, 11.7 mmol), Pd₂dba₃ (1.6 g, 1.9 mmol), tris-tert-butyl phosphine (P(t-Bu)₃, 1.6 mL, 3.8 mmol), and sodium tert-butoxide (Na tBuO, 5.8 g, 60 mmol) were added and dissolved in 200 mL of o-xylene, and the reaction solution was stirred at about 140° C. for about 2 hours. After cooling the solution, water (1 L) and ethyl acetate (300 mL) were added, and the obtained mixture was subjected to extraction to collect an organic layer, was dried over MgSO₄, and filtered. A solvent was removed from the filtered solution under reduced pressure, and the obtained solid was purified and separated by column chromatography using silica gel with CH₂Cl₂ and hexane as a developing solvent to obtain Intermediate Compound 79-a (white solids, 12 g, 65%).

ESI-LCMS: [M]⁺: C₁₁₄H₇₇D₁₉ClN₃O. 1576.8462.

### Synthesis of Intermediate Compound 79-b

Under an argon atmosphere, in a flask of 1 L, Intermediate Compound 79-a (12 g, 7.6 mmol) was added and dissolved in 100 mL of o-dichlorobenzene, and BBr₃ (2.5 equiv.) was added. The reaction solution was stirred at about 140° C. for about 12 hours. After cooling the solution, triethylamine was added to terminate the reaction, and a solvent was removed under reduced pressure, and the obtained solid was purified and separated by column chromatography using silica gel with CH₂Cl₂ and hexane as a developing solvent to obtain Intermediate Compound 79-b (yellow solids, 2.6 g, 22%).

ESI-LCMS: [M]⁺: C₁₁₄H₇₁D₁₉B₂ClN₃O. 1592.8224

### Synthesis of Compound 79

Under an argon atmosphere, in a flask of 2 L, Intermediate Compound 79-b (2.6 g, 1.6 mmol), 9H-carbazole-1,2,3,4,5,6,7,8-d8 (0.28 g, 1.6 mmol), Pd₂dba₃ (0.14 g, 0.16 mmol), tris-tert-butyl phosphine (P(t-Bu)₃, 0.14 mL, 0.32 mmol), and sodium tert-butoxide (Na tBuO, 0.5 g, 5 mmol) were added and dissolved in 20 mL of o-xylene, and the reaction solution was stirred at about 140° C. for about 2 hours. After cooling the solution, water (1 L) and ethyl acetate (300 mL) were added, and the obtained mixture was subjected to extraction to collect an organic layer, was dried over MgSO₄, and filtered. A solvent was removed from the filtered solution under reduced pressure, and the obtained solid was purified and separated by column chromatography using silica gel with CH₂Cl₂ and hexane as a developing solvent to obtain Compound 79 (yellow solids, 2 g, 74%).

ESI-LCMS: [M]⁺: C₁₂₆H₇₁D₂₇B₂N₄O. 1731.9629.

1H-NMR (CDCl₃): δ=8.22 (m, 2H), 7.99 (s, 4H), 7.94 (s, 1H), 7.73 (m, 3H), 7.61 (m, 2H), 7.49 (m, 3H), 7.41 (m, 16H), 7.21 (m, 10H), 7.04 (m, 2H), 6.55 (s, 1H), 1.28 (s, 18H), 1.19 (s, 9H)

### 2. Evaluation of Compounds

Example Compounds and Comparative Example Compounds were evaluated and the evaluation results are listed in Table 1. Compounds 4, 22, 24, 34, 37, 43, 73, and 79, which are fused polycyclic compounds according to an embodiment, were evaluated as the Example Compounds.

### Example Compounds

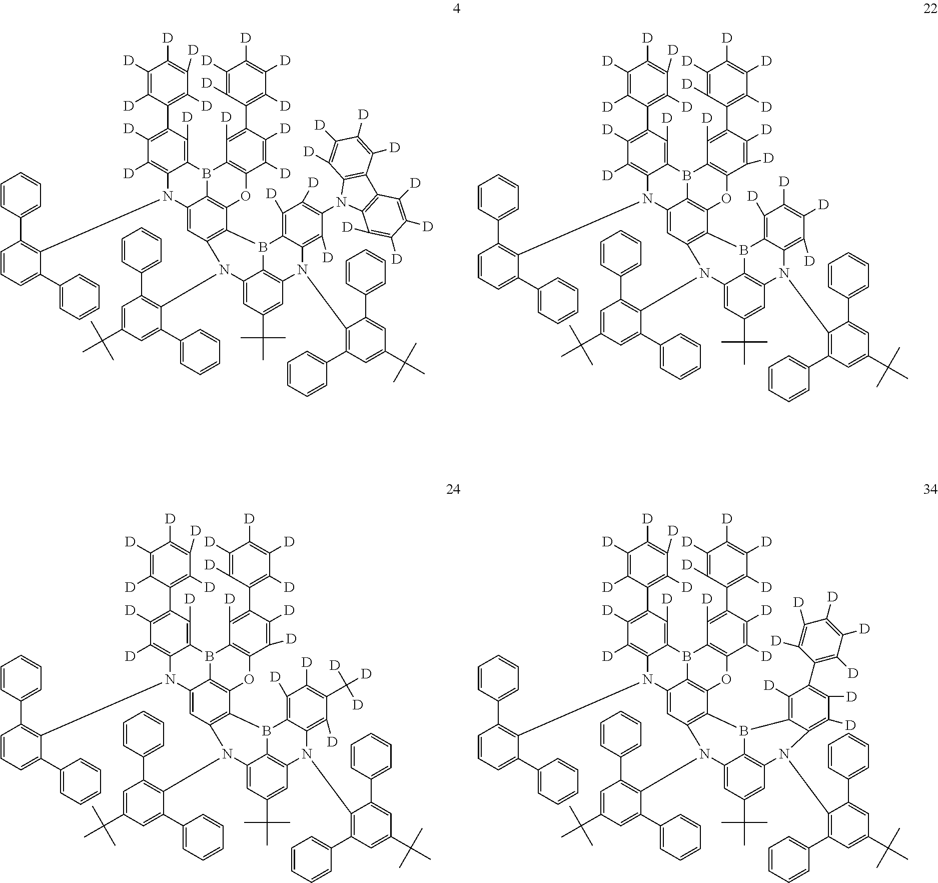

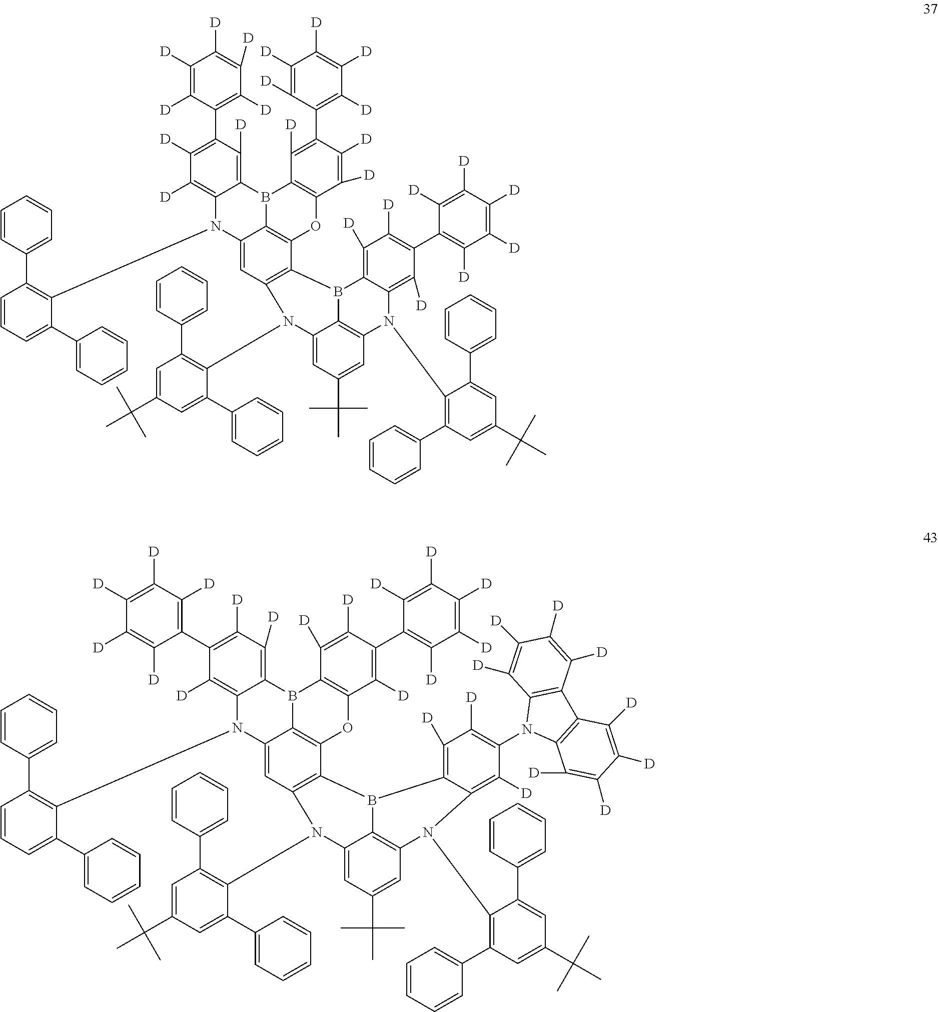

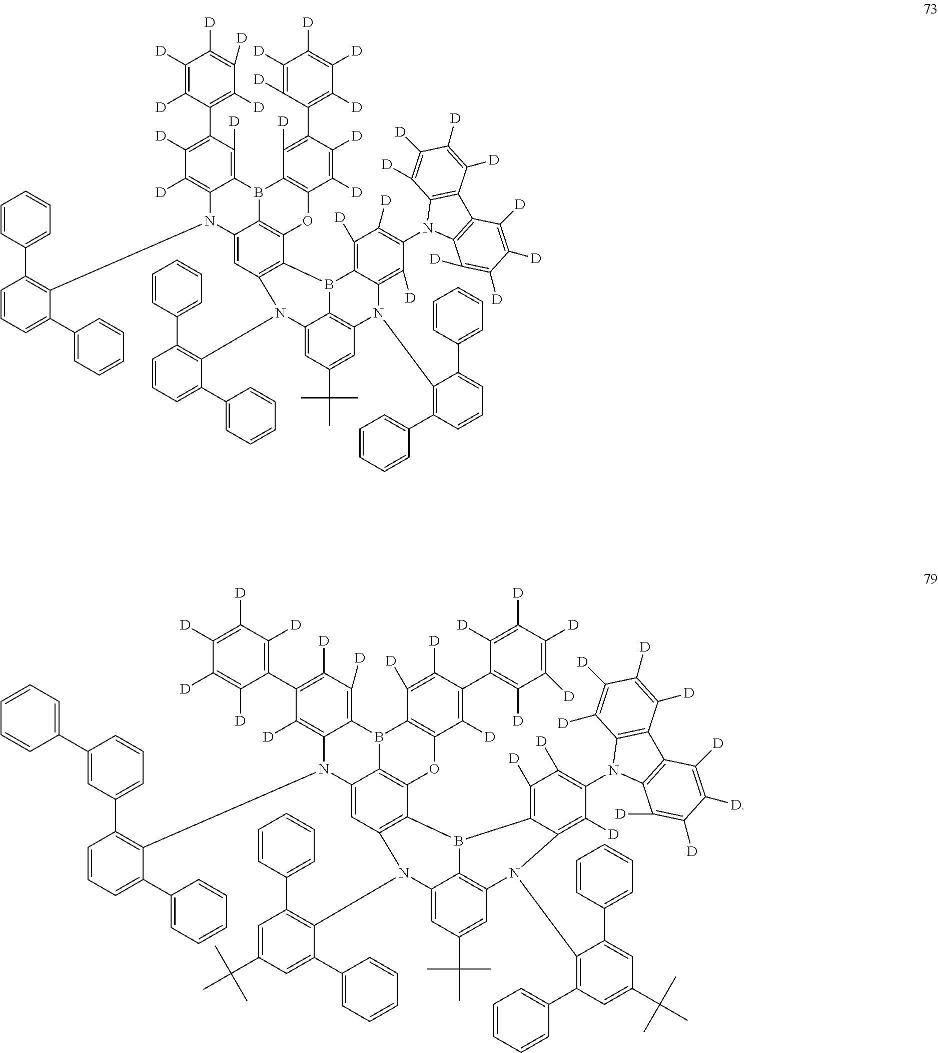

### Comparative Example Compounds

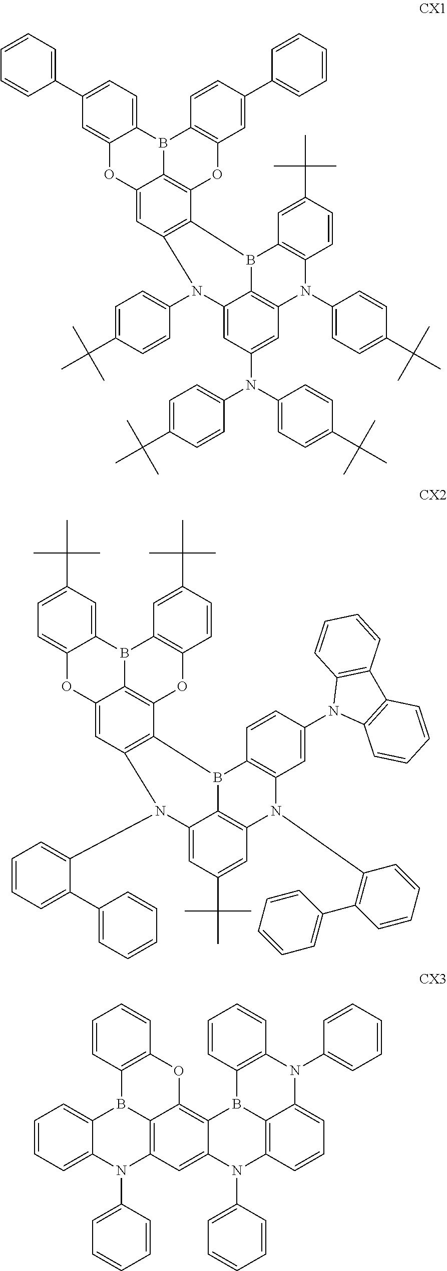

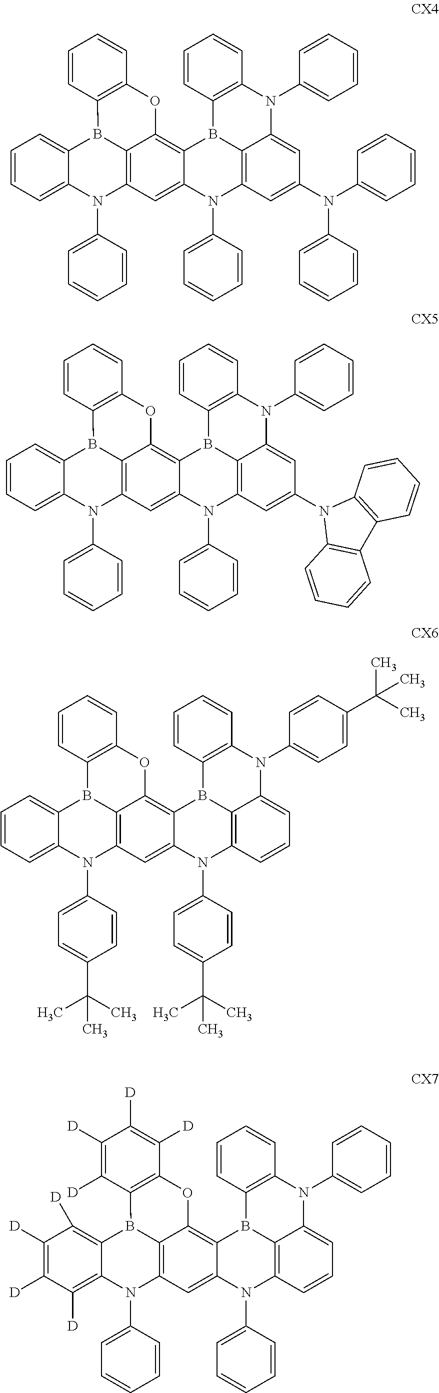

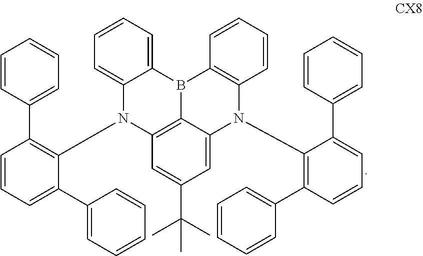 [SMILES: CC(C)(C)c1cc2c3c(c1)N(c1c(-c4ccccc4)cccc1-c1ccccc1)c1ccccc1B3c1ccccc1N2c1c(-c2ccccc2)cccc1-c1ccccc1]

In Table 1, λ_{Abs} represents an absorption wavelength measured in a solution, λₑₘᵢ represents an emission wavelength measured in a solution, and toluene is used as the solvent. Ts represents a temperature of purification by sublimation for synthesis of compound, and Stokes-shift represents a difference between a maximum energy absorption wavelength and a maximum energy emission wavelength. PLQY represents a measured photoluminescence quantum yield, and FWQM represents a full width at quarter maximum and is a width of an emission spectrum curve measured between those points on the y-axis which are a quarter of the maximum value.

In Table 1, λ_{Abs} was measured using UV-1800 UV/Visible scanning spectrophotometer made by SHIMADZU Corporation, equipped with a deuterium/tungsten-halogen light source and a silicon photodiode, and analyzed using Labsolution UV-Vis software. λₑₘᵢ and FWQM were measured using a fluoromax⁺ spectrometer made by HORIBA. Ltd, equipped with a xenon light source and a monochromator and analyzed using FluorEssence software. PLQY was measured using Quantaurus-QY Absolute PL quantum yield spectrometer made by Hamamatsu Corporation, equipped with a xenon light source, a monochromator, a photonic multichannel analyzer, and an integrating sphere and analyzed using PLQY measurement software.

Ts is a temperature at which 1 g of each compound is completely sublimated for about 3 hours in P100D-PC made by Physical vapor deposition Co., Ltd.

TABLE 1

| | λ_{Abs} | λₑₘᵢ | Ts | Stokes- | PLQY | FWQM |
|---|---|---|---|---|---|---|
| Dopant | (nm) | (nm) | (° C.) | shift | (%) | (nm) |
| Example 4 | 449 | 454 | 343 | 5 | 99 | 36 |
| Example 22 | 448 | 454 | 327 | 6 | 99 | 33 |
| Example 24 | 446 | 453 | 330 | 7 | 98 | 33 |
| Example 34 | 450 | 456 | 335 | 6 | 98 | 35 |
| Example 37 | 449 | 456 | 334 | 7 | 99 | 33 |
| Example 43 | 447 | 455 | 350 | 8 | 97 | 34 |
| Example 73 | 447 | 453 | 353 | 6 | 98 | 33 |
| Example 79 | 447 | 455 | 354 | 8 | 99 | 32 |
| Comparative | 435 | 449 | 383 | 14 | 54 | 47 |
| Example CX1 | | | | | | |
| Comparative | 440 | 453 | 376 | 13 | 48 | 44 |
| Example CX2 | | | | | | |
| Comparative | 430 | 445 | 350 | 15 | 84 | 40 |
| Example CX3 | | | | | | |
| Comparative | 425 | 441 | 355 | 16 | 76 | 39 |
| Example CX4 | | | | | | |
| Comparative | 430 | 442 | 367 | 12 | 66 | 43 |
| Example CX5 | | | | | | |
| Comparative | 431 | 446 | 360 | 15 | 77 | 40 |
| Example CX6 | | | | | | |
| Comparative | 430 | 445 | 350 | 15 | 84 | 40 |
| Example CX7 | | | | | | |
| Comparative | 440 | 455 | 330 | 15 | 89 | 36 |
| Example CX8 | | | | | | |

Referring to λ_{Abs} and λₑₘᵢ in Table 1, it can be seen that each of Comparative Example Compounds CX1 to CX3 and CX5 to CX8 and Compounds 4, 22, 24, 34, 37, 43, 73, and 79 emits light in a wavelength region in a range of about 430 nm to about 470 nm. It can be seen that each of Compounds 4, 22, 24, 34, 37, 43, 73, and 79 has a smaller Stokes-shift and/or FWQM than those of Comparative Example Compounds CX1 to CX8. It can be seen that Compounds 4, 22, 24, 34, 37, 43, 73, and 79 each emit light having a narrow full width at quarter maximum to thereby exhibit excellent color purity.

Referring to Table 1, it can be seen that each of Compounds 4, 22, 24, 34, 37, 43, 73, and 79 has a high PLQY, compared to Comparative Example Compounds CX1 to CX8. It can be seen that Compounds 4, 22, 24, 34, 37, 43, 73, and 79 exhibit excellent efficiency.

Compounds 4, 22, 24, 34, 37, 43, 73, and 79 are each a fused polycyclic compound according to an embodiment, and includes a core structure and three terphenyl moieties bonded to the core structure. The core structure includes nine rings fused together, with three nitrogen atoms, two boron atoms, and an oxygen atom as ring-forming atoms. Therefore, the fused polycyclic compound according to an embodiment emits light having improved color purity and exhibit excellent efficiency.

Each of Comparative Example Compounds CX1 and CX2 includes a core structure having nine rings fused together, but no terphenyl moiety is bonded to the core structure, which is different from the fused polycyclic compound according to an embodiment. In each of Comparative Example Compounds CX1 and CX2, the core structure includes two nitrogen atoms, two boron atoms, and two oxygen atoms, which differs from the fused polycyclic compound according to an embodiment in terms of the number of ring-forming nitrogen atoms and the number of ring-forming oxygen atoms. Therefore, Comparative Example Compound CX1 and CX2 exhibit relatively large Stokes-shift and FWQM and low efficiency.

Each of Comparative Example Compounds CX3 to CX7 includes a core structure having nine rings fused together, but no terphenyl moiety is bonded to the core structure, which differs from the fused polycyclic compound according to an embodiment. In the core structure of Comparative Example Compounds CX3 to CX7, an unsubstituted phenyl group or a phenyl group substituted with an alkyl group is bonded to a ring-forming nitrogen atom. Therefore, Comparative Example Compounds CX3 to CX7 exhibit relatively large Stokes-shift and FWQM and low efficiency.

Comparative Example Compound CX8 includes a terphenyl moiety but also includes a core structure having only five rings fused together, which differs from the fused polycyclic compound according to an embodiment. In Comparative Example Compound CX8, the core structure includes two nitrogen atoms and a boron atom as ring-forming atoms. Therefore, Comparative Example Compound CX8 exhibits relatively large Stokes-shift and low efficiency.

### 3. Manufacture and Evaluation of Light-Emitting Element

### (1) Manufacture of Light-Emitting Element

Light-emitting elements having an emission layer that includes an Example Compound or a Comparative Example Compound was manufactured by the following method. The light-emitting elements according to Examples 1 to 8 were respectively manufactured using, as a dopant material in the emission layer, Compounds 4, 22, 24, 34, 37, 43, 73, and 79, which are the Example Compounds. The light-emitting elements according to Comparative Examples 1 to 8 were respectively manufactured using, as a dopant material in the emission layer, Comparative Example Compounds CX1 to CX8.

For each of the light-emitting elements according to the Examples and the Comparative Examples, a glass substrate (made by Corning Co.), on which an ITO electrode of about 15 Ω/cm² (1,200 Å) was formed as a first electrode (anode), was cut to a size of about 50 mm×50 mm×0.7 mm, cleansed by ultrasonic waves using isopropyl alcohol and pure water for about five minutes each, and irradiated with ultraviolet rays for about 30 minutes and exposed to ozone to be cleansed. The glass substrate was mounted on a vacuum deposition apparatus.

NPD was deposited on the first electrode to form a hole injection layer having a thickness of about 300 Å, and Compound H-1-19 was deposited on the hole injection layer to form a hole transport layer having a thickness of about 200 Å. CzSi was deposited on the hole transport layer to form an electron blocking layer having a thickness of about 100 Å.

A mixed host, a sensitizer, and a dopant were co-deposited at a weight ratio of about 85:14:1 to form an emission layer having a thickness of about 200 Å. Materials as listed in Table 2 were used as the mixed host, the sensitizer, and the dopant. The mixed host includes a hole transporting host (Compound HT1) and an electron transporting host (Compound ETH66) at a weight ratio of 1:1. The dopant is an Example Compound or a Comparative Example Compound.

TSP01 was deposited on the emission layer to form a hole blocking layer having a thickness of about 200 Å. TPBi was deposited on the hole blocking layer to form an electron transport layer having a thickness of about 300 Å, and LiF was deposited on the electron transport layer to form an electron injection layer having a thickness of about 10 Å.

The second electrode was formed at a thickness of about 3,000 Å using Al, thereby forming a LiF/Al electrode. A capping layer having a thickness of about 700 Å was formed on the second electrode using Compound P4. Each layer was formed by a vacuum deposition method. The materials used for the manufacture of light-emitting elements according to Examples and Comparative Examples are disclosed below. The following materials were purified by sublimation from commercially available products.

### <Materials Used for Manufacture of Light-Emitting Element>

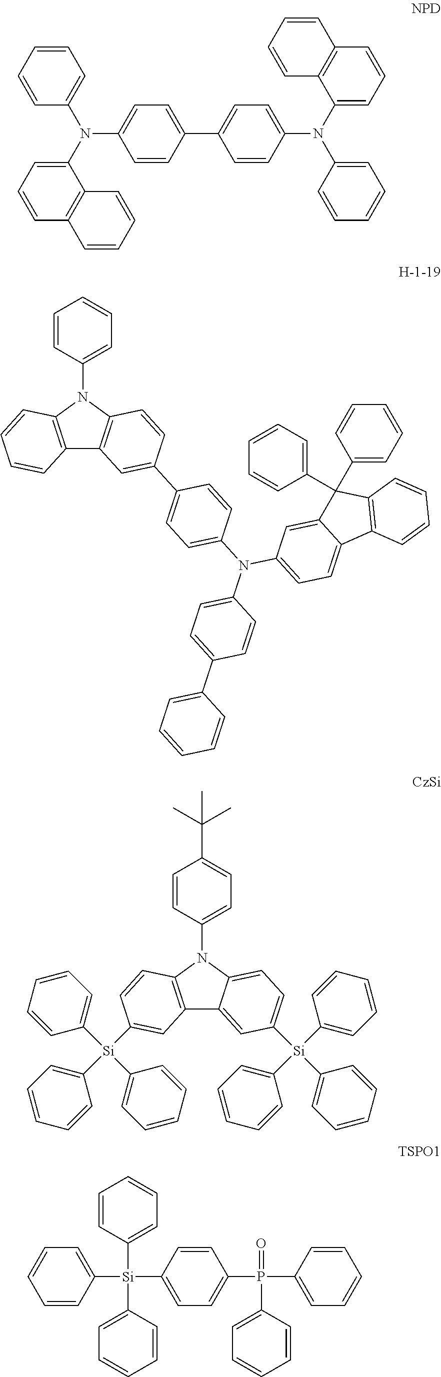

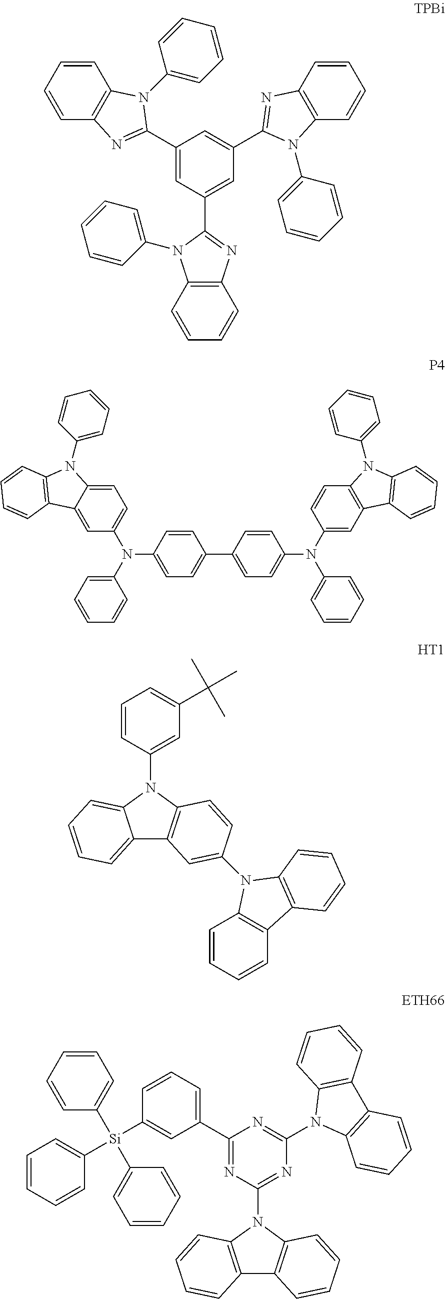 [SMILES: c1ccc(-n2c(-c3cc(-c4nc5ccccc5n4-c4ccccc4)cc(-c4nc5ccccc5n4-c4ccccc4)c3)nc3ccccc32)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC(C)(C)c1cccc(-n2c3ccccc3c3cc(-n4c5ccccc5c5ccccc54)ccc32)c1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1]

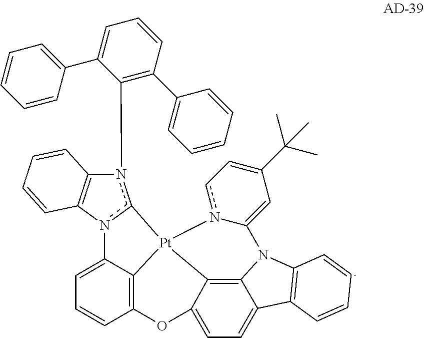

### (2) Evaluation of Light-Emitting Element

The light-emitting elements according to the Examples and Comparative Examples were evaluated and the evaluation results were listed in Table 2 below. Among the evaluation results listed in Table 2, the remaining results excluding an emission wavelength were measured using V7000 OLED IVL test system, (Polaronix) at a current density of about 10 mA/cm². The emission wavelength was measured using Keithley MU 236 and PR650 luminance meter at luminance of about 1,000 cd/m². Front efficiency (cd/A/y) represents a value of measured efficiency (cd/A) divided by the CIE y, which is chromaticity coordinate. For a lifespan (T95), the time taken for an initial luminance to decrease from 100% to 95% was measured and calculated relative to the value of the light-emitting element according to Comparative Example 1.

TABLE 2

| | | | | Driving | Front | Emission | | |
|---|---|---|---|---|---|---|---|---|
| | Host mixture | | | voltage | efficiency | efficiency | Lifespan | |
| | (HT/ET) | Sensitizer | Dopant | (V) | (cd/A/y) | (nm) | (T95) | CIE y |
| Example 1 | HT1/ETH66 | AD-39 | Compound 4 | 3.8 | 530 | 455 | 10.7 | 0.045 |
| Example 2 | HT1/ETH66 | AD-39 | Compound 22 | 3.9 | 500 | 455 | 8.5 | 0.045 |
| Example 3 | HT1/ETH66 | AD-39 | Compound 24 | 3.9 | 480 | 454 | 7.6 | 0.040 |
| Example 4 | HT1/ETH66 | AD-39 | Compound 34 | 3.7 | 525 | 457 | 16.5 | 0.045 |
| Example 5 | HT1/ETH66 | AD-39 | Compound 37 | 3.8 | 520 | 457 | 15.0 | 0.044 |
| Example 6 | HT1/ETH66 | AD-39 | Compound 43 | 3.6 | 530 | 456 | 13.5 | 0.042 |
| Example 7 | HT1/ETH66 | AD-39 | Compound 73 | 3.7 | 500 | 454 | 9.3 | 0.044 |
| Example 8 | HT1/ETH66 | AD-39 | Compound 79 | 3.6 | 550 | 456 | 14.2 | 0.045 |
| Comparative | HT1/ETH66 | AD-39 | Comparative | 4.3 | 380 | 454 | 1 | 0.047 |
| Example 1 | | | Example | | | | | |
| | | | Compound CX1 | | | | | |
| Comparative | HT1/ETH66 | AD-39 | Comparative | 4.1 | 350 | 457 | 1.3 | 0.050 |
| Example 2 | | | Example | | | | | |
| | | | Compound CX2 | | | | | |
| Comparative | HT1/ETH66 | AD-39 | Comparative | 4.3 | 300 | 450 | 0.07 | 0.040 |
| Example 3 | | | Example | | | | | |
| | | | Compound CX3 | | | | | |
| Comparative | HT1/ETH66 | AD-39 | Comparative | 4.6 | 350 | 445 | 0.05 | 0.033 |
| Example 4 | | | Example | | | | | |
| | | | Compound CX4 | | | | | |
| Comparative | HT1/ETH66 | AD-39 | Comparative | 4.1 | 400 | 448 | 0.7 | 0.037 |
| Example 5 | | | Example | | | | | |
| | | | Compound CX5 | | | | | |
| Comparative | HT1/ETH66 | AD-39 | Comparative | 4.3 | 300 | 452 | 0.3 | 0.045 |
| Example 6 | | | Example | | | | | |
| | | | Compound CX6 | | | | | |
| Comparative | HT1/ETH66 | AD-39 | Comparative | 4.3 | 310 | 453 | 0.1 | 0.047 |
| Example 7 | | | Example | | | | | |
| | | | Compound CX7 | | | | | |
| Comparative | HT1/ETH66 | AD-39 | Comparative | 4.9 | 290 | 460 | 0.4 | 0.063 |
| Example 8 | | | Example | | | | | |
| | | | Compound CX8 | | | | | |

Referring to Table 2, it can be seen that each of the light-emitting elements according to the Comparative Examples and the Examples emits light in a wavelength region in a range of about 430 nm to about 470 nm. It can be seen that the light-emitting elements according to Examples 1 to 8 have a low driving voltage, high efficiency, and a long lifespan, as compared to the light-emitting elements according to Comparative Examples 1 to 8. The light-emitting elements according to Examples 1 to 8 respectively include Compounds 4, 22, 24, 34, 37, 43, 73, and 79, wherein Compounds 4, 22, 24, 34, 37, 43, 73, and 79 are each a fused polycyclic compound according to an embodiment.

Compounds 4, 22, 24, 34, 37, 43, 73, and 79 are fused polycyclic compounds according to embodiments and each include a core structure and three terphenyl moieties bonded to the core structure. The core structure includes nine rings fused together, with three nitrogen atoms, two boron atoms, and an oxygen atom as ring-forming atoms. Therefore, it can be seen that the light-emitting element that includes the fused polycyclic compound according to an embodiment emits light having improved color purity and exhibits properties of a low driving voltage, high efficiency, and a long lifespan.

The light-emitting element according to Comparative Example 1 includes Comparative Example Compound CX1, and the light-emitting element according to Comparative Example 2 includes Comparative Example Compound CX2. Comparative Example Compounds CX1 and CX2 include a core structure having nine rings fused together, but no terphenyl moiety is bonded to the core structure, which differs from the fused polycyclic compound according to an embodiment. The core structures of Comparative Example Compounds CX1 and CX2 include two nitrogen atoms, two boron atoms, and two oxygen atoms as ring-forming atoms, which differ from the fused polycyclic compound according to an embodiment in terms of the number of nitrogen atoms and the number of oxygen atoms. Therefore, the light-emitting elements according to Comparative Examples 1 and 2 exhibit a high driving voltage, low efficiency, and a short lifespan.

The light-emitting element according to Comparative Examples 3 to 7 respectively include Comparative Example Compounds CX3 to CX7. Comparative Example Compounds CX3 to CX7 each includes a core structure having nine rings fused together, but no terphenyl moiety is bonded to the core structure, which differs from the fused polycyclic compound according to an embodiment. In the core structure of Comparative Example Compounds CX3 to CX7, an unsubstituted phenyl group or a phenyl group substituted with an alkyl group is bonded to a ring-forming nitrogen atom. Therefore, the light-emitting elements according to Comparative Examples 3 to 7 exhibit a high driving voltage, low efficiency, and a short lifespan.

The light-emitting element according to Comparative Example 8 includes Comparative Example Compound CX8. Comparative Example Compound CX8 includes a terphenyl moiety but includes a core structure having only five rings fused together, which differs from the fused polycyclic compound according to an embodiment. The core structure in Comparative Example Compound CX8 includes two nitrogen atoms and a boron atom as ring forming atoms. Therefore, the light-emitting element according to Comparative Example 8 exhibits a high driving voltage, low efficiency, and a short lifespan.

A display device according to an embodiment may include a light-emitting element. In the light-emitting element according to an embodiment, an emission layer may include the fused polycyclic compound according to an embodiment, represented by Formula 1. The fused polycyclic compound according to an embodiment may include a core structure and three terphenyl moieties bonded to the core structure. The core structure may include nine rings fused together, with three nitrogen atoms, two boron atoms, and an oxygen atom as ring-forming atoms. The three terphenyl moieties may be bonded to three nitrogen atoms, respectively. The fused polycyclic compound according to an embodiment including three terphenyl moieties may exhibit excellent material stability. The light-emitting element that includes the fused polycyclic compound may emit light having improved color purity and exhibit long lifespan properties.

The light-emitting element according to an embodiment and the display device including the same may exhibit improved color purity and long lifespan properties by including the fused polycyclic compound according to an embodiment.

The fused polycyclic compound according to an embodiment may contribute to improvements in color purity and long lifespan of the light-emitting element.

Embodiments have been disclosed herein, and although terms are employed, they are used and are to be interpreted in a generic and descriptive sense only and not for the purposes of limitation. In some instances, as would be apparent to one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

What is claimed is:

1. A light-emitting element comprising:
a first electrode;
a second electrode disposed on the first electrode; and
an emission layer disposed between the first electrode and the second electrode, wherein
the emission layer includes a first compound represented by Formula 1: 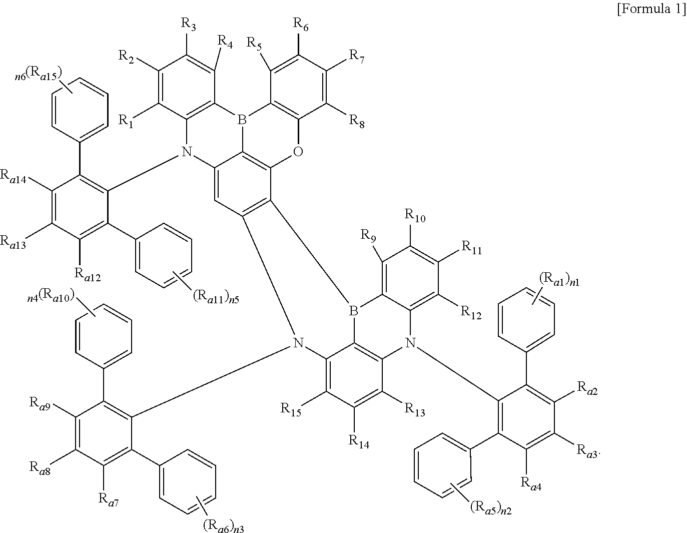
wherein in Formula 1,
n1 to n6 are each independently an integer from 0 to 5, and
R₁ to R₁₅ and Rₐ₁ to Rₐ₁₅ are each independently a hydrogen atom, a deuterium atom, a halogen atom, a cyano group, a nitro group, a substituted or unsubstituted silyl group, a substituted or unsubstituted amine group, a substituted or unsubstituted oxy group, a substituted or unsubstituted thio group, a substituted or unsubstituted selenium group, a substituted or unsubstituted alkyl group having 1 to 60 carbons, a substituted or unsubstituted cycloalkyl group having 3 to 60 carbons, a substituted or unsubstituted alkenyl group having 2 to 60 carbons, a substituted or unsubstituted hydrocarbon ring group having 6 to 60 ring-forming carbons, or a substituted or unsubstituted heterocyclic group having 2 to 60 ring-forming carbons, or bonded to an adjacent group to form a ring.

2. The light-emitting element of claim 1, wherein the emission layer further comprises at least one of a second compound represented by Formula HT-1, a third compound represented by Formula ET-1, and a fourth compound represented by Formula D-1: 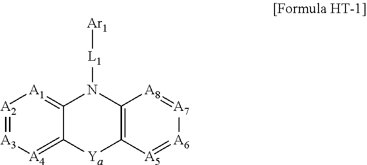
wherein in Formula HT-1,
A₁ to A₈ are each independently N or C(R₅₁),
L₁ is a direct linkage, a substituted or unsubstituted arylene group having 6 to 30 ring-forming carbons, or a substituted or unsubstituted heteroarylene group having 2 to 30 ring-forming carbons,
Yₐ is a direct linkage, C(R₅₂)(R₅₃), or Si(R₅₄)(R₅₅),
Ar₁ is a substituted or unsubstituted aryl group having 6 to 30 ring-forming carbons or a substituted or unsubstituted heteroaryl group having 2 to 30 ring-forming carbons, and
R₅₁ to R₅₅ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbons, a substituted or unsubstituted alkenyl group having 2 to 20 carbons, a substituted or unsubstituted aryl group having 6 to 60 ring-forming carbons, or a substituted or unsubstituted heteroaryl group having 2 to 60 ring-forming carbons, or bonded to an adjacent group to form a ring; 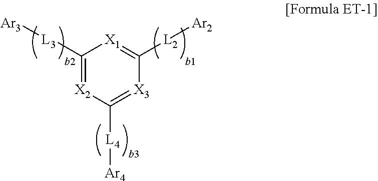
wherein in Formula ET-1,
at least one of X₁ to X₃ is N,
the remainder of X₁ to X₃ are each independently C(R_{b}),
R₅₆ is a hydrogen atom, a deuterium atom, a substituted or unsubstituted alkyl group having 1 to 20 carbons, a substituted or unsubstituted aryl group having 6 to 60 ring-forming carbons, or a substituted or unsubstituted heteroaryl group having 2 to 60 ring-forming carbons,
b1 to b3 are each independently an integer from 0 to 10,
Ar₂ to Ar₄ are each independently a hydrogen atom, a deuterium atom, a substituted or unsubstituted alkyl group having 1 to 20 carbons, a substituted or unsubstituted aryl group having 6 to 30 ring-forming carbons, or a substituted or unsubstituted heteroaryl group having 2 to 30 ring-forming carbons, and
L₂ to L₄ are each independently a direct linkage, a substituted or unsubstituted arylene group having 6 to 30 ring-forming carbons, or a substituted or unsubstituted heteroarylene group having 2 to 30 ring-forming carbons; 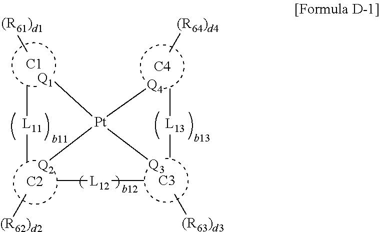
wherein in Formula D-1,
Q₁ to Q₄ are each independently C or N,
C1 to C4 are each independently a substituted or unsubstituted hydrocarbon ring having 5 to 30 ring-forming carbons, a substituted or unsubstituted aryl group having 6 to 30 ring-forming carbons, or a substituted or unsubstituted heterocycle having 2 to 30 ring-forming carbons,
L₁₁ to L₁₃ are each independently a direct linkage, 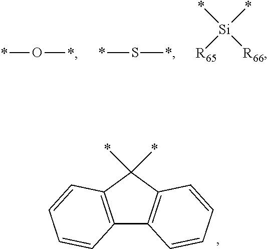
a substituted or unsubstituted alkylene group having 1 to 20 carbons, a substituted or unsubstituted arylene group having 6 to 30 ring-forming carbons, or a substituted or unsubstituted heteroarylene group having 2 to 30 ring-forming carbons,
b11 to b13 are each independently 0 or 1,
R₆₁ to R₆₆ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbons, a substituted or unsubstituted alkenyl group having 2 to 20 carbons, a substituted or unsubstituted aryl group having 6 to 60 ring-forming carbons, or a substituted or unsubstituted heteroaryl group having 2 to 60 ring-forming carbons, and
d1 to d4 are each independently an integer from 0 to 4.

3. The light-emitting element of claim 1, wherein the first compound is represented by one of Formula 1-A1 to Formula 1-A3: 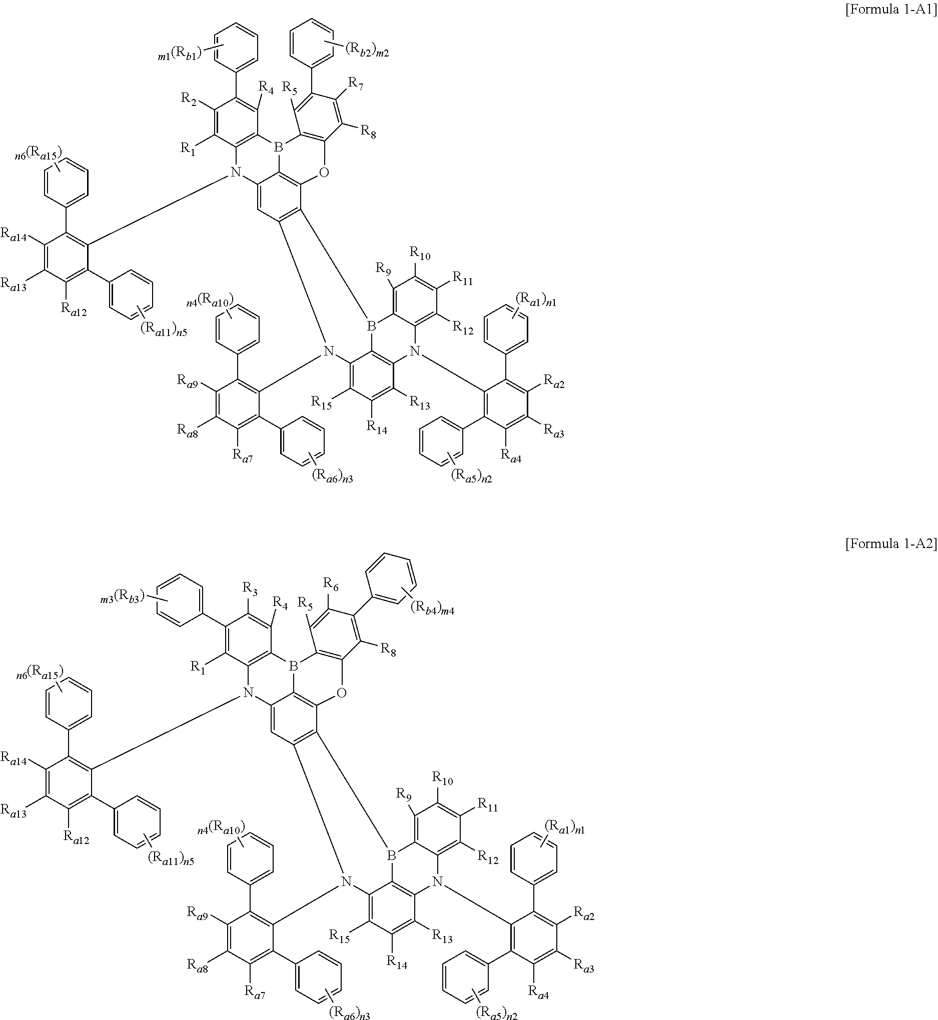 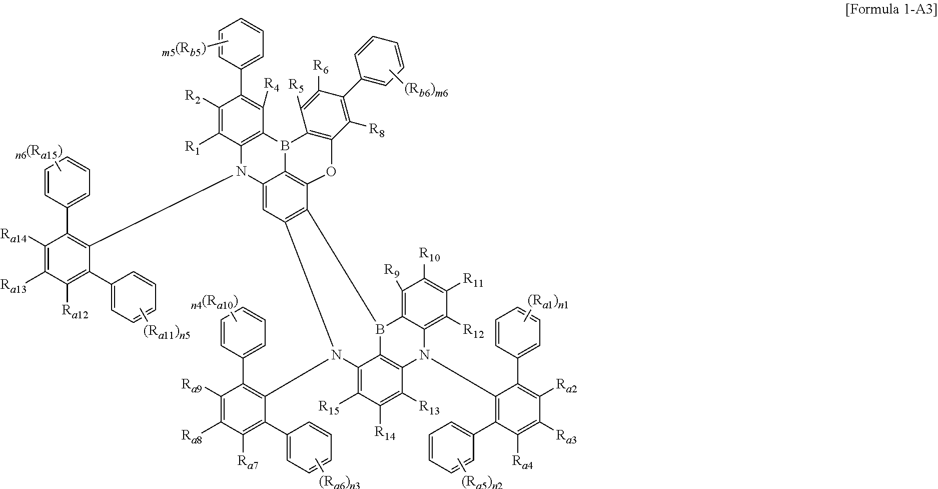
wherein in Formula 1-A1 to Formula 1-A3,
m1 to m6 are each independently an integer from 0 to 5,
R_{b1} to R_{b6} are each independently a hydrogen atom, a deuterium atom, a substituted or unsubstituted oxy group, a substituted or unsubstituted thio group, a substituted or unsubstituted alkyl group having 1 to 30 carbons, or a substituted or unsubstituted aryl group having 6 to 30 ring-forming carbons, or bonded to an adjacent group to form a ring, and
n1 to n6, R₁ to R₁₅, and Rₐ₁ to Rₐ₁₅ are the same as defined in Formula 1.

4. The light-emitting element of claim 1, wherein the first compound is represented by one of Formula 1-A4 to Formula 1-A6: 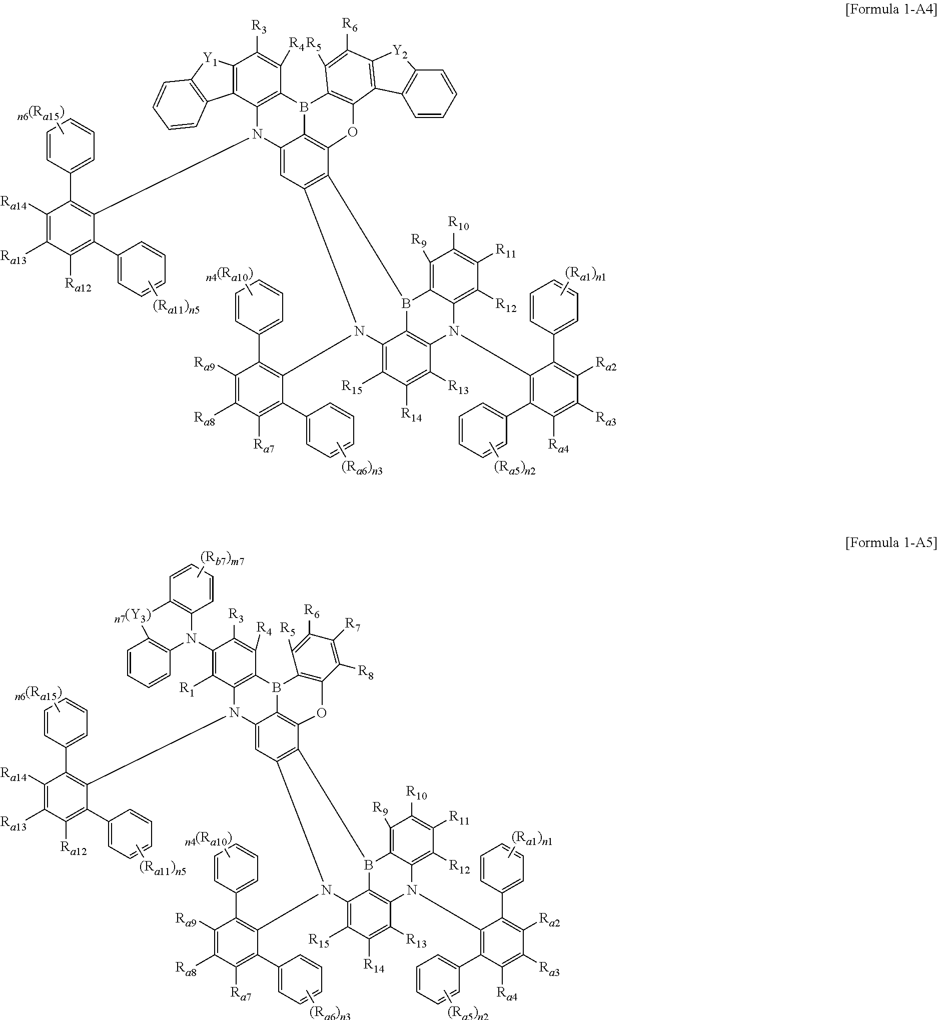 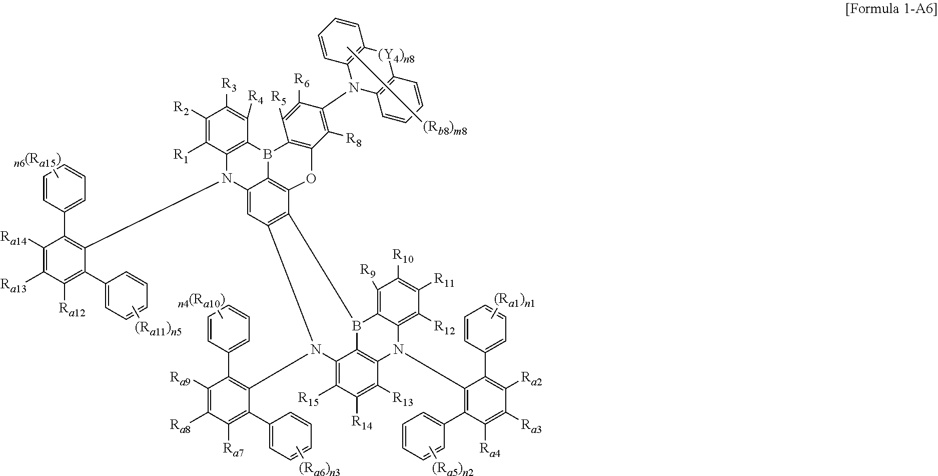
wherein in Formula 1-A4,
Y₁ and Y₂ are each independently N(R₁₆), O, or S, and
R₁₆ is a substituted or unsubstituted aryl group having 6 to 30 ring-forming carbons,
wherein in Formula 1-A5,
n7 is 0 or 1,
Y₃ is a direct linkage,
m7 is an integer from 0 to 10, and
R_{b7} is a hydrogen atom or a deuterium atom,
wherein in Formula 1-A6,
n8 is 0 or 1,
Y₄ is a direct linkage,
m8 is an integer from 0 to 10, and
R_{b8} is a hydrogen atom or a deuterium atom, and
wherein in Formula 1-A4 to Formula 1-A6,
n1 to n6, R₁ to R₁₅, and Rₐ₁ to Rₐ₁₅ are the same as defined in Formula 1.

5. The light-emitting element of claim 1, wherein the first compound is represented by Formula 1-B1: 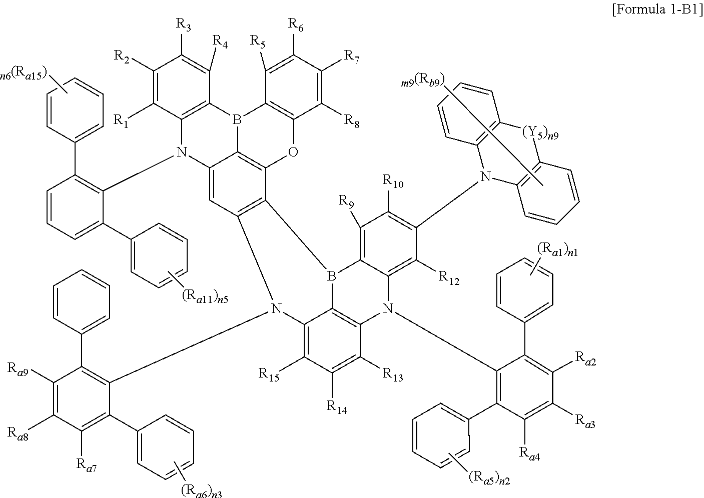
wherein in Formula 1-B1,
n9 is 0 or 1,
Y₅ is a direct linkage,
m9 is an integer from 0 to 10,
R_{b9} is a hydrogen atom, a deuterium atom, a substituted or unsubstituted oxy group, a substituted or unsubstituted thio group, a substituted or unsubstituted selenium group, a substituted or unsubstituted alkyl group having 1 to 30 carbons, a substituted or unsubstituted alkenyl group having 2 to 30 carbons, a substituted or unsubstituted aryl group having 6 to 30 ring-forming carbons, or a substituted or unsubstituted heteroaryl group having 2 to 30 ring-forming carbons, or bonded to an adjacent group to form a ring, and
n1 to n6, R₁ to R₁₀, R₁₂ to R₁₅, and Rₐ₁ to Rₐ₁₅ are the same as defined in Formula 1.

6. The light-emitting element of claim 1, wherein in Formula 1, R₁₀ and R₁₁ are each independently a hydrogen atom, a deuterium atom, or a group represented by one of Formulas R-1 to R-33: 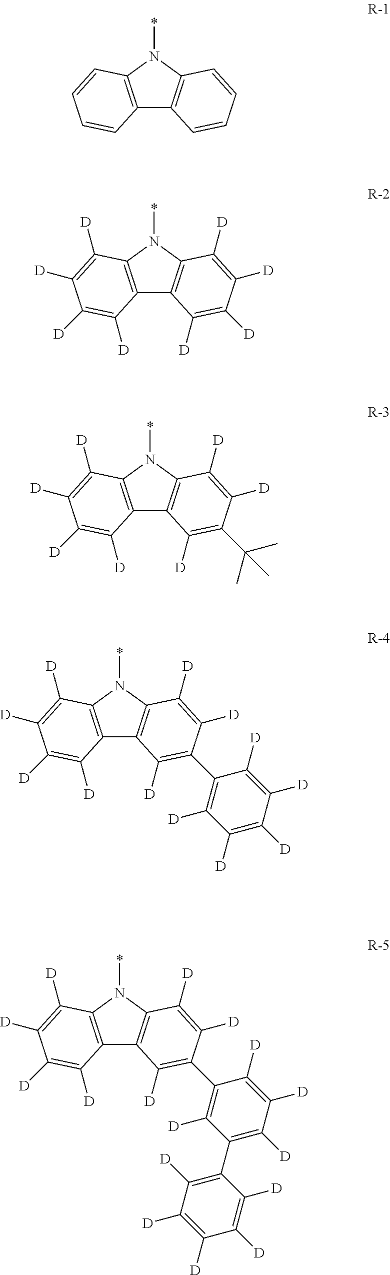 [SMILES: *n1c2ccccc2c2ccccc21 ; *n1c2c([2H])c([2H])c([2H])c([2H])c2c2c([2H])c([2H])c([2H])c([2H])c21 ; *n1c2c([2H])c([2H])c([2H])c([2H])c2c2c([2H])c(C(C)(C)C)c([2H])c([2H])c21 ; *n1c2c([2H])c([2H])c([2H])c([2H])c2c2c([2H])c(-c3c([2H])c([2H])c([2H])c([2H])c3[2H])c([2H])c([2H])c21 ; *n1c2c([2H])c([2H])c([2H])c([2H])c2c2c([2H])c(-c3c([2H])c([2H])c([2H])c(-c4c([2H])c([2H])c([2H])c([2H])c4[2H])c3[2H])c([2H])c([2H])c21] 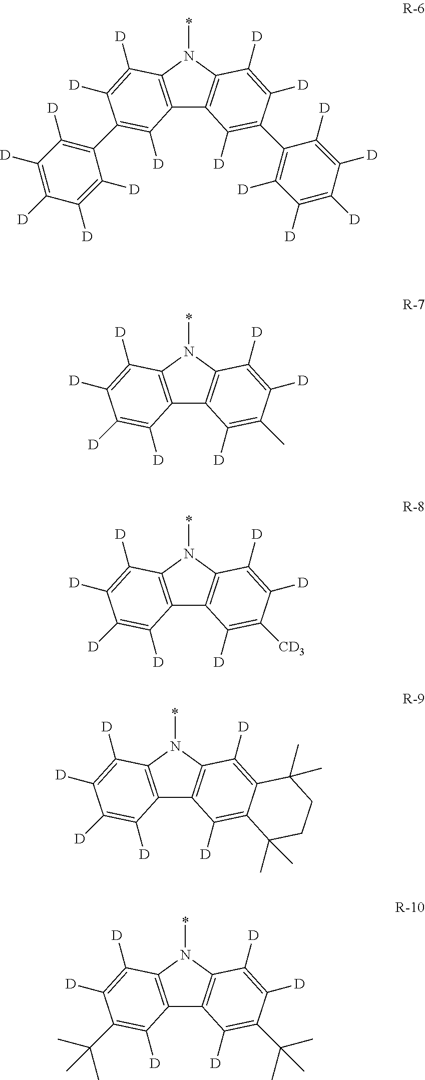 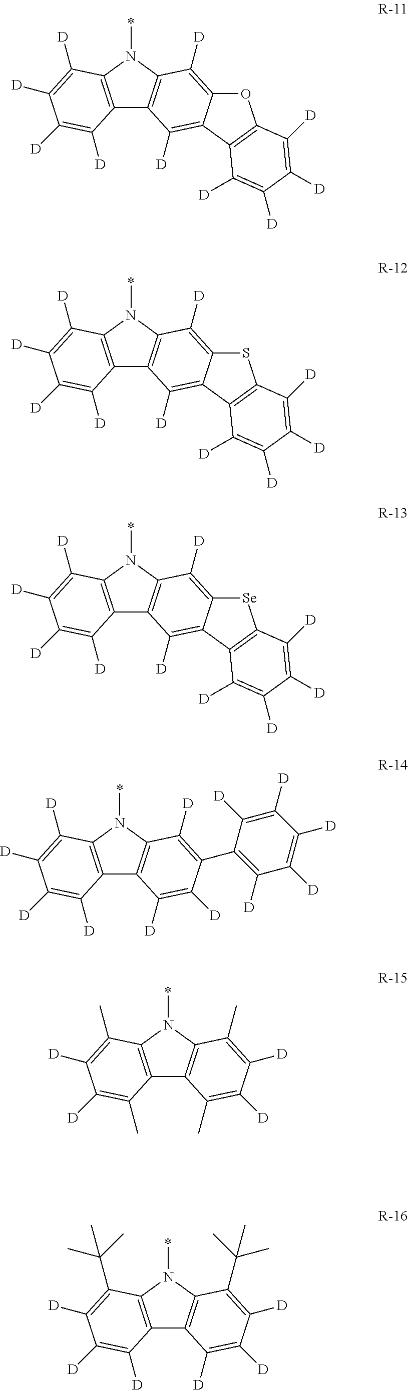 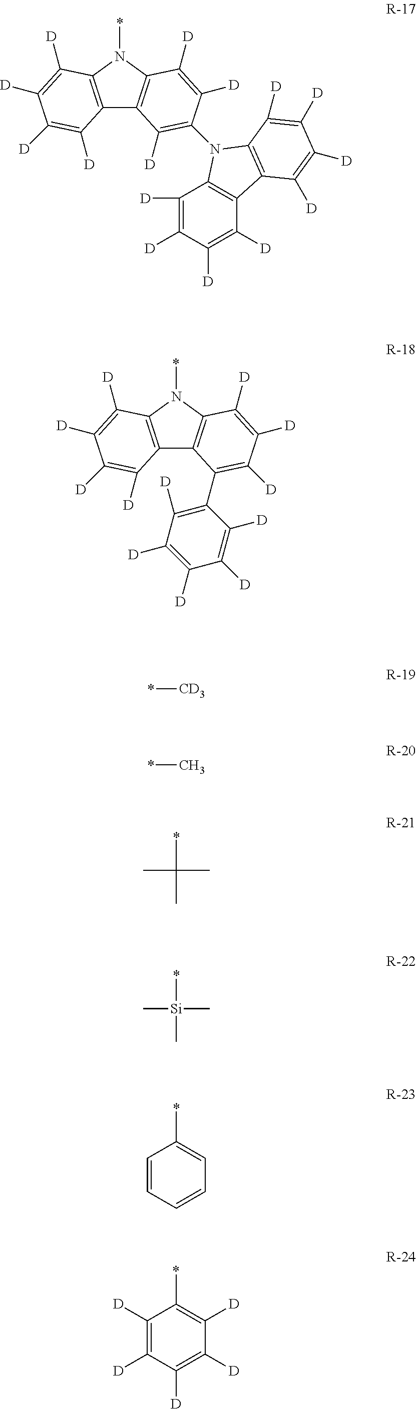 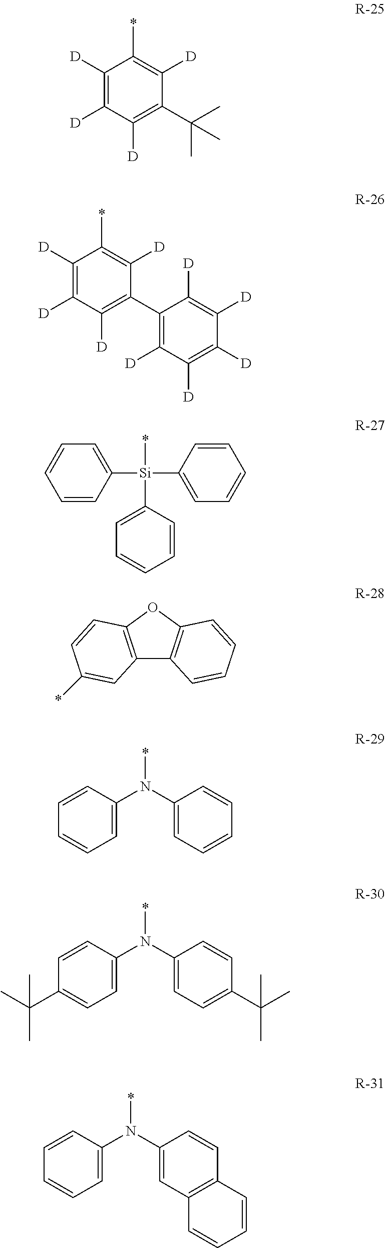 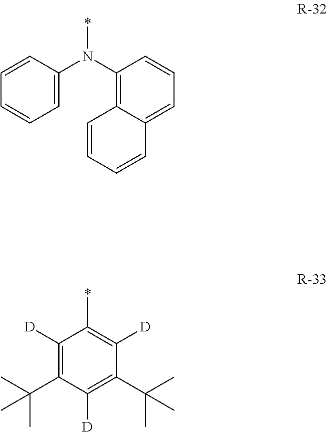 [SMILES: *N(c1ccccc1)c1cccc2ccccc12 ; *c1c([2H])c(C(C)(C)C)c([2H])c(C(C)(C)C)c1[2H]]
wherein in Formulas R-2 to R-19, R-24 to R-26, and R-33,
D is a deuterium atom.

7. The light-emitting element of claim 1, wherein in Formula 1, a first terphenyl moiety that includes Rₐ₁ to Rₐ₅, a second terphenyl moiety that includes Rₐ₆ to Rₐ₁₀, and a third terphenyl moiety that includes Rₐ₁₁ to Rₐ₁₅ are each independently a moiety represented by one of Formulas RA-1 to RA-8:

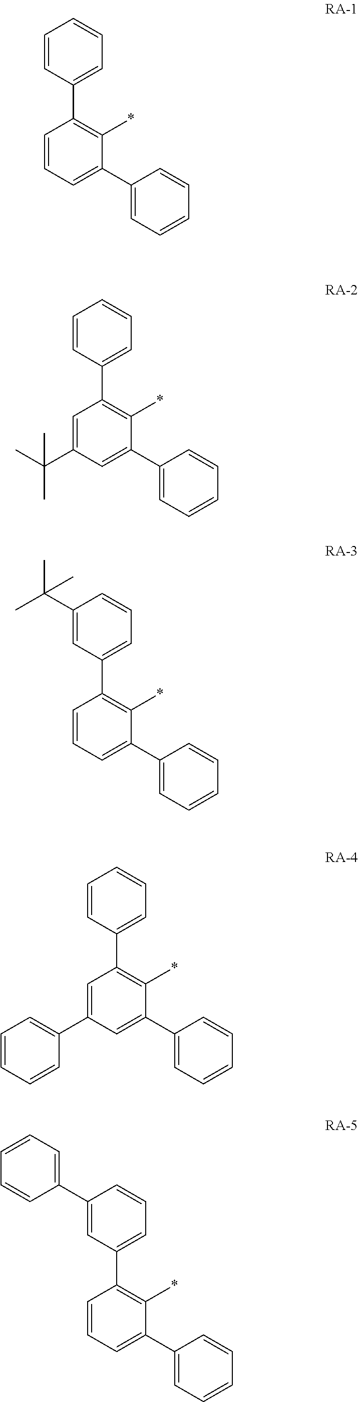 [SMILES: *c1c(-c2ccccc2)cccc1-c1ccccc1 ; *c1c(-c2ccccc2)cc(C(C)(C)C)cc1-c1ccccc1 ; *c1c(-c2ccccc2)cccc1-c1cccc(C(C)(C)C)c1 ; *c1c(-c2ccccc2)cc(-c2ccccc2)cc1-c1ccccc1 ; *c1c(-c2ccccc2)cccc1-c1cccc(-c2ccccc2)c1]

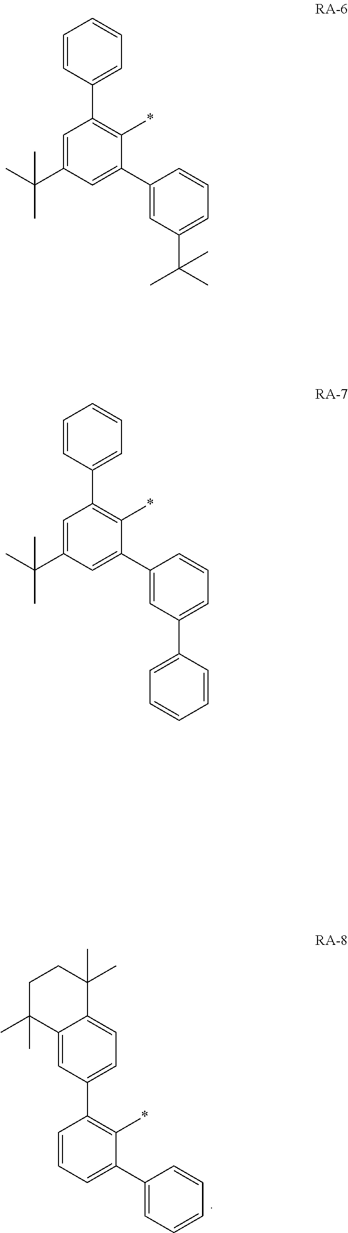

8. The light-emitting element of claim 1, wherein in Formula 1, R₁₃ to R₁₅ are each independently a hydrogen atom, a deuterium atom, a substituted or unsubstituted diphenylamine group, a substituted or unsubstituted methyl group, a substituted or unsubstituted t-butyl group, a substituted or unsubstituted phenyl group, or a substituted or unsubstituted carbazole group.

9. The light-emitting element of claim 1, wherein the first compound includes at least one compound selected from Compound Group 1: 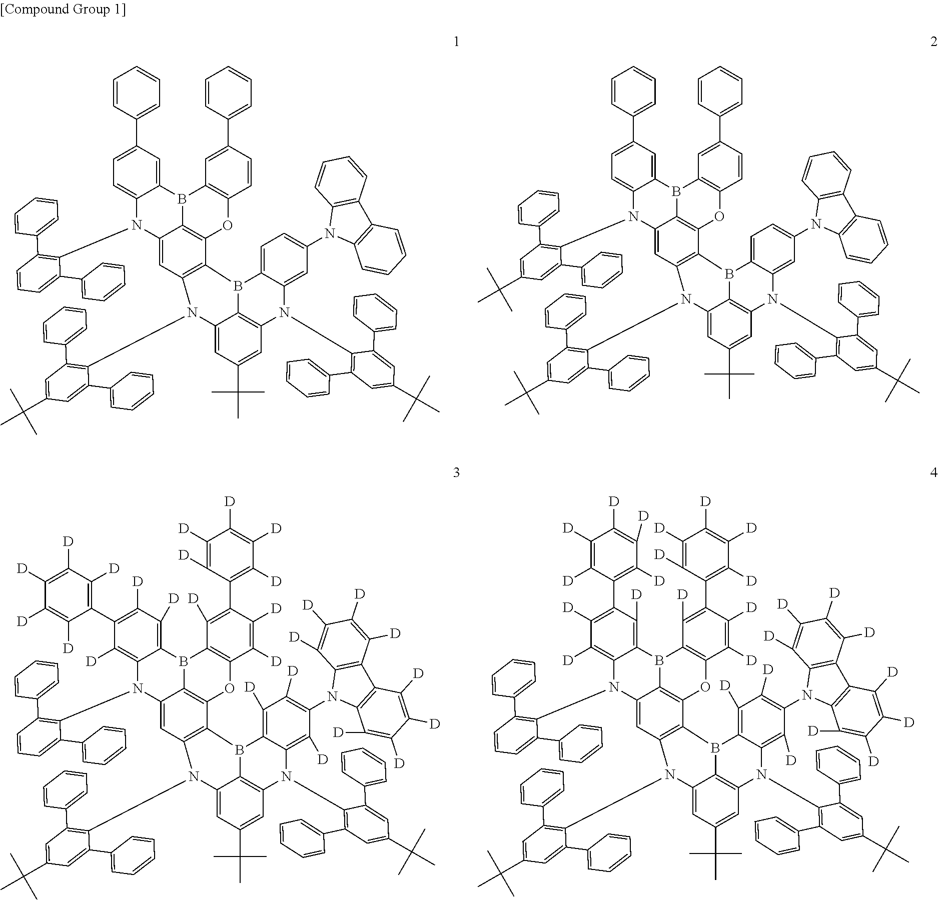 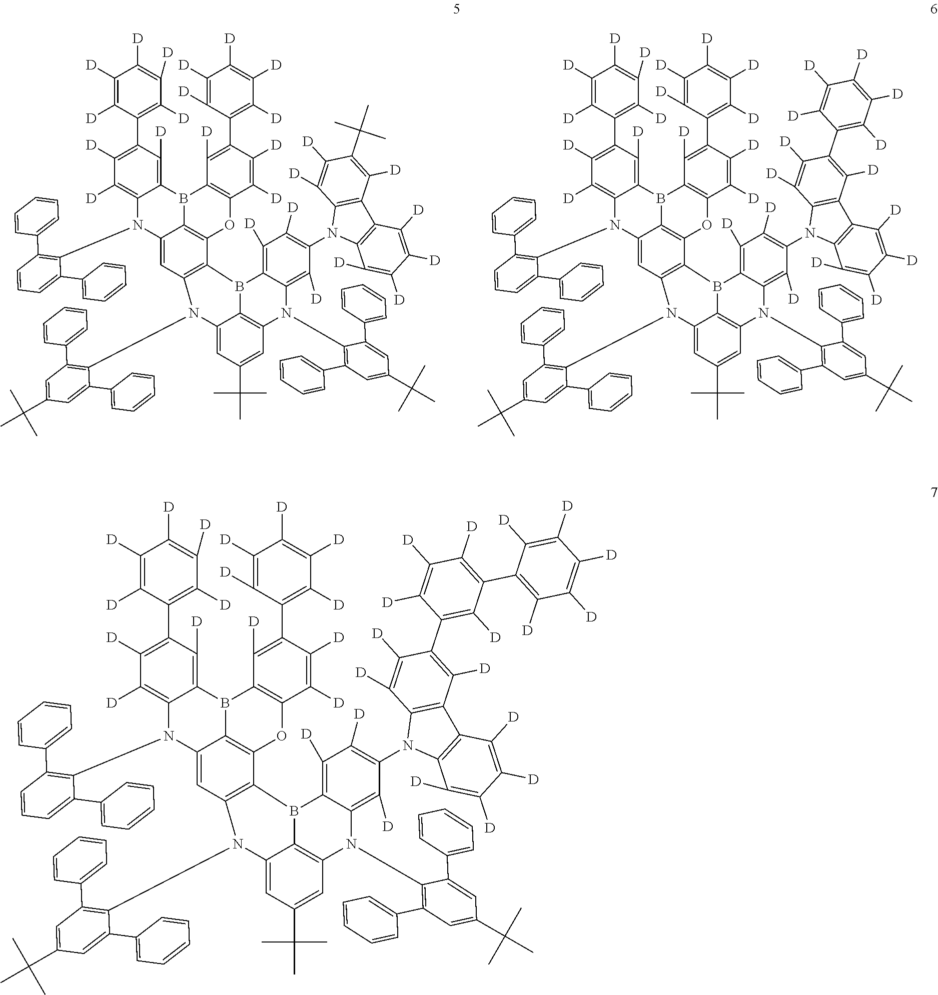 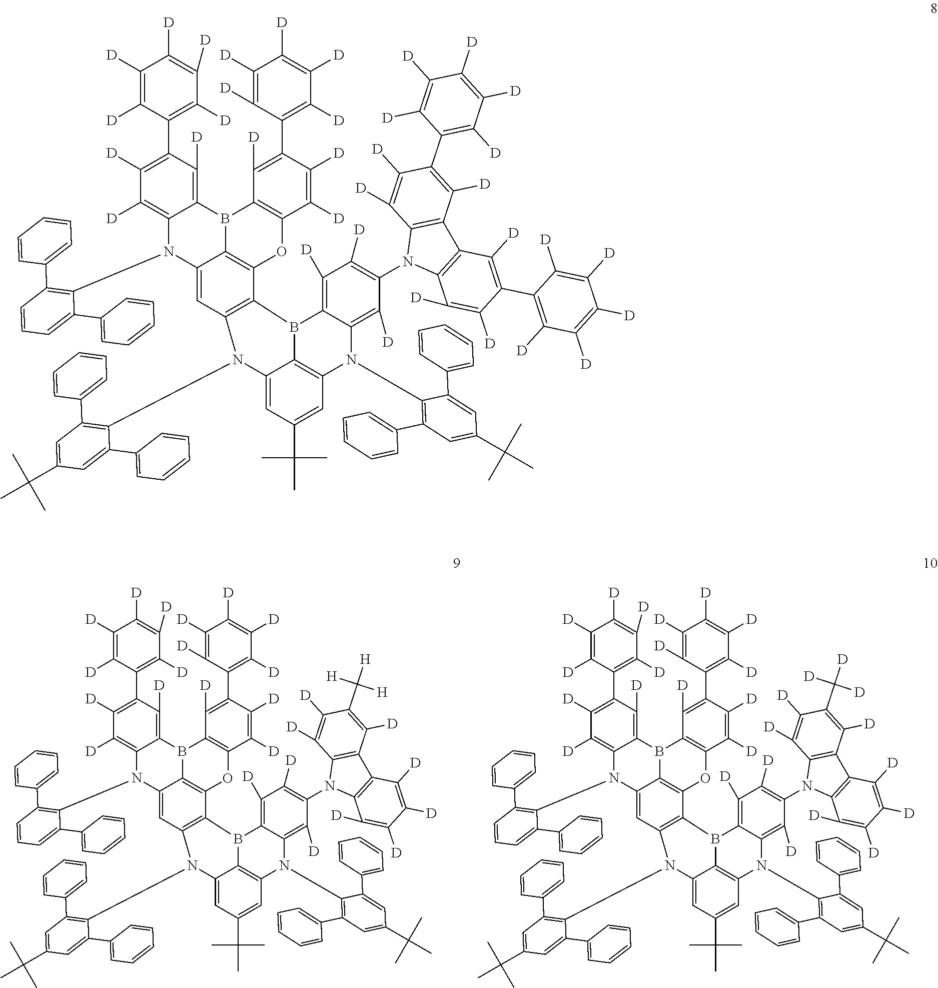 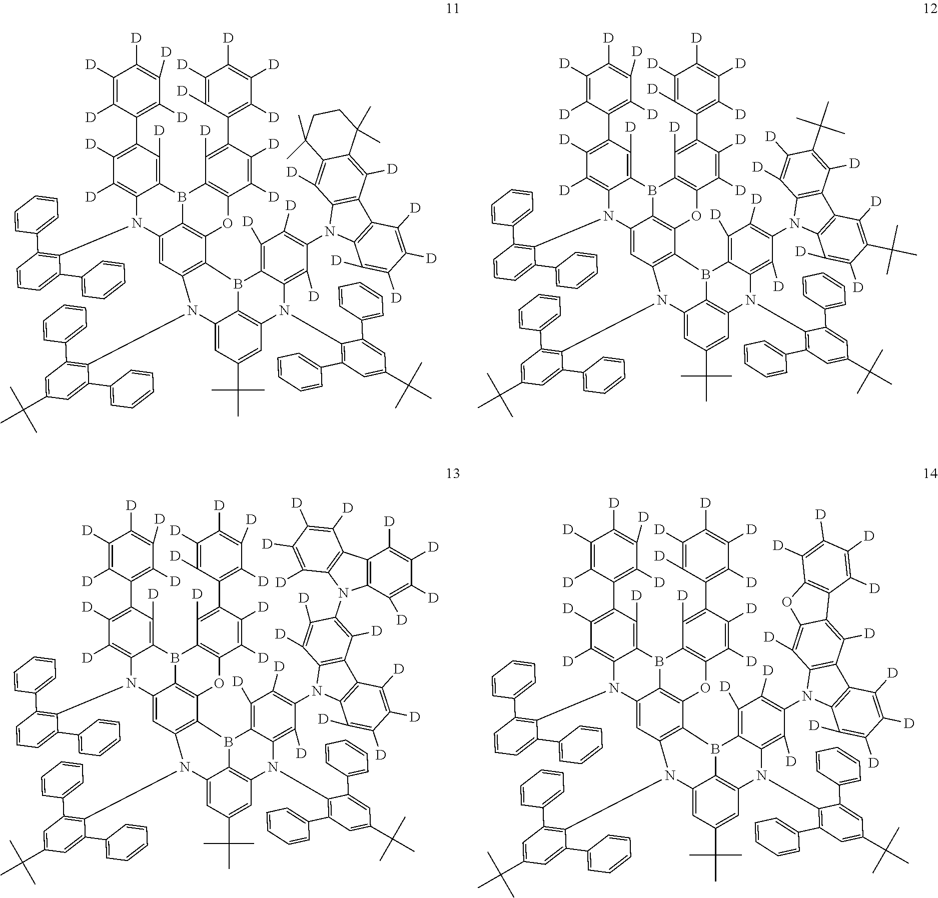 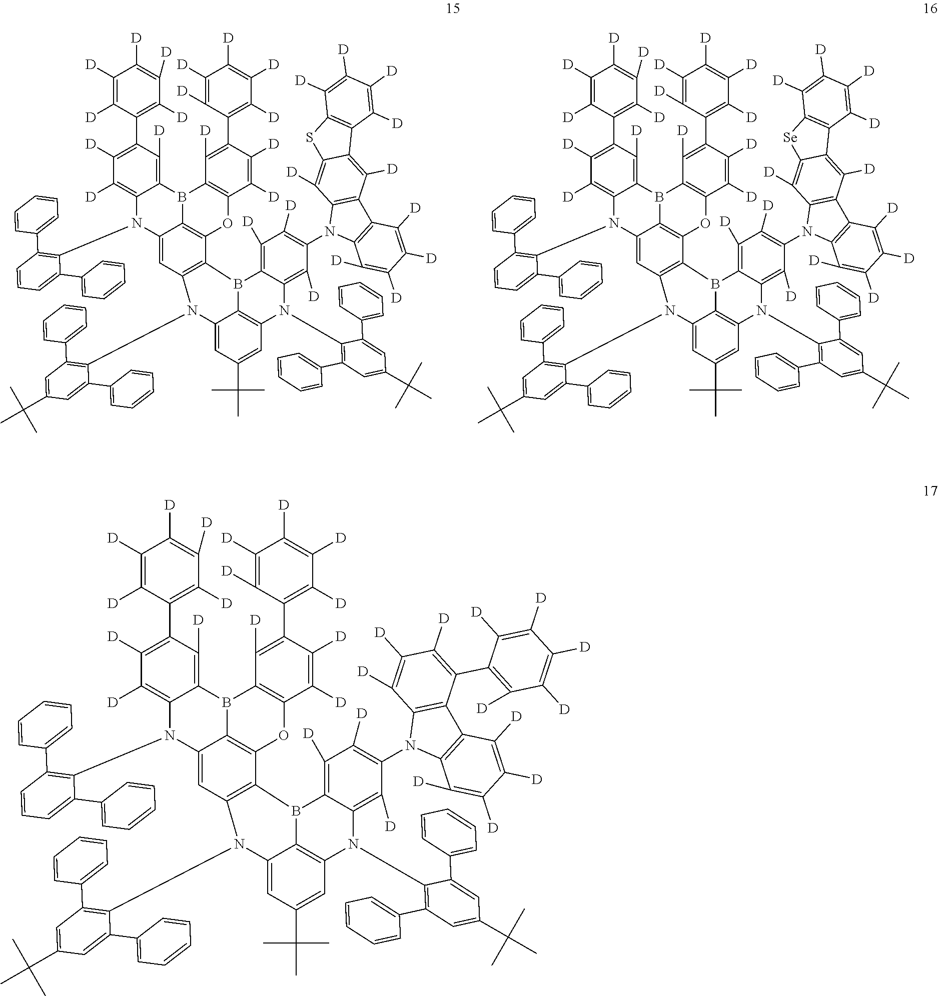 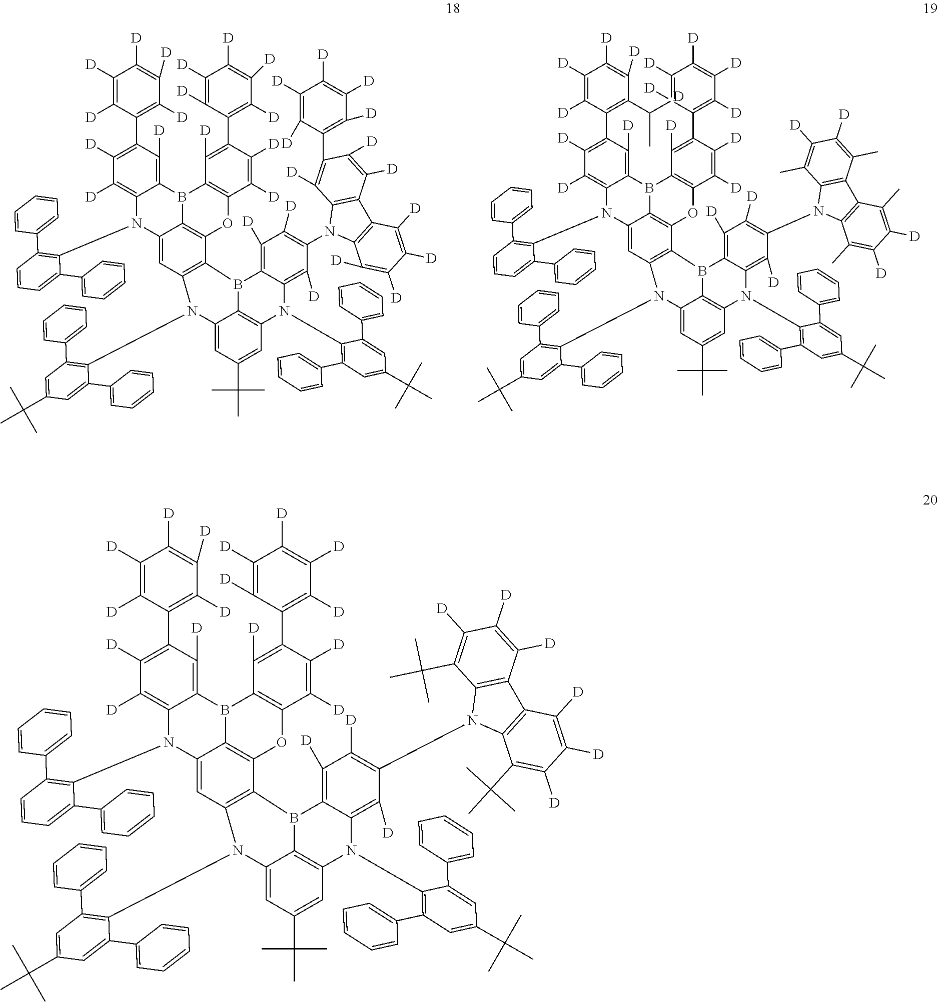 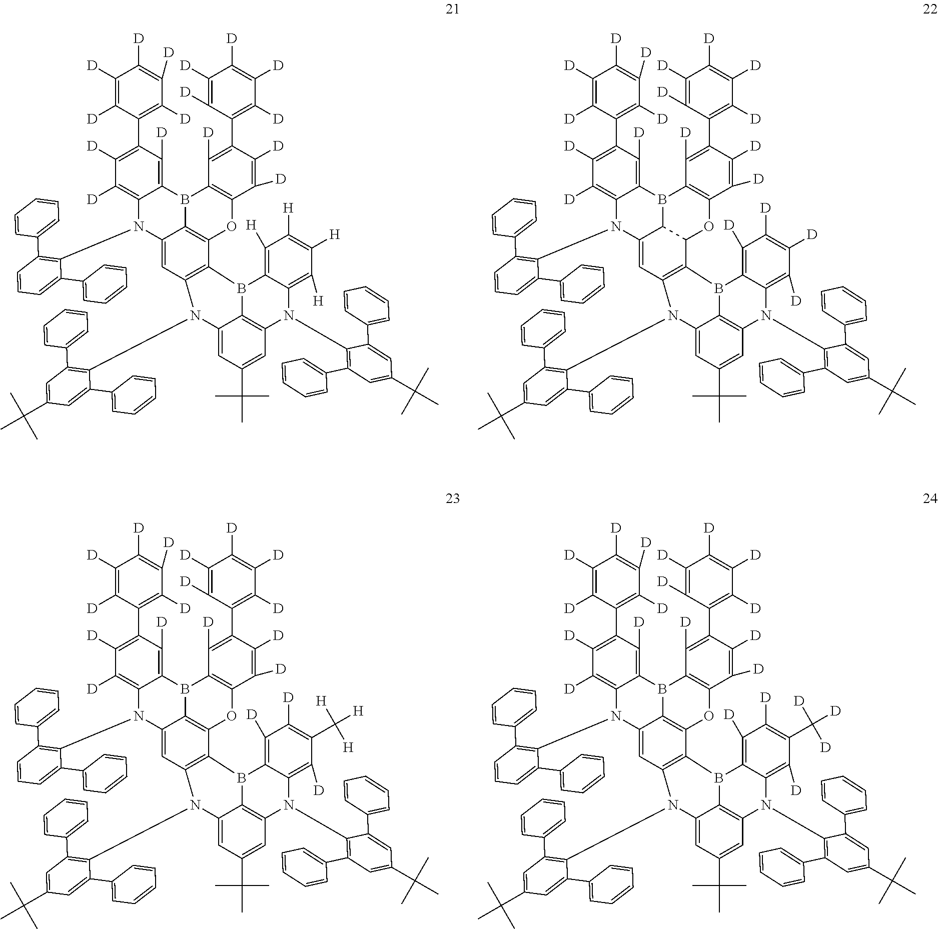 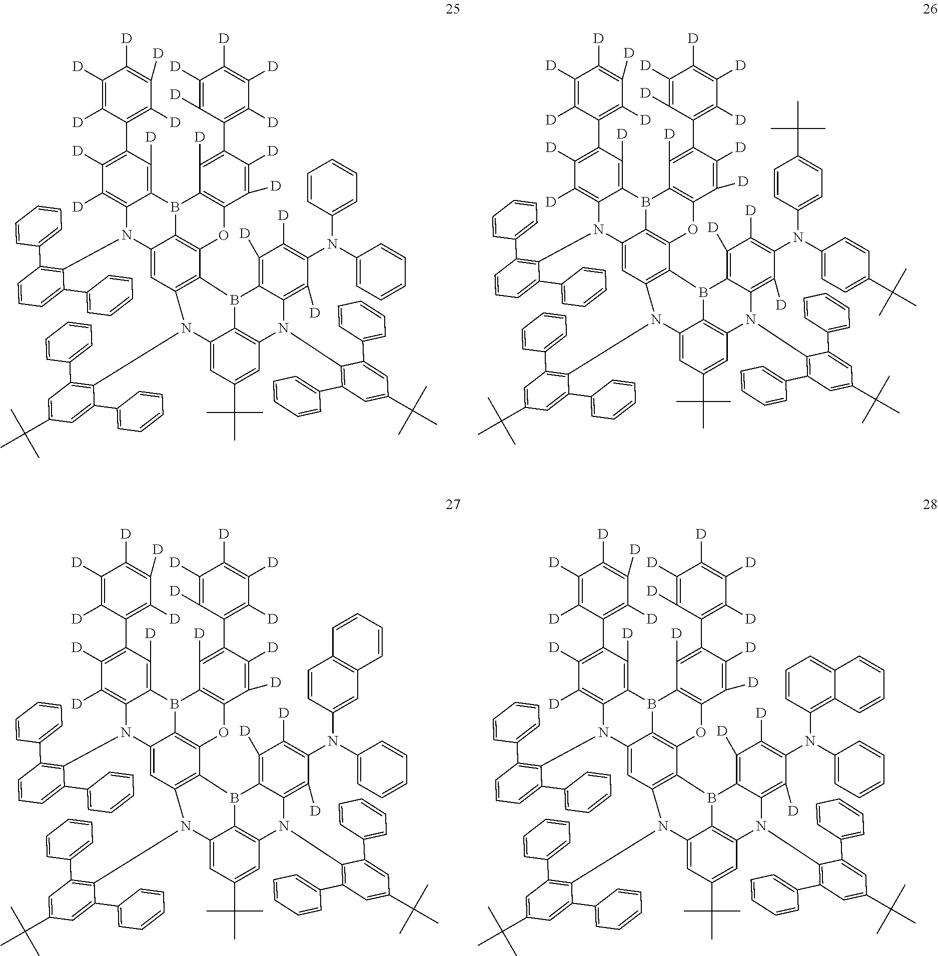 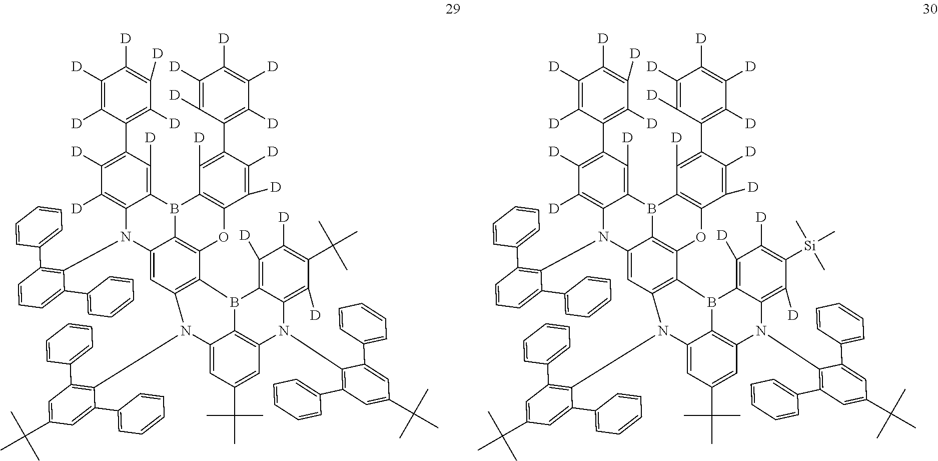 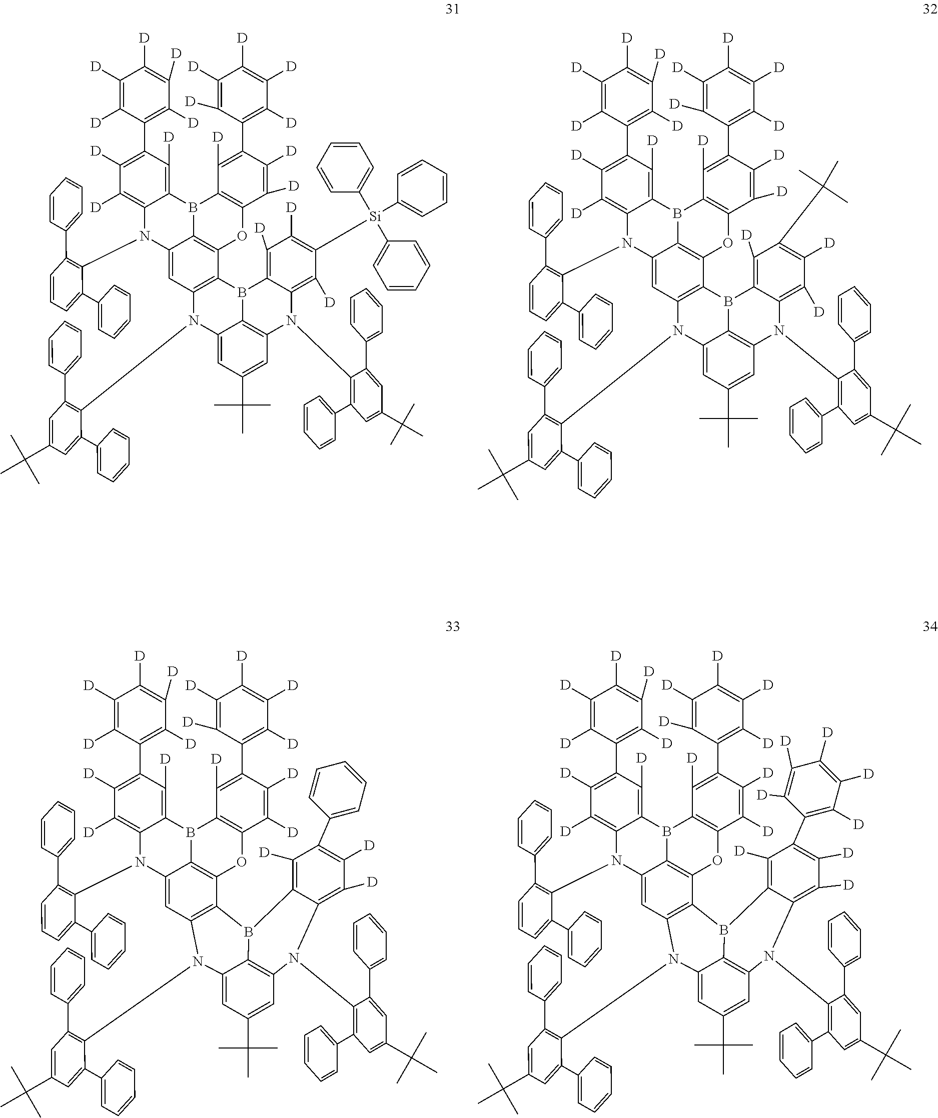 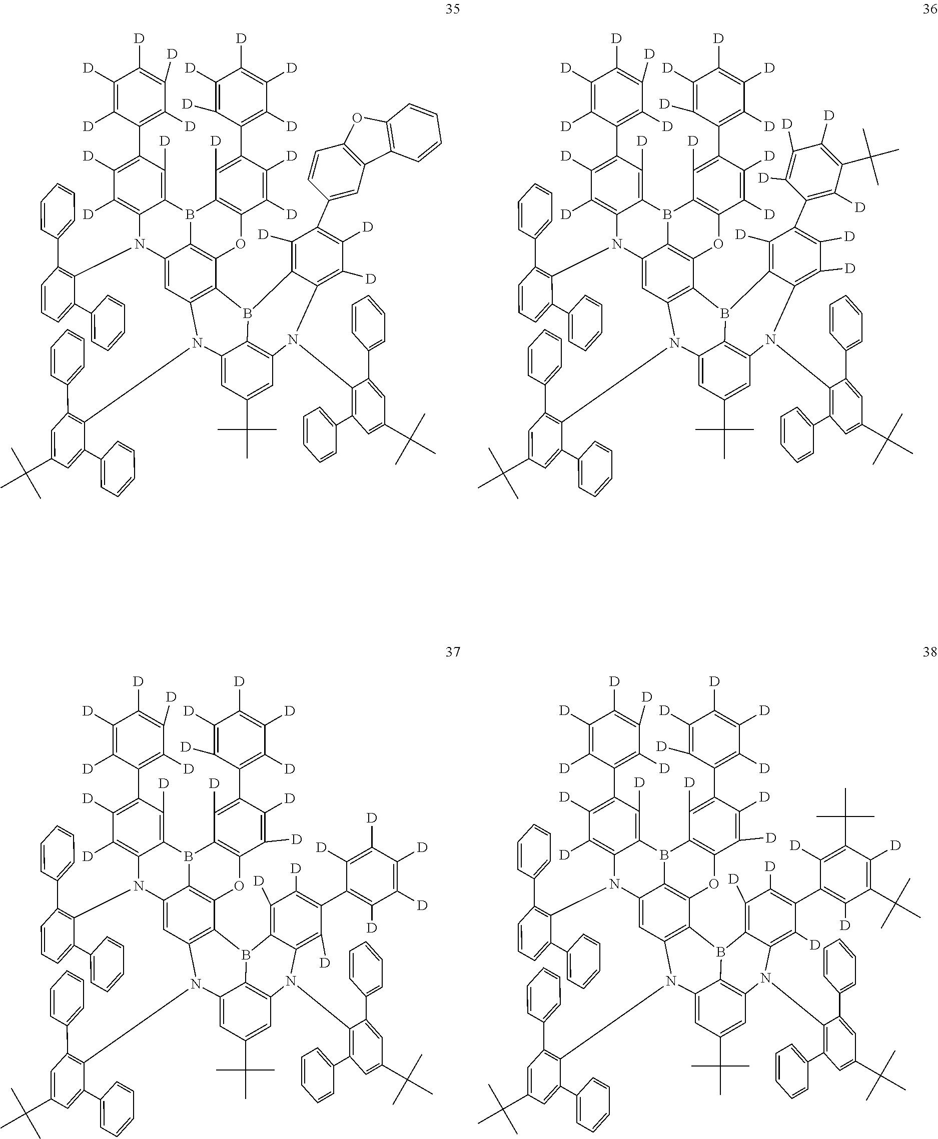 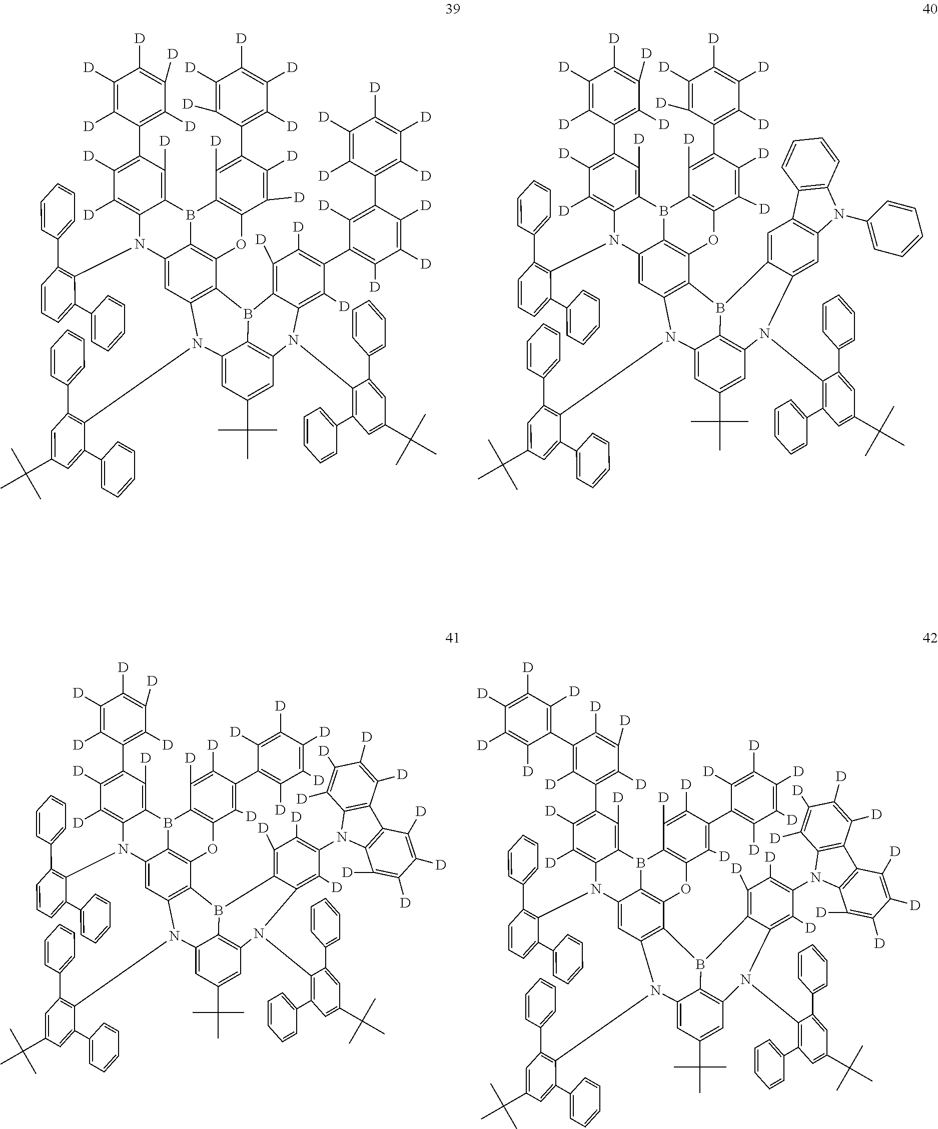 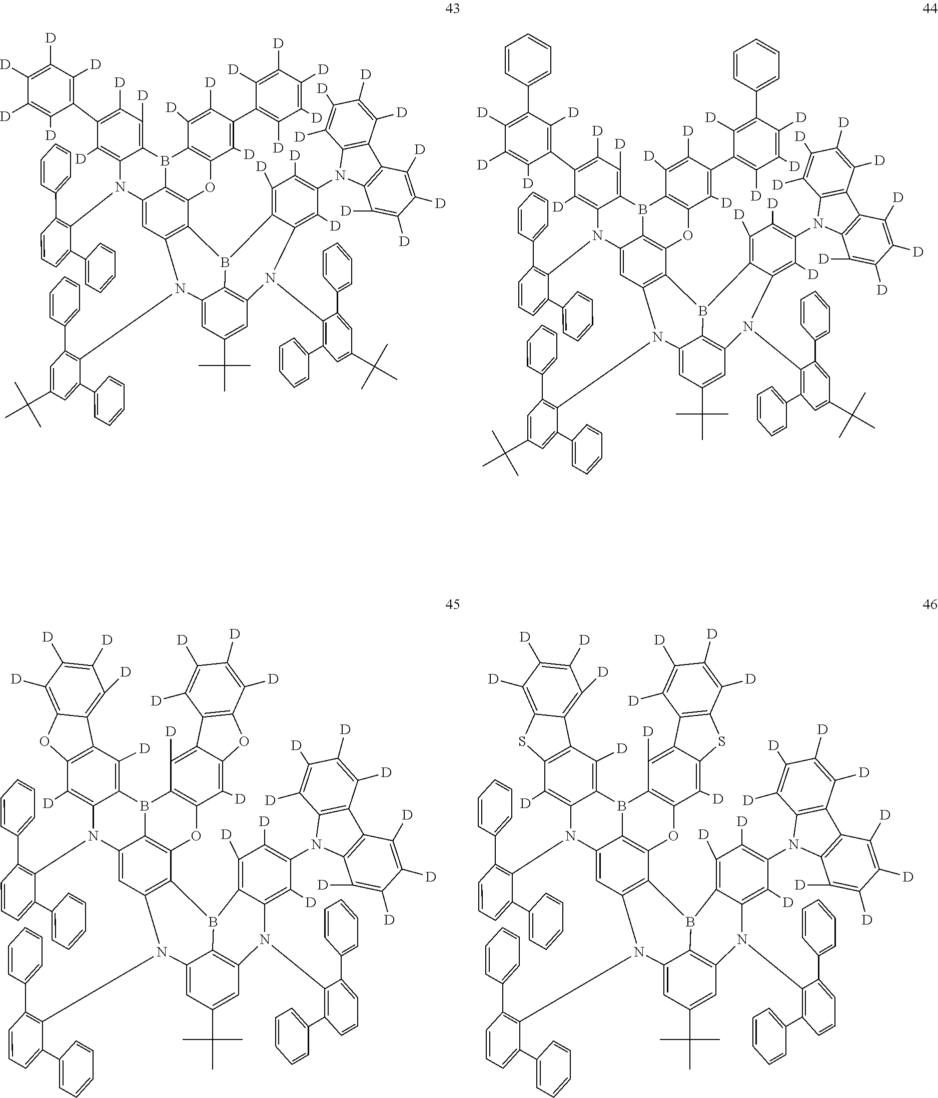 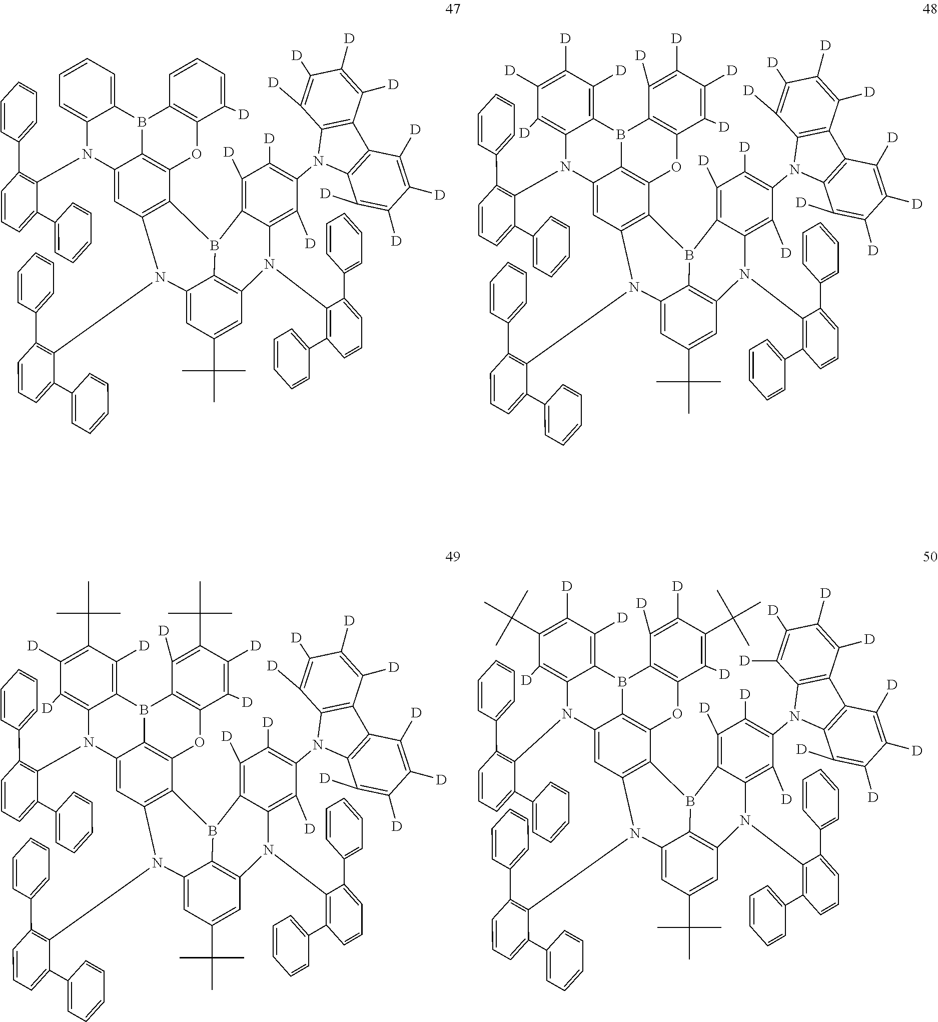 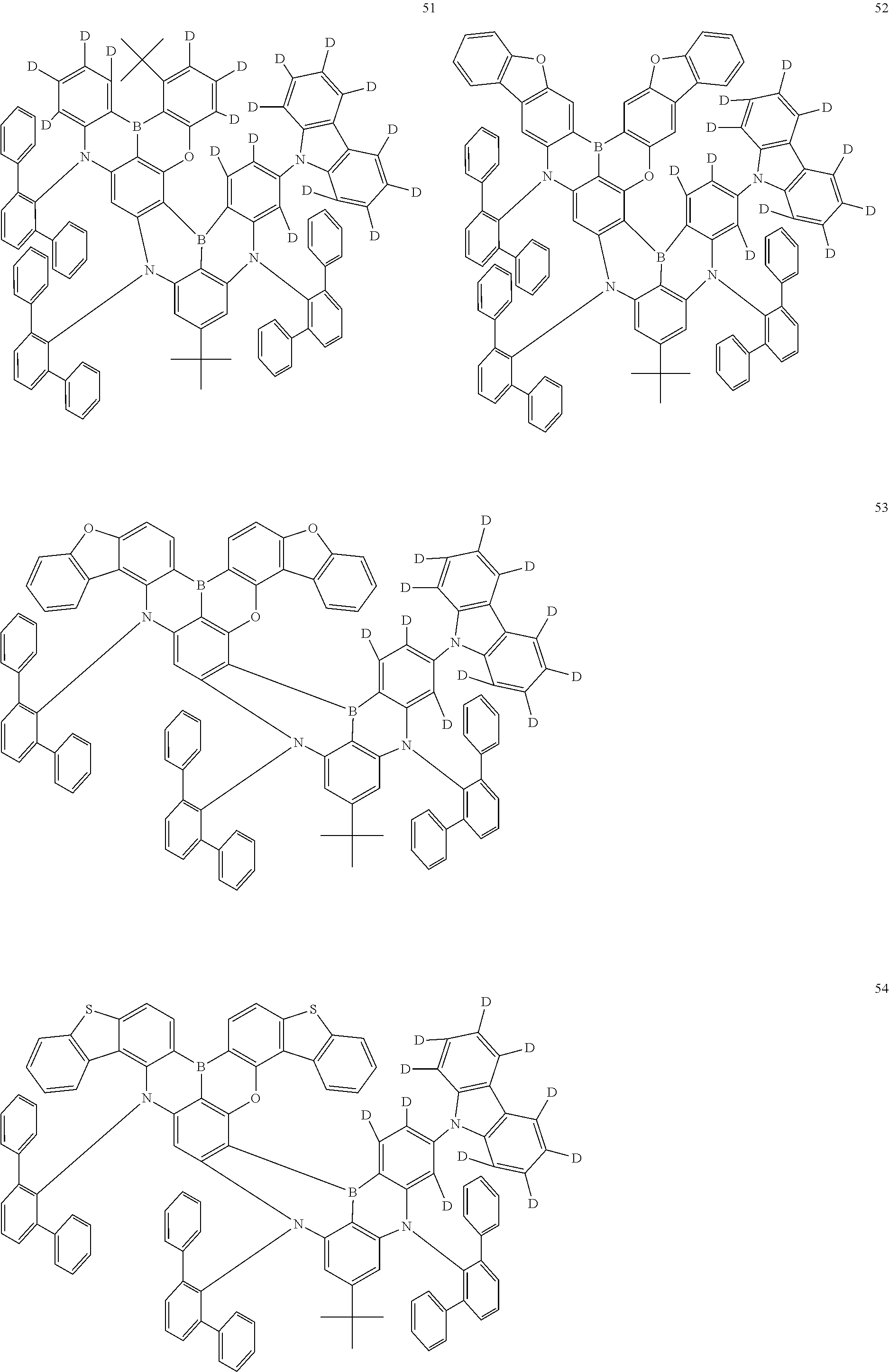 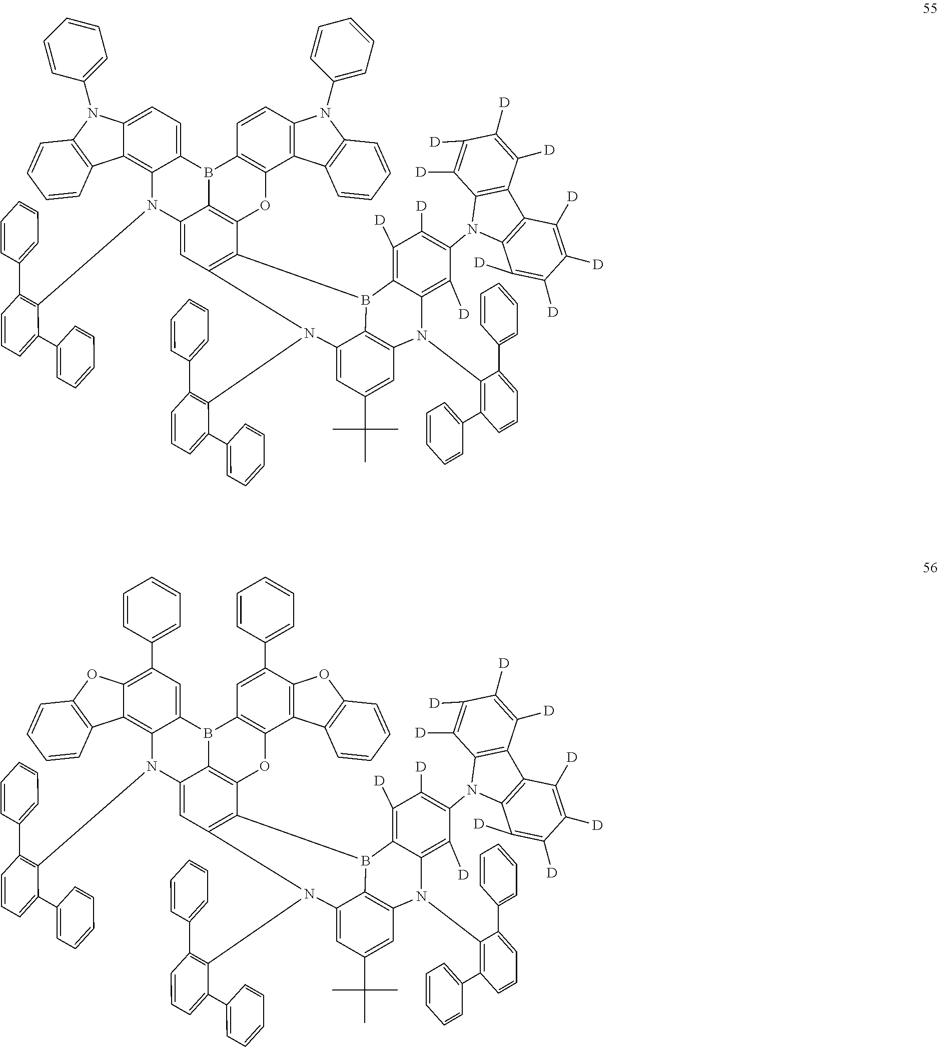 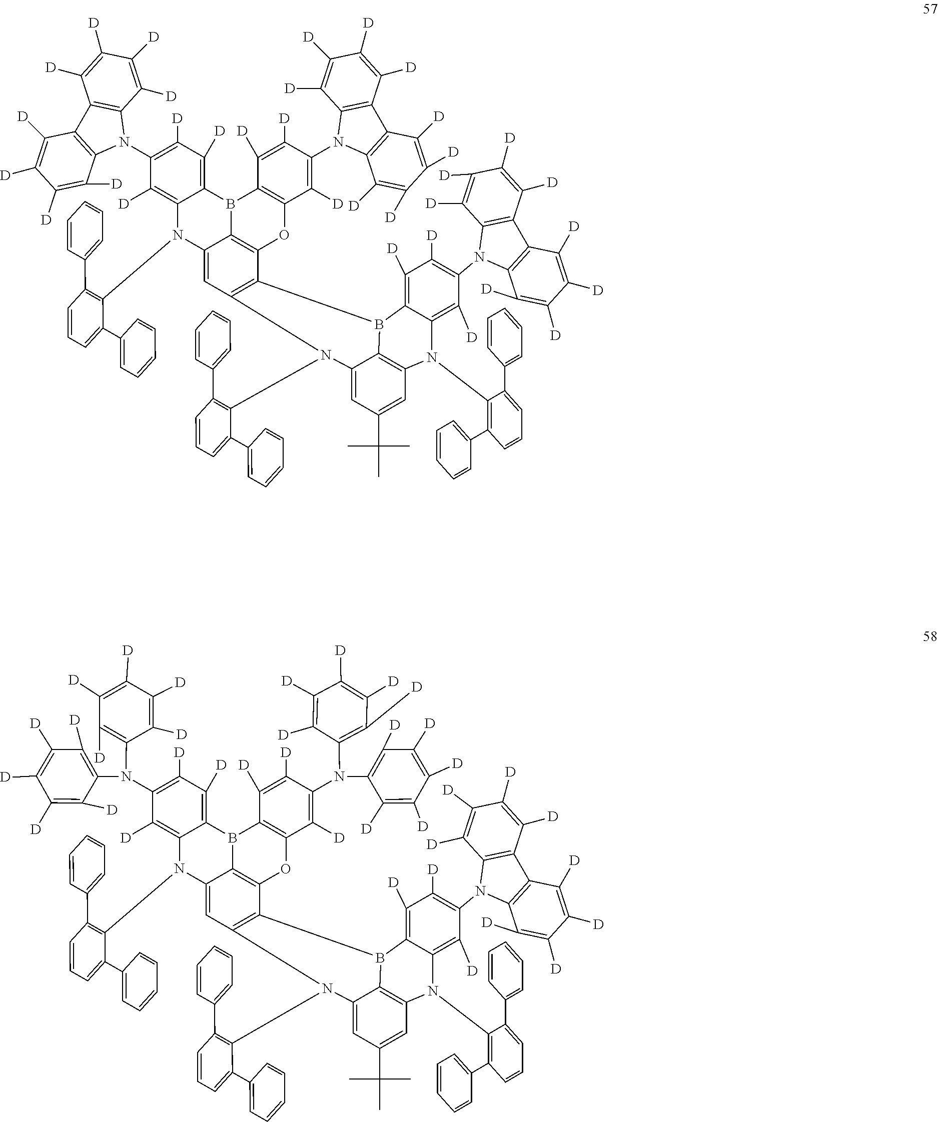 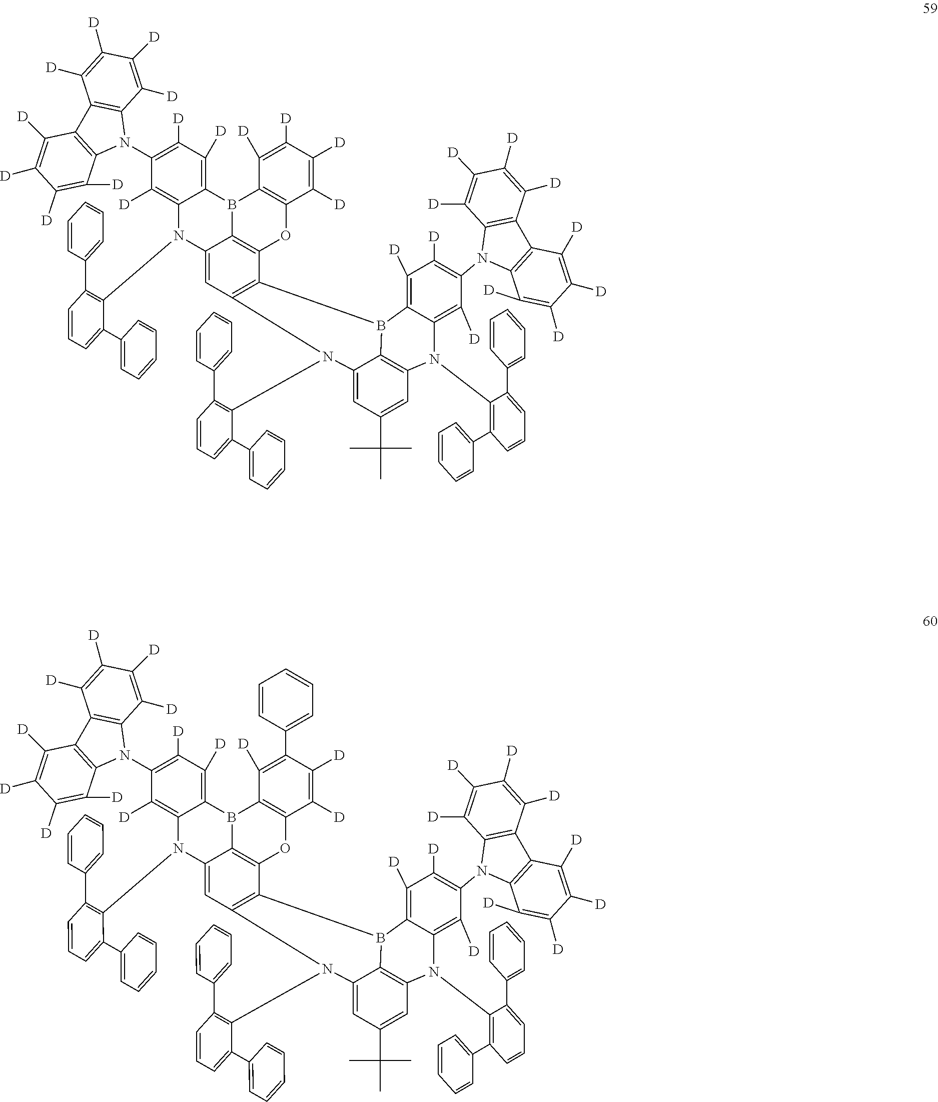 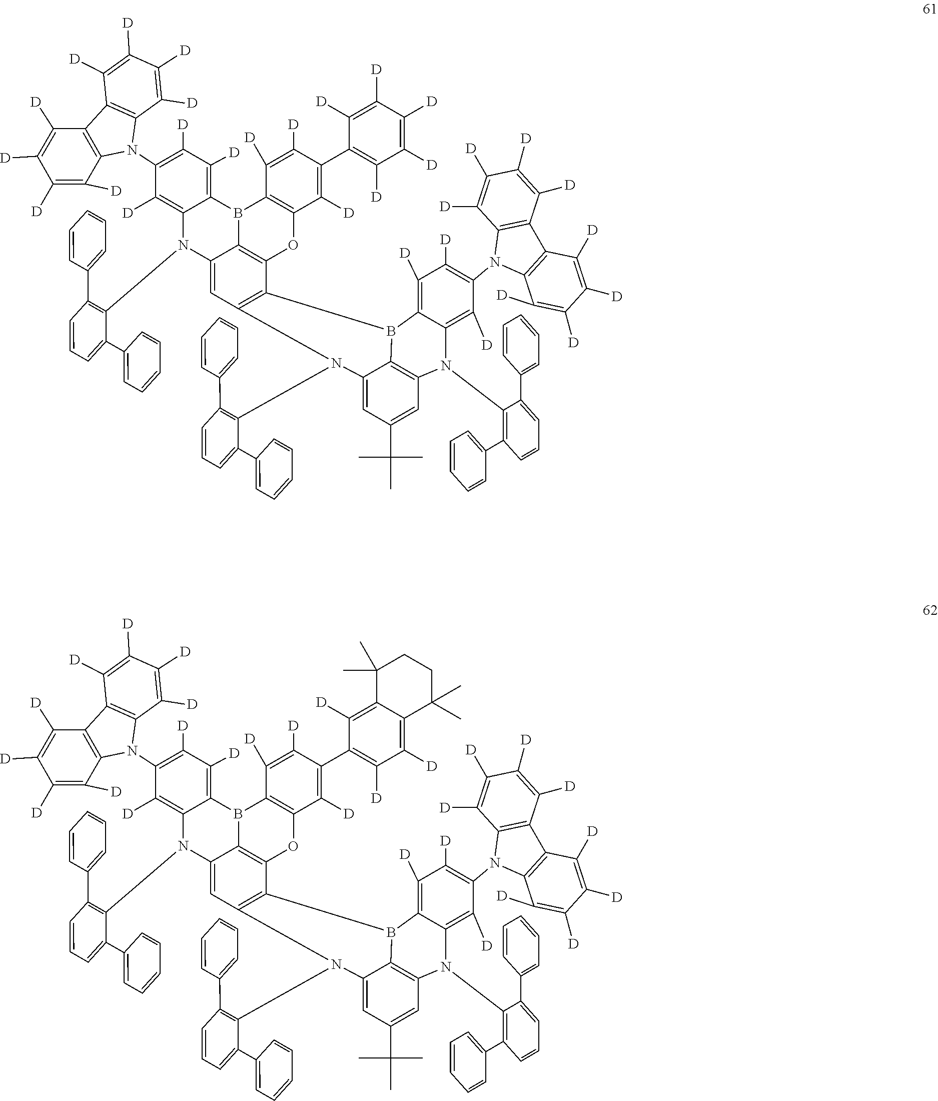 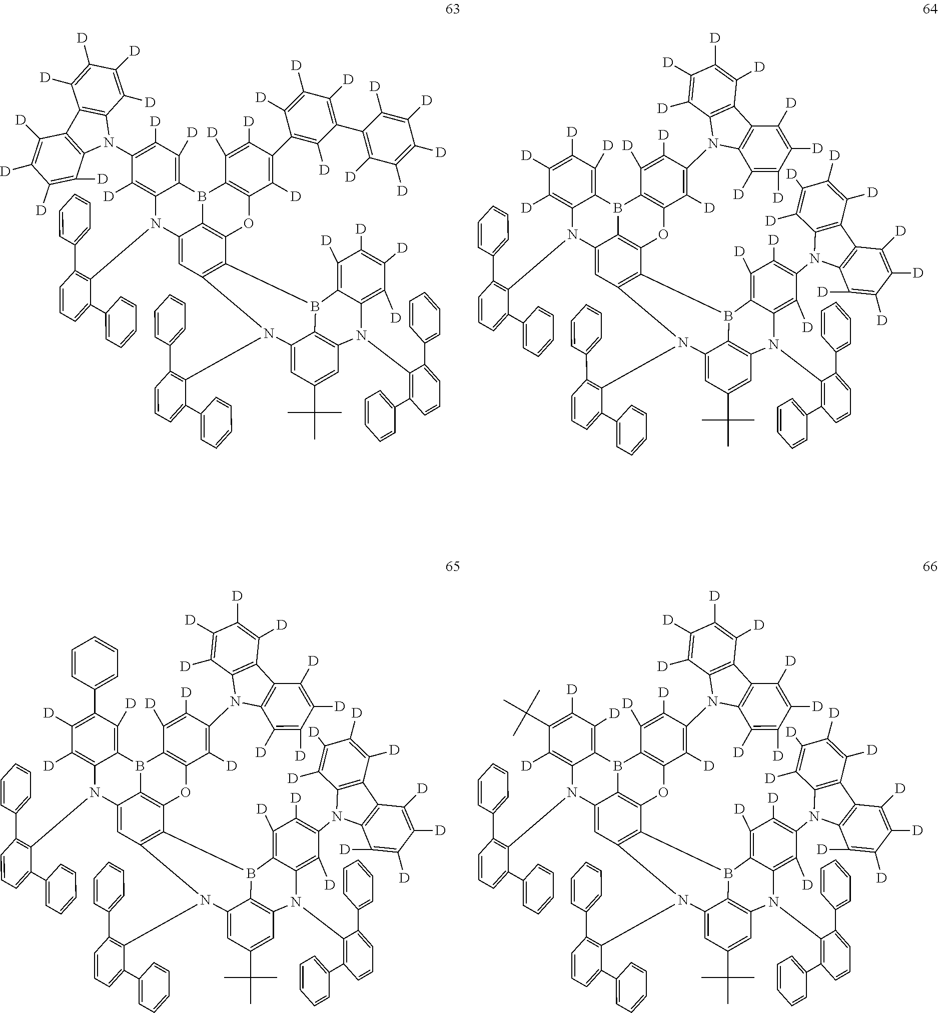 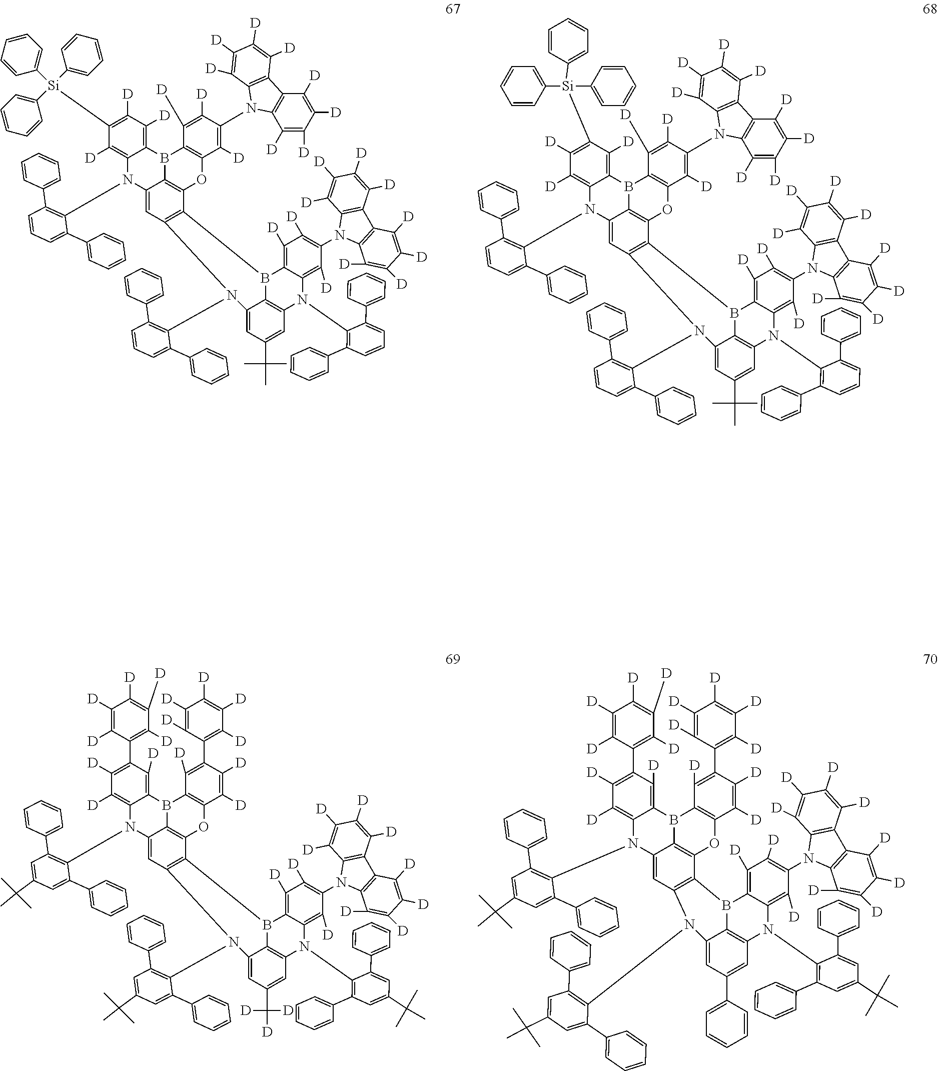 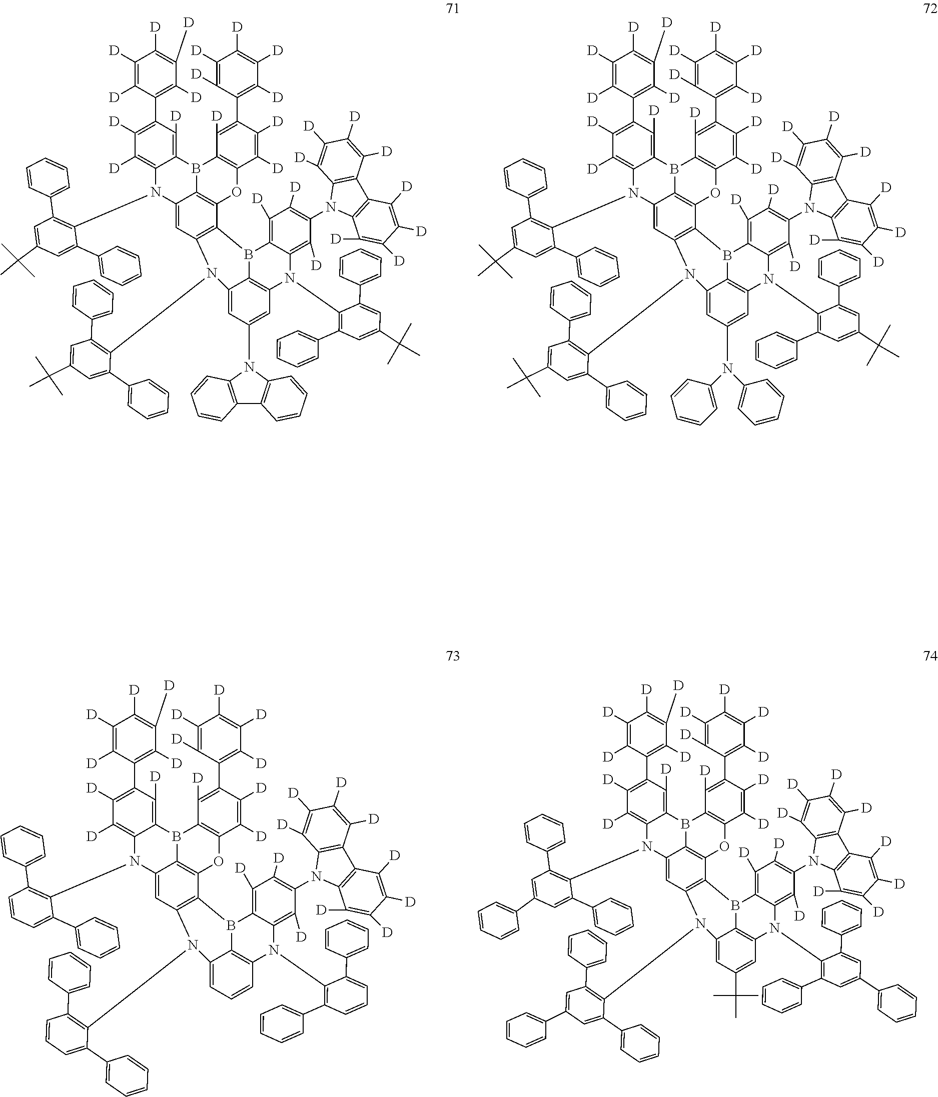 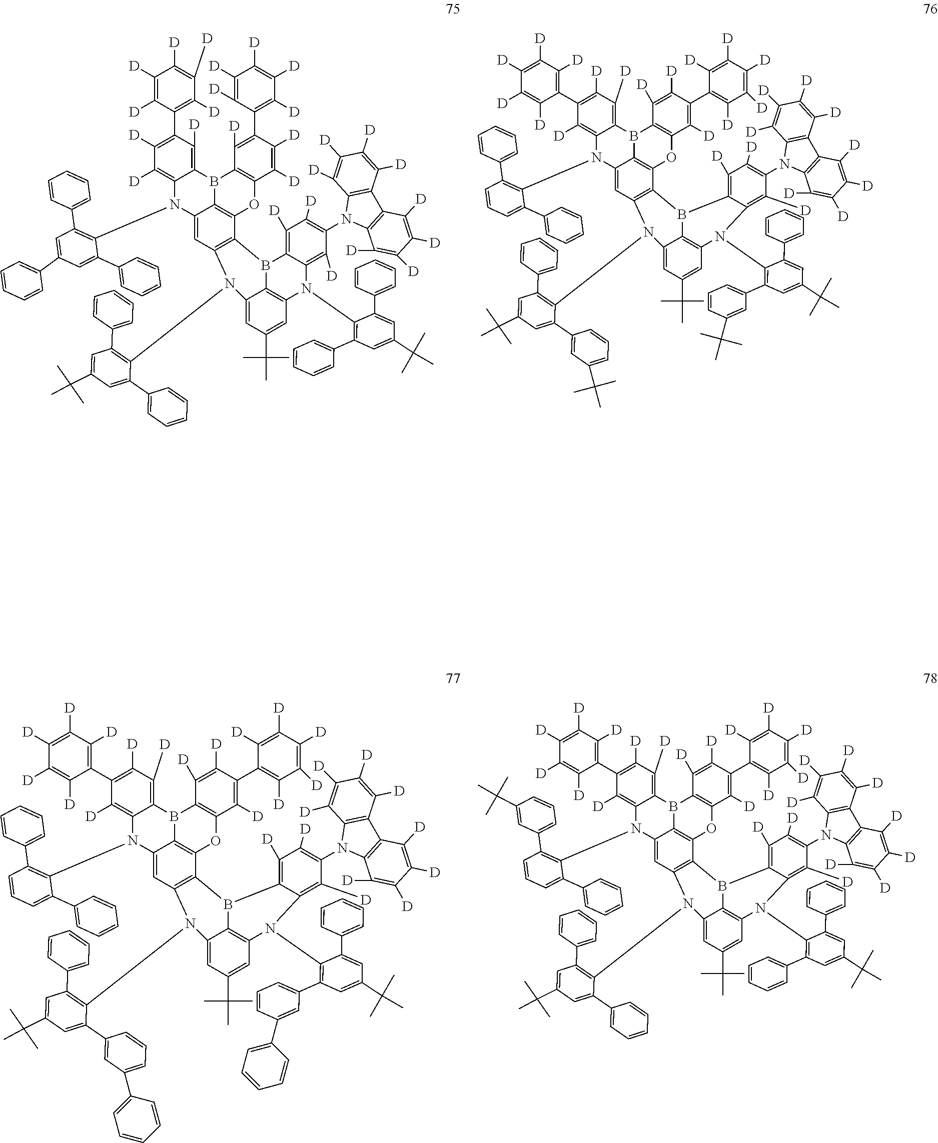 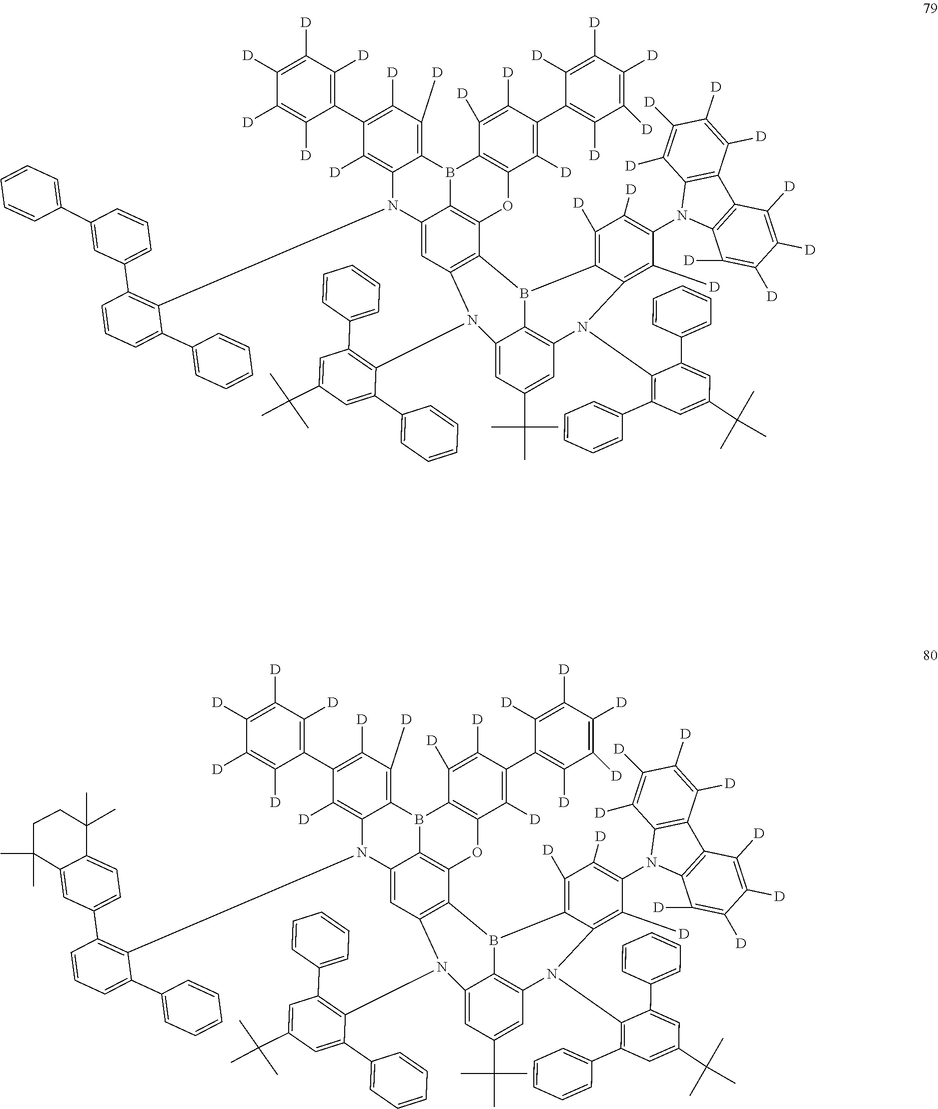
wherein in Compound Group 1,
D is a deuterium atom.

10. A fused polycyclic compound represented by Formula 1: 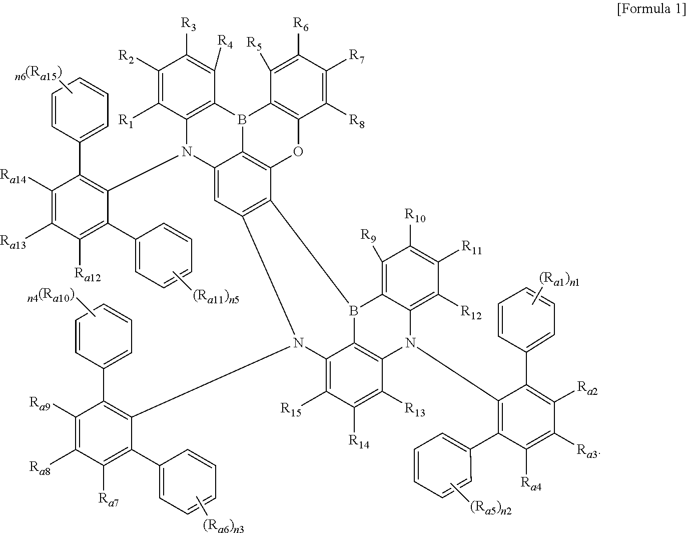
wherein in Formula 1,
n1 to n6 are each independently an integer from 0 to 5, and
R₁ to R₁₅ and Rₐ₁ to Rₐ₁₅ are each independently a hydrogen atom, a deuterium atom, a halogen atom, a cyano group, a nitro group, a substituted or unsubstituted silyl group, a substituted or unsubstituted amine group, a substituted or unsubstituted oxy group, a substituted or unsubstituted thio group, a substituted or unsubstituted selenium group, a substituted or unsubstituted alkyl group having 1 to 60 carbons, a substituted or unsubstituted cycloalkyl group having 3 to 60 carbons, a substituted or unsubstituted alkenyl group having 2 to 60 carbons, a substituted or unsubstituted hydrocarbon ring group having 6 to 60 ring-forming carbons, or a substituted or unsubstituted heterocyclic group having 2 to 60 ring-forming carbons, or bonded to an adjacent group to form a ring.

11. The fused polycyclic compound of claim 10, wherein the fused polycyclic compound is represented by one of Formula 1-A1 to Formula 1-A3: 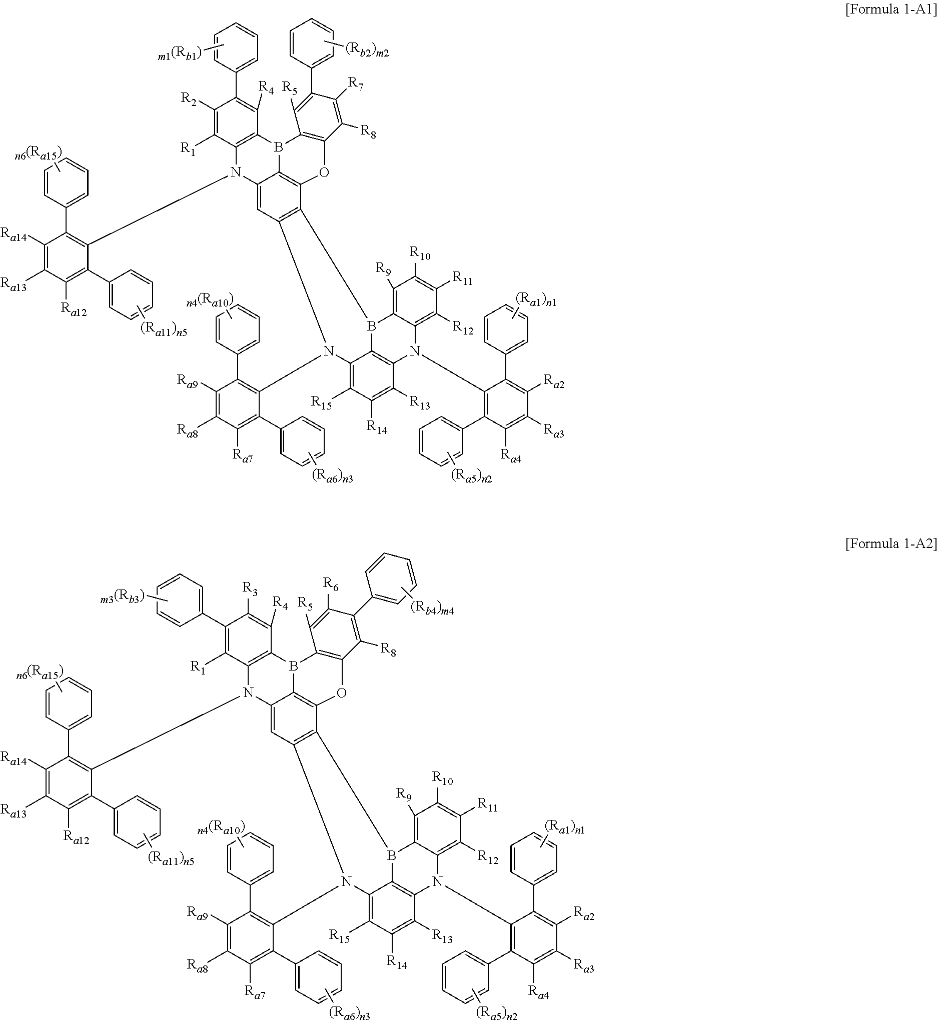 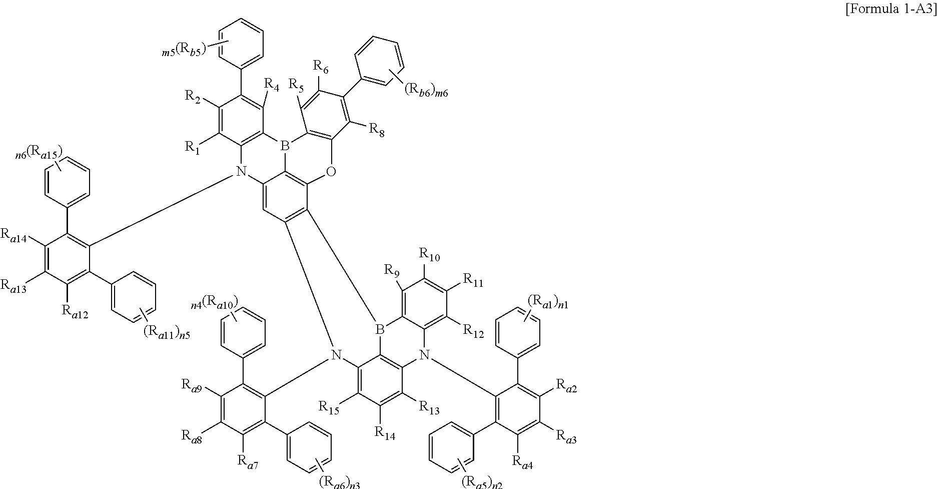
wherein in Formula 1-A1 to Formula 1-A3,
m1 to m6 are each independently an integer from 0 to 5,
R_{b1} to R_{b6} are each independently a hydrogen atom, a deuterium atom, a substituted or unsubstituted oxy group, a substituted or unsubstituted thio group, a substituted or unsubstituted alkyl group having 1 to 30 carbons, or a substituted or unsubstituted aryl group having 6 to 30 ring-forming carbons, or bonded to an adjacent group to form a ring, and
n1 to n6, R₁ to R₁₅, and Rₐ₁ to Rₐ₁₅ are the same as defined in Formula 1.

12. The fused polycyclic compound of claim 10, wherein the fused polycyclic compound is represented by one of Formula 1-A4 to Formula 1-A6: 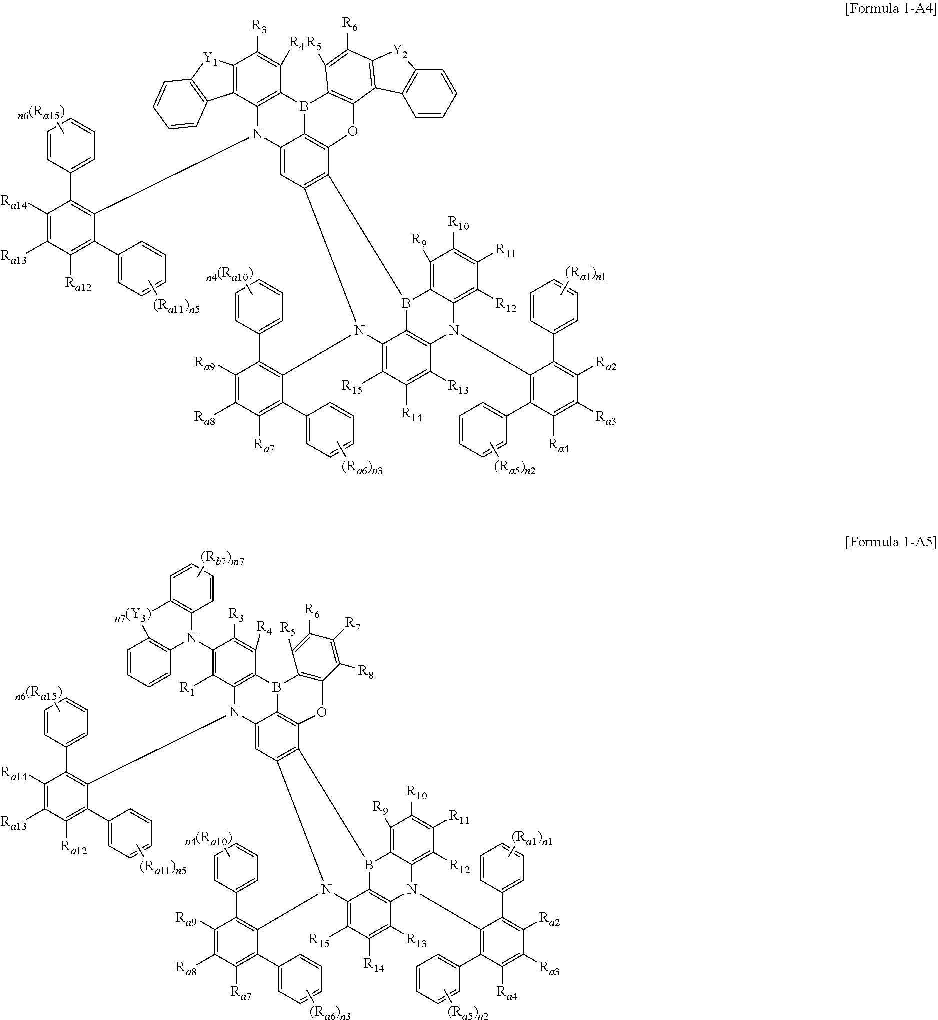 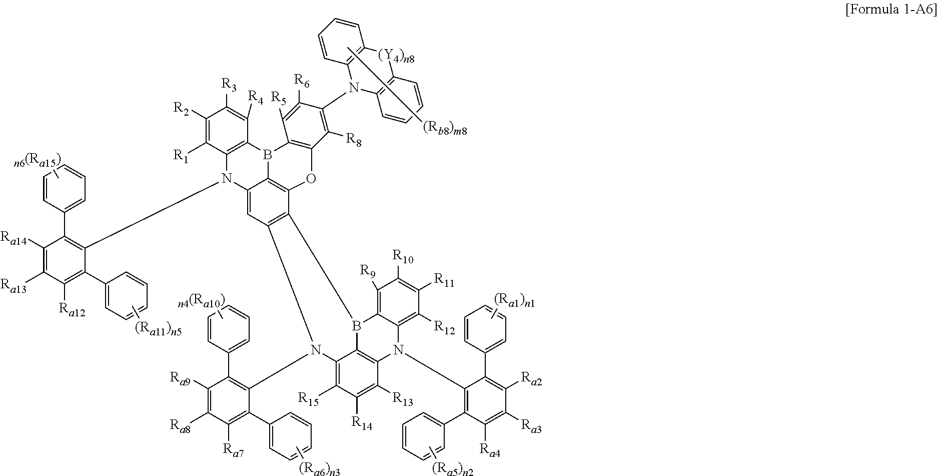
wherein in Formula 1-A4,
Y₁ and Y₂ are each independently N(R₁₆), O, or S, and
R₁₆ is a substituted or unsubstituted aryl group having 6 to 30 ring-forming carbons,
wherein in Formula 1-A5,
n7 is 0 or 1,
Y₃ is a direct linkage,
m7 is an integer from 0 to 10, and
R_{b7} is a hydrogen atom or a deuterium atom,
wherein in Formula 1-A6,
n8 is 0 or 1,
Y₄ is a direct linkage,
m8 is an integer from 0 to 10, and
R_{b8} is a hydrogen atom or a deuterium atom, and
wherein in Formula 1-A4 to Formula 1-A6,
n1 to n6, R₁ to R₁₅, and Rₐ₁ to Rₐ₁₅ are the same as defined in Formula 1.

13. The fused polycyclic compound of claim 10, wherein the fused polycyclic compound is represented by Formula 1-B1: 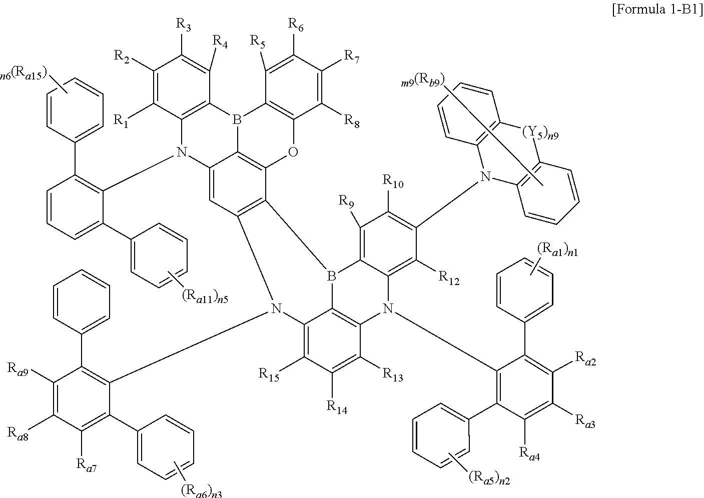
wherein in Formula 1-B1,
n9 is 0 or 1,
Y₅ is a direct linkage,
m9 is an integer from 0 to 10,
R_{b9} is a hydrogen atom, a deuterium atom, a substituted or unsubstituted oxy group, a substituted or unsubstituted thio group, a substituted or unsubstituted selenium group, a substituted or unsubstituted alkyl group having 1 to 30 carbons, a substituted or unsubstituted alkenyl group having 2 to 30 carbons, a substituted or unsubstituted aryl group having 6 to 30 ring-forming carbons, or a substituted or unsubstituted heteroaryl group having 2 to 30 ring-forming carbons, or bonded to an adjacent group to form a ring, and
n1 to n6, R₁ to R₁₀, R₁₂ to R₁₅, and Rₐ₁ to Rₐ₁₅ are the same as defined in Formula 1.

14. The fused polycyclic compound of claim 10, wherein in Formula 1, R₁₀ and R₁₁ are each independently a hydrogen atom, a deuterium atom, or a group represented by one of Formulas R-1 to R-33: 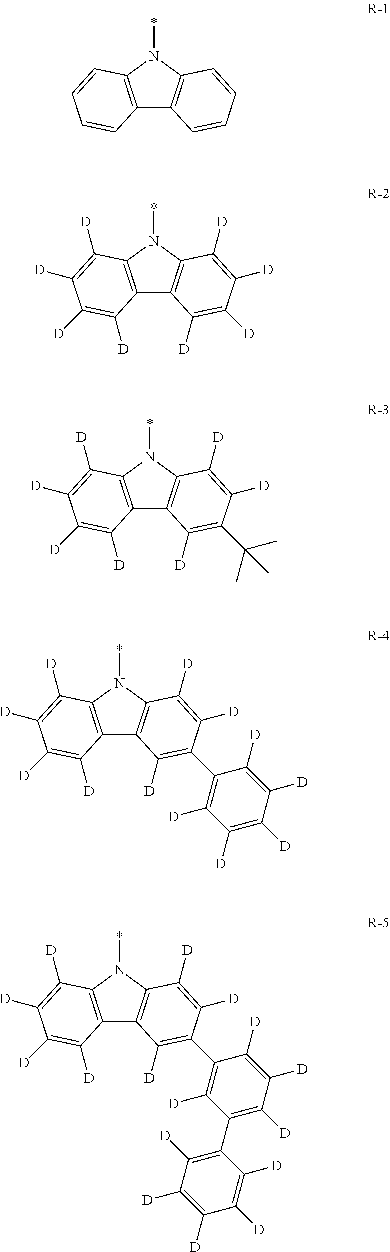 [SMILES: *n1c2ccccc2c2ccccc21 ; *n1c2c([2H])c([2H])c([2H])c([2H])c2c2c([2H])c([2H])c([2H])c([2H])c21 ; *n1c2c([2H])c([2H])c([2H])c([2H])c2c2c([2H])c(C(C)(C)C)c([2H])c([2H])c21 ; *n1c2c([2H])c([2H])c([2H])c([2H])c2c2c([2H])c(-c3c([2H])c([2H])c([2H])c([2H])c3[2H])c([2H])c([2H])c21 ; *n1c2c([2H])c([2H])c([2H])c([2H])c2c2c([2H])c(-c3c([2H])c([2H])c([2H])c(-c4c([2H])c([2H])c([2H])c([2H])c4[2H])c3[2H])c([2H])c([2H])c21] 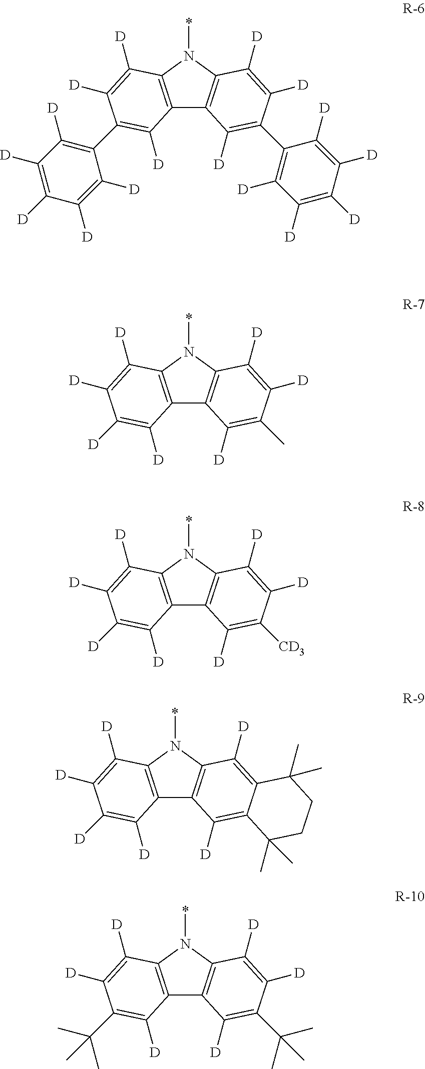 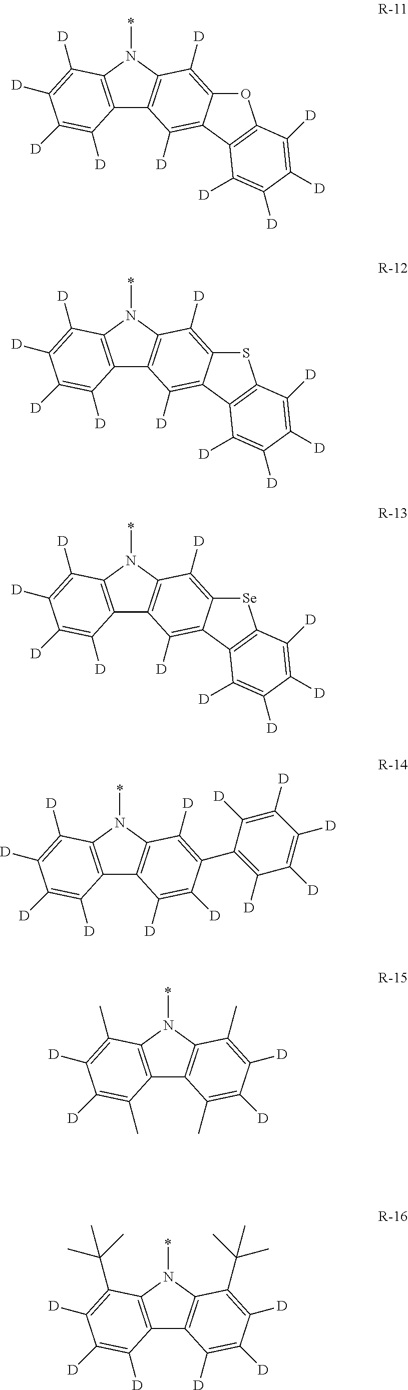 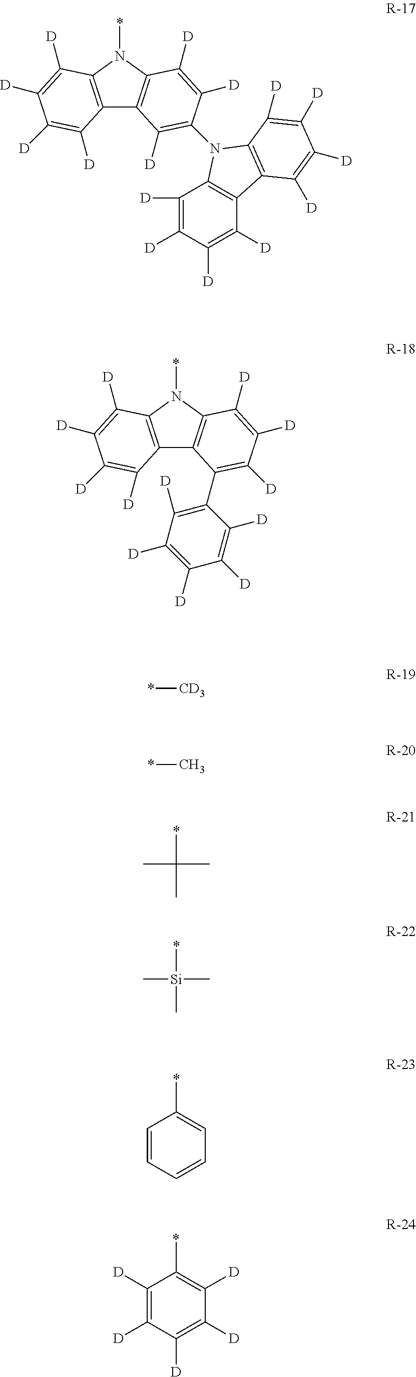 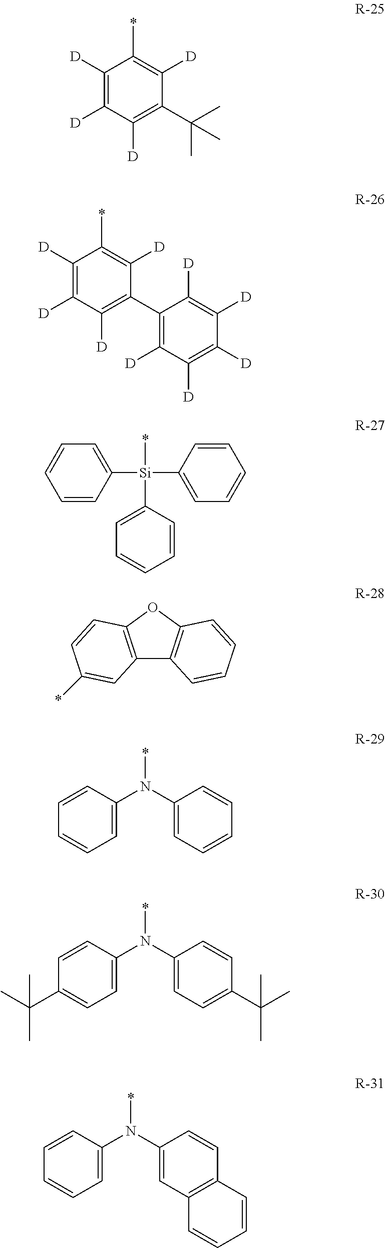 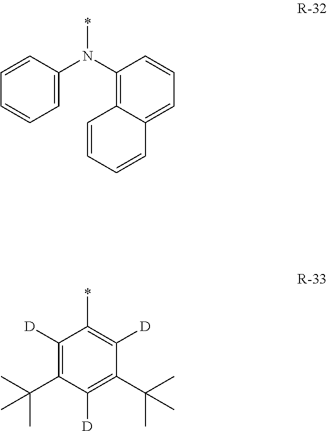 [SMILES: *N(c1ccccc1)c1cccc2ccccc12 ; *c1c([2H])c(C(C)(C)C)c([2H])c(C(C)(C)C)c1[2H]]
wherein in Formulas R-2 to R-19, R-24 to R-26, and R-33,
D is a deuterium atom.

15. The fused polycyclic compound of claim 10, wherein in Formula 1, a first terphenyl moiety that includes Rₐ₁ to Rₐ₅, a second terphenyl moiety that includes Rₐ₆ to Rₐ₁₀, and a third terphenyl moiety that includes Rₐ₁₁ to Rₐ₁₅ are each independently a moiety represented by one of Formulas RA-1 to RA-8:

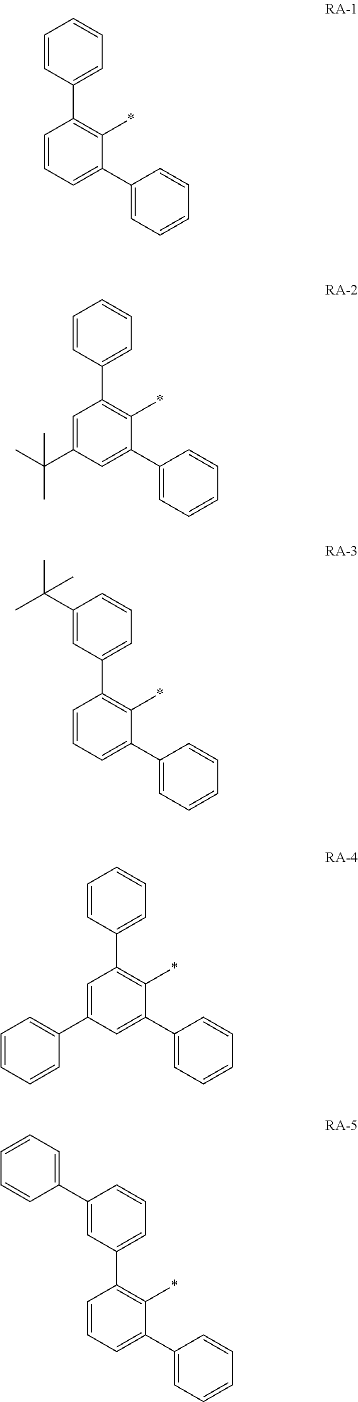 [SMILES: *c1c(-c2ccccc2)cccc1-c1ccccc1 ; *c1c(-c2ccccc2)cc(C(C)(C)C)cc1-c1ccccc1 ; *c1c(-c2ccccc2)cccc1-c1cccc(C(C)(C)C)c1 ; *c1c(-c2ccccc2)cc(-c2ccccc2)cc1-c1ccccc1 ; *c1c(-c2ccccc2)cccc1-c1cccc(-c2ccccc2)c1]

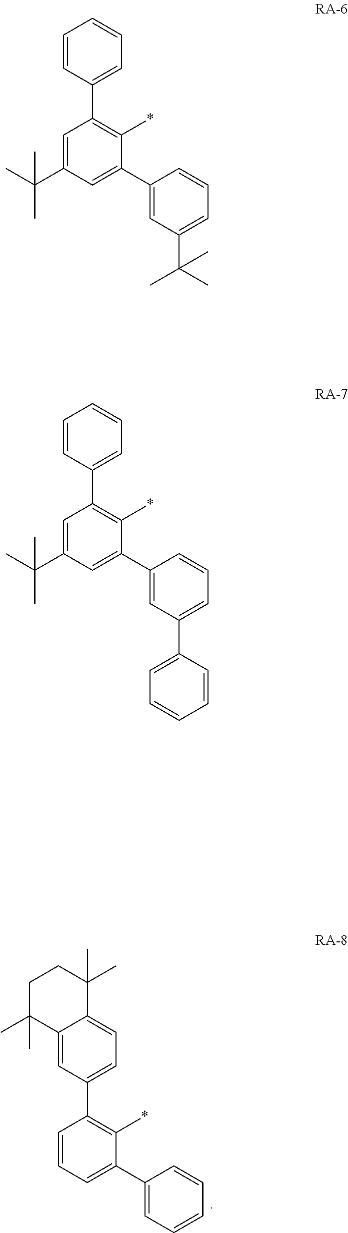

16. The fused polycyclic compound of claim 10, wherein in Formula 1, R₁₃ to R₁₅ are each independently a hydrogen atom, a deuterium atom, a substituted or unsubstituted diphenylamine group, a substituted or unsubstituted methyl group, a substituted or unsubstituted t-butyl group, a substituted or unsubstituted phenyl group, or a substituted or unsubstituted carbazole group.

17. The fused polycyclic compound of claim 10, wherein the fused polycyclic compound is selected from Compound Group 1: 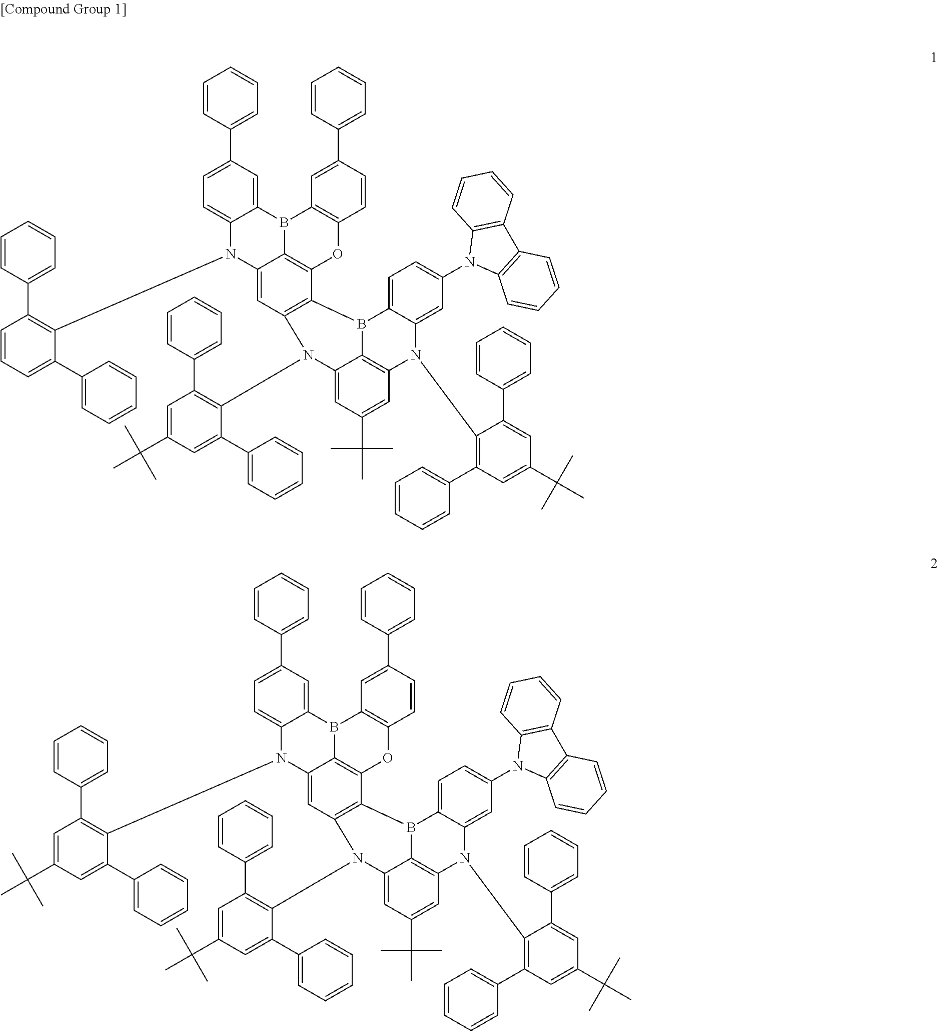 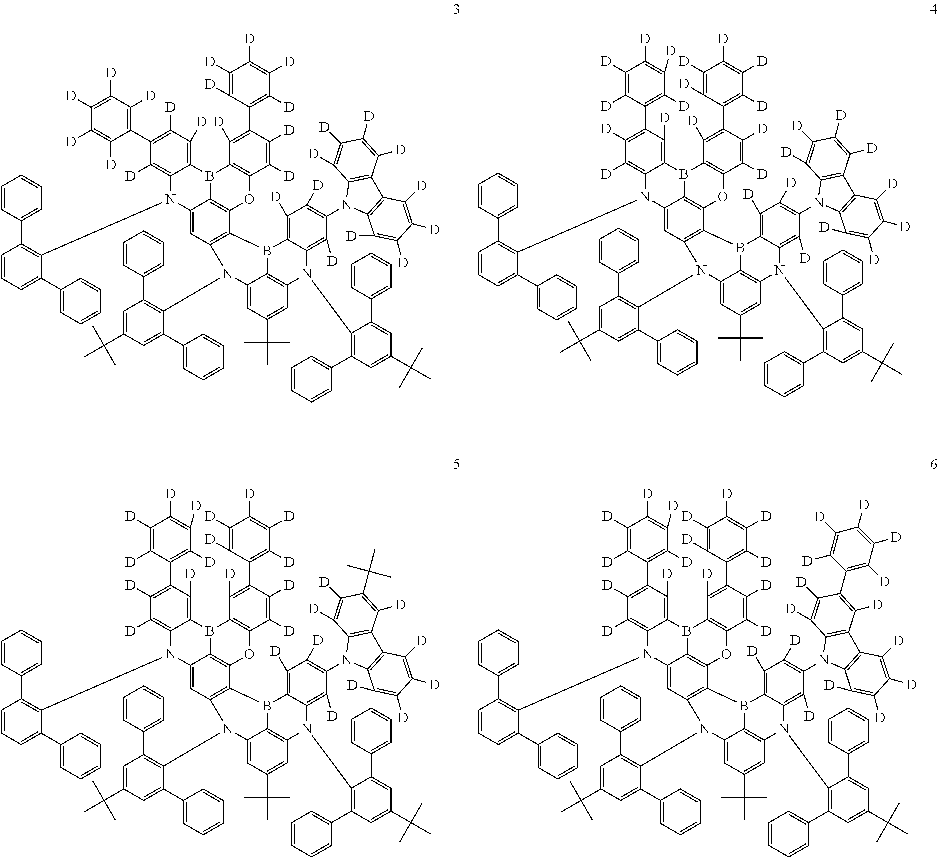 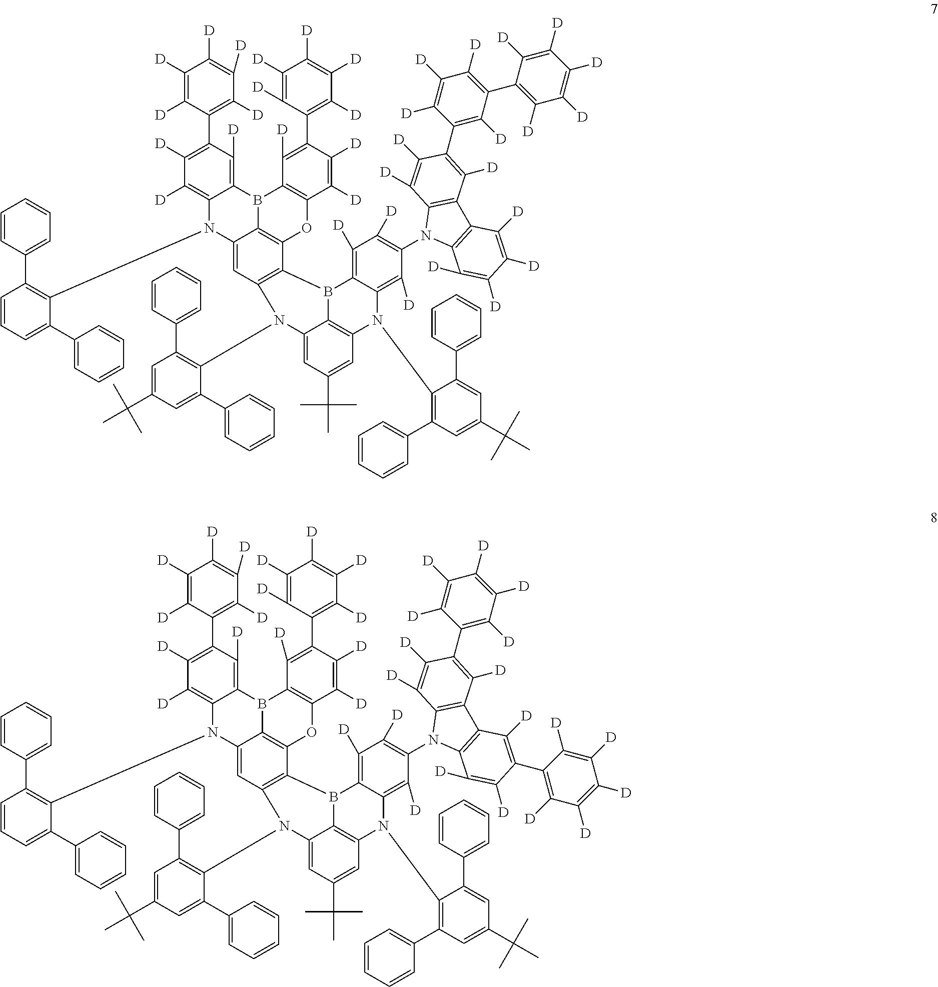 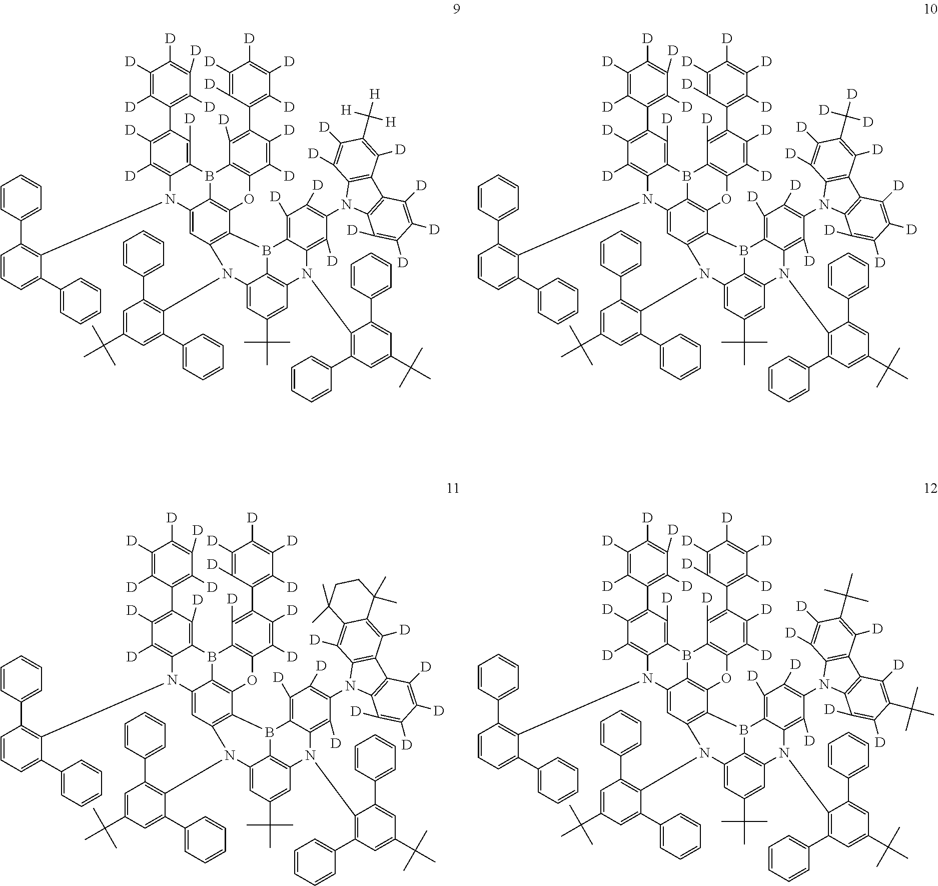 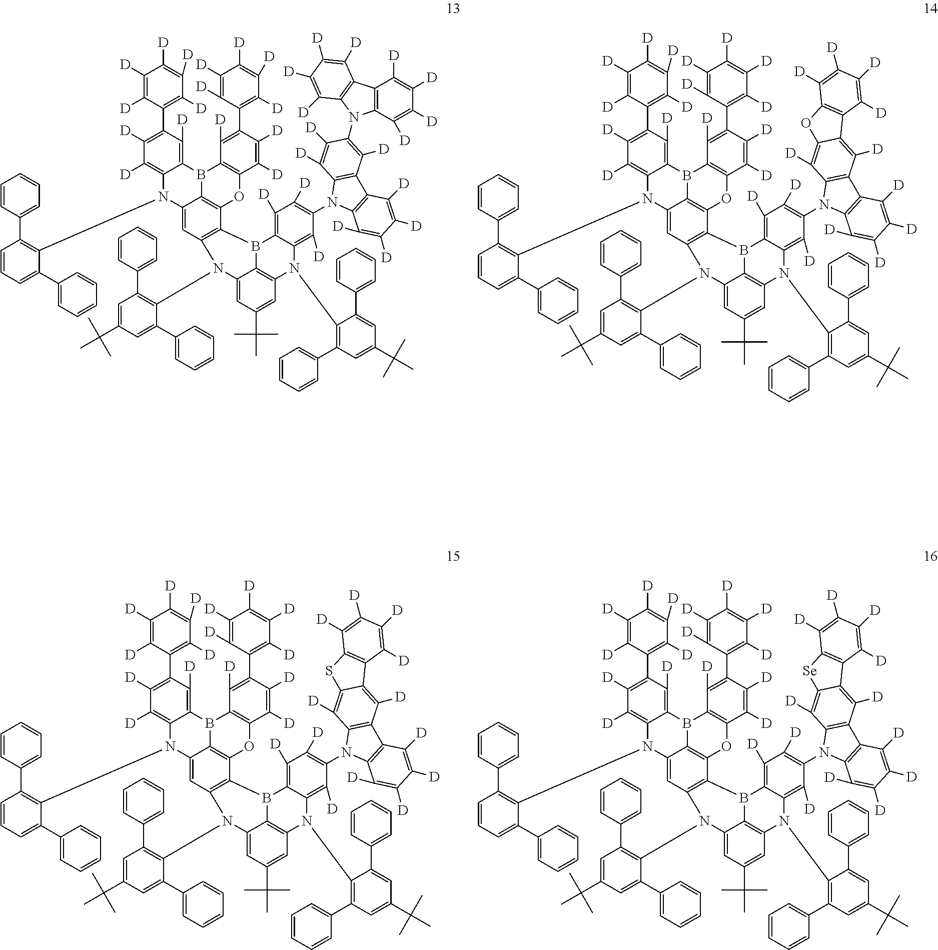 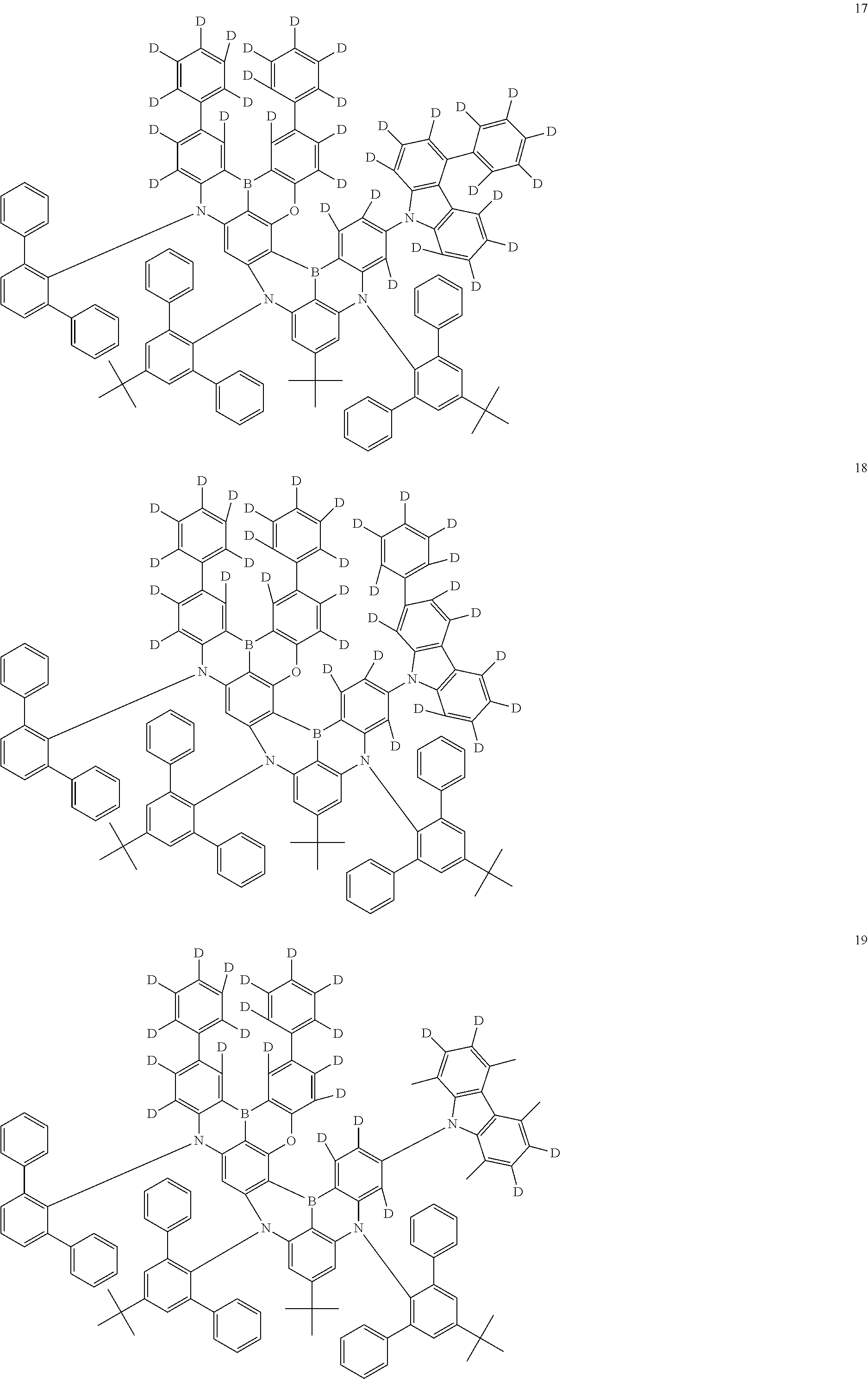 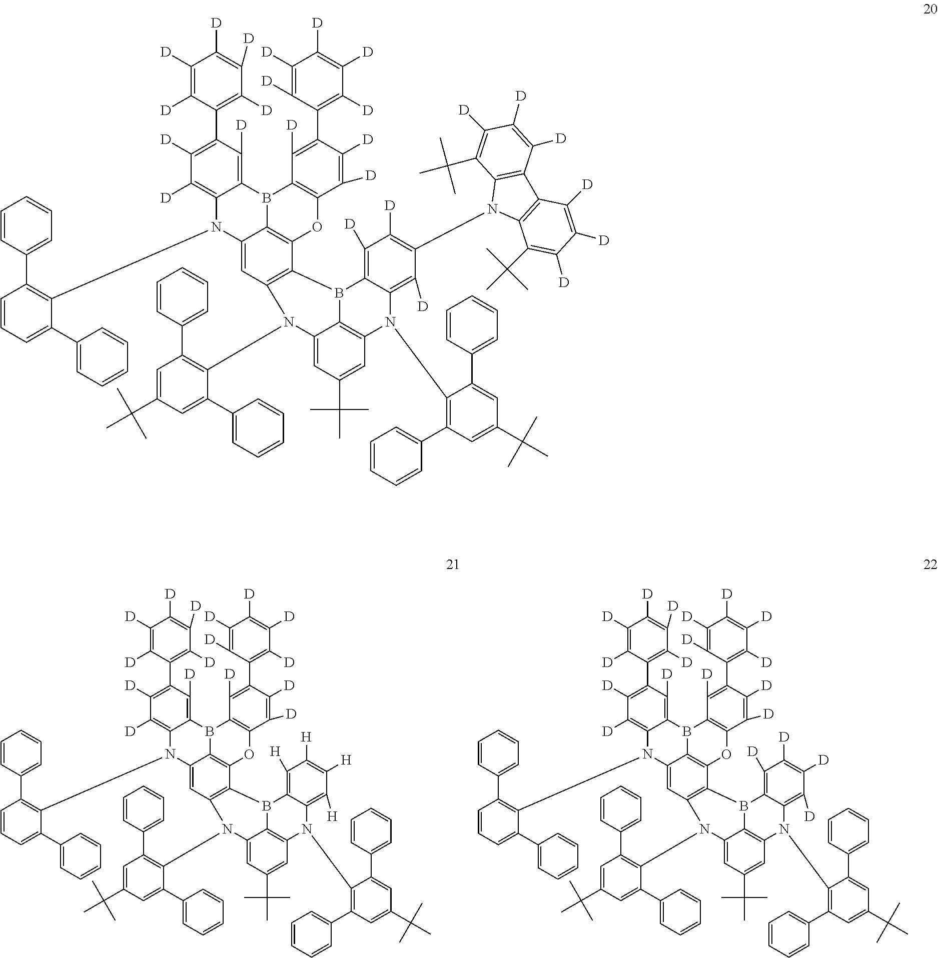 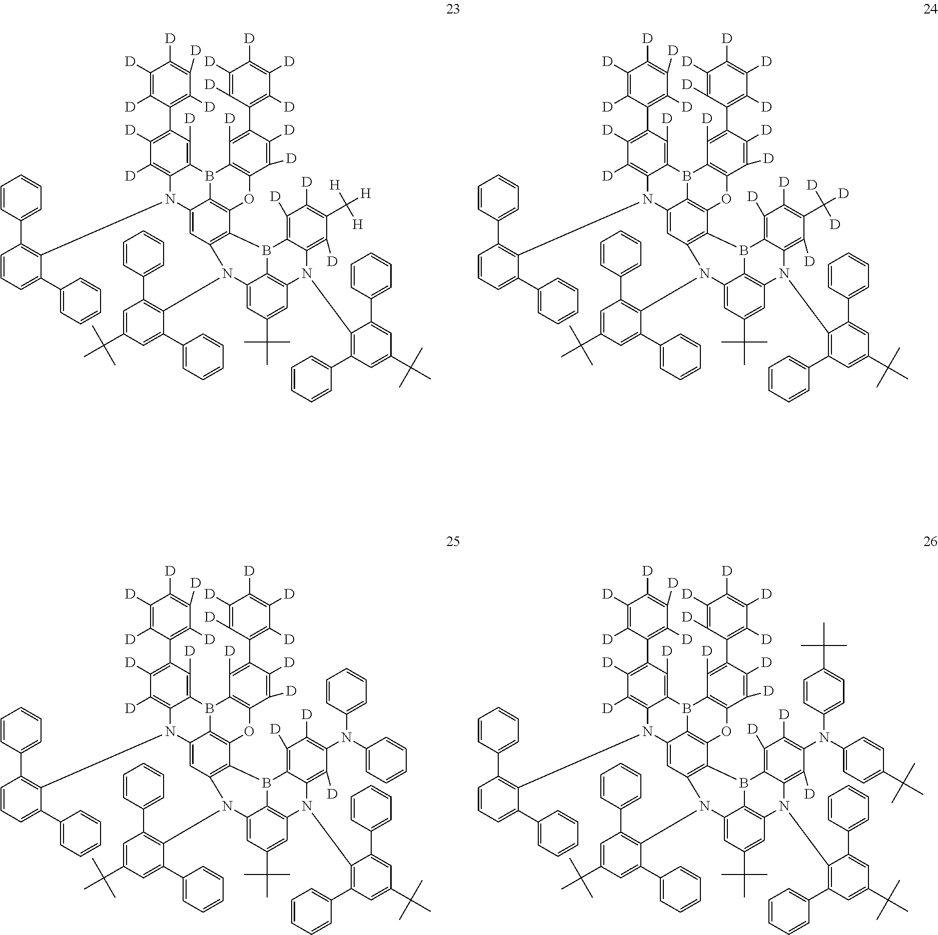 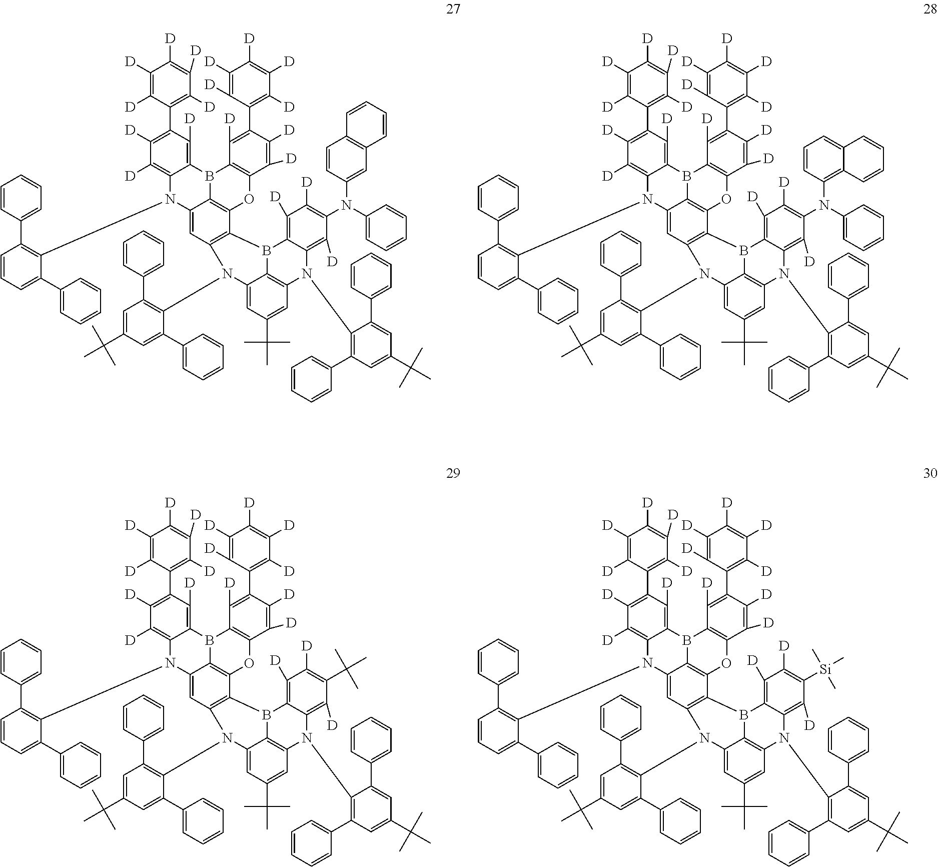 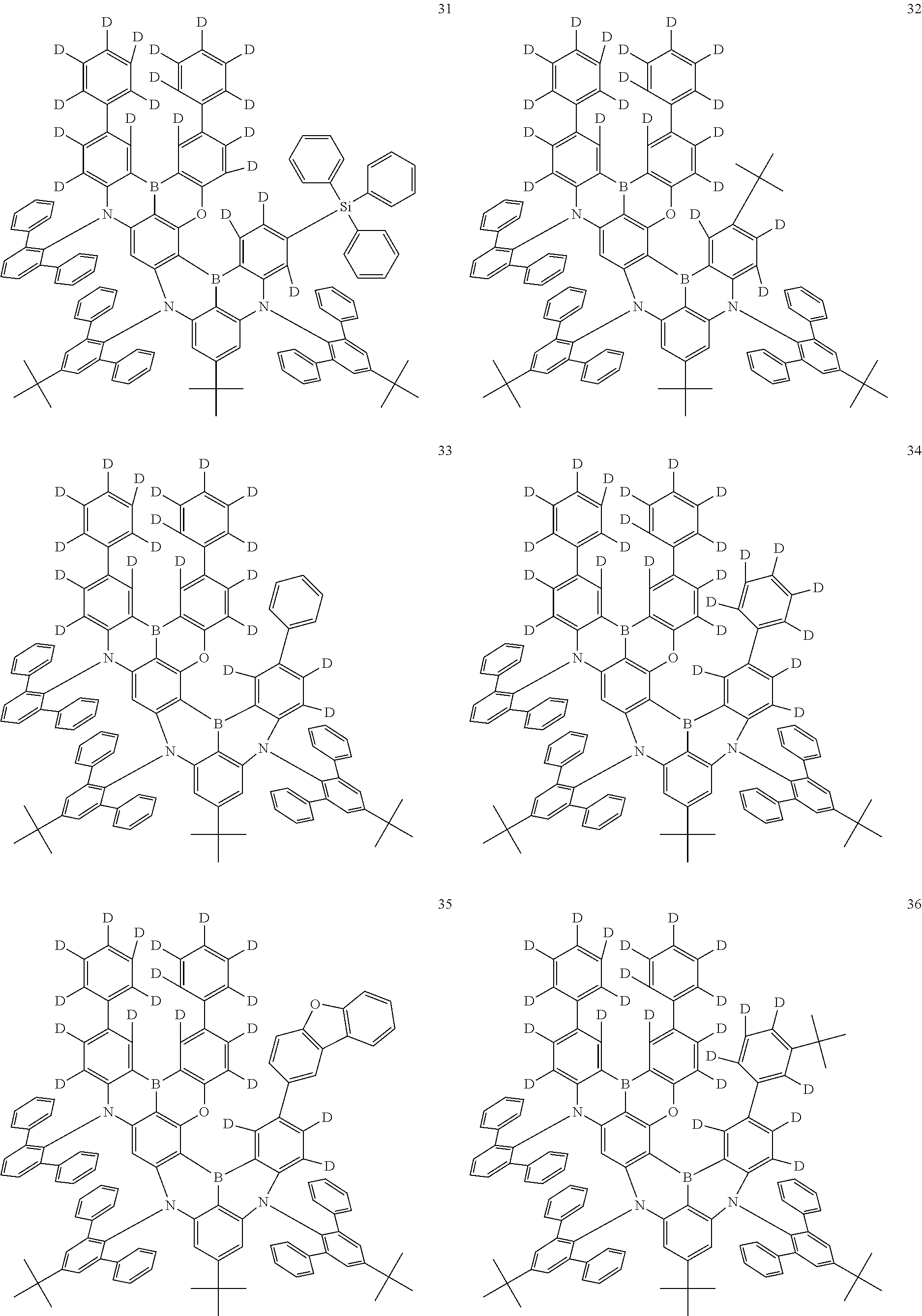 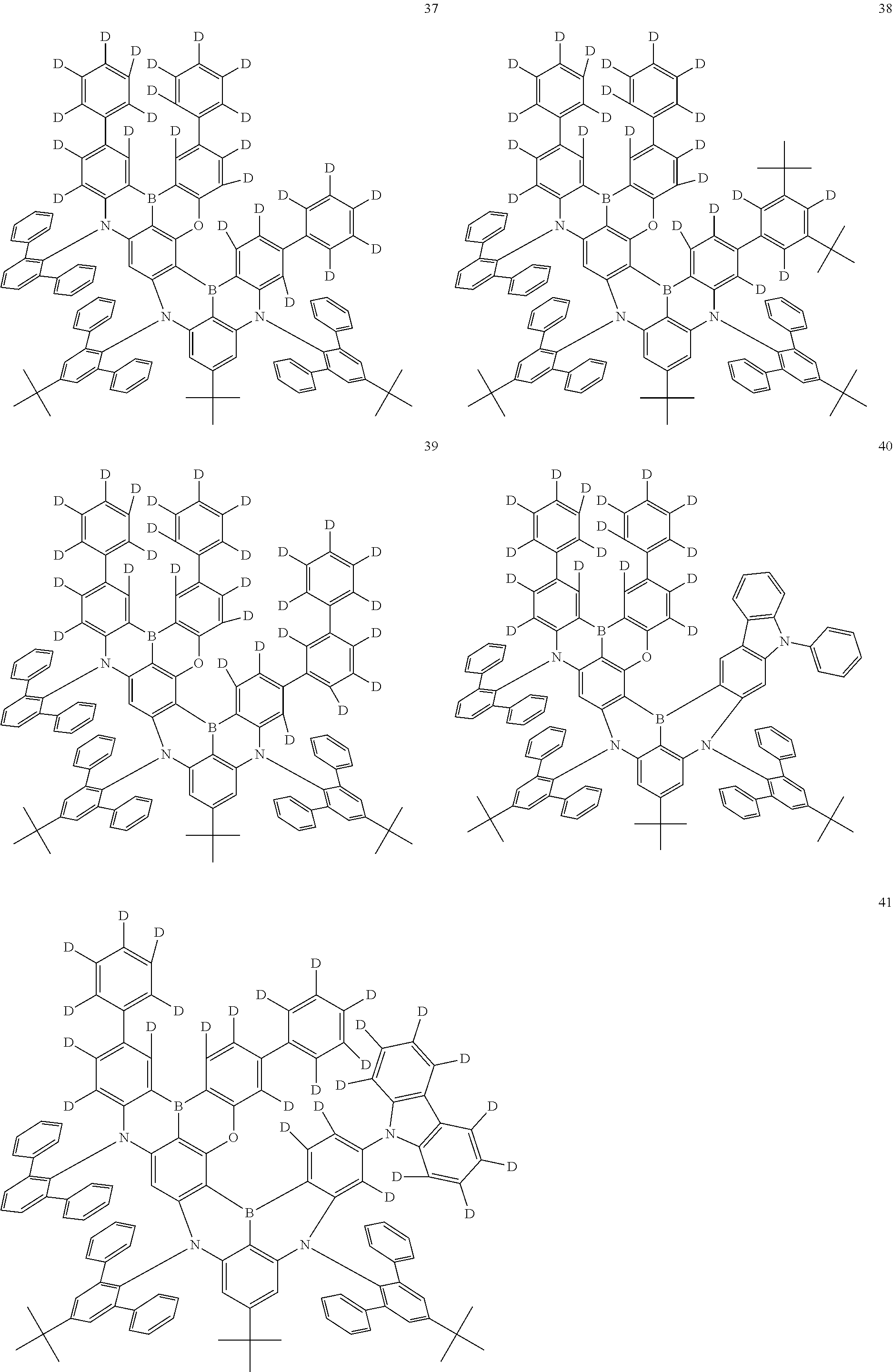 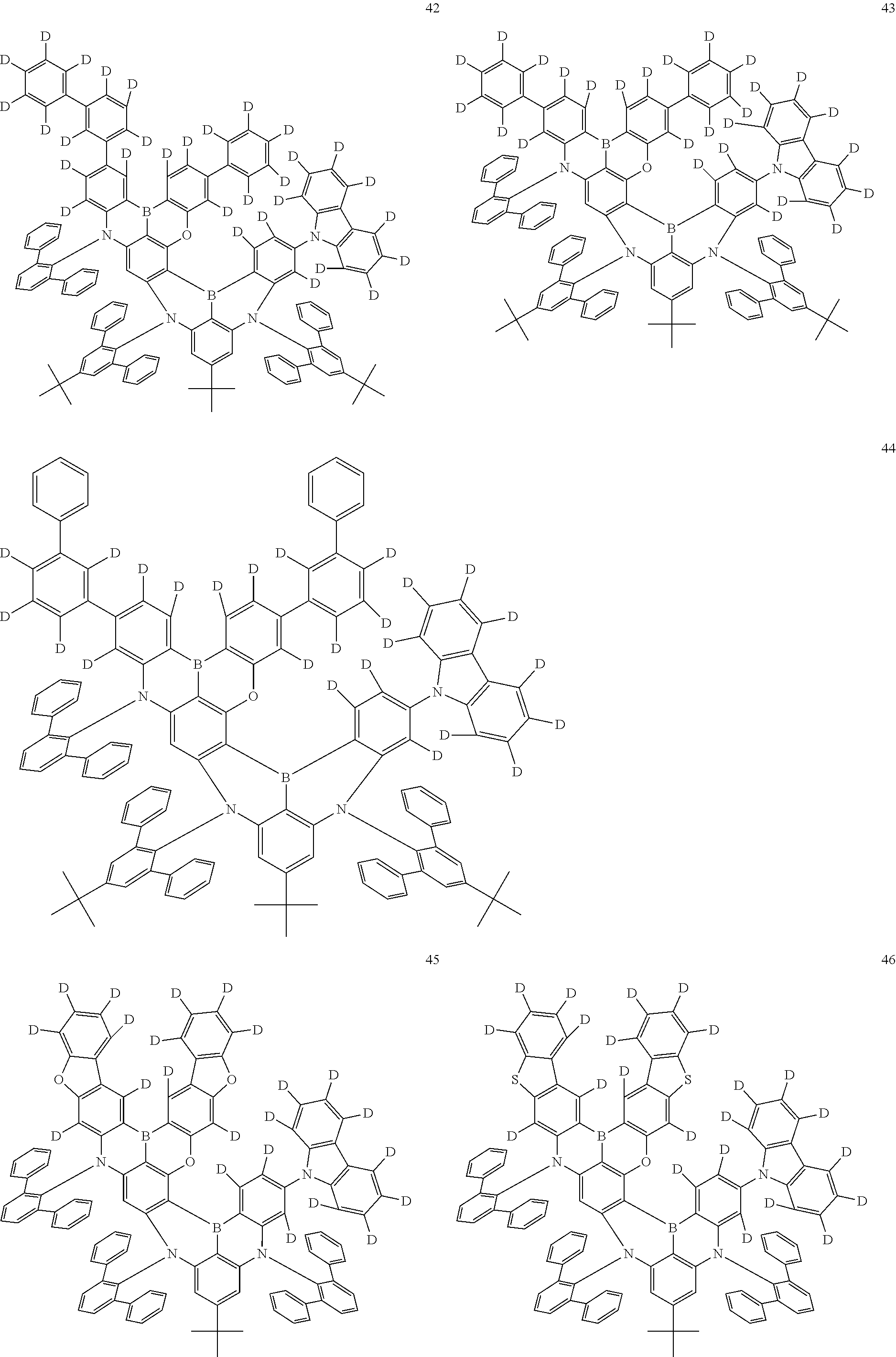 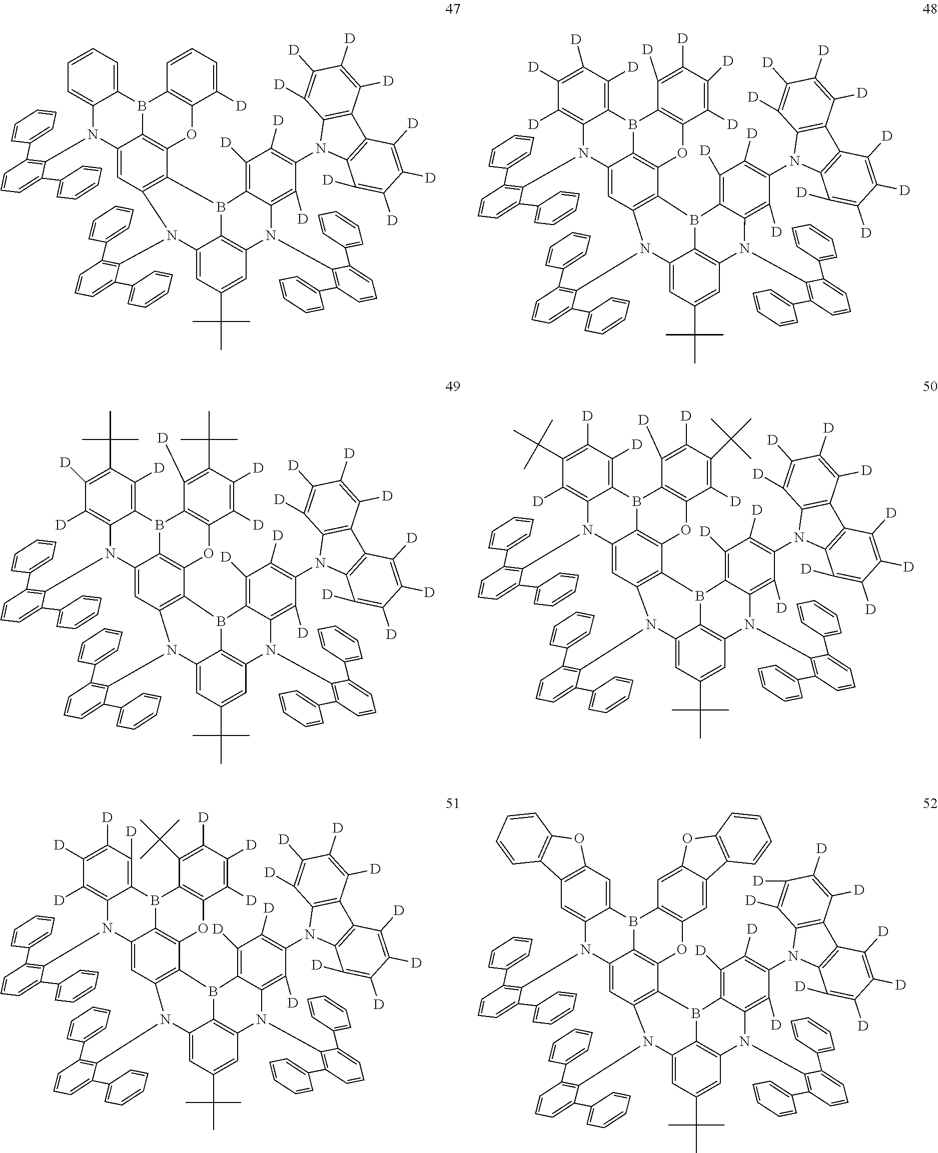 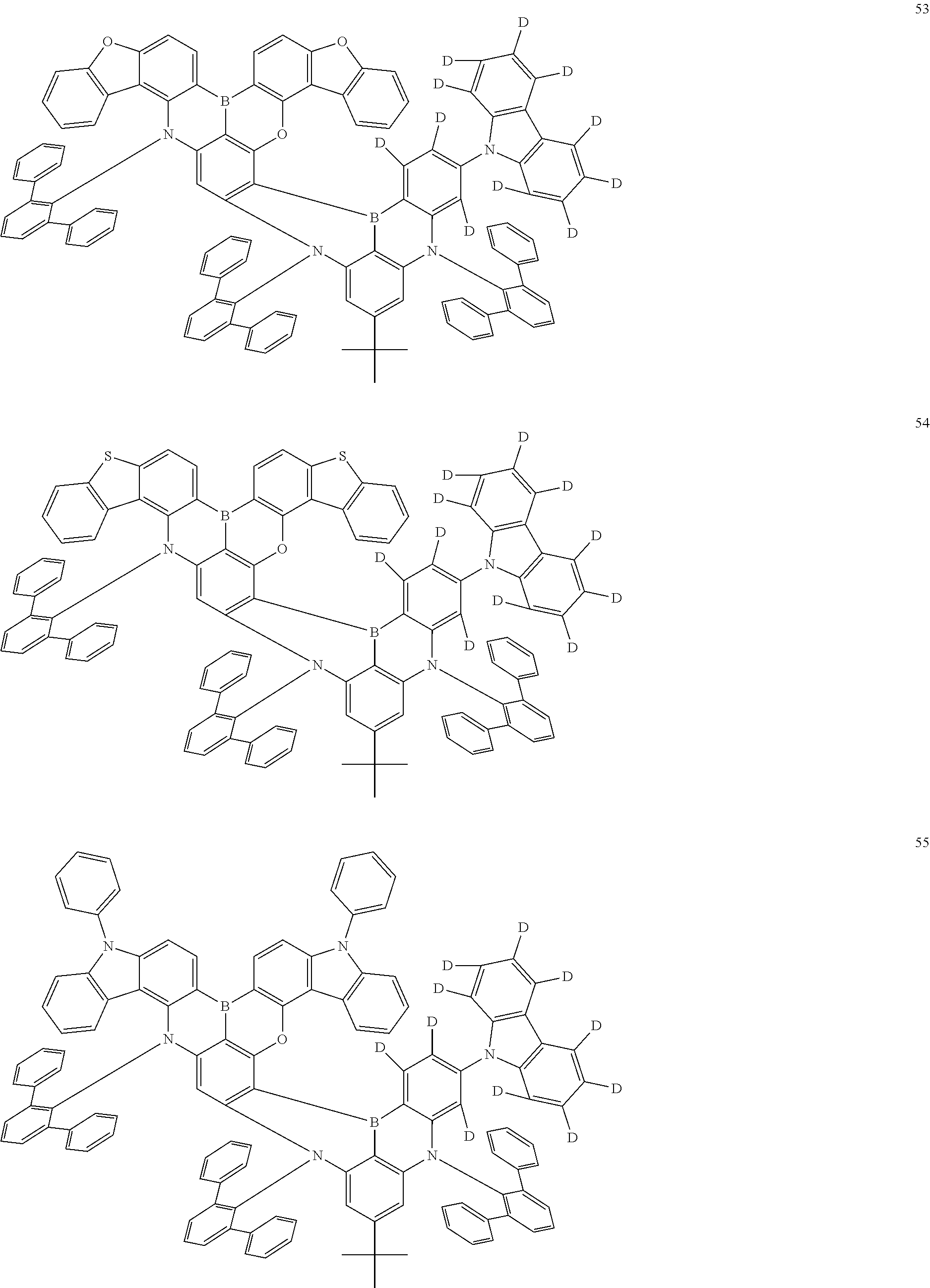 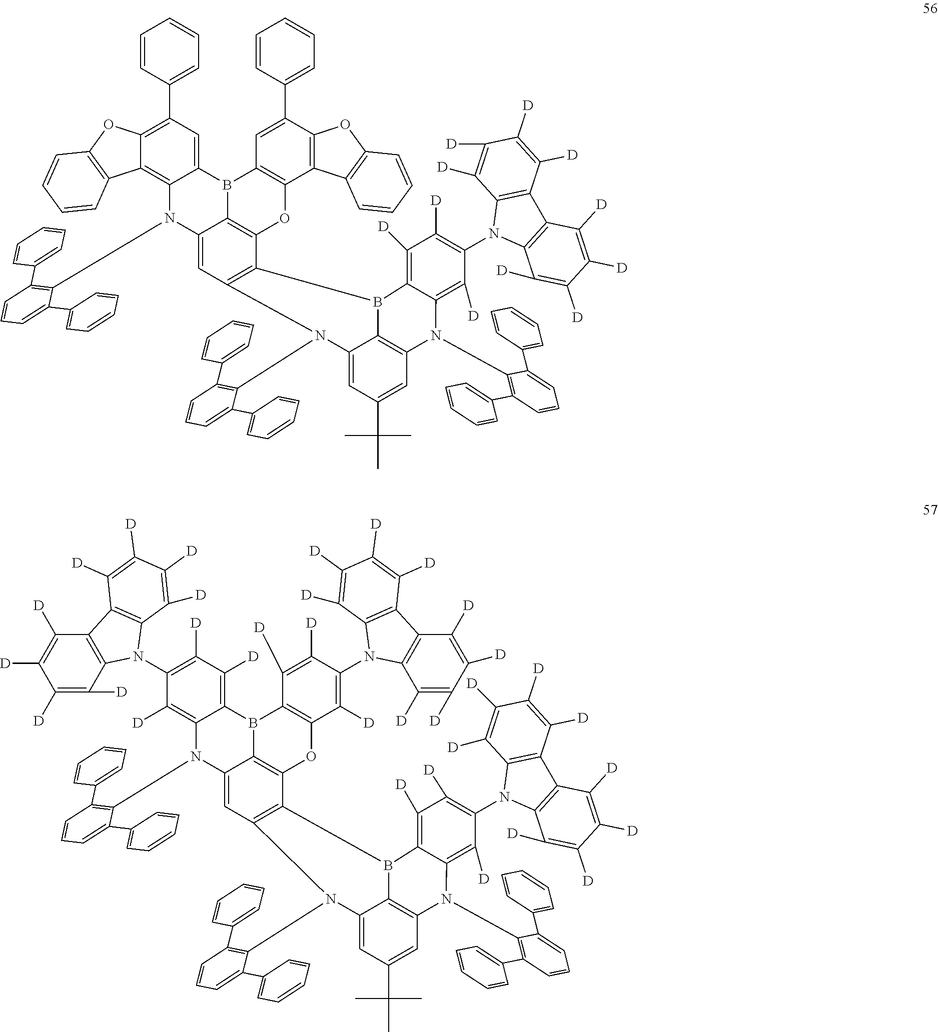 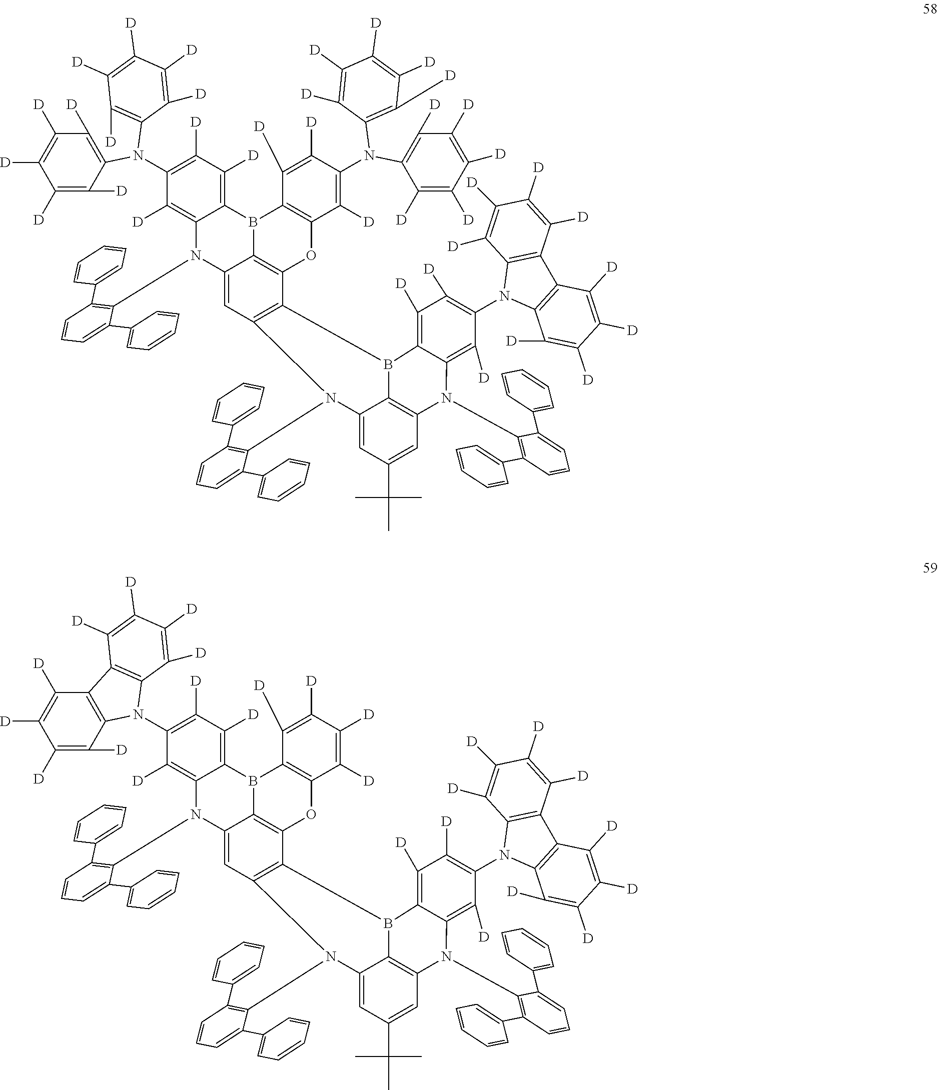 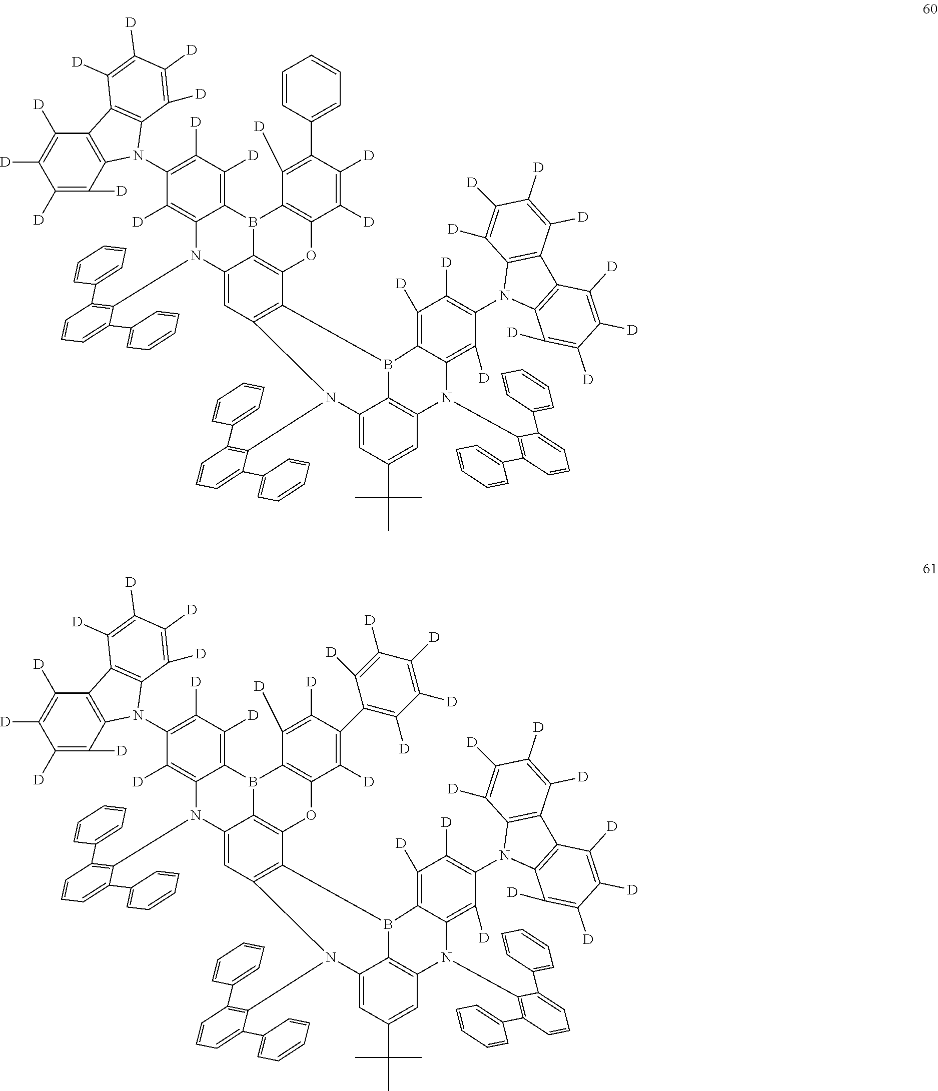 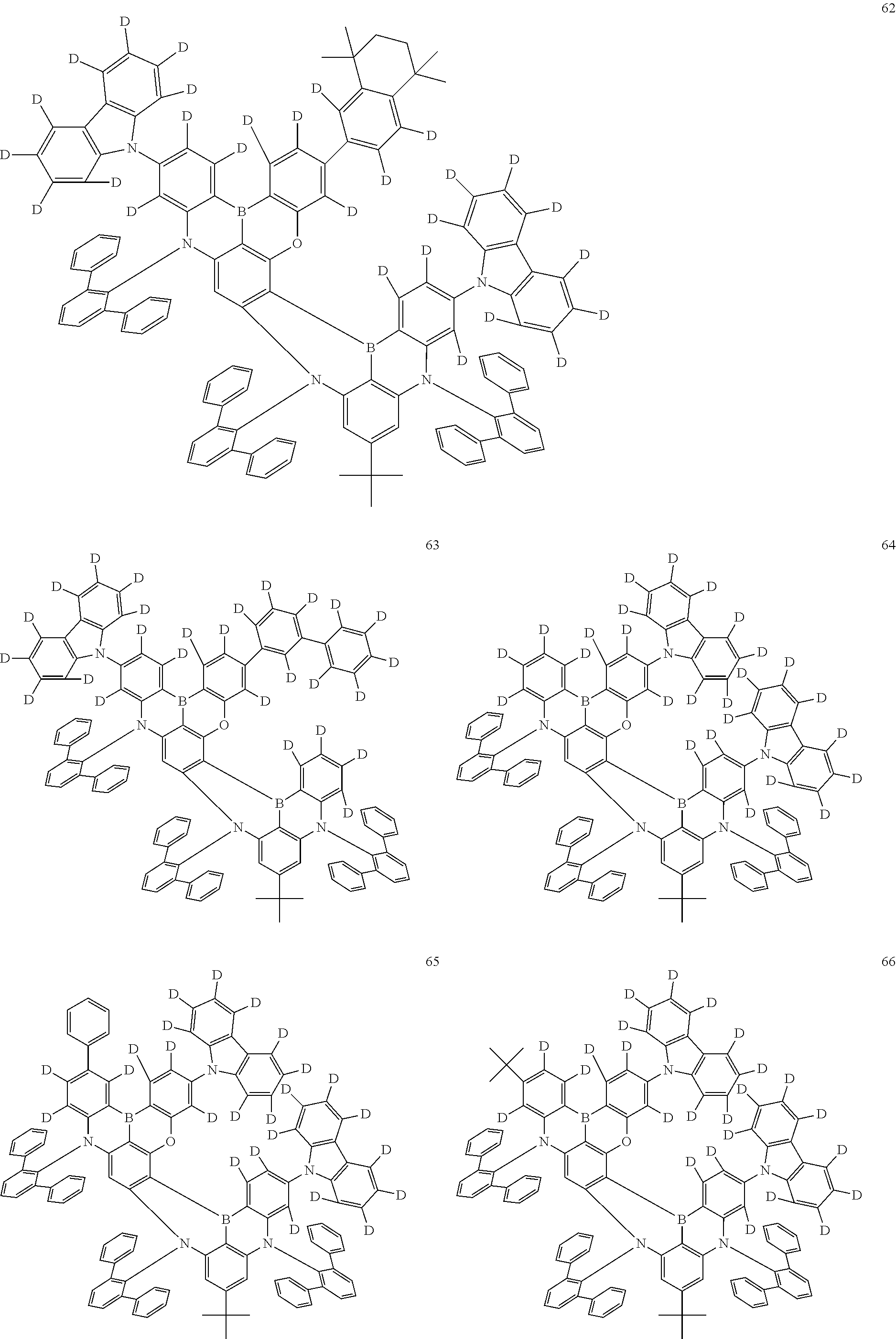 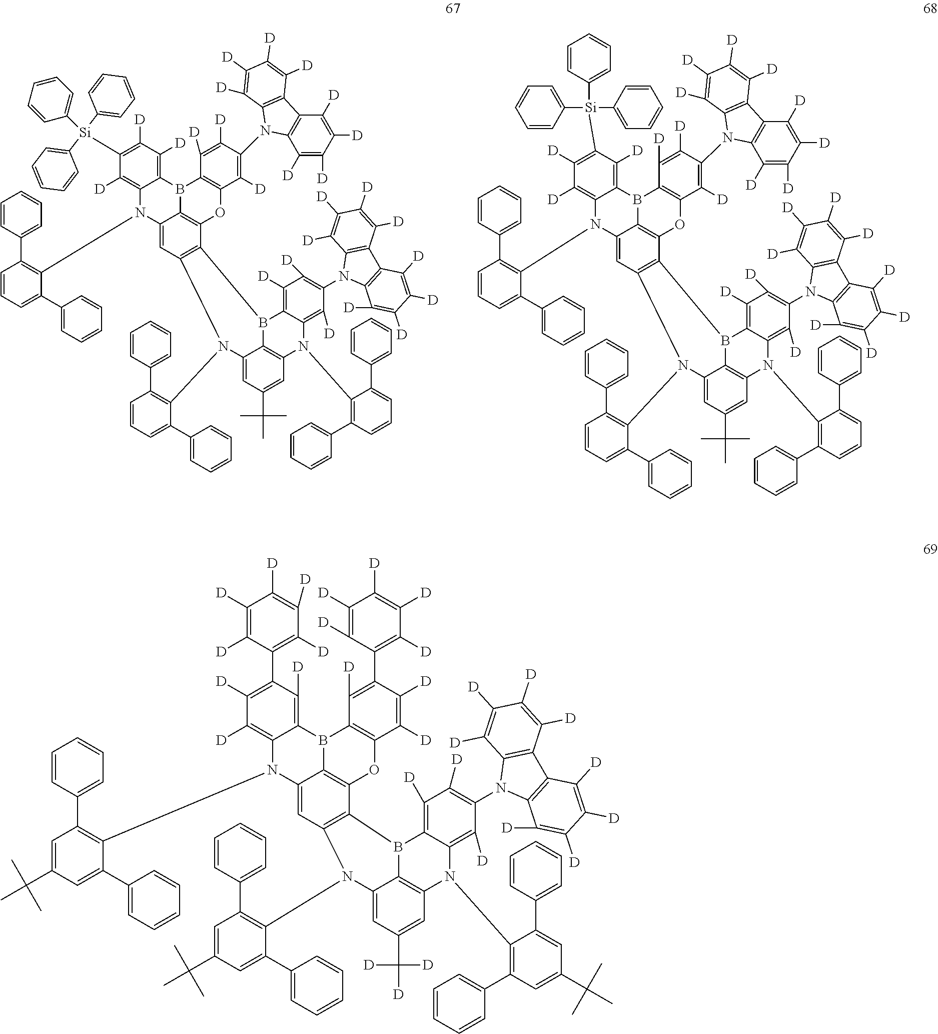 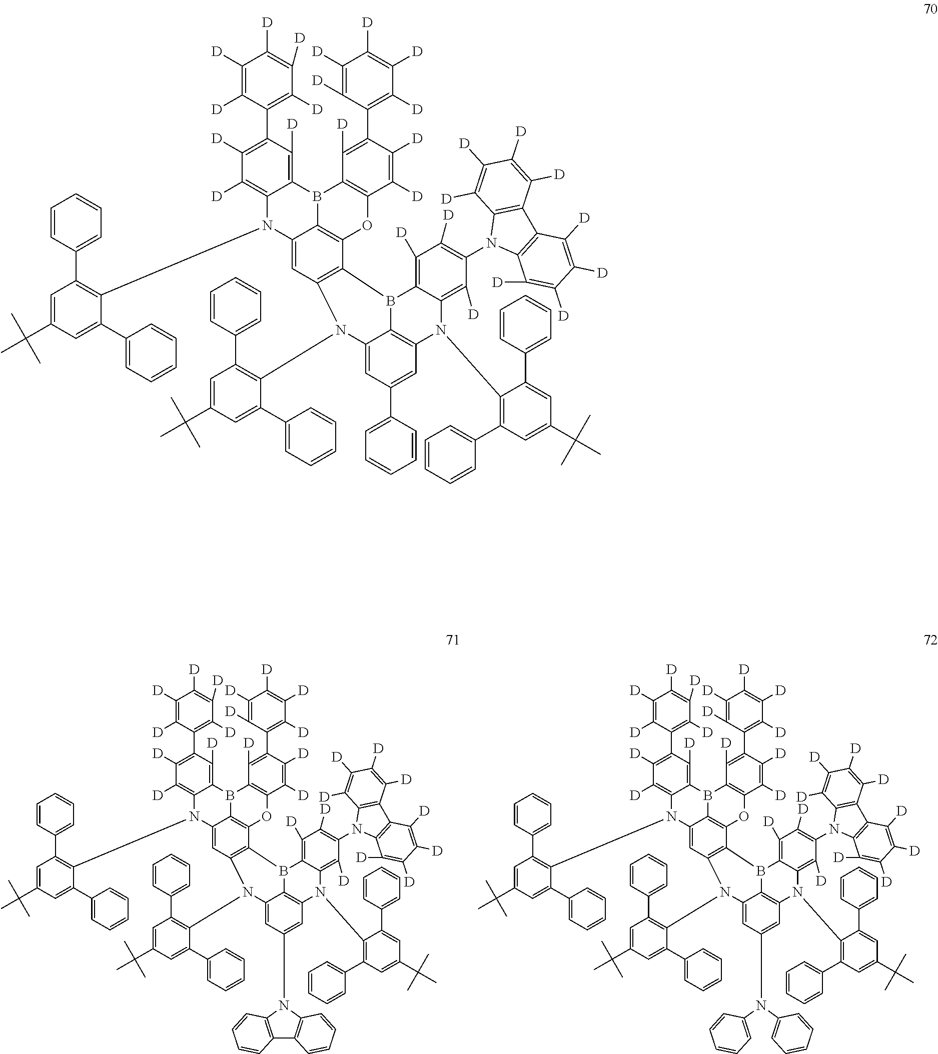 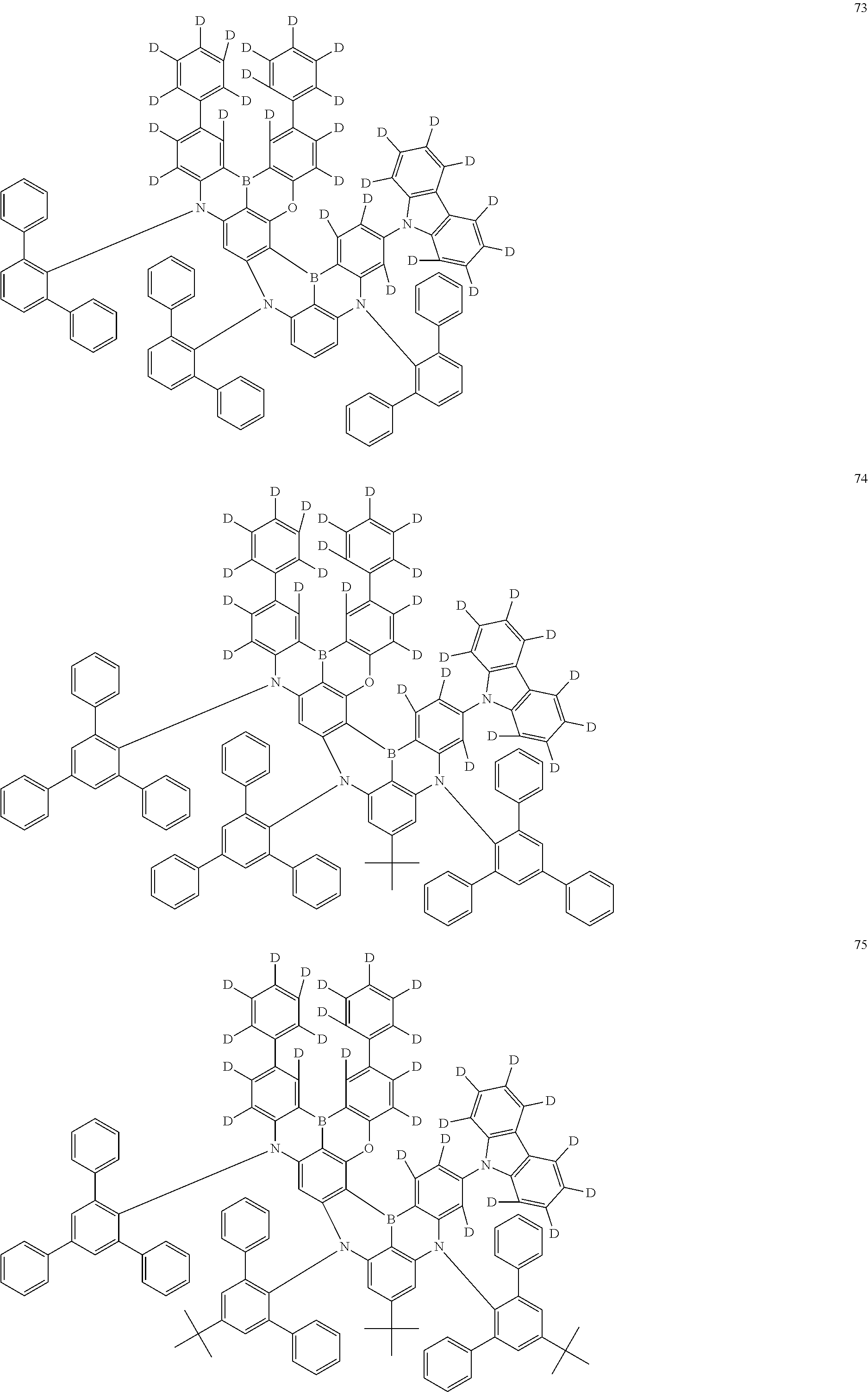 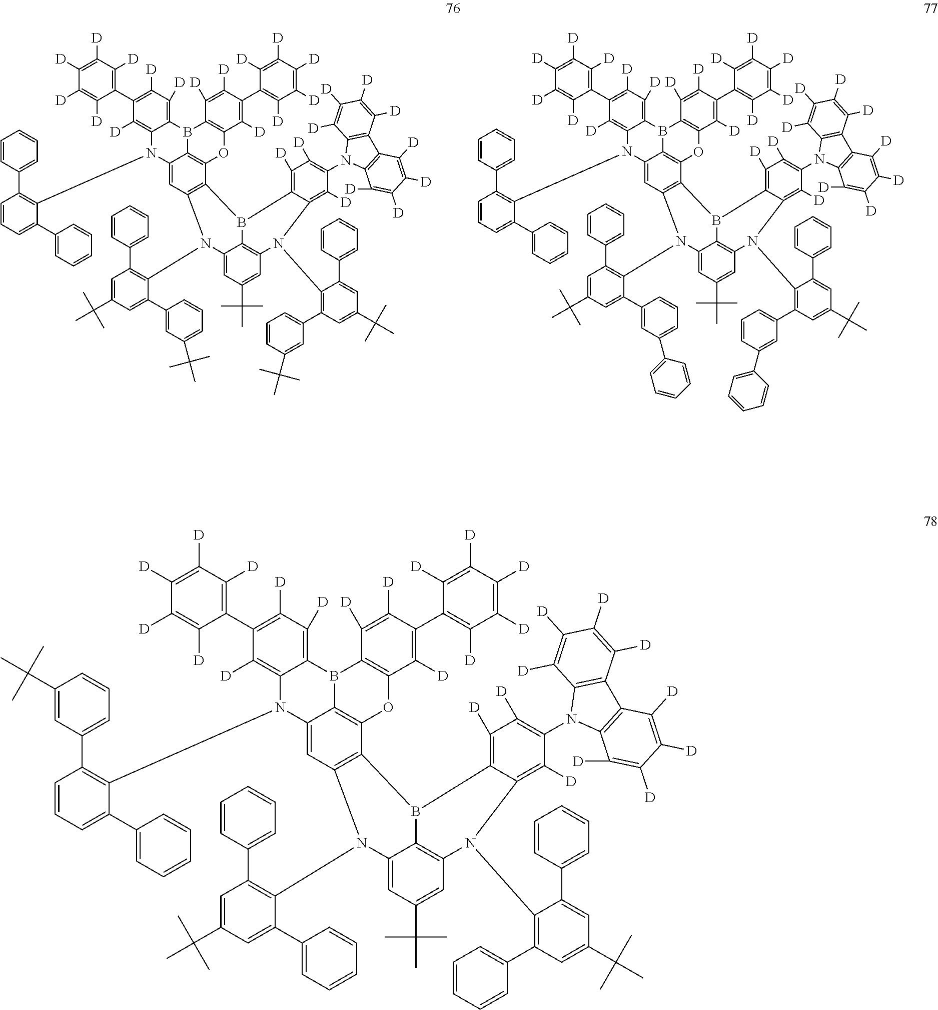 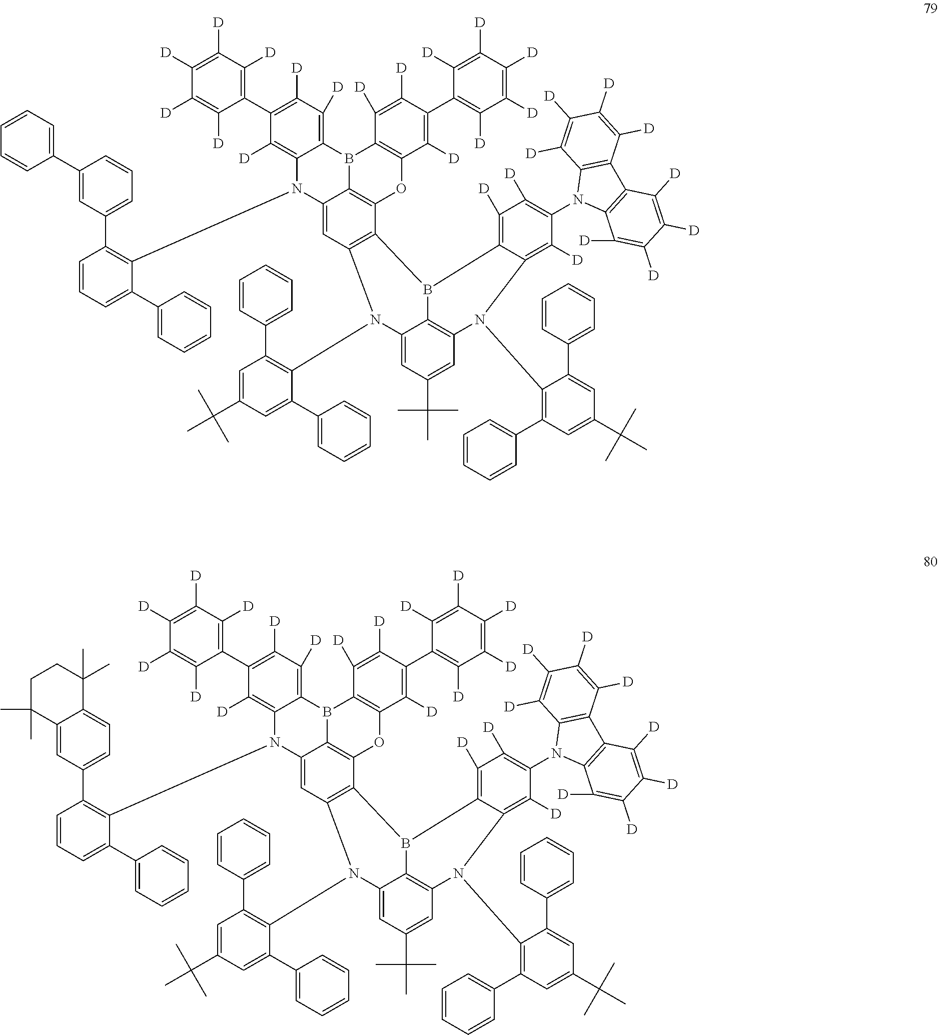
wherein in Compound Group 1,
D is a deuterium atom.

18. An electronic apparatus, comprising:
a circuit layer disposed on a base layer; and
a display element layer disposed on the circuit layer and including a light-emitting element, wherein
the light-emitting element includes:
a first electrode;
a second electrode disposed on the first electrode; and
an emission layer disposed between the first electrode and the second electrode and including a fused polycyclic compound represented by Formula 1: 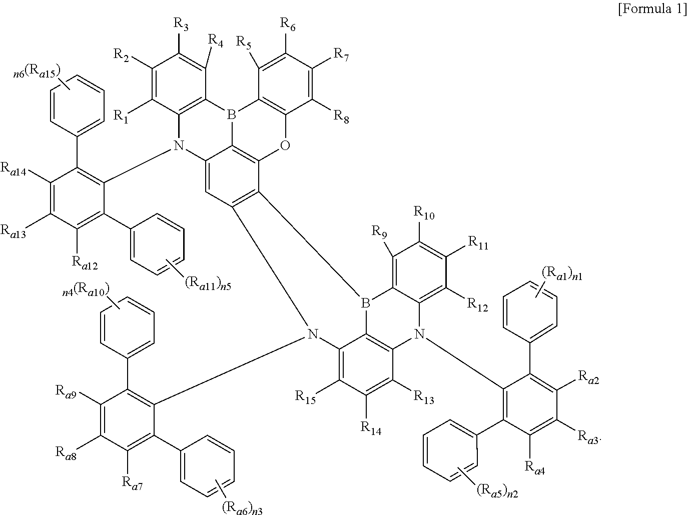
wherein in Formula 1,
n1 to n6 are each independently an integer from 0 to 5, and
R₁ to R₁₅ and Rₐ₁ to Rₐ₁₅ are each independently a hydrogen atom, a deuterium atom, a halogen atom, a cyano group, a nitro group, a substituted or unsubstituted silyl group, a substituted or unsubstituted amine group, a substituted or unsubstituted oxy group, a substituted or unsubstituted thio group, a substituted or unsubstituted selenium (Se) group, a substituted or unsubstituted alkyl group having 1 to 60 carbons, a substituted or unsubstituted cycloalkyl group having 3 to 60 carbons, a substituted or unsubstituted alkenyl group having 2 to 60 carbons, a substituted or unsubstituted hydrocarbon ring group having 6 to 60 ring-forming carbons, or a substituted or unsubstituted heterocyclic group having 2 to 60 ring-forming carbons, or bonded to an adjacent group to form a ring.

19. The electronic apparatus of claim 18, further comprising:
at least one of a light control layer and a color filter layer, wherein
the light control layer comprises a quantum dot, and
the color filter layer comprises a pigment or dye.

20. The electronic apparatus of claim 19, wherein
the light-emitting element emits first color light, and
the light control layer comprises:
a first light control part including a first quantum dot that converts the first color light into second color light that is different from the first color light;
a second light control part including a second quantum dot that converts the first color light into third color light that is different from the first color light and the second color light; and
a third light control part that transmits the first color light.
